(19) United States
(12) Patent Application Publication
(10) Pub. No.: US 2024/0337938 A1
(43) Pub. Date: Oct. 10, 2024

(54) RESIST COMPOSITION AND PATTERN FORMING PROCESS

(71) Applicant: Shin-Etsu Chemical Co., Ltd., Tokyo (JP)

(72) Inventors: Jun Hatakeyama, Joetsu-shi (JP); Takayuki Fujiwara, Joetsu-shi (JP)

(73) Assignee: Shin-Etsu Chemical Co., Ltd., Tokyo (JP)

(21) Appl. No.: 18/380,852

(22) Filed: Oct. 17, 2023

(30) Foreign Application Priority Data
Oct. 24, 2022 (JP) 2022-169769

(51) Int. Cl. G03F 7/039; C08F 212/14; C08F 220/18; C08F 220/22

(52) U.S. Cl. CPC G03F 7/0392; C08F 212/24; C08F 220/1806; C08F 220/22

(57) ABSTRACT

A resist composition comprising a base polymer containing repeat units (a) having a salt structure containing a sulfonic acid anion bonded to a polymer backbone and a sulfonium cation having formula (1).

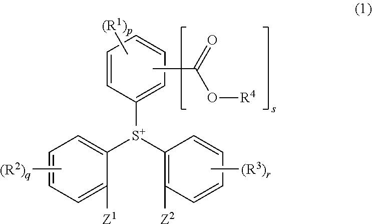

### CROSS-REFERENCE TO RELATED APPLICATIONS

This non-provisional application claims priority under 35 U.S.C. § 119(a) on Patent Application No. 2022-169769 filed in Japan on Oct. 24, 2022, the entire contents of which are hereby incorporated by reference.

### TECHNICAL FIELD

The present invention relates to a resist composition and a pattern forning process.

### BACKGROUND ART

To meet the demand for higher integration density and higher operating speed of LSIs, the effort to reduce the pattern rule is in rapid progress. As the use of 5G high-speed communications and artificial intelligence (AI) is widely spreading, high-performance devices are needed for their processing. As the most advanced miniaturization technology, mass production of microelectronic devices at the 5-nm node by the lithography using extreme ultraviolet (EUV) having a wavelength of 13.5 nm has been implemented. Studies are made on the application of EUV lithography to 3-nm node devices of the next generation and 2-nm node devices of the next-but-one generation. IMEC in Belgium announced its successful development of 1-nm and 0.7-nm node devices.

As the feature size reduces, image blurs due to acid diffusion become a problem. To ensure resolution for fine patterns of sub-45-nm size, not only an improvement in dissolution contrast is important as previously reported, but also the control of acid diffusion is important as reported in Non-Patent Document 1. Since chemically amplified resist compositions are designed such that sensitivity and contrast are enhanced by acid diffusion, an attempt to minimize acid diffusion by reducing the temperature and/or time of post exposure bake (PEB) fails, resulting in drastic reductions of sensitivity and contrast.

A triangular tradeoff relationship among sensitivity, resolution, and edge roughness (LWR) has been pointed out. Specifically, a resolution improvement requires to reduce acid diffusion whereas a short acid diffusion distance leads to a decline of sensitivity.

The addition of an acid generator capable of generating a bulky acid is an effective means for reducing acid diffusion. It was then proposed to incorporate repeat units derived from an onium salt having a polymerizable unsaturated bond in a polymer. Since this polymer functions as an acid generator, it is referred to as polymer-bound acid generator. Patent Document 1 discloses a sulfonium or iodonium salt having a polymerizable unsaturated bond and capable of generating a specific sulfonic acid. Patent Document 2 discloses a sulfonium salt having a sulfonic acid directly bonded to the backbone.

A resist composition has been proposed which has a triphenylsulfonium cation in which the 3-position of a phenyl group is substituted with an electron withdrawing group selected from a halogen atom, a halogenated alkyl group, an acyloxy group, an acyl group, a cyano group, a nitro group, and a sulfonyl group, and to which an acid generator that generates fluorosulfonic acid is added (Patent Document 3). In addition, a salt has been proposed which contains a triphenylsulfonium cation in which a phenyl group is substituted with an alkoxycarbonyl group, and a weak acid anion such as a carboxylic acid anion (Patent Document 4), and a salt has been proposed which contains a triphenylsulfonium cation in which a phenyl group is substituted with an alkoxycarbonyl group bonded to an aromatic group substituted with an iodine atom, and a strong acid anion such as a fluorosulfonic acid anion (Patent Document 5).

### CITATION LIST

Patent Document 1: JP-A 2006-045311
Patent Document 2: JP-A 2006-178317
Patent Document 3: JP 6244109
Patent Document 4: JP-A 2022-068394
Patent Document 5: JP-A 2020-046661
Non-Patent Document 1: SPIE Vol. 6520 65203L-1 (2007)

### SUMMARY OF THE INVENTION

For resist compositions, it is desired to develop an acid generator capable of improving the LWR of line patterns or the critical dimension uniformity (CDU) of hole patterns and enhancing sensitivity. For this purpose, it is necessary that a resist composition have high decomposition efficiency in exposure, reduce acid diffusion, and have high affinity with an alkaline developer.

The present invention has been made in view of the above circumstances, and an object of the present invention is to provide a resist composition, especially a positive resist composition which exhibits higher sensitivity and improved LWR or CDU, and a pattern forming process using the resist composition.

As a result of intensive studies to achieve the above object, the present inventors have found the following matter. That is, use of a base polymer containing repeat units (a) having a salt structure containing a sulfonic acid anion bonded to a polymer backbone and a triphenylsulfonium cation in which at least one phenyl group is substituted with a predetermined hydrocarbyloxycarbonyl group provides low acid diffusibility due to a sulfonic acid bonded to the polymer backbone and generated by exposure, and the electron withdrawing property of the hydrocarbylcarbonyl group. Therefore, the resist composition has high decomposition efficiency in exposure, reduces acid diffusion, and has high affinity with an alkaline developer, and thus, provides properties such as high sensitivity, reduced acid diffusion, high contrast, and low swelling. As a result, the present inventors have found that the LWR and CDU are improved, and a resist composition excellent in high sensitivity and resolution and having a wide process margin can be obtained, thereby completing the present invention.

That is, the present invention provides the following resist composition and pattern forming process.

1. A resist composition comprising a base polymer containing repeat units (a) having a salt structure containing a sulfonic acid anion bonded to a polymer backbone and a sulfonium cation having formula (1):

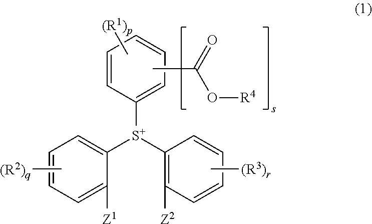

wherein p, q, and r are each independently an integer of 0 to 3, and s is 1 or 2, provided that 1≤r+s≤3,
R¹ is a halogen atom, a trifluoromethyl group, a trifluoromethoxy group, a trifluoromethylthio group, a nitro group, a cyano group, —C(═O)—R⁵, —O—C(═O)—R⁵, or —O—R⁵,
R² and R³ are each independently a halogen atom, a trifluoromethyl group, a trifluoromethoxy group, a trifluoromethylthio group, a nitro group, a cyano group. —C(═O)—O—R⁴, —C(═O)—R, —O—C(═O)—R⁵, —O—C(═O)—O—R. or —O—R⁵,
R⁴ is a C₁-C₁₀ aliphatic hydrocarbyl group, a C₆-C₁₂ aryl group, or a C₄-C₁₂ heteroaryl group, some or all of hydrogen atoms of these groups may be substituted with a halogen atom other than an iodine atom, a hydroxy group, a cyano group, a nitro group, a halogenated alkyl group, a halogenated alkoxy group, or a halogenated alkylthio group, and some of —CH₂— of these groups may be substituted with an ether bond, an ester bond, a carbonyl group, or a sulfonic ester bond, provided that R⁴ is not an acid labile group,
R⁵ is a C₁-C₁₀ hydrocarbyl group, and
Z¹ and Z² are each independently a hydrogen atom, a halogen atom, a trifluoromethyl group, a trifluoromethoxy group, a trifluoromethylthio group, a nitro group, a cyano group, —C(═O)—O—R⁴, —C(═O)—R⁵, —O—C(═O)—R⁵, —O—C(═O)—O—R⁵, or —O—R⁵, and Z¹ and Z² may together form a single bond, an ether bond, a carbonyl group, —N(R^{N})—, a sulfide bond, or a sulfonyl group, wherein R^{N} is a hydrogen atom or a C₁-C₆ saturated hydrocarbyl group.

2. The resist composition of item 1, wherein the repeat units (a) have formula (a1) or (a2):

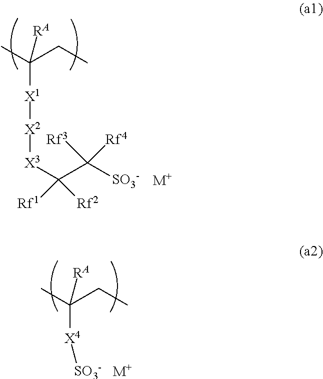

wherein R^{A} is each independently a hydrogen atom or a methyl group,
X¹ is a single bond or an ester bond,
X² is a single bond, —X²¹—C(═O)—O—, or —X²¹—O—, wherein X²¹ is a C₁-C₁₂ hydrocarbylene group, a phenylene group, or a C₇-C₁₈ group obtained by combining the foregoing, which may contain a carbonyl group, a nitro group, a cyano group, an ester bond, an ether bond, a urethane bond, a fluorine atom, an iodine atom, or a bromine atom,
X³ is a single bond, a methylene group, or an ethylene group,
X⁴ is a single bond, a methylene group, an ethylene group, a phenylene group, a methylphenylene group, a dimethylphenylene group, a fluorinated phenylene group, a trifluoromethyl-substituted phenylene group, —O—X⁴¹—, —C(═O)—O—X⁴¹—, or —C(═O)—NH—X⁴¹—, wherein X⁴¹ is a C₁-C₆ aliphatic hydrocarbylene group, a phenylene group, a methylphenylene group, a dimethylphenylene group, a fluorinated phenylene group, or a trifluoromethyl-substituted phenylene group, which may contain a carbonyl group, an ester bond, an ether bond, a hydroxy group, or a halogen atom,
Rf¹ to Rf⁴ are each independently a hydrogen atom, a fluorine atom, or a trifluoromethyl group, at least one of Rf¹ to Rf⁴ is a fluorine atom or a trifluoromethyl group, and Rf¹ and Rf² may together form a carbonyl group, and
M⁺ is the sulfonium cation having formula (1).

3. The resist composition of item 1 or 2, wherein the base polymer further contains repeat units having formula (b1) or repeat units having formula (b2):

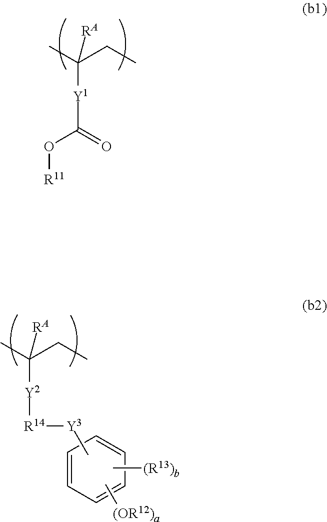

wherein R^{A} is each independently a hydrogen atom or a methyl group,
Y¹ is a single bond, a phenylene group, a naphthylene group, or a C₁-C₁₂ linking group containing at least one moiety selected from an ester bond, an ether bond, and a lactone ring,
Y² is a single bond or an ester bond,
Y³ is a single bond, an ether bond, or an ester bond,
R¹¹ and R¹² are each independently an acid labile group,
R¹³ is a fluorine atom, a trifluoromethyl group, a cyano group, a C₁-C₆ saturated hydrocarbyl group, a C₁-C₆ saturated hydrocarbyloxy group, a C₁-C₇ saturated hydrocarbylcarbonyl group, a C₂-C₇ saturated hydrocarbylcarbonyloxy group, or a C₂-C₇ saturated hydrocarbyloxycarbonyl group,
R¹⁴ is a single bond or a C₁-C₆ alkanediyl group in which some constituent —CH₂— may be substituted with an ether bond or an ester bond, and
a is 1 or 2, and b is an integer of 0 to 4, provided that 1 s a+b≤5.

4. The resist composition of item 3, which is a chemically amplified positive resist composition.

5. The resist composition of any one of items 1 to 4, further comprising an organic solvent.

6. The resist composition of any one of items 1 to 5, further comprising a surfactant.

7. A pattern forming process comprising the steps of:
applying the resist composition of any one of items 1 to 6 onto a substrate to form a resist film thereon,
exposing the resist film to high-energy radiation, and
developing the exposed resist film in a developer.

8. The pattern forming process of item 7, wherein the high-energy radiation is KrF excimer laser, ArF excimer laser, electron beam (EB), or EUV having a wavelength of 3 to 15 nm.

### Advantageous Effects of the Invention

In the resist composition comprising a base polymer containing repeat units (a), when the base polymer further contains an acid labile group, an acid is generated upon exposure, and a polarity switch occurs due to the acid-catalyzed reaction, whereby the alkali dissolution rate is increased. In the unexposed region, the repeat unit (a) itself is not dissolved in the developer. In the exposed region, a carboxy group is generated under the action of the acid generated by the repeat unit (a), whereby the alkali dissolution rate is increased. Accordingly, a resist composition having improved LWR and CDU is formulated.

### DETAILED DESCRIPTION OF THE INVENTION

### Resist Composition

The resist composition of the present invention comprises a base polymer containing repeat units (a) having a salt structure containing a sulfonic acid anion bonded to a polymer backbone and a triphenylsulfonium cation in which at least one phenyl group is substituted with a predetermined hydrocarbyloxycarbonyl group. Since the repeat unit (a) fumctions as an acid generator, the base polymer is a polymer-bound acid generator.

### Base Polymer

The triphenylsulfonium cation contained in the repeat units (a) have formula (1).

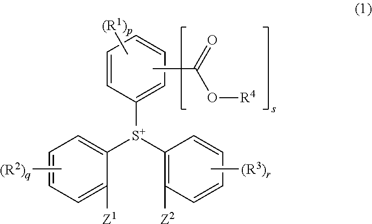

In formula (1), p, q, and r are each independently an integer of 0 to 3, and s is 1 or 2, provided that 1≤r+s≤3.

In formula (1), R¹ is a halogen atom, a trifluoromethyl group, a trifluoromethoxy group, a trifluoromethylthio group, a nitro group, a cyano group. —C(═O)—R⁵, —O—C(═O)—R⁵, or —O—R⁵.

In formula (1). R² and R³ are each independently a halogen atom, a trifluoromethyl group, a trifluoromethoxy group, a trifluoromethylthio group, a nitro group, a cyano group, —C(═O)—O—R⁴, —C(═O)—R⁵, —O—C(═O)—R⁵, —O—C(═O)—O—R⁵, or —O—R⁵.

In formula (1), R⁴ is a C₁-C₁₀ aliphatic hydrocarbyl group, a C₆-C₁₂ aryl group, or a C₄-C₁₂ heteroaryl group, some or all of hydrogen atoms of these groups may be substituted with a halogen atom other than an iodine atom, a hydroxy group, a cyano group, a nitro group, a halogenated alkyl group, a halogenated alkoxy group, or a halogenated alkylthio group, and some of —CH₂— of these groups may be substituted with an ether bond, an ester bond, a carbonyl group, or a sulfonic ester bond.

The C₁-C₁₀ aliphatic hydrocarbyl group represented by R⁴ may be saturated or unsaturated, and may be straight, branched, or cyclic. Examples thereof include C₁-C₁₀ alkyl groups such as a methyl group, an ethyl group, a n-propyl group, an isopropyl group, a n-butyl group, an isobutyl group, a sec-butyl group, a n-pentyl group, an isopentyl group, a sec-pentyl group, a 3-pentyl group, a neopentyl group, a n-hexyl group, a n-octyl group, a n-nonyl group, and a n-decyl group; C₃-C₁₀ cyclic saturated hydrocarbyl groups such as a cyclopropyl group, a cyclobutyl group, a cyclopentyl group, a cyclohexyl group, an adamantyl group, a norbornyl group, a cyclopropyhmethyl group, a cyclopropylethyl group, a cyclobutylmethyl group, a cyclobutylethyl group, a cyclopentylnethyl group, a cyclopentylethyl group, a cyclohexylmethyl group, a cyclohexylethyl group, a methylcyclopropyl group, a methylcyclobutyl group, a methylcyclopentyl group, a methylcyclohexyl group, an ethylcyclopropyl group, an ethylcyclobutyl group, an ethylcyclopentyl group, and an ethylcyclohexyl group; C₂-C₁₀ alkenyl groups such as a vinyl group, a 1-propenyl group, a 2-propenyl group, a butenyl group, a pentenyl group, a hexenyl group, a heptenyl group, a nonenyl group, and a decenyl group; C₂-C₁₀ alkynyl groups such as an ethynyl group, a propynyl group, a butynyl group, a pentynyl group, a hexynyl group, a heptynyl group, an octynyl group, a nonynyl group, and a decynyl group; C₃-C₁₀ cyclic unsaturated aliphatic hydrocarbyl groups such as a cyclopentenyl group, a cyclohexenyl group, a methylcyclopentenyl group, a methylcyclohexenyl group, an ethylcyclopentenyl group, an ethylcyclohexenyl group, and a norbomenyl group; and groups obtained by combining the foregoing.

Examples of the C₆-C₁₂ aryl group represented by R⁴ include a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, an indanyl group, and a tetralinyl group. Examples of the C₄-C₁₂ heteroaryl group represented by R⁴ include a furyl group and a thienyl group.

R⁴ is not an acid labile group. For example, the following 1) to 3) correspond to the case where R⁴ is an acid labile group.

1) The carbon atom bonded to the oxygen atom of the ester bond is a tertiary carbon atom, and the alkyl group bonded to the tertiary carbon atom does not contain a halogen atom, a cyano group, or a nitro group.

2) The carbon atom bonded to the oxygen atom of the ester bond is a secondary carbon atom, and R⁴ has a cyclic structure containing the secondary carbon atom, does not contain a heteroatom such as an oxygen atom, a sulfur atom, a nitrogen atom, or a halogen atom, and has a double bond, a triple bond, or an aromatic group on a carbon atom other than the carbon atom bonded to the oxygen atom of the ester bond.

3) R⁴ is an acetal group having an ether bond next to the carbon atom bonded to the oxygen atom of the ester bond.

R⁵ is a C₁-C₁₀ hydrocarbyl group. The hydrocarbyl group may be saturated or unsaturated, and may be straight, branched, or cyclic. Examples thereof include C₁-C₁₀ alkyl groups such as a methyl group, an ethyl group, a n-propyl group, an isopropyl group, a n-butyl group, an isobutyl group, a sec-butyl group, a tert-butyl group, a n-pentyl group, an isopentyl group, a sec-pentyl group, a 3-pentyl group, a tert-pentyl group, a neopentyl group, a n-hexyl group, a n-octyl group, a n-nonyl group, and a n-decyl group; C₃-C₁₀ cyclic saturated hydrocarbyl groups such as a cyclopropyl group, a cyclobutyl group, a cyclopentyl group, a cyclohexyl group, an adamantyl group, a norbornyl group, a cyclopropylmethyl group, a cyclopropylethyl group, a cyclobutyhnethyl group, a cyclobutylethyl group, a cyclopentylmethyl group, a cyclopentylethyl group, a cyclohexylmethyl group, a cyclohexylethyl group, a methylcyclopropyl group, a methylcyclobutyl group, a methylcyclopentyl group, a methylcyclohexyl group, an ethylcyclopropyl group, an ethylcyclobutyl group, an ethylcyclopentyl group, and an ethylcyclohexyl group; C₂-C₁₀ alkenyl groups such as a vinyl group, a 1-propenyl group, a 2-propenyl group, a butenyl group, a pentenyl group, a hexenyl group, a heptenyl group, a nonenyl group, and a decenyl group; C₂-C₁₀ alkynyl groups such as an ethynyl group, a propynyl group, a butynyl group, a pentynyl group, a hexynyl group, a heptynyl group, an octynyl group, a nonynyl group, and a decynyl group; C₃-C₁₀ cyclic unsaturated aliphatic hydrocarbyl groups such as a cyclopentenyl group, a cyclohexenyl group, a methylcyclopentenyl group, a methylcyclohexenyl group, an ethylcyclopentenyl group, an ethylcyclohexenyl group, and a norbornenyl group; C₆-C₁₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, and a naphthyl group; C₇-C₁₀ aralkyl groups such as a benzyl group, a phenethyl group, a phenylpropyl group, and a phenylbutyl group; and groups obtained by combining the foregoing.

In formula (1), Z¹ and Z² are each independently a hydrogen atom, a halogen atom, a trifluoromethyl group, a trifluoromethoxy group, a trifluoromethylthio group, a nitro group, a cyano group, —C(═O)—O—R⁴, —C(═O)—R⁵, —O—C(═O)—R⁵, —O—C(═O)—O—R⁵, or —O—R⁵. Z¹ and Z² may together form a single bond, an ether bond, a carbonyl group, —N(R^{N})—, a sulfide bond, or a sulfonyl group. R^{N} is a hydrogen atom or a C₁-C₆ saturated hydrocarbyl group.

Examples of the structure formed by Z¹ and Z² together in the sulfonium cation having formula (1) include those shown below.

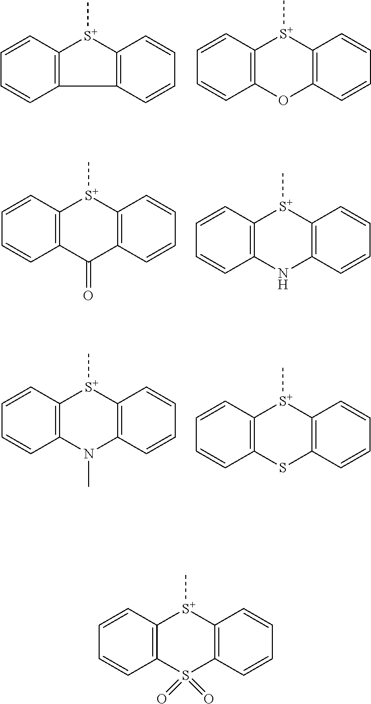

In the formulae, a broken line designates a bond.

Examples of the sulfonium cation having formula (1) include those shown below, but are not limited thereto.

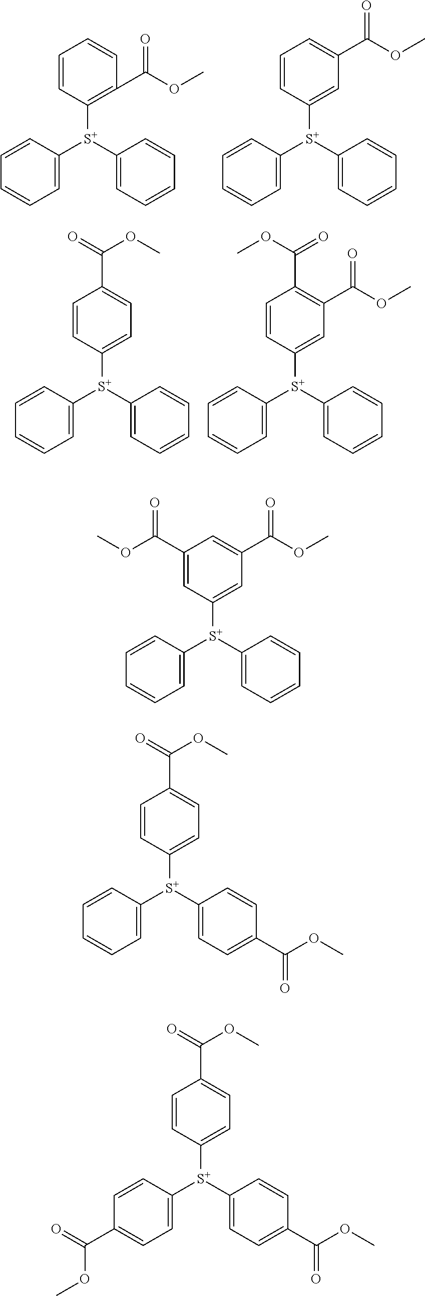

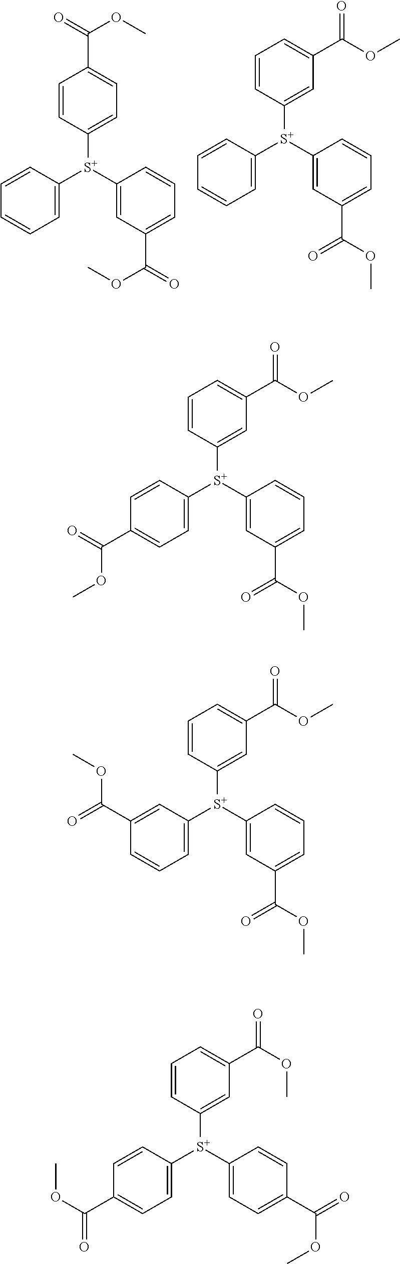 [SMILES: COC(=O)c1ccc([S+](c2ccccc2)c2cccc(C(=O)OC)c2)cc1 ; COC(=O)c1cccc([S+](c2ccccc2)c2cccc(C(=O)OC)c2)c1 ; COC(=O)c1ccc([S+](c2cccc(C(=O)OC)c2)c2cccc(C(=O)OC)c2)cc1 ; COC(=O)c1cccc([S+](c2cccc(C(=O)OC)c2)c2cccc(C(=O)OC)c2)c1 ; COC(=O)c1ccc([S+](c2ccc(C(=O)OC)cc2)c2cccc(C(=O)OC)c2)cc1]

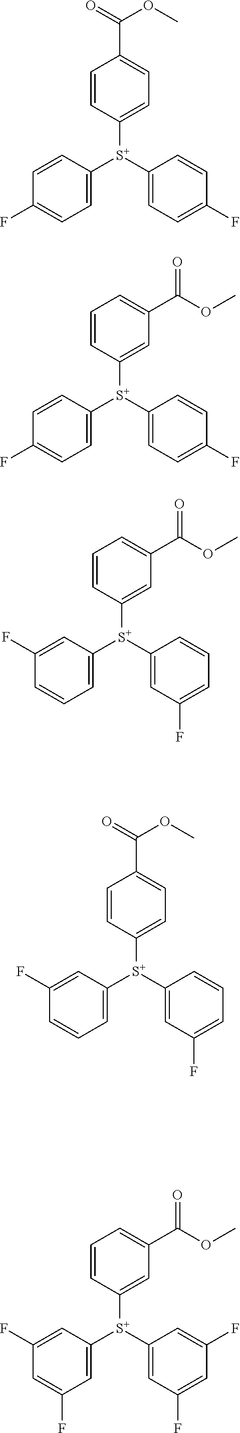 [SMILES: COC(=O)c1ccc([S+](c2ccc(F)cc2)c2ccc(F)cc2)cc1 ; COC(=O)c1cccc([S+](c2ccc(F)cc2)c2ccc(F)cc2)c1 ; COC(=O)c1cccc([S+](c2cccc(F)c2)c2cccc(F)c2)c1 ; COC(=O)c1ccc([S+](c2cccc(F)c2)c2cccc(F)c2)cc1 ; COC(=O)c1cccc([S+](c2cc(F)cc(F)c2)c2cc(F)cc(F)c2)c1]

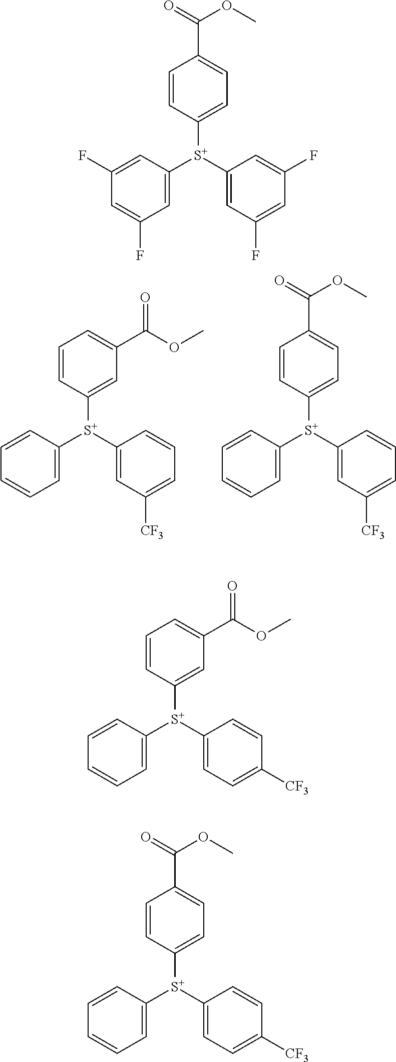 [SMILES: COC(=O)c1ccc([S+](c2cc(F)cc(F)c2)c2cc(F)cc(F)c2)cc1 ; COC(=O)c1cccc([S+](c2ccccc2)c2cccc(C(F)(F)F)c2)c1 ; COC(=O)c1ccc([S+](c2ccccc2)c2cccc(C(F)(F)F)c2)cc1 ; COC(=O)c1cccc([S+](c2ccccc2)c2ccc(C(F)(F)F)cc2)c1 ; COC(=O)c1ccc([S+](c2ccccc2)c2ccc(C(F)(F)F)cc2)cc1]

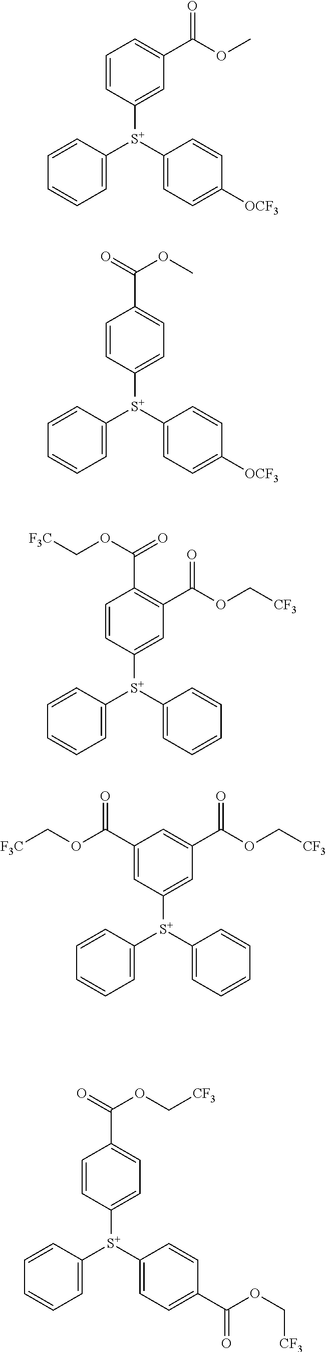 [SMILES: COC(=O)c1cccc([S+](c2ccccc2)c2ccc(OC(F)(F)F)cc2)c1 ; COC(=O)c1ccc([S+](c2ccccc2)c2ccc(OC(F)(F)F)cc2)cc1 ; O=C(OCC(F)(F)F)c1ccc([S+](c2ccccc2)c2ccccc2)cc1C(=O)OCC(F)(F)F ; O=C(OCC(F)(F)F)c1cc(C(=O)OCC(F)(F)F)cc([S+](c2ccccc2)c2ccccc2)c1 ; O=C(OCC(F)(F)F)c1ccc([S+](c2ccccc2)c2ccc(C(=O)OCC(F)(F)F)cc2)cc1]

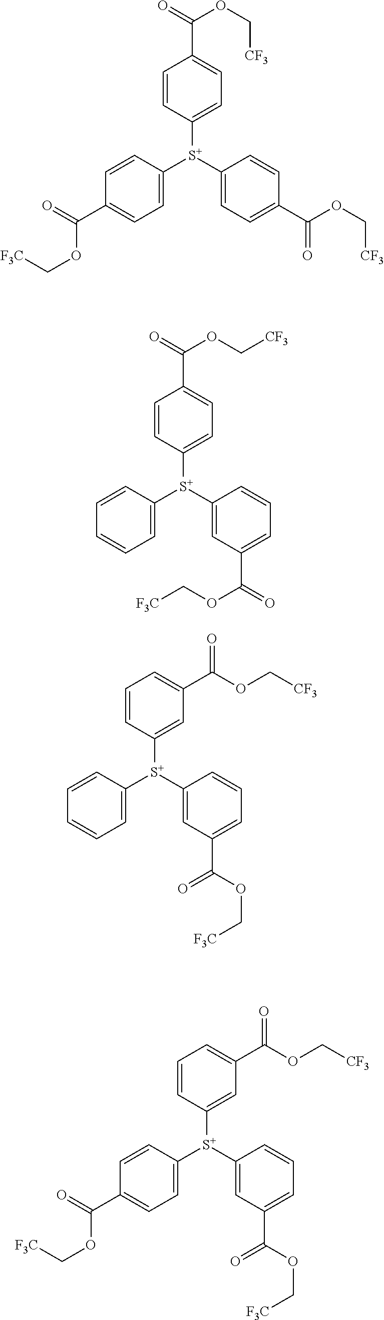 [SMILES: O=C(OCC(F)(F)F)c1ccc([S+](c2ccc(C(=O)OCC(F)(F)F)cc2)c2ccc(C(=O)OCC(F)(F)F)cc2)cc1 ; O=C(OCC(F)(F)F)c1ccc([S+](c2ccccc2)c2cccc(C(=O)OCC(F)(F)F)c2)cc1 ; O=C(OCC(F)(F)F)c1cccc([S+](c2ccccc2)c2cccc(C(=O)OCC(F)(F)F)c2)c1 ; O=C(OCC(F)(F)F)c1ccc([S+](c2cccc(C(=O)OCC(F)(F)F)c2)c2cccc(C(=O)OCC(F)(F)F)c2)cc1]

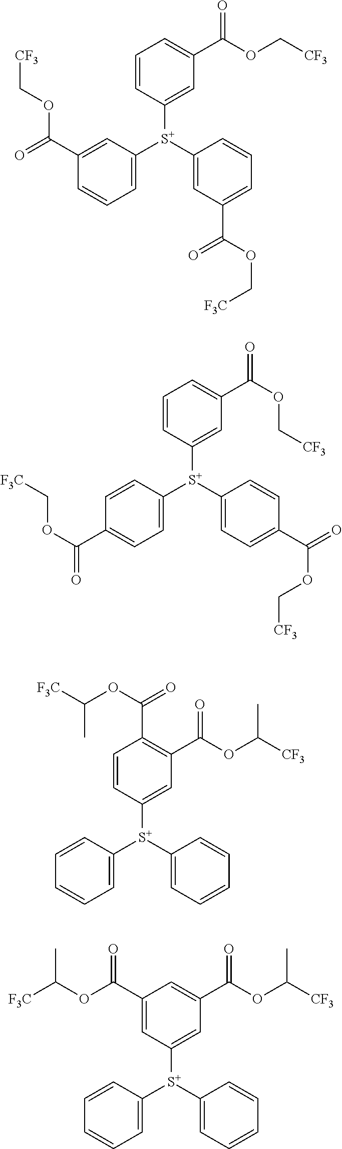 [SMILES: O=C(OCC(F)(F)F)c1cccc([S+](c2cccc(C(=O)OCC(F)(F)F)c2)c2cccc(C(=O)OCC(F)(F)F)c2)c1 ; O=C(OCC(F)(F)F)c1ccc([S+](c2ccc(C(=O)OCC(F)(F)F)cc2)c2cccc(C(=O)OCC(F)(F)F)c2)cc1 ; CC(OC(=O)c1ccc([S+](c2ccccc2)c2ccccc2)cc1C(=O)OC(C)C(F)(F)F)C(F)(F)F ; CC(OC(=O)c1cc(C(=O)OC(C)C(F)(F)F)cc([S+](c2ccccc2)c2ccccc2)c1)C(F)(F)F]

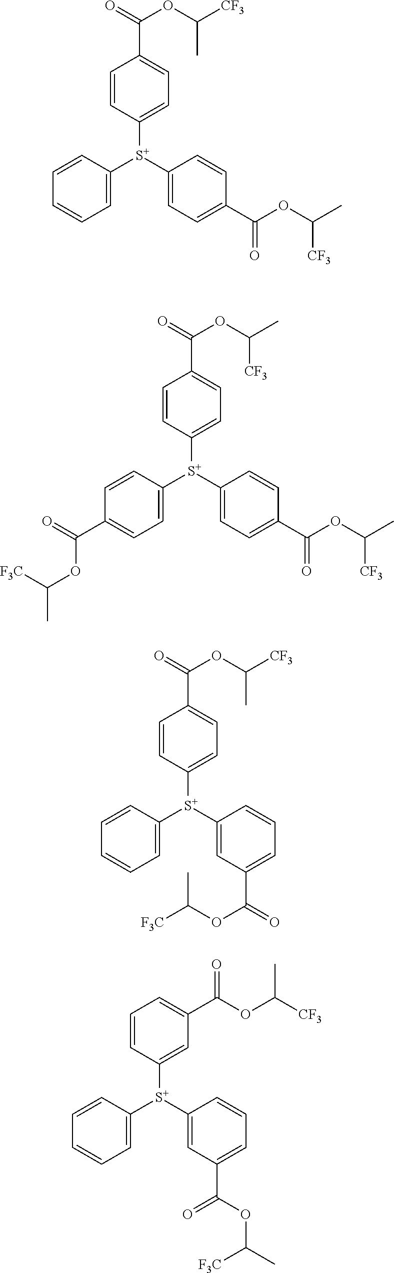 [SMILES: CC(OC(=O)c1ccc([S+](c2ccccc2)c2ccc(C(=O)OC(C)C(F)(F)F)cc2)cc1)C(F)(F)F ; CC(OC(=O)c1ccc([S+](c2ccc(C(=O)OC(C)C(F)(F)F)cc2)c2ccc(C(=O)OC(C)C(F)(F)F)cc2)cc1)C(F)(F)F ; CC(OC(=O)c1ccc([S+](c2ccccc2)c2cccc(C(=O)OC(C)C(F)(F)F)c2)cc1)C(F)(F)F ; CC(OC(=O)c1cccc([S+](c2ccccc2)c2cccc(C(=O)OC(C)C(F)(F)F)c2)c1)C(F)(F)F]

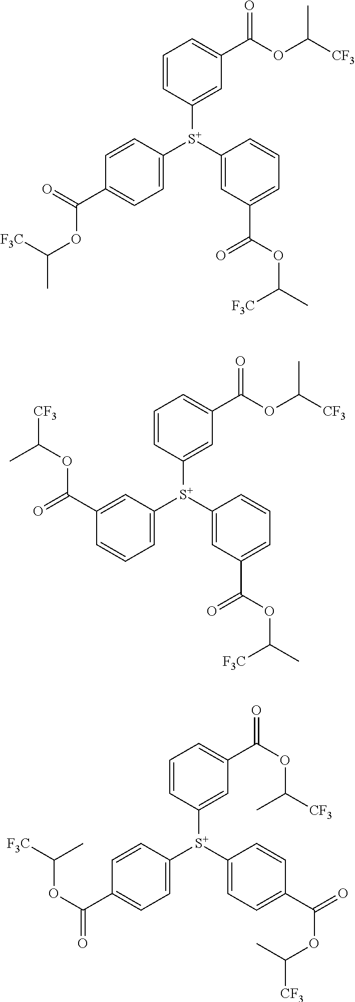 [SMILES: CC(OC(=O)c1ccc([S+](c2cccc(C(=O)OC(C)C(F)(F)F)c2)c2cccc(C(=O)OC(C)C(F)(F)F)c2)cc1)C(F)(F)F ; CC(OC(=O)c1cccc([S+](c2cccc(C(=O)OC(C)C(F)(F)F)c2)c2cccc(C(=O)OC(C)C(F)(F)F)c2)c1)C(F)(F)F ; CC(OC(=O)c1ccc([S+](c2ccc(C(=O)OC(C)C(F)(F)F)cc2)c2cccc(C(=O)OC(C)C(F)(F)F)c2)cc1)C(F)(F)F]

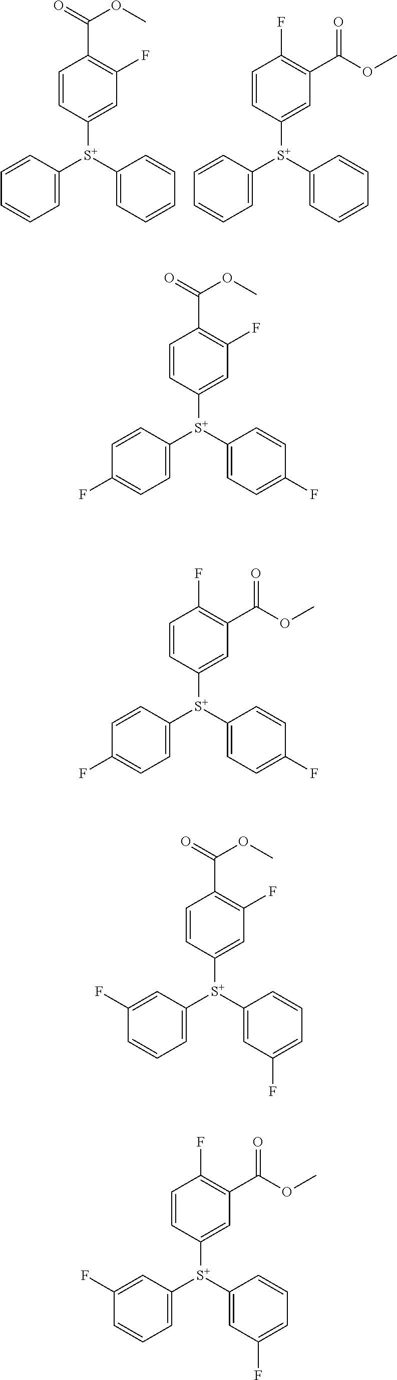 [SMILES: COC(=O)c1ccc([S+](c2ccccc2)c2ccccc2)cc1F ; COC(=O)c1cc([S+](c2ccccc2)c2ccccc2)ccc1F ; COC(=O)c1ccc([S+](c2ccc(F)cc2)c2ccc(F)cc2)cc1F ; COC(=O)c1cc([S+](c2ccc(F)cc2)c2ccc(F)cc2)ccc1F ; COC(=O)c1ccc([S+](c2cccc(F)c2)c2cccc(F)c2)cc1F ; COC(=O)c1cc([S+](c2cccc(F)c2)c2cccc(F)c2)ccc1F]

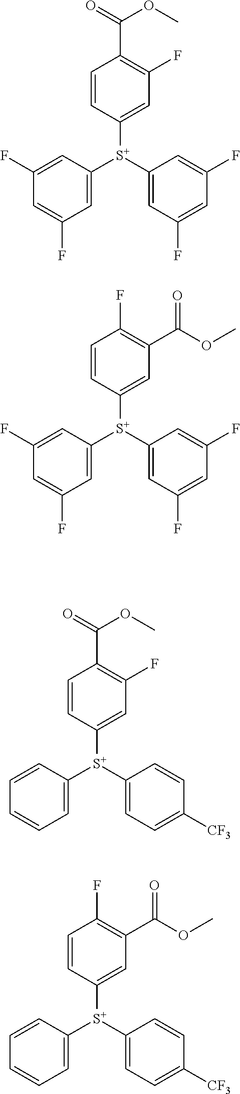 [SMILES: COC(=O)c1ccc([S+](c2cc(F)cc(F)c2)c2cc(F)cc(F)c2)cc1F ; COC(=O)c1cc([S+](c2cc(F)cc(F)c2)c2cc(F)cc(F)c2)ccc1F ; COC(=O)c1ccc([S+](c2ccccc2)c2ccc(C(F)(F)F)cc2)cc1F ; COC(=O)c1cc([S+](c2ccccc2)c2ccc(C(F)(F)F)cc2)ccc1F]

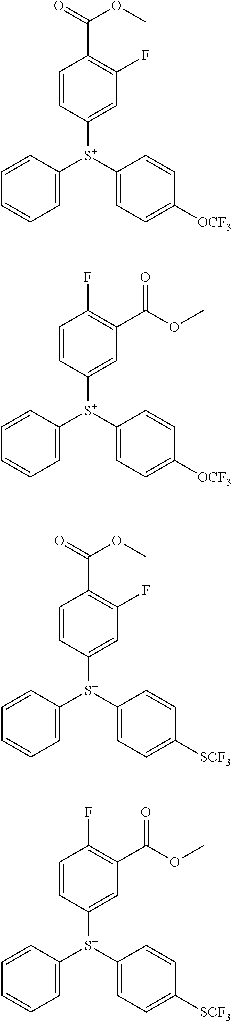

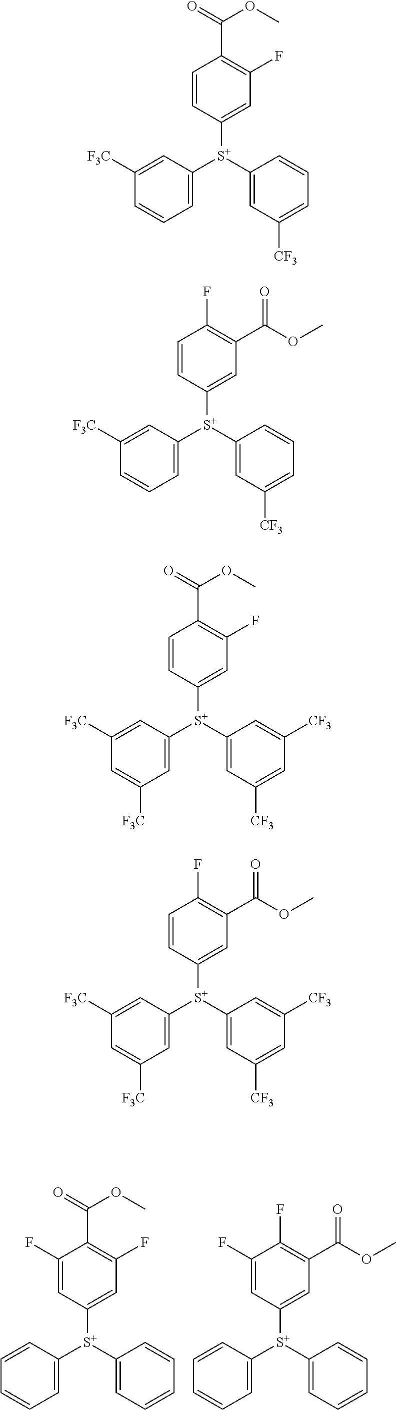 [SMILES: COC(=O)c1ccc([S+](c2cccc(C(F)(F)F)c2)c2cccc(C(F)(F)F)c2)cc1F ; COC(=O)c1cc([S+](c2cccc(C(F)(F)F)c2)c2cccc(C(F)(F)F)c2)ccc1F ; COC(=O)c1ccc([S+](c2cc(C(F)(F)F)cc(C(F)(F)F)c2)c2cc(C(F)(F)F)cc(C(F)(F)F)c2)cc1F ; COC(=O)c1cc([S+](c2cc(C(F)(F)F)cc(C(F)(F)F)c2)c2cc(C(F)(F)F)cc(C(F)(F)F)c2)ccc1F ; COC(=O)c1c(F)cc([S+](c2ccccc2)c2ccccc2)cc1F ; COC(=O)c1cc([S+](c2ccccc2)c2ccccc2)cc(F)c1F]

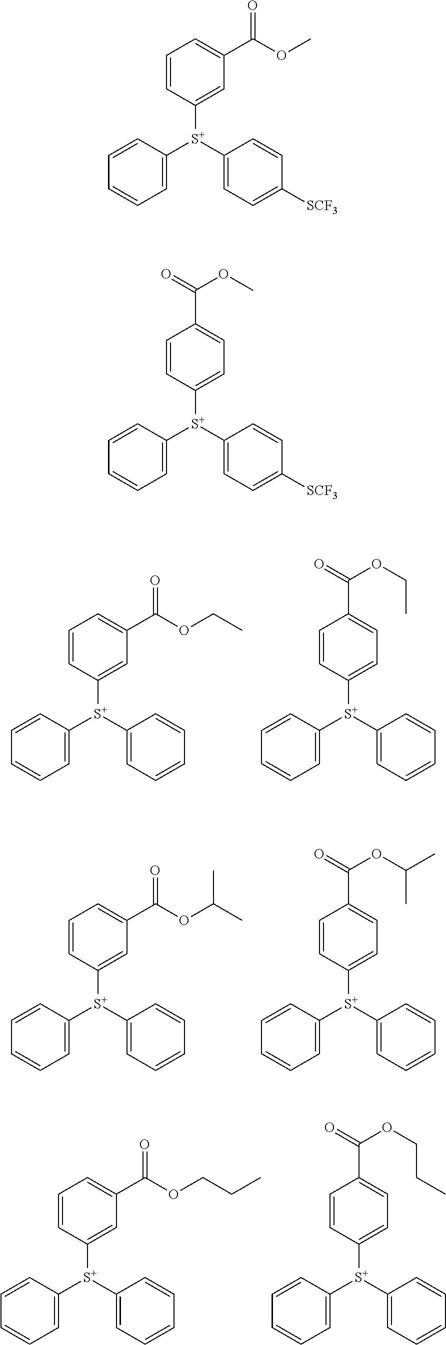

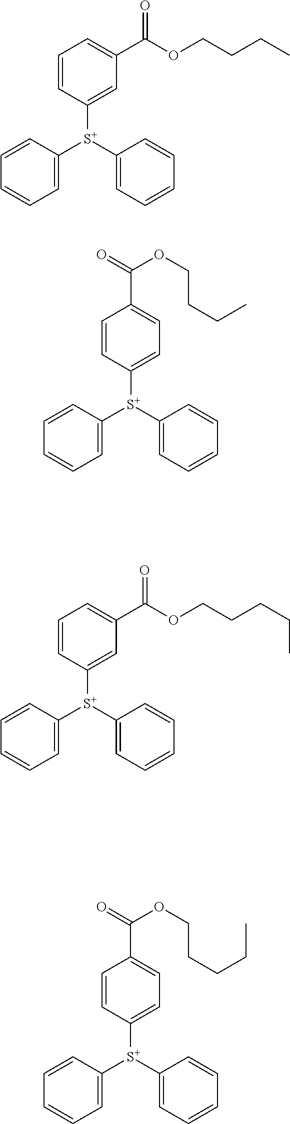 [SMILES: CCCCOC(=O)c1cccc([S+](c2ccccc2)c2ccccc2)c1 ; CCCCOC(=O)c1ccc([S+](c2ccccc2)c2ccccc2)cc1 ; CCCCCOC(=O)c1cccc([S+](c2ccccc2)c2ccccc2)c1 ; CCCCCOC(=O)c1ccc([S+](c2ccccc2)c2ccccc2)cc1]

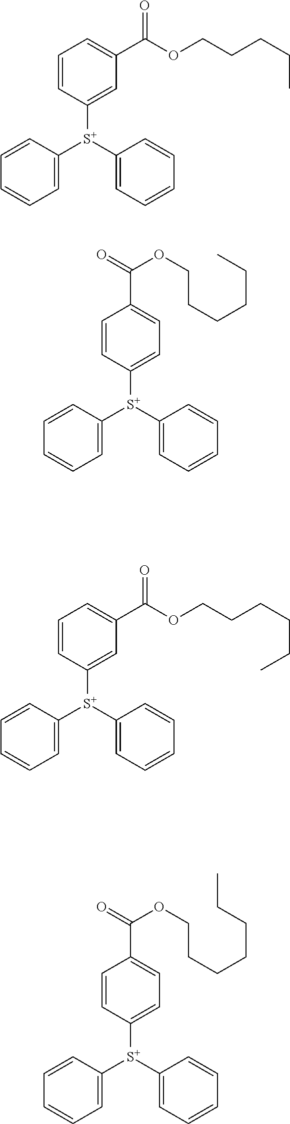 [SMILES: CCCCCOC(=O)c1cccc([S+](c2ccccc2)c2ccccc2)c1 ; CCCCCCOC(=O)c1ccc([S+](c2ccccc2)c2ccccc2)cc1 ; CCCCCCOC(=O)c1cccc([S+](c2ccccc2)c2ccccc2)c1 ; CCCCCCCOC(=O)c1ccc([S+](c2ccccc2)c2ccccc2)cc1]

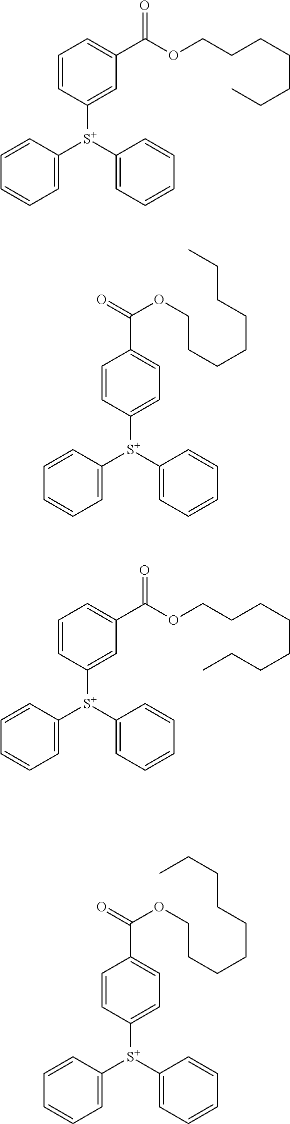 [SMILES: CCCCCCCOC(=O)c1cccc([S+](c2ccccc2)c2ccccc2)c1 ; CCCCCCCCOC(=O)c1ccc([S+](c2ccccc2)c2ccccc2)cc1 ; CCCCCCCCOC(=O)c1cccc([S+](c2ccccc2)c2ccccc2)c1 ; CCCCCCCCCOC(=O)c1ccc([S+](c2ccccc2)c2ccccc2)cc1]

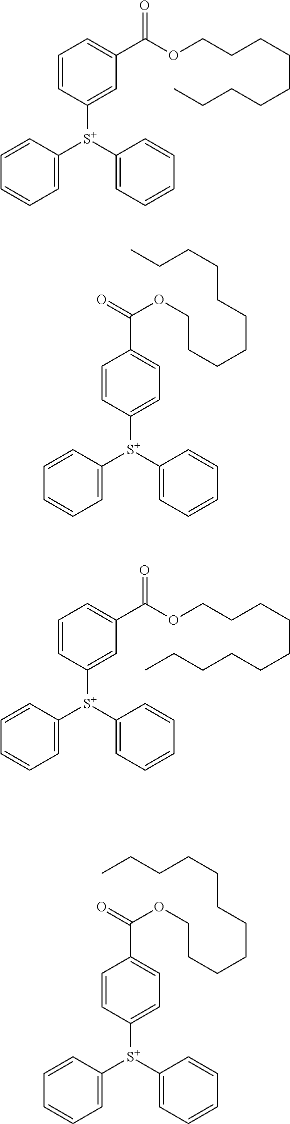 [SMILES: CCCCCCCCCOC(=O)c1cccc([S+](c2ccccc2)c2ccccc2)c1 ; CCCCCCCCCCOC(=O)c1ccc([S+](c2ccccc2)c2ccccc2)cc1 ; CCCCCCCCCCOC(=O)c1cccc([S+](c2ccccc2)c2ccccc2)c1 ; CCCCCCCCCCCOC(=O)c1ccc([S+](c2ccccc2)c2ccccc2)cc1]

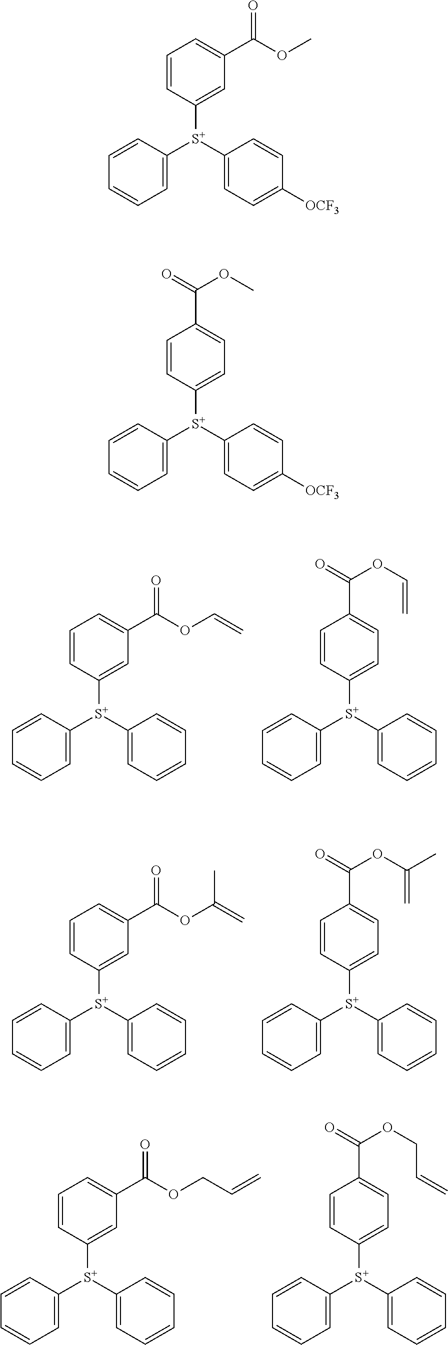

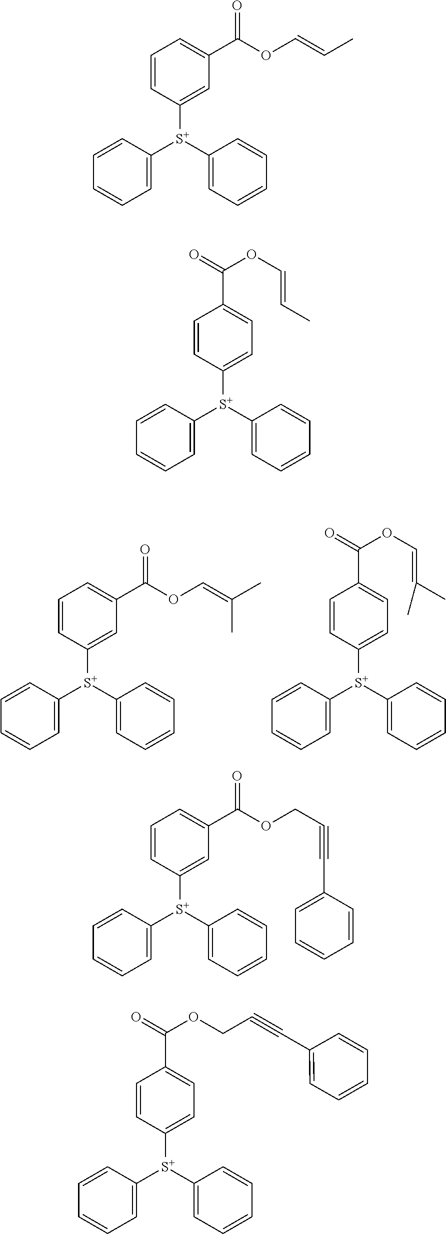 [SMILES: C/C=C/OC(=O)c1cccc([S+](c2ccccc2)c2ccccc2)c1 ; C/C=C/OC(=O)c1ccc([S+](c2ccccc2)c2ccccc2)cc1 ; CC(C)=COC(=O)c1cccc([S+](c2ccccc2)c2ccccc2)c1 ; CC(C)=COC(=O)c1ccc([S+](c2ccccc2)c2ccccc2)cc1 ; O=C(OCC#Cc1ccccc1)c1cccc([S+](c2ccccc2)c2ccccc2)c1 ; O=C(OCC#Cc1ccccc1)c1ccc([S+](c2ccccc2)c2ccccc2)cc1]

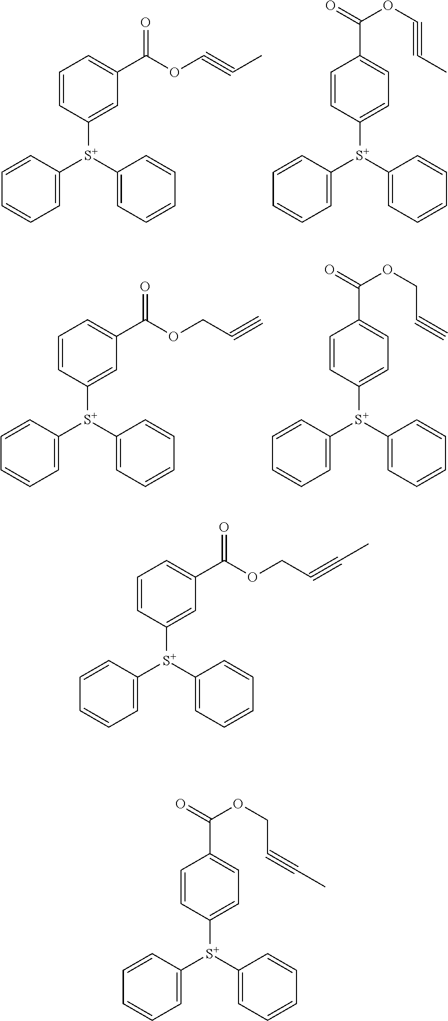 [SMILES: CC#COC(=O)c1cccc([S+](c2ccccc2)c2ccccc2)c1 ; CC#COC(=O)c1ccc([S+](c2ccccc2)c2ccccc2)cc1 ; C#CCOC(=O)c1cccc([S+](c2ccccc2)c2ccccc2)c1 ; C#CCOC(=O)c1ccc([S+](c2ccccc2)c2ccccc2)cc1 ; CC#CCOC(=O)c1cccc([S+](c2ccccc2)c2ccccc2)c1 ; CC#CCOC(=O)c1ccc([S+](c2ccccc2)c2ccccc2)cc1]

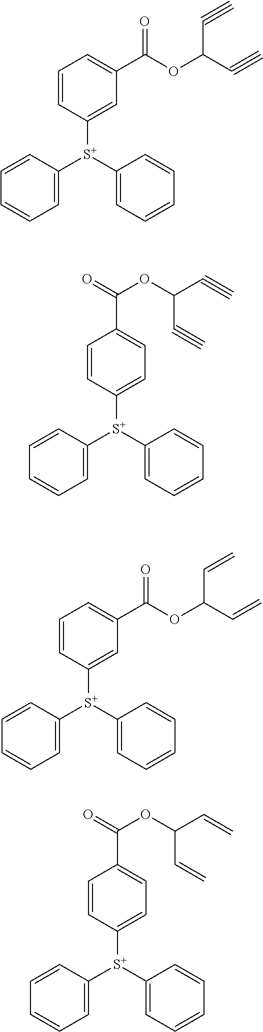 [SMILES: C#CC(C#C)OC(=O)c1cccc([S+](c2ccccc2)c2ccccc2)c1 ; C#CC(C#C)OC(=O)c1ccc([S+](c2ccccc2)c2ccccc2)cc1 ; C=CC(C=C)OC(=O)c1cccc([S+](c2ccccc2)c2ccccc2)c1 ; C=CC(C=C)OC(=O)c1ccc([S+](c2ccccc2)c2ccccc2)cc1]

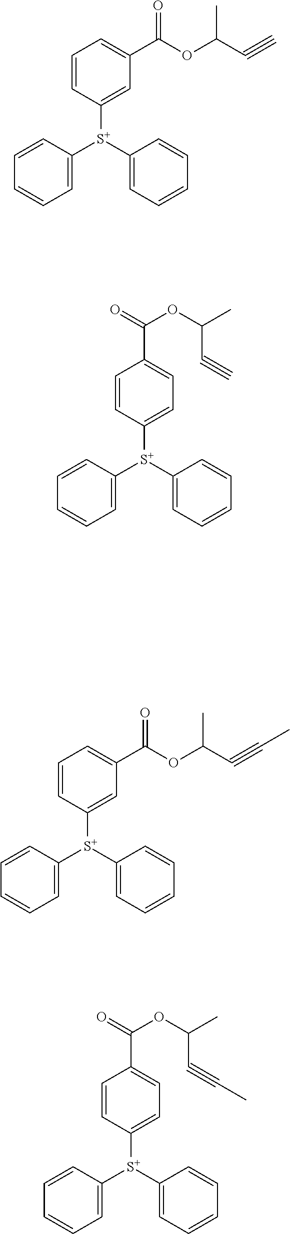 [SMILES: C#CC(C)OC(=O)c1cccc([S+](c2ccccc2)c2ccccc2)c1 ; C#CC(C)OC(=O)c1ccc([S+](c2ccccc2)c2ccccc2)cc1 ; CC#CC(C)OC(=O)c1cccc([S+](c2ccccc2)c2ccccc2)c1 ; CC#CC(C)OC(=O)c1ccc([S+](c2ccccc2)c2ccccc2)cc1]

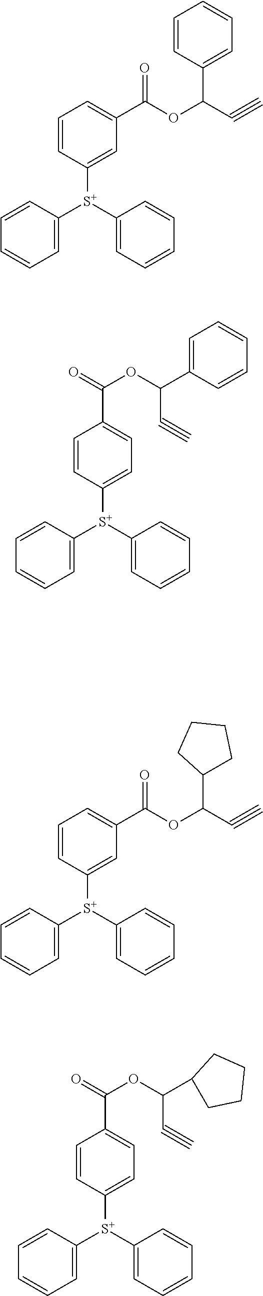 [SMILES: C#CC(OC(=O)c1cccc([S+](c2ccccc2)c2ccccc2)c1)c1ccccc1 ; C#CC(OC(=O)c1ccc([S+](c2ccccc2)c2ccccc2)cc1)c1ccccc1 ; C#CC(OC(=O)c1cccc([S+](c2ccccc2)c2ccccc2)c1)C1CCCC1 ; C#CC(OC(=O)c1ccc([S+](c2ccccc2)c2ccccc2)cc1)C1CCCC1]

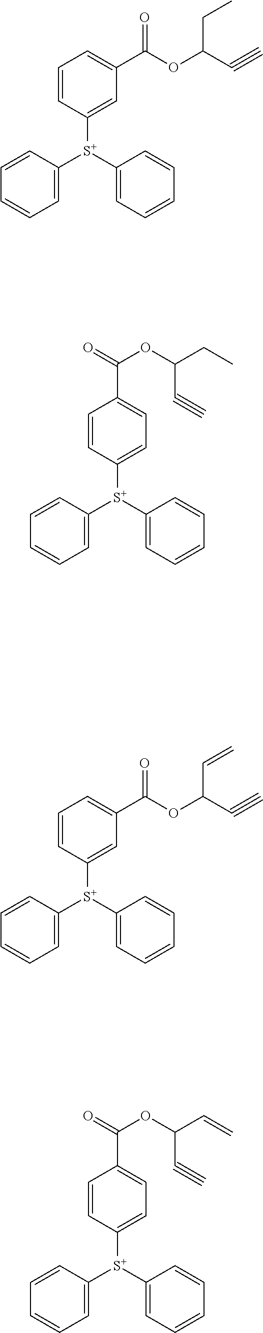 [SMILES: C#CC(CC)OC(=O)c1cccc([S+](c2ccccc2)c2ccccc2)c1 ; C#CC(CC)OC(=O)c1ccc([S+](c2ccccc2)c2ccccc2)cc1 ; C#CC(C=C)OC(=O)c1cccc([S+](c2ccccc2)c2ccccc2)c1 ; C#CC(C=C)OC(=O)c1ccc([S+](c2ccccc2)c2ccccc2)cc1]

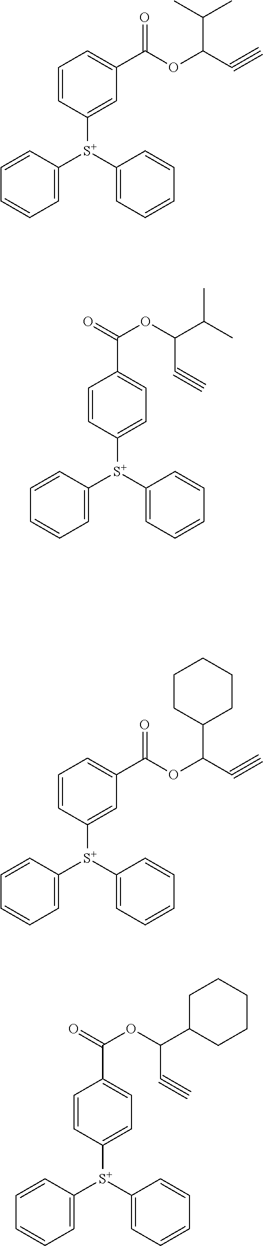 [SMILES: C#CC(OC(=O)c1cccc([S+](c2ccccc2)c2ccccc2)c1)C(C)C ; C#CC(OC(=O)c1ccc([S+](c2ccccc2)c2ccccc2)cc1)C(C)C ; C#CC(OC(=O)c1cccc([S+](c2ccccc2)c2ccccc2)c1)C1CCCCC1 ; C#CC(OC(=O)c1ccc([S+](c2ccccc2)c2ccccc2)cc1)C1CCCCC1]

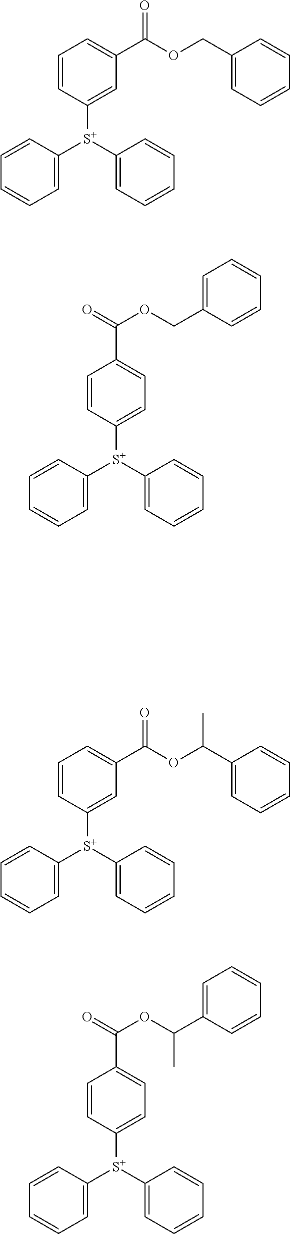 [SMILES: O=C(OCc1ccccc1)c1cccc([S+](c2ccccc2)c2ccccc2)c1 ; O=C(OCc1ccccc1)c1ccc([S+](c2ccccc2)c2ccccc2)cc1 ; CC(OC(=O)c1cccc([S+](c2ccccc2)c2ccccc2)c1)c1ccccc1 ; CC(OC(=O)c1ccc([S+](c2ccccc2)c2ccccc2)cc1)c1ccccc1]

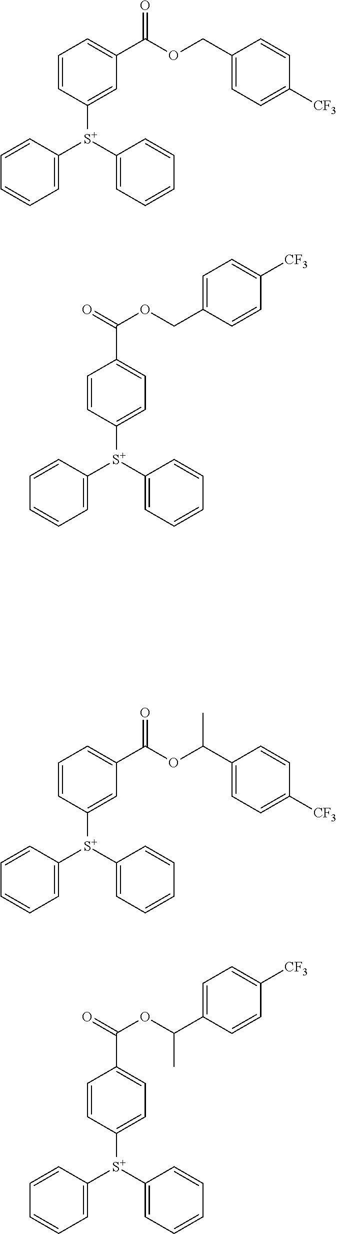 [SMILES: O=C(OCc1ccc(C(F)(F)F)cc1)c1cccc([S+](c2ccccc2)c2ccccc2)c1 ; O=C(OCc1ccc(C(F)(F)F)cc1)c1ccc([S+](c2ccccc2)c2ccccc2)cc1 ; CC(OC(=O)c1cccc([S+](c2ccccc2)c2ccccc2)c1)c1ccc(C(F)(F)F)cc1 ; CC(OC(=O)c1ccc([S+](c2ccccc2)c2ccccc2)cc1)c1ccc(C(F)(F)F)cc1]

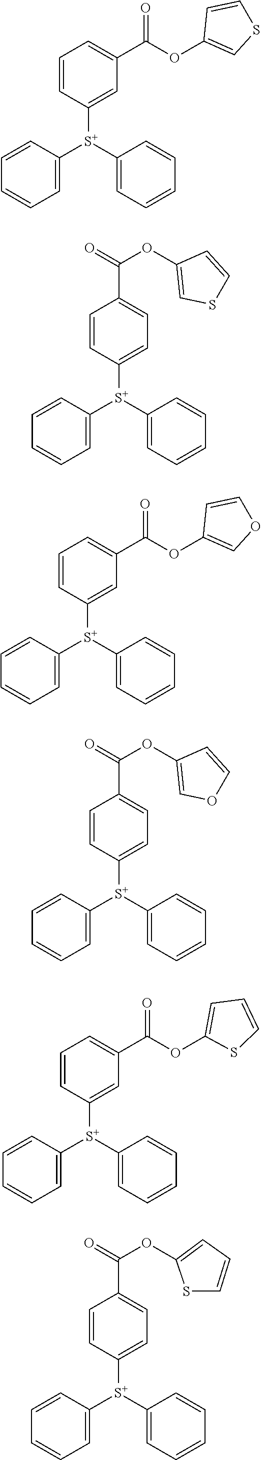 [SMILES: O=C(Oc1ccsc1)c1cccc([S+](c2ccccc2)c2ccccc2)c1 ; O=C(Oc1ccsc1)c1ccc([S+](c2ccccc2)c2ccccc2)cc1 ; O=C(Oc1ccoc1)c1cccc([S+](c2ccccc2)c2ccccc2)c1 ; O=C(Oc1ccoc1)c1ccc([S+](c2ccccc2)c2ccccc2)cc1 ; O=C(Oc1cccs1)c1cccc([S+](c2ccccc2)c2ccccc2)c1 ; O=C(Oc1cccs1)c1ccc([S+](c2ccccc2)c2ccccc2)cc1]

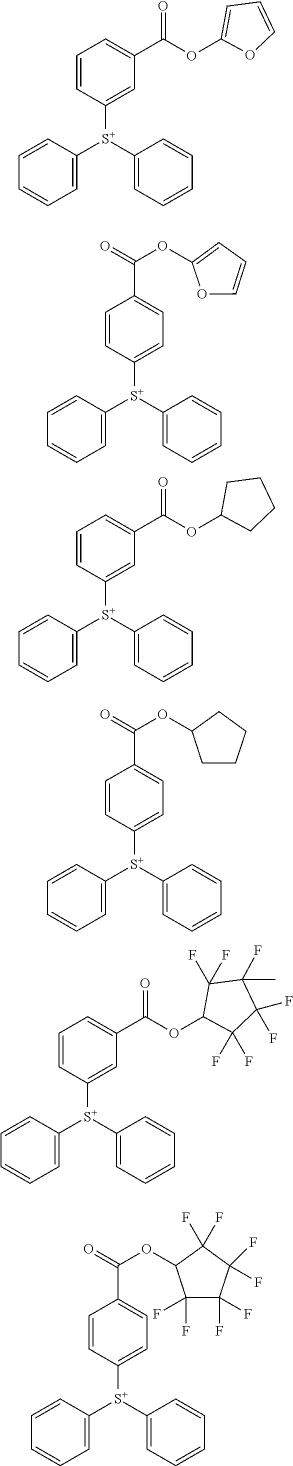 [SMILES: O=C(Oc1ccco1)c1cccc([S+](c2ccccc2)c2ccccc2)c1 ; O=C(Oc1ccco1)c1ccc([S+](c2ccccc2)c2ccccc2)cc1 ; O=C(OC1CCCC1)c1cccc([S+](c2ccccc2)c2ccccc2)c1 ; O=C(OC1CCCC1)c1ccc([S+](c2ccccc2)c2ccccc2)cc1 ; CC1(F)C(F)(F)C(OC(=O)c2cccc([S+](c3ccccc3)c3ccccc3)c2)C(F)(F)C1(F)F ; O=C(OC1C(F)(F)C(F)(F)C(F)(F)C1(F)F)c1ccc([S+](c2ccccc2)c2ccccc2)cc1]

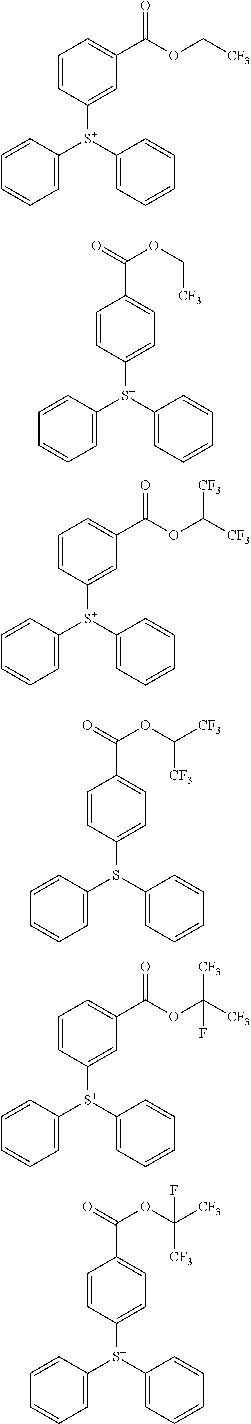 [SMILES: O=C(OCC(F)(F)F)c1cccc([S+](c2ccccc2)c2ccccc2)c1 ; O=C(OCC(F)(F)F)c1ccc([S+](c2ccccc2)c2ccccc2)cc1 ; O=C(OC(C(F)(F)F)C(F)(F)F)c1cccc([S+](c2ccccc2)c2ccccc2)c1 ; O=C(OC(C(F)(F)F)C(F)(F)F)c1ccc([S+](c2ccccc2)c2ccccc2)cc1 ; O=C(OC(F)(C(F)(F)F)C(F)(F)F)c1cccc([S+](c2ccccc2)c2ccccc2)c1 ; O=C(OC(F)(C(F)(F)F)C(F)(F)F)c1ccc([S+](c2ccccc2)c2ccccc2)cc1]

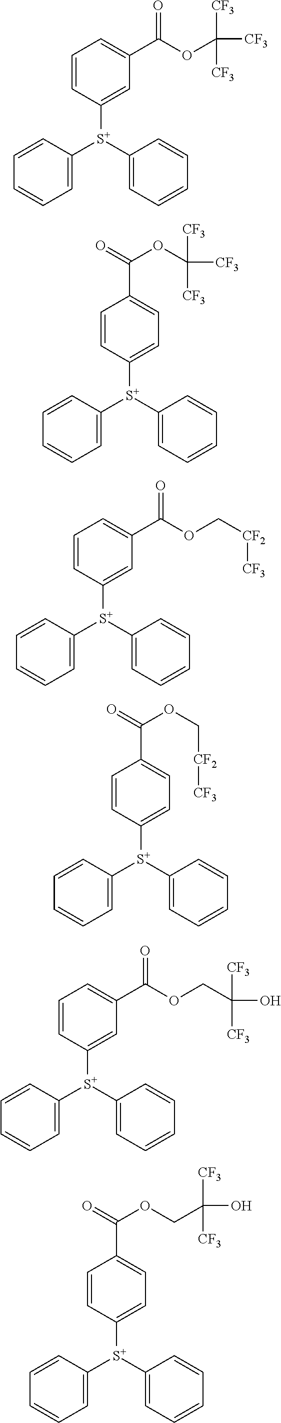

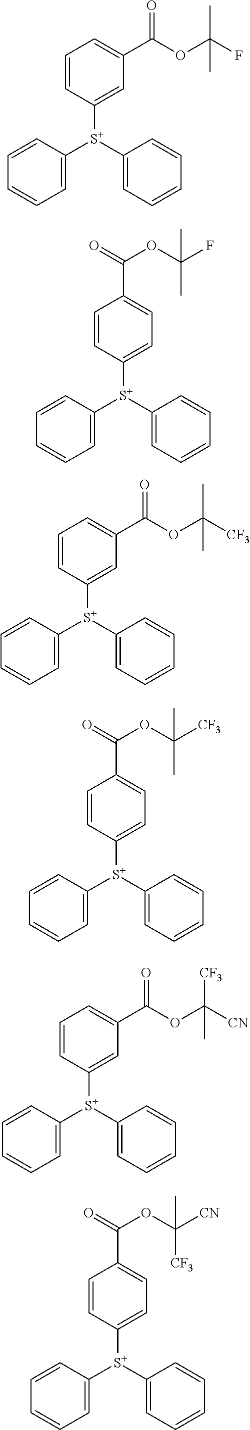 [SMILES: CC(C)(F)OC(=O)c1cccc([S+](c2ccccc2)c2ccccc2)c1 ; CC(C)(F)OC(=O)c1ccc([S+](c2ccccc2)c2ccccc2)cc1 ; CC(C)(OC(=O)c1cccc([S+](c2ccccc2)c2ccccc2)c1)C(F)(F)F ; CC(C)(OC(=O)c1ccc([S+](c2ccccc2)c2ccccc2)cc1)C(F)(F)F ; CC(C#N)(OC(=O)c1cccc([S+](c2ccccc2)c2ccccc2)c1)C(F)(F)F ; CC(C#N)(OC(=O)c1ccc([S+](c2ccccc2)c2ccccc2)cc1)C(F)(F)F]

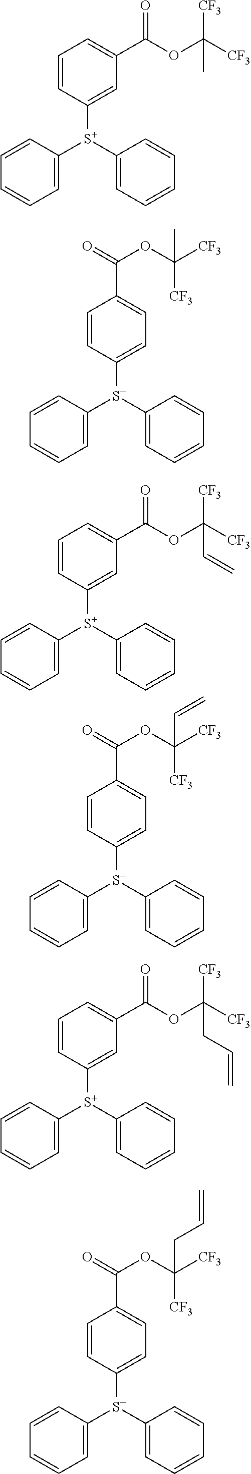 [SMILES: CC(OC(=O)c1cccc([S+](c2ccccc2)c2ccccc2)c1)(C(F)(F)F)C(F)(F)F ; CC(OC(=O)c1ccc([S+](c2ccccc2)c2ccccc2)cc1)(C(F)(F)F)C(F)(F)F ; C=CC(OC(=O)c1cccc([S+](c2ccccc2)c2ccccc2)c1)(C(F)(F)F)C(F)(F)F ; C=CC(OC(=O)c1ccc([S+](c2ccccc2)c2ccccc2)cc1)(C(F)(F)F)C(F)(F)F ; C=CCC(OC(=O)c1cccc([S+](c2ccccc2)c2ccccc2)c1)(C(F)(F)F)C(F)(F)F ; C=CCC(OC(=O)c1ccc([S+](c2ccccc2)c2ccccc2)cc1)(C(F)(F)F)C(F)(F)F]

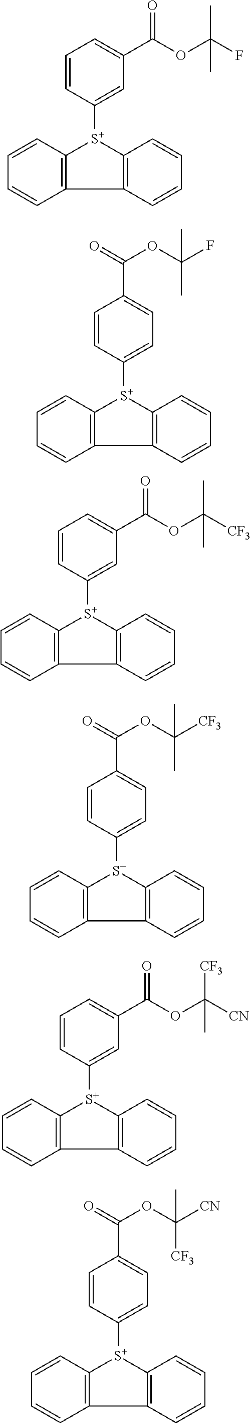 [SMILES: CC(C)(F)OC(=O)c1cccc(-[s+]2c3ccccc3c3ccccc32)c1 ; CC(C)(F)OC(=O)c1ccc(-[s+]2c3ccccc3c3ccccc32)cc1 ; CC(C)(OC(=O)c1cccc(-[s+]2c3ccccc3c3ccccc32)c1)C(F)(F)F ; CC(C)(OC(=O)c1ccc(-[s+]2c3ccccc3c3ccccc32)cc1)C(F)(F)F ; CC(C#N)(OC(=O)c1cccc(-[s+]2c3ccccc3c3ccccc32)c1)C(F)(F)F ; CC(C#N)(OC(=O)c1ccc(-[s+]2c3ccccc3c3ccccc32)cc1)C(F)(F)F]

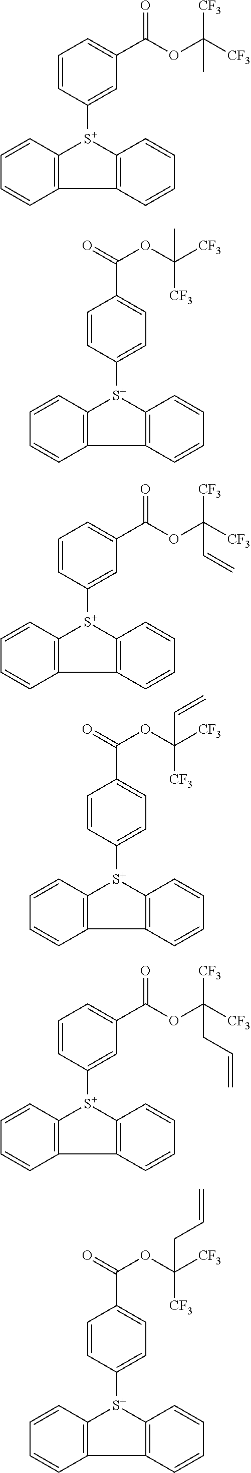 [SMILES: CC(OC(=O)c1cccc(-[s+]2c3ccccc3c3ccccc32)c1)(C(F)(F)F)C(F)(F)F ; CC(OC(=O)c1ccc(-[s+]2c3ccccc3c3ccccc32)cc1)(C(F)(F)F)C(F)(F)F ; C=CC(OC(=O)c1cccc(-[s+]2c3ccccc3c3ccccc32)c1)(C(F)(F)F)C(F)(F)F ; C=CC(OC(=O)c1ccc(-[s+]2c3ccccc3c3ccccc32)cc1)(C(F)(F)F)C(F)(F)F ; C=CCC(OC(=O)c1cccc(-[s+]2c3ccccc3c3ccccc32)c1)(C(F)(F)F)C(F)(F)F ; C=CCC(OC(=O)c1ccc(-[s+]2c3ccccc3c3ccccc32)cc1)(C(F)(F)F)C(F)(F)F]

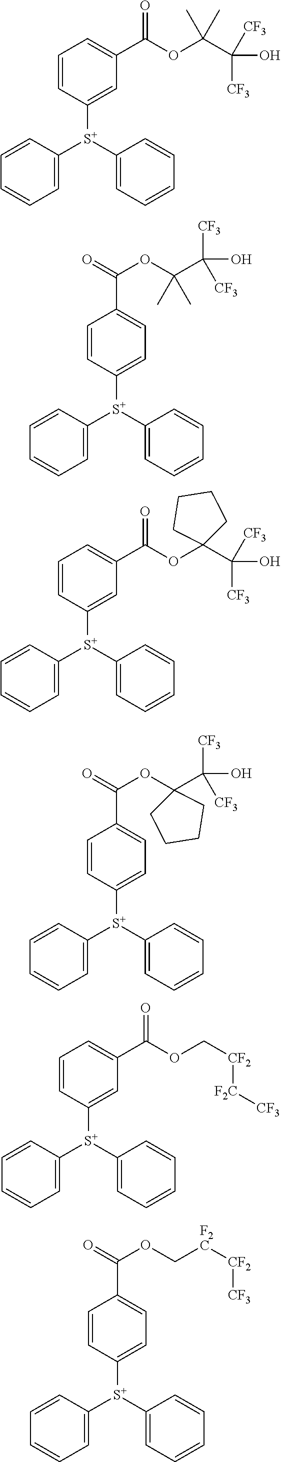 [SMILES: CC(C)(OC(=O)c1cccc([S+](c2ccccc2)c2ccccc2)c1)C(O)(C(F)(F)F)C(F)(F)F ; CC(C)(OC(=O)c1ccc([S+](c2ccccc2)c2ccccc2)cc1)C(O)(C(F)(F)F)C(F)(F)F ; O=C(OC1(C(O)(C(F)(F)F)C(F)(F)F)CCCC1)c1cccc([S+](c2ccccc2)c2ccccc2)c1 ; O=C(OC1(C(O)(C(F)(F)F)C(F)(F)F)CCCC1)c1ccc([S+](c2ccccc2)c2ccccc2)cc1 ; O=C(OCC(F)(F)C(F)(F)C(F)(F)F)c1cccc([S+](c2ccccc2)c2ccccc2)c1 ; O=C(OCC(F)(F)C(F)(F)C(F)(F)F)c1ccc([S+](c2ccccc2)c2ccccc2)cc1]

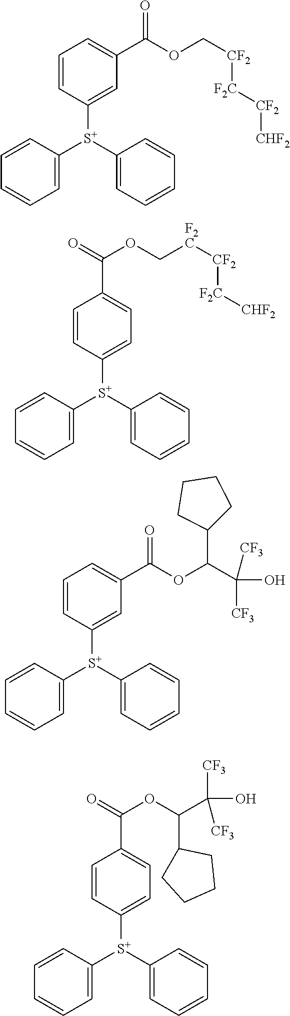 [SMILES: O=C(OCC(F)(F)C(F)(F)C(F)(F)C(F)F)c1cccc([S+](c2ccccc2)c2ccccc2)c1 ; O=C(OCC(F)(F)C(F)(F)C(F)(F)C(F)F)c1ccc([S+](c2ccccc2)c2ccccc2)cc1 ; O=C(OC(C1CCCC1)C(O)(C(F)(F)F)C(F)(F)F)c1cccc([S+](c2ccccc2)c2ccccc2)c1 ; O=C(OC(C1CCCC1)C(O)(C(F)(F)F)C(F)(F)F)c1ccc([S+](c2ccccc2)c2ccccc2)cc1]

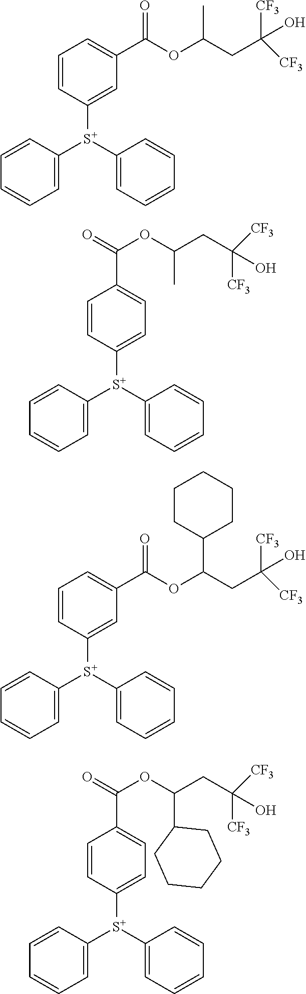 [SMILES: CC(CC(O)(C(F)(F)F)C(F)(F)F)OC(=O)c1cccc([S+](c2ccccc2)c2ccccc2)c1 ; CC(CC(O)(C(F)(F)F)C(F)(F)F)OC(=O)c1ccc([S+](c2ccccc2)c2ccccc2)cc1 ; O=C(OC(CC(O)(C(F)(F)F)C(F)(F)F)C1CCCCC1)c1cccc([S+](c2ccccc2)c2ccccc2)c1 ; O=C(OC(CC(O)(C(F)(F)F)C(F)(F)F)C1CCCCC1)c1ccc([S+](c2ccccc2)c2ccccc2)cc1]

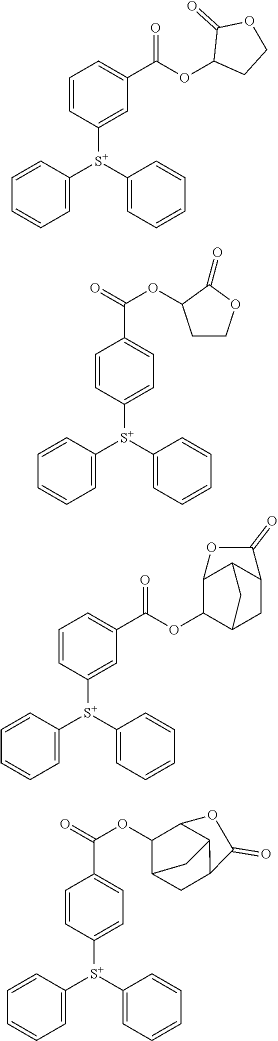 [SMILES: O=C(OC1CCOC1=O)c1cccc([S+](c2ccccc2)c2ccccc2)c1 ; O=C(OC1CCOC1=O)c1ccc([S+](c2ccccc2)c2ccccc2)cc1 ; O=C(OC1C2CC3C(=O)OC1C3C2)c1cccc([S+](c2ccccc2)c2ccccc2)c1 ; O=C(OC1C2CC3C(=O)OC1C3C2)c1ccc([S+](c2ccccc2)c2ccccc2)cc1]

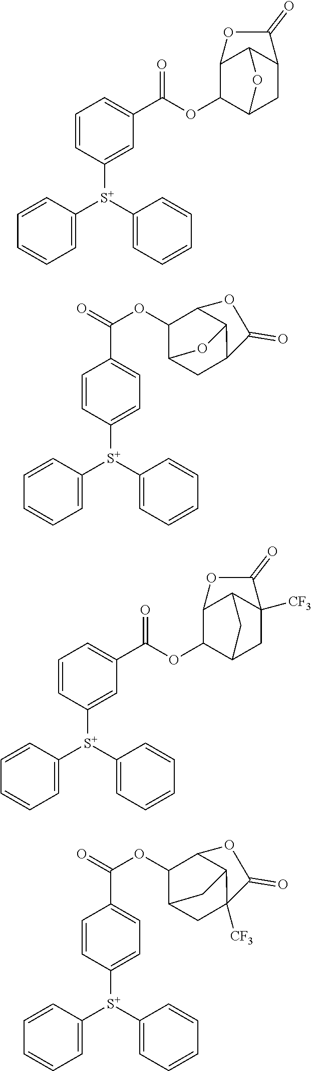 [SMILES: O=C(OC1C2CC3C(=O)OC1C3O2)c1cccc([S+](c2ccccc2)c2ccccc2)c1 ; O=C(OC1C2CC3C(=O)OC1C3O2)c1ccc([S+](c2ccccc2)c2ccccc2)cc1 ; O=C(OC1C2CC3C1OC(=O)C3(C(F)(F)F)C2)c1cccc([S+](c2ccccc2)c2ccccc2)c1 ; O=C(OC1C2CC3C1OC(=O)C3(C(F)(F)F)C2)c1ccc([S+](c2ccccc2)c2ccccc2)cc1]

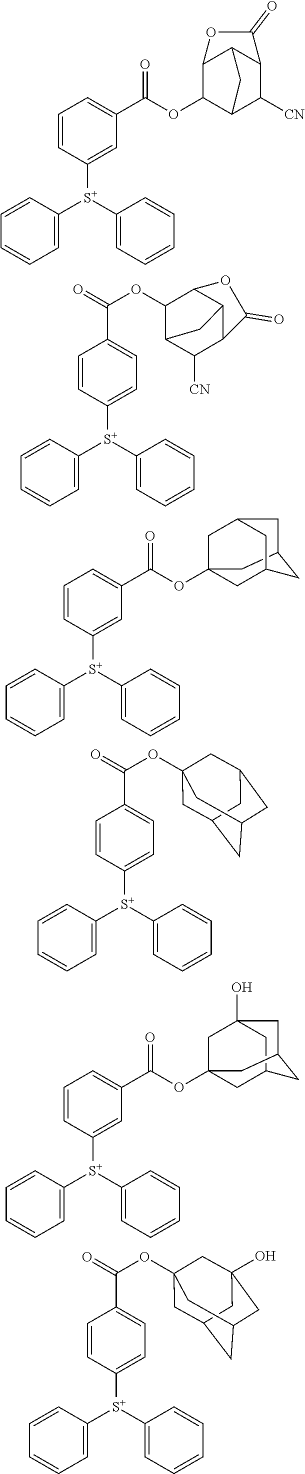 [SMILES: N#CC1C2CC3C(OC(=O)C13)C2OC(=O)c1cccc([S+](c2ccccc2)c2ccccc2)c1 ; N#CC1C2CC3C(OC(=O)C13)C2OC(=O)c1ccc([S+](c2ccccc2)c2ccccc2)cc1 ; O=C(OC12CC3CC(CC(C3)C1)C2)c1cccc([S+](c2ccccc2)c2ccccc2)c1 ; O=C(OC12CC3CC(CC(C3)C1)C2)c1ccc([S+](c2ccccc2)c2ccccc2)cc1 ; O=C(OC12CC3CC(CC(O)(C3)C1)C2)c1cccc([S+](c2ccccc2)c2ccccc2)c1 ; O=C(OC12CC3CC(CC(O)(C3)C1)C2)c1ccc([S+](c2ccccc2)c2ccccc2)cc1]

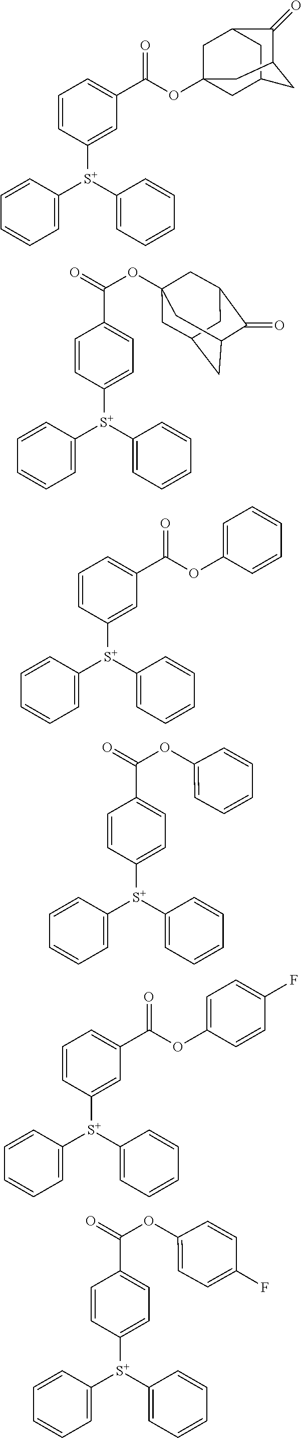 [SMILES: O=C(OC12CC3CC(C1)C(=O)C(C3)C2)c1cccc([S+](c2ccccc2)c2ccccc2)c1 ; O=C(OC12CC3CC(C1)C(=O)C(C3)C2)c1ccc([S+](c2ccccc2)c2ccccc2)cc1 ; O=C(Oc1ccccc1)c1cccc([S+](c2ccccc2)c2ccccc2)c1 ; O=C(Oc1ccccc1)c1ccc([S+](c2ccccc2)c2ccccc2)cc1 ; O=C(Oc1ccc(F)cc1)c1cccc([S+](c2ccccc2)c2ccccc2)c1 ; O=C(Oc1ccc(F)cc1)c1ccc([S+](c2ccccc2)c2ccccc2)cc1]

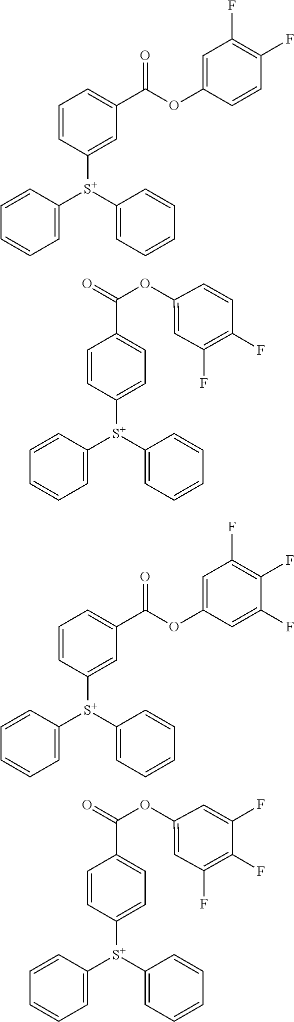 [SMILES: O=C(Oc1ccc(F)c(F)c1)c1cccc([S+](c2ccccc2)c2ccccc2)c1 ; O=C(Oc1ccc(F)c(F)c1)c1ccc([S+](c2ccccc2)c2ccccc2)cc1 ; O=C(Oc1cc(F)c(F)c(F)c1)c1cccc([S+](c2ccccc2)c2ccccc2)c1 ; O=C(Oc1cc(F)c(F)c(F)c1)c1ccc([S+](c2ccccc2)c2ccccc2)cc1]

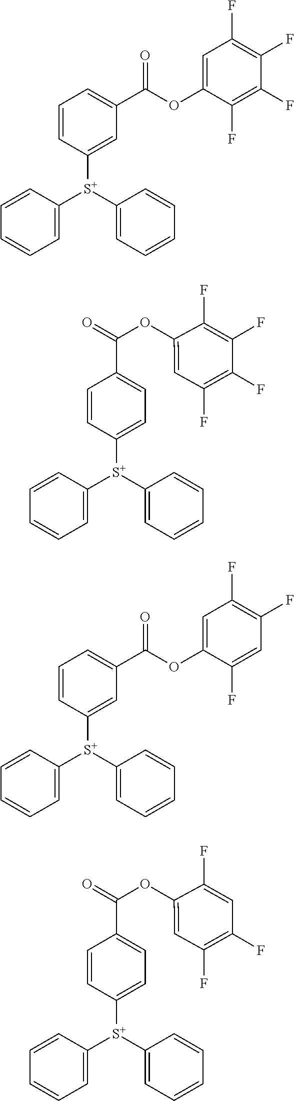 [SMILES: O=C(Oc1cc(F)c(F)c(F)c1F)c1cccc([S+](c2ccccc2)c2ccccc2)c1 ; O=C(Oc1cc(F)c(F)c(F)c1F)c1ccc([S+](c2ccccc2)c2ccccc2)cc1 ; O=C(Oc1cc(F)c(F)cc1F)c1cccc([S+](c2ccccc2)c2ccccc2)c1 ; O=C(Oc1cc(F)c(F)cc1F)c1ccc([S+](c2ccccc2)c2ccccc2)cc1]

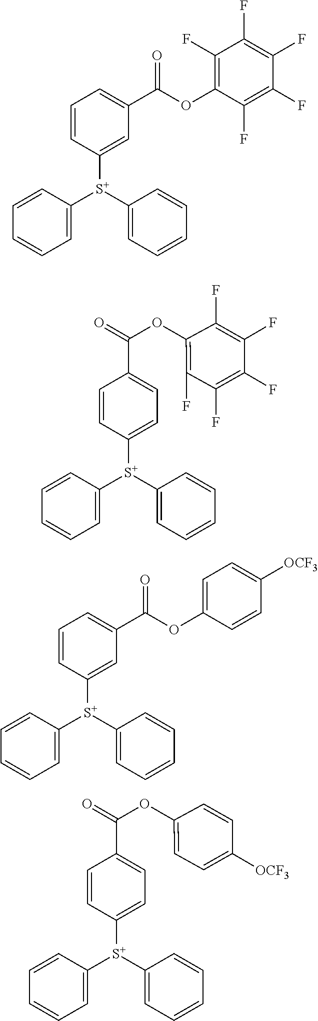 [SMILES: O=C(Oc1c(F)c(F)c(F)c(F)c1F)c1cccc([S+](c2ccccc2)c2ccccc2)c1 ; O=C(Oc1c(F)c(F)c(F)c(F)c1F)c1ccc([S+](c2ccccc2)c2ccccc2)cc1 ; O=C(Oc1ccc(OC(F)(F)F)cc1)c1cccc([S+](c2ccccc2)c2ccccc2)c1 ; O=C(Oc1ccc(OC(F)(F)F)cc1)c1ccc([S+](c2ccccc2)c2ccccc2)cc1]

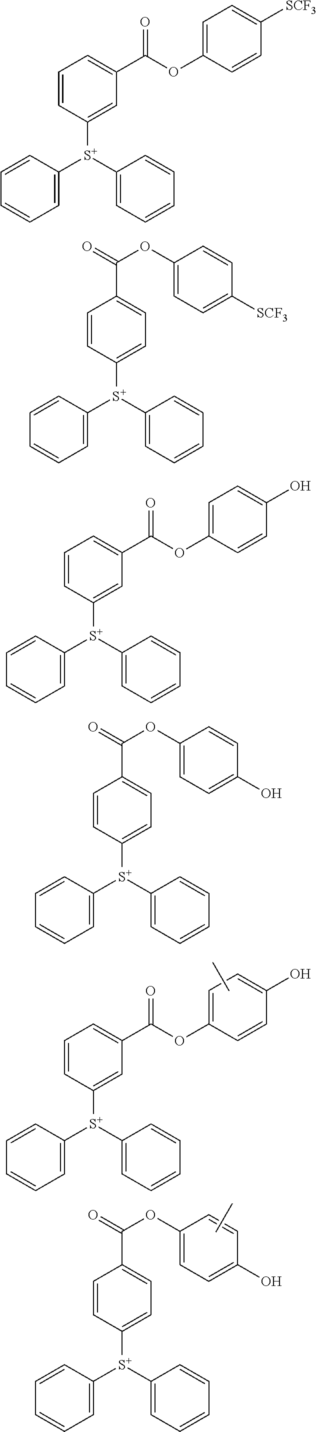

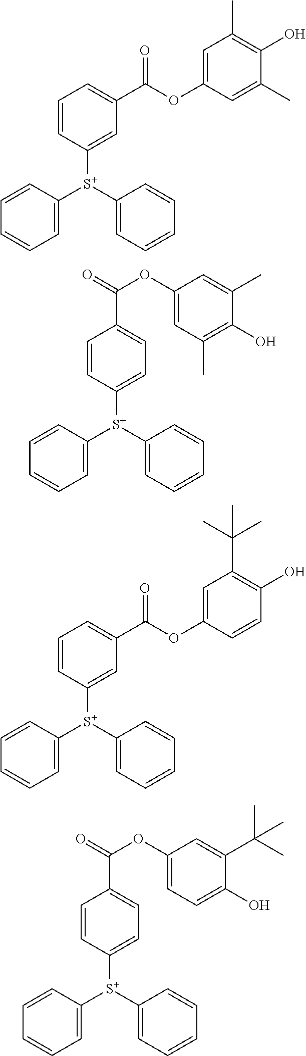 [SMILES: Cc1cc(OC(=O)c2cccc([S+](c3ccccc3)c3ccccc3)c2)cc(C)c1O ; Cc1cc(OC(=O)c2ccc([S+](c3ccccc3)c3ccccc3)cc2)cc(C)c1O ; CC(C)(C)c1cc(OC(=O)c2cccc([S+](c3ccccc3)c3ccccc3)c2)ccc1O ; CC(C)(C)c1cc(OC(=O)c2ccc([S+](c3ccccc3)c3ccccc3)cc2)ccc1O]

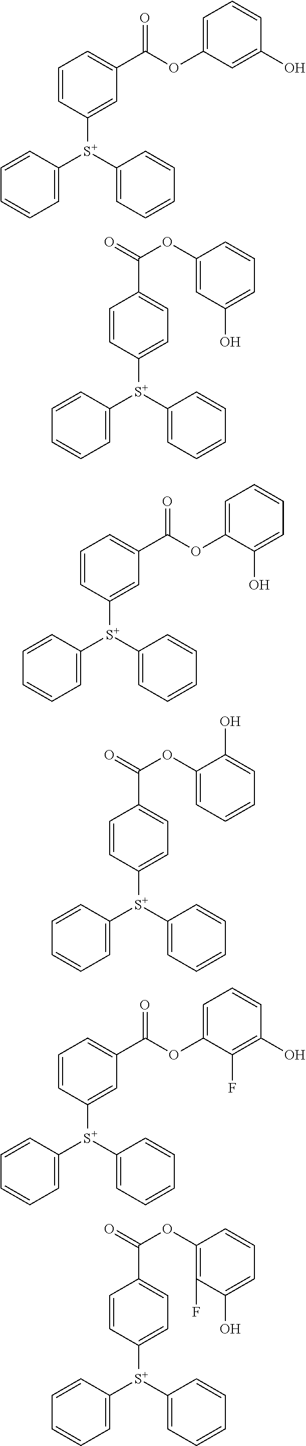 [SMILES: O=C(Oc1cccc(O)c1)c1cccc([S+](c2ccccc2)c2ccccc2)c1 ; O=C(Oc1cccc(O)c1)c1ccc([S+](c2ccccc2)c2ccccc2)cc1 ; O=C(Oc1ccccc1O)c1cccc([S+](c2ccccc2)c2ccccc2)c1 ; O=C(Oc1ccccc1O)c1ccc([S+](c2ccccc2)c2ccccc2)cc1 ; O=C(Oc1cccc(O)c1F)c1cccc([S+](c2ccccc2)c2ccccc2)c1 ; O=C(Oc1cccc(O)c1F)c1ccc([S+](c2ccccc2)c2ccccc2)cc1]

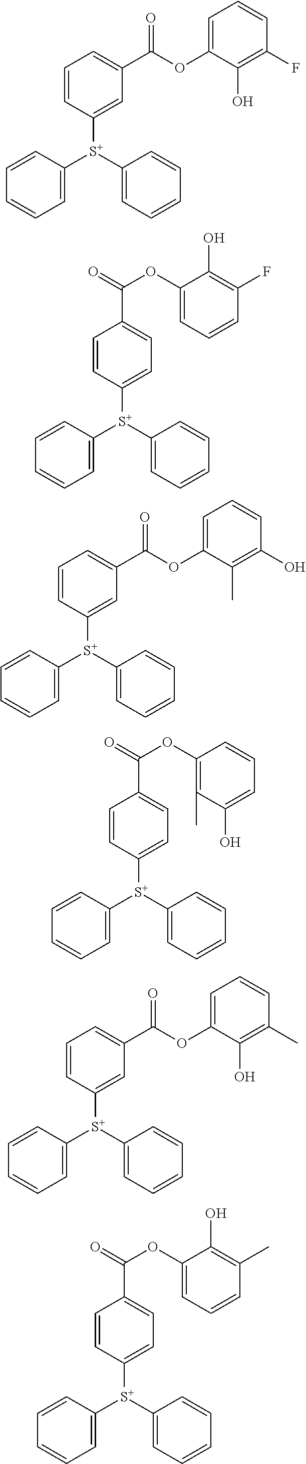 [SMILES: O=C(Oc1cccc(F)c1O)c1cccc([S+](c2ccccc2)c2ccccc2)c1 ; O=C(Oc1cccc(F)c1O)c1ccc([S+](c2ccccc2)c2ccccc2)cc1 ; Cc1c(O)cccc1OC(=O)c1cccc([S+](c2ccccc2)c2ccccc2)c1 ; Cc1c(O)cccc1OC(=O)c1ccc([S+](c2ccccc2)c2ccccc2)cc1 ; Cc1cccc(OC(=O)c2cccc([S+](c3ccccc3)c3ccccc3)c2)c1O ; Cc1cccc(OC(=O)c2ccc([S+](c3ccccc3)c3ccccc3)cc2)c1O]

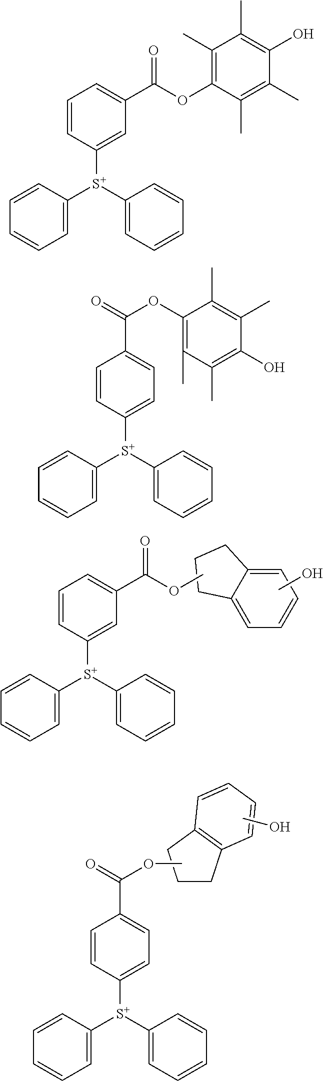

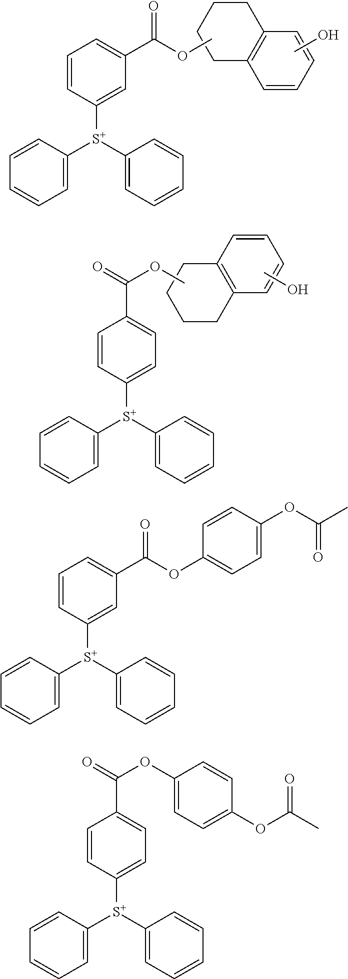

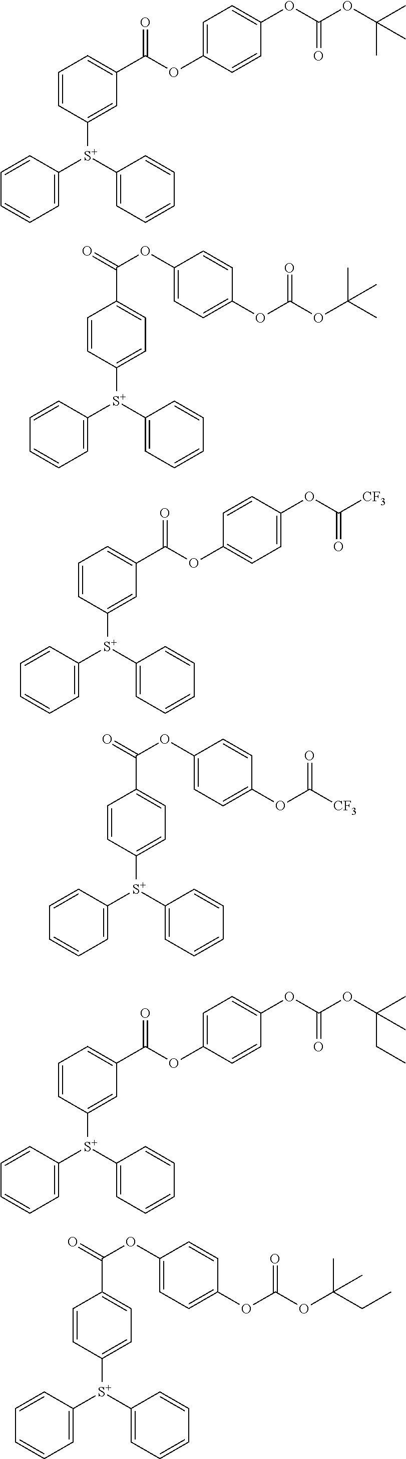 [SMILES: CC(C)(C)OC(=O)Oc1ccc(OC(=O)c2cccc([S+](c3ccccc3)c3ccccc3)c2)cc1 ; CC(C)(C)OC(=O)Oc1ccc(OC(=O)c2ccc([S+](c3ccccc3)c3ccccc3)cc2)cc1 ; O=C(Oc1ccc(OC(=O)C(F)(F)F)cc1)c1cccc([S+](c2ccccc2)c2ccccc2)c1 ; O=C(Oc1ccc(OC(=O)C(F)(F)F)cc1)c1ccc([S+](c2ccccc2)c2ccccc2)cc1 ; CCC(C)(C)OC(=O)Oc1ccc(OC(=O)c2cccc([S+](c3ccccc3)c3ccccc3)c2)cc1 ; CCC(C)(C)OC(=O)Oc1ccc(OC(=O)c2ccc([S+](c3ccccc3)c3ccccc3)cc2)cc1]

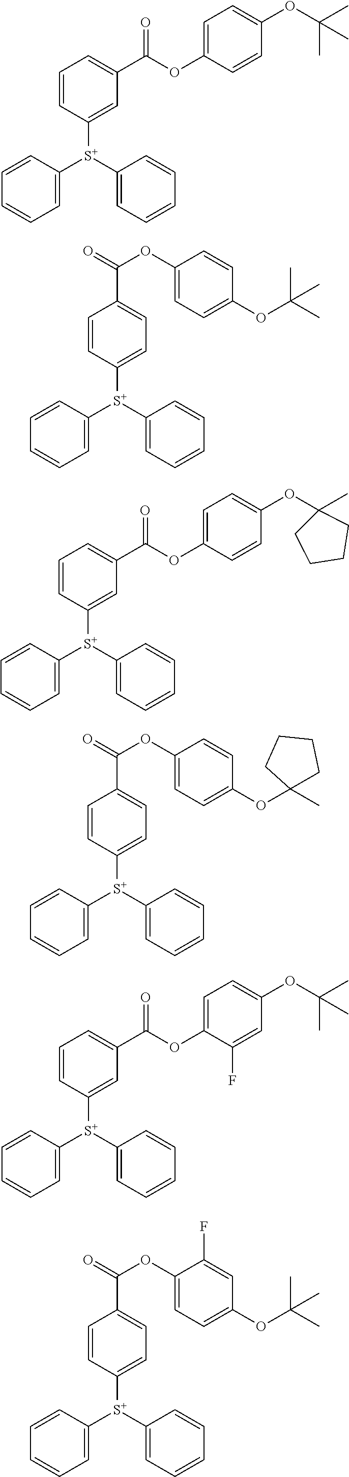 [SMILES: CC(C)(C)Oc1ccc(OC(=O)c2cccc([S+](c3ccccc3)c3ccccc3)c2)cc1 ; CC(C)(C)Oc1ccc(OC(=O)c2ccc([S+](c3ccccc3)c3ccccc3)cc2)cc1 ; CC1(Oc2ccc(OC(=O)c3cccc([S+](c4ccccc4)c4ccccc4)c3)cc2)CCCC1 ; CC1(Oc2ccc(OC(=O)c3ccc([S+](c4ccccc4)c4ccccc4)cc3)cc2)CCCC1 ; CC(C)(C)Oc1ccc(OC(=O)c2cccc([S+](c3ccccc3)c3ccccc3)c2)c(F)c1 ; CC(C)(C)Oc1ccc(OC(=O)c2ccc([S+](c3ccccc3)c3ccccc3)cc2)c(F)c1]

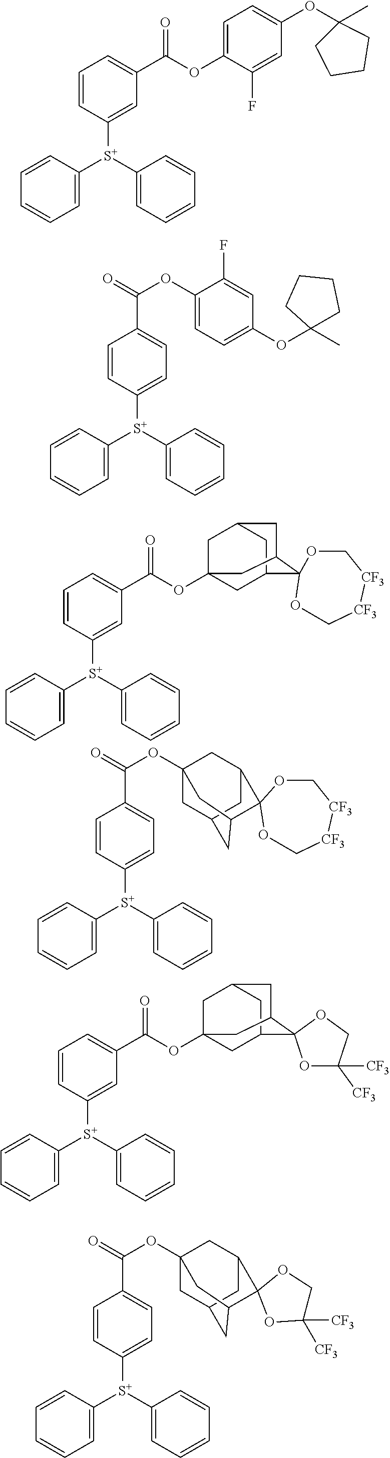

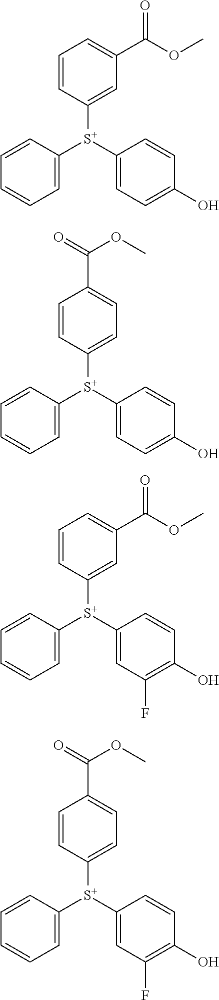 [SMILES: COC(=O)c1cccc([S+](c2ccccc2)c2ccc(O)cc2)c1 ; COC(=O)c1ccc([S+](c2ccccc2)c2ccc(O)cc2)cc1 ; COC(=O)c1cccc([S+](c2ccccc2)c2ccc(O)c(F)c2)c1 ; COC(=O)c1ccc([S+](c2ccccc2)c2ccc(O)c(F)c2)cc1]

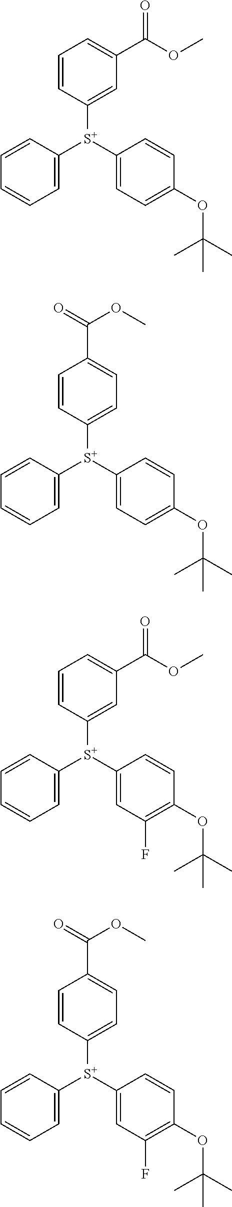 [SMILES: COC(=O)c1cccc([S+](c2ccccc2)c2ccc(OC(C)(C)C)cc2)c1 ; COC(=O)c1ccc([S+](c2ccccc2)c2ccc(OC(C)(C)C)cc2)cc1 ; COC(=O)c1cccc([S+](c2ccccc2)c2ccc(OC(C)(C)C)c(F)c2)c1 ; COC(=O)c1ccc([S+](c2ccccc2)c2ccc(OC(C)(C)C)c(F)c2)cc1]

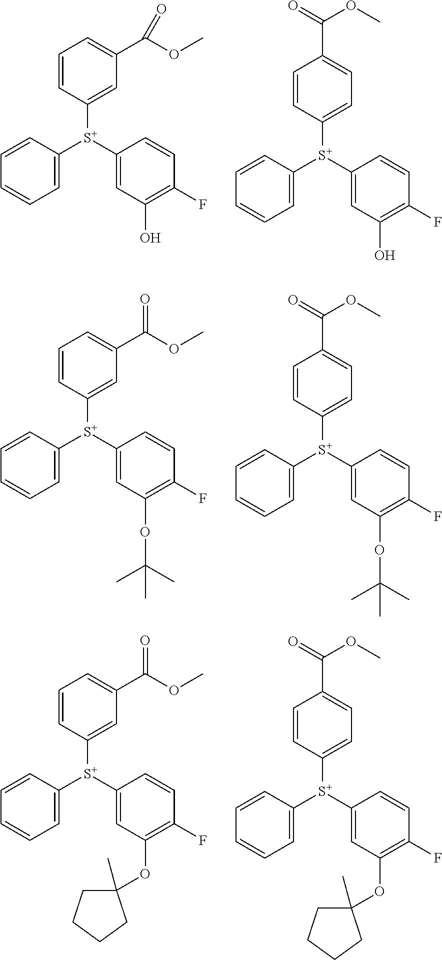 [SMILES: COC(=O)c1cccc([S+](c2ccccc2)c2ccc(F)c(O)c2)c1 ; COC(=O)c1ccc([S+](c2ccccc2)c2ccc(F)c(O)c2)cc1 ; COC(=O)c1cccc([S+](c2ccccc2)c2ccc(F)c(OC(C)(C)C)c2)c1 ; COC(=O)c1ccc([S+](c2ccccc2)c2ccc(F)c(OC(C)(C)C)c2)cc1 ; COC(=O)c1cccc([S+](c2ccccc2)c2ccc(F)c(OC3(C)CCCC3)c2)c1 ; COC(=O)c1ccc([S+](c2ccccc2)c2ccc(F)c(OC3(C)CCCC3)c2)cc1]

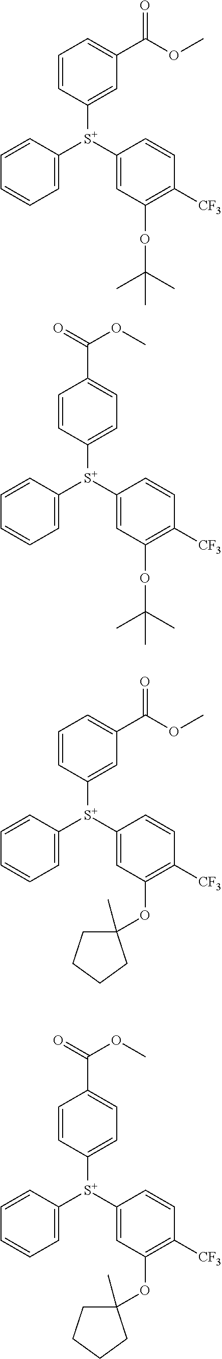 [SMILES: COC(=O)c1cccc([S+](c2ccccc2)c2ccc(C(F)(F)F)c(OC(C)(C)C)c2)c1 ; COC(=O)c1ccc([S+](c2ccccc2)c2ccc(C(F)(F)F)c(OC(C)(C)C)c2)cc1 ; COC(=O)c1cccc([S+](c2ccccc2)c2ccc(C(F)(F)F)c(OC3(C)CCCC3)c2)c1 ; COC(=O)c1ccc([S+](c2ccccc2)c2ccc(C(F)(F)F)c(OC3(C)CCCC3)c2)cc1]

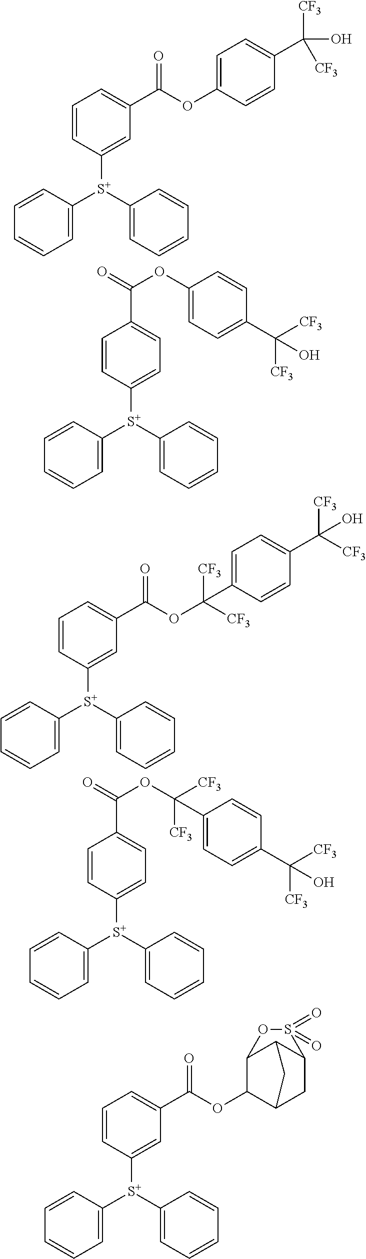 [SMILES: O=C(Oc1ccc(C(O)(C(F)(F)F)C(F)(F)F)cc1)c1cccc([S+](c2ccccc2)c2ccccc2)c1 ; O=C(Oc1ccc(C(O)(C(F)(F)F)C(F)(F)F)cc1)c1ccc([S+](c2ccccc2)c2ccccc2)cc1 ; O=C(OC(c1ccc(C(O)(C(F)(F)F)C(F)(F)F)cc1)(C(F)(F)F)C(F)(F)F)c1cccc([S+](c2ccccc2)c2ccccc2)c1 ; O=C(OC(c1ccc(C(O)(C(F)(F)F)C(F)(F)F)cc1)(C(F)(F)F)C(F)(F)F)c1ccc([S+](c2ccccc2)c2ccccc2)cc1 ; O=C(OC1C2CC3C1OS(=O)(=O)C3C2)c1cccc([S+](c2ccccc2)c2ccccc2)c1]

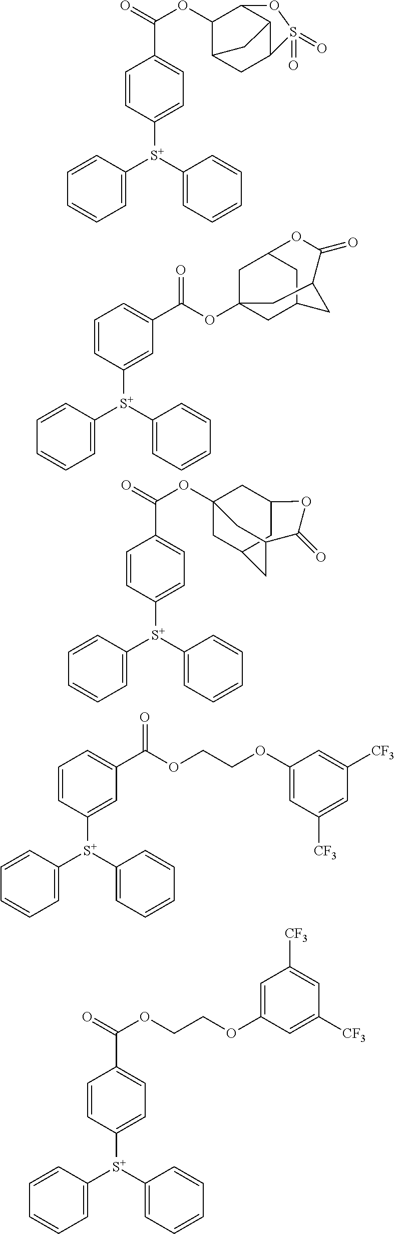 [SMILES: O=C(OC1C2CC3C1OS(=O)(=O)C3C2)c1ccc([S+](c2ccccc2)c2ccccc2)cc1 ; O=C(OC12CC3CC(C1)OC(=O)C(C3)C2)c1cccc([S+](c2ccccc2)c2ccccc2)c1 ; O=C(OC12CC3CC(C1)OC(=O)C(C3)C2)c1ccc([S+](c2ccccc2)c2ccccc2)cc1 ; O=C(OCCOc1cc(C(F)(F)F)cc(C(F)(F)F)c1)c1cccc([S+](c2ccccc2)c2ccccc2)c1 ; O=C(OCCOc1cc(C(F)(F)F)cc(C(F)(F)F)c1)c1ccc([S+](c2ccccc2)c2ccccc2)cc1]

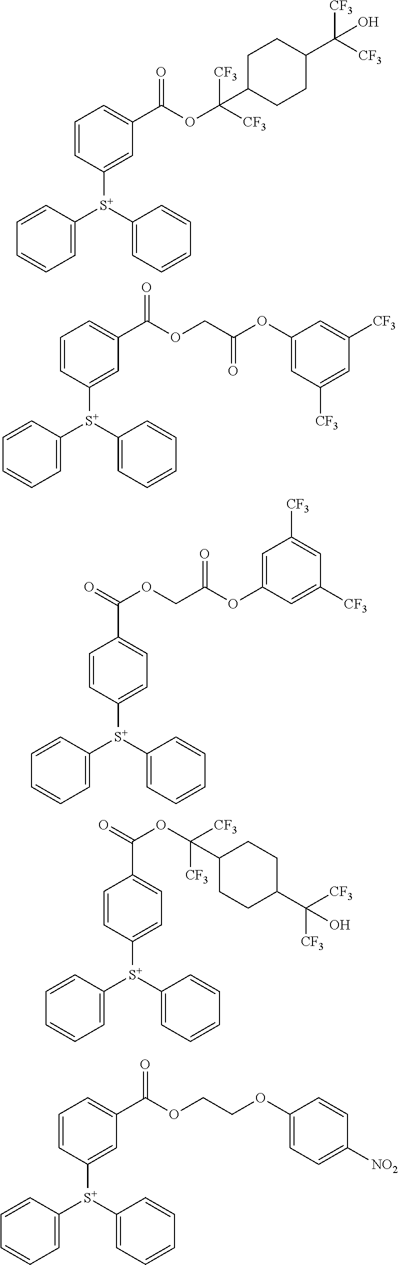 [SMILES: O=C(OC(C1CCC(C(O)(C(F)(F)F)C(F)(F)F)CC1)(C(F)(F)F)C(F)(F)F)c1cccc([S+](c2ccccc2)c2ccccc2)c1 ; O=C(COC(=O)c1cccc([S+](c2ccccc2)c2ccccc2)c1)Oc1cc(C(F)(F)F)cc(C(F)(F)F)c1 ; O=C(COC(=O)c1ccc([S+](c2ccccc2)c2ccccc2)cc1)Oc1cc(C(F)(F)F)cc(C(F)(F)F)c1 ; O=C(OC(C1CCC(C(O)(C(F)(F)F)C(F)(F)F)CC1)(C(F)(F)F)C(F)(F)F)c1ccc([S+](c2ccccc2)c2ccccc2)cc1 ; O=C(OCCOc1ccc([N+](=O)[O-])cc1)c1cccc([S+](c2ccccc2)c2ccccc2)c1]

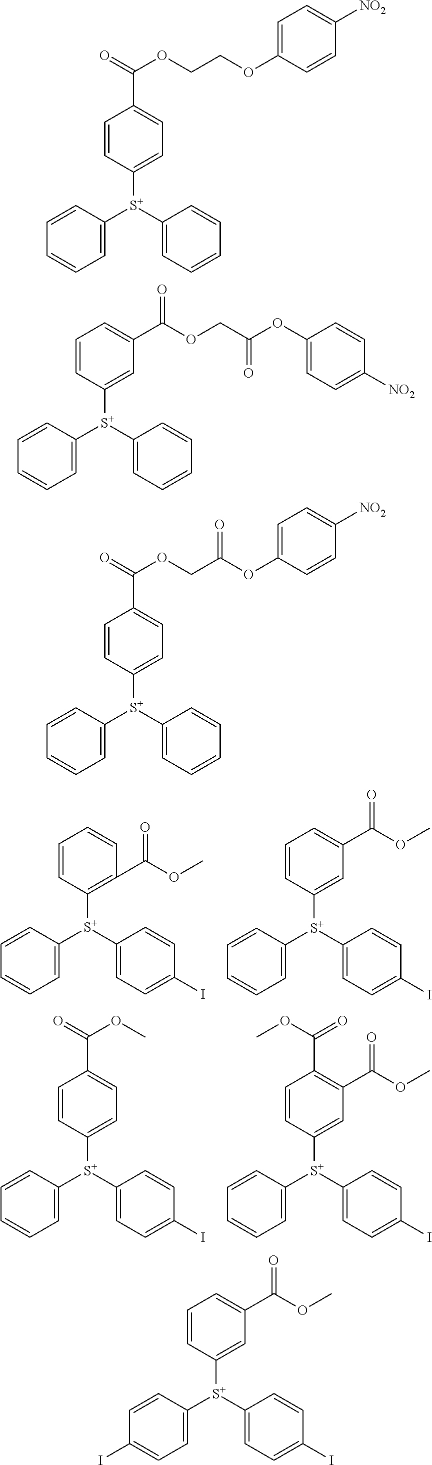

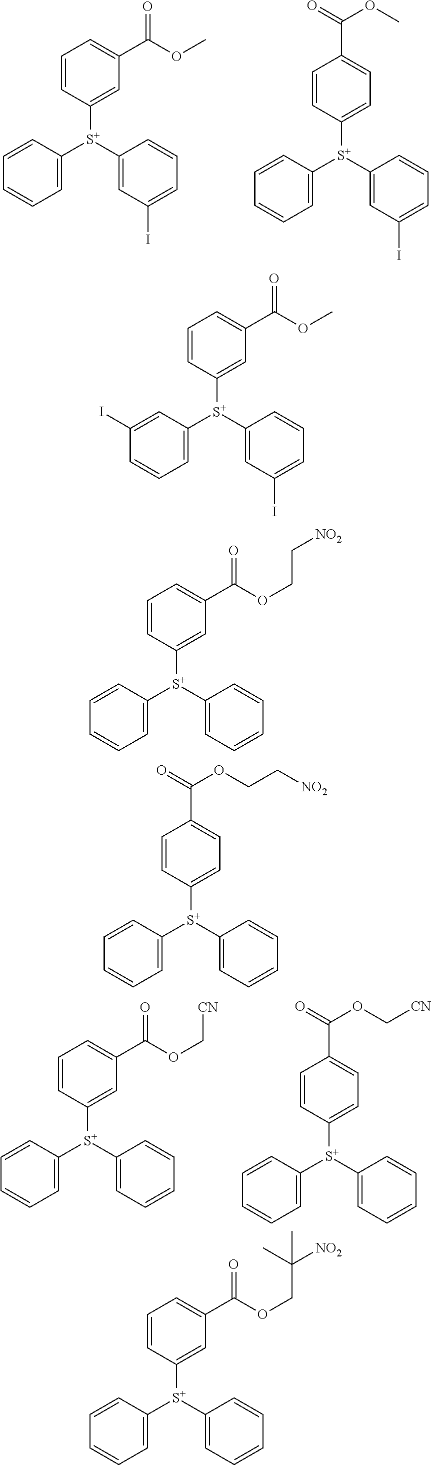

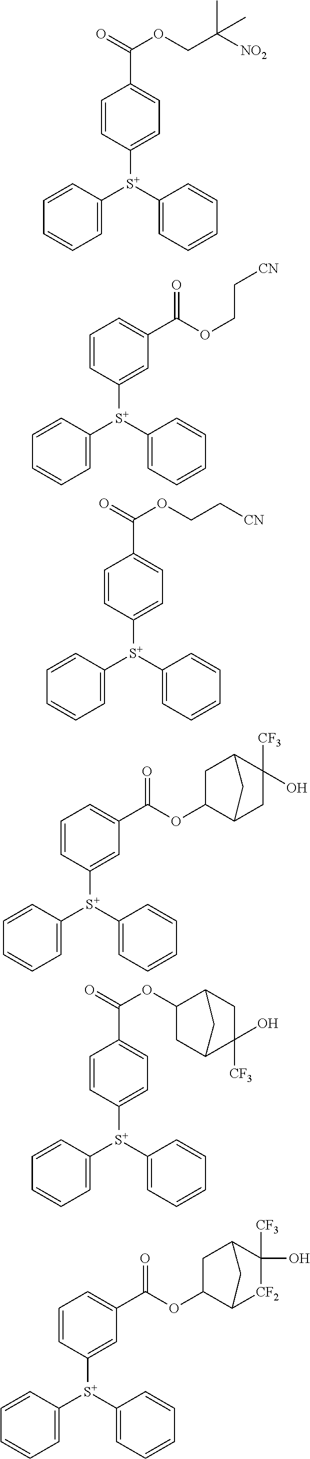 [SMILES: CC(C)(COC(=O)c1ccc([S+](c2ccccc2)c2ccccc2)cc1)[N+](=O)[O-] ; N#CCCOC(=O)c1cccc([S+](c2ccccc2)c2ccccc2)c1 ; N#CCCOC(=O)c1ccc([S+](c2ccccc2)c2ccccc2)cc1 ; O=C(OC1CC2CC1CC2(O)C(F)(F)F)c1cccc([S+](c2ccccc2)c2ccccc2)c1 ; O=C(OC1CC2CC1CC2(O)C(F)(F)F)c1ccc([S+](c2ccccc2)c2ccccc2)cc1 ; O=C(OC1CC2CC1C(F)(F)C2(O)C(F)(F)F)c1cccc([S+](c2ccccc2)c2ccccc2)c1]

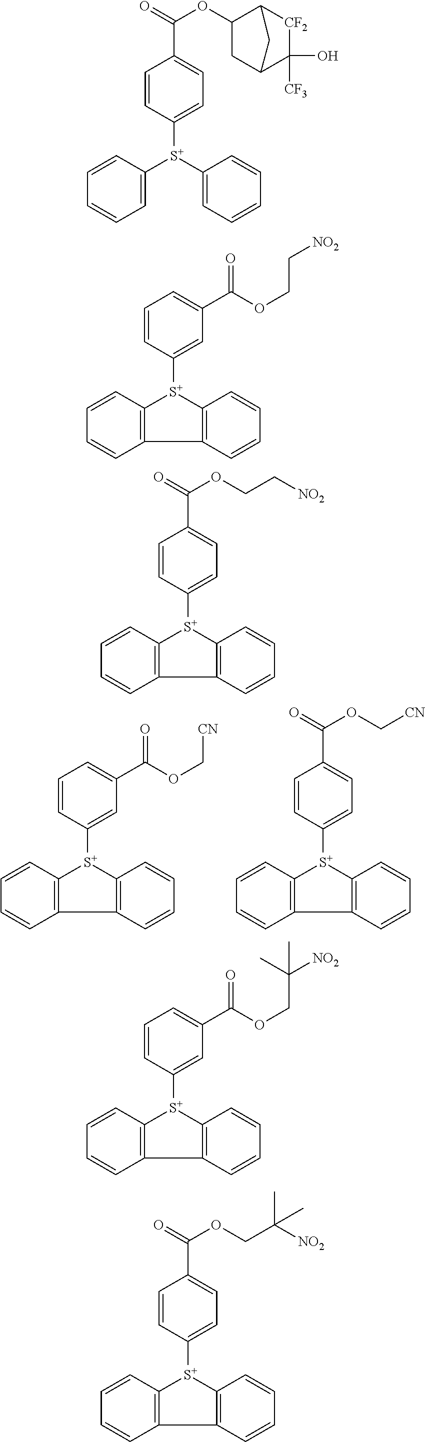

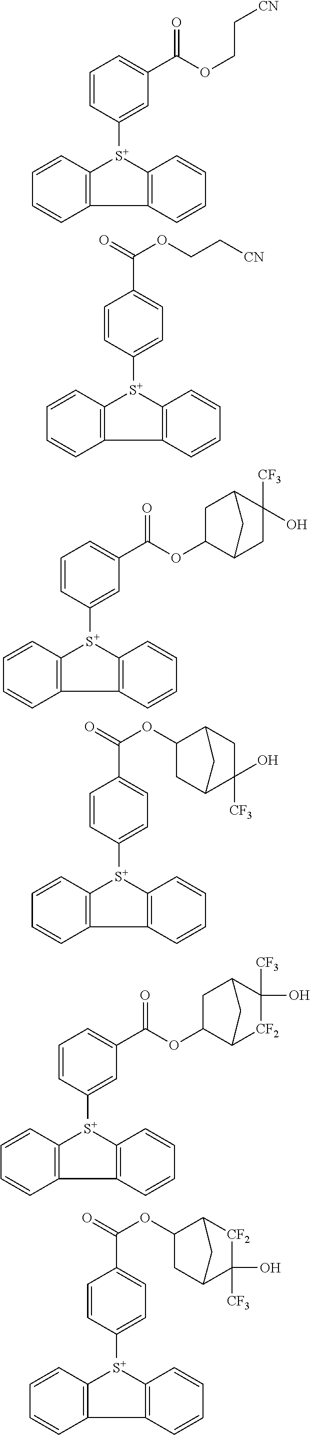 [SMILES: N#CCCOC(=O)c1cccc(-[s+]2c3ccccc3c3ccccc32)c1 ; N#CCCOC(=O)c1ccc(-[s+]2c3ccccc3c3ccccc32)cc1 ; O=C(OC1CC2CC1CC2(O)C(F)(F)F)c1cccc(-[s+]2c3ccccc3c3ccccc32)c1 ; O=C(OC1CC2CC1CC2(O)C(F)(F)F)c1ccc(-[s+]2c3ccccc3c3ccccc32)cc1 ; O=C(OC1CC2CC1C(F)(F)C2(O)C(F)(F)F)c1cccc(-[s+]2c3ccccc3c3ccccc32)c1 ; O=C(OC1CC2CC1C(F)(F)C2(O)C(F)(F)F)c1ccc(-[s+]2c3ccccc3c3ccccc32)cc1]

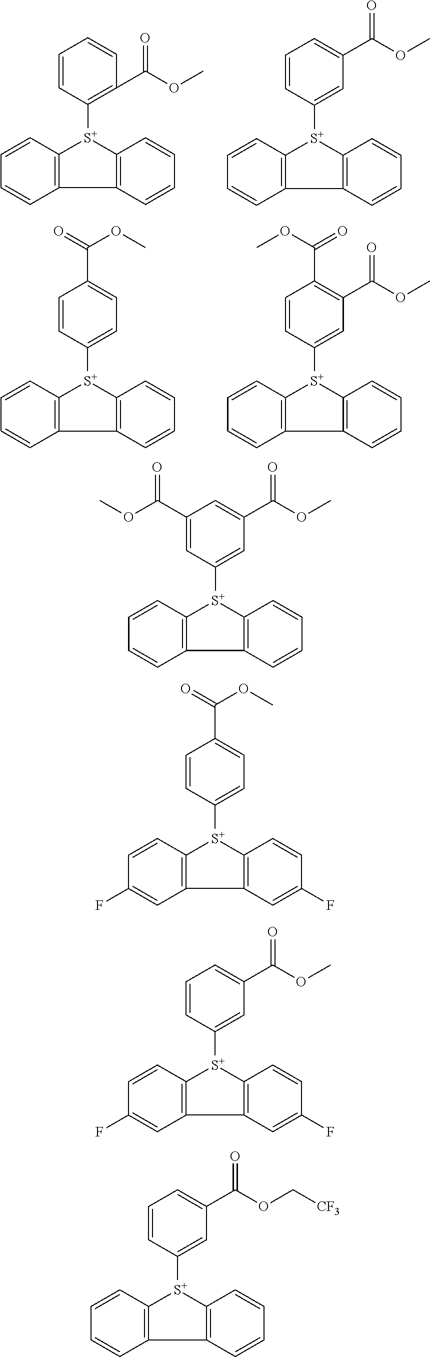

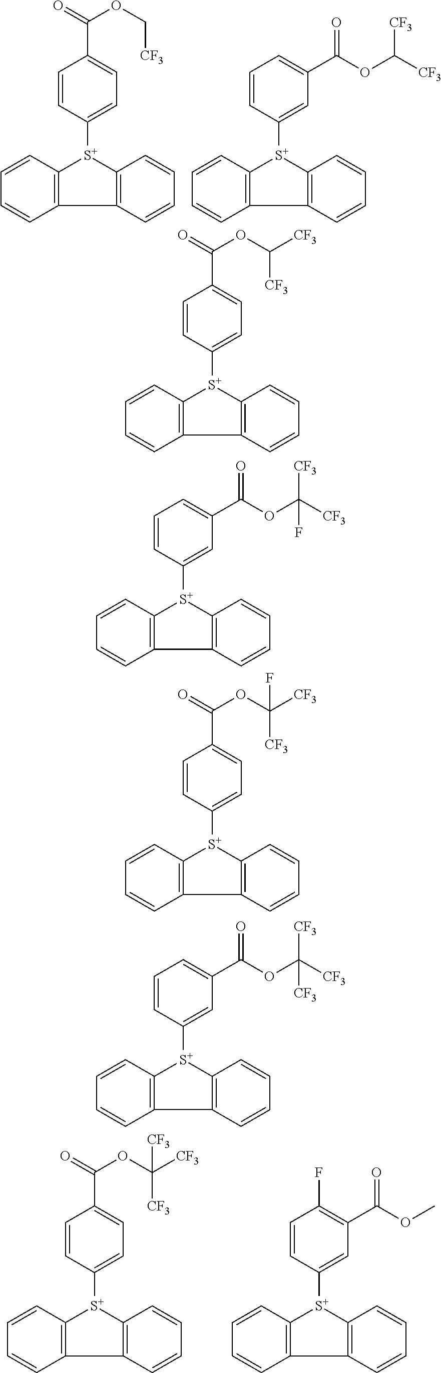

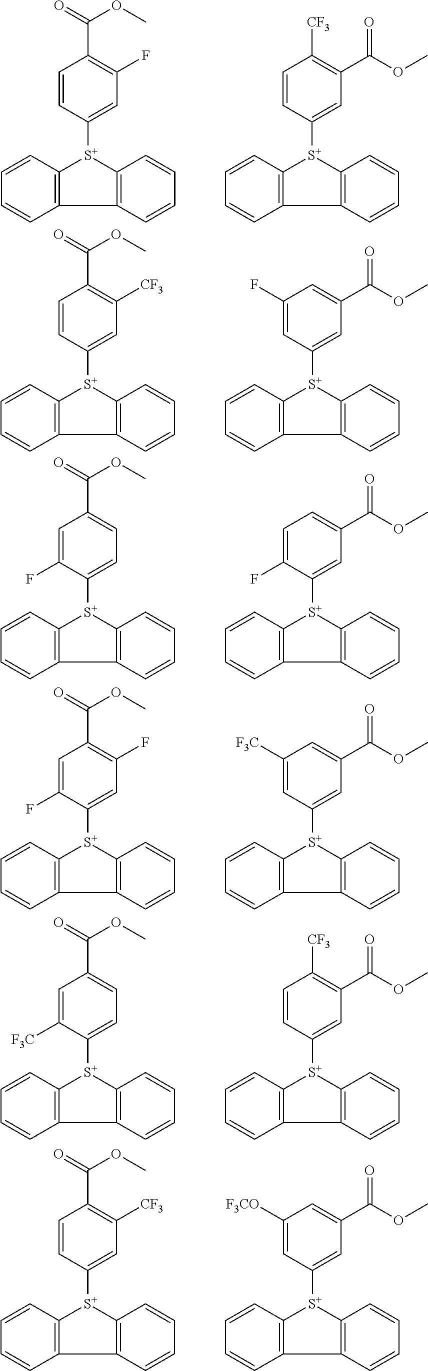

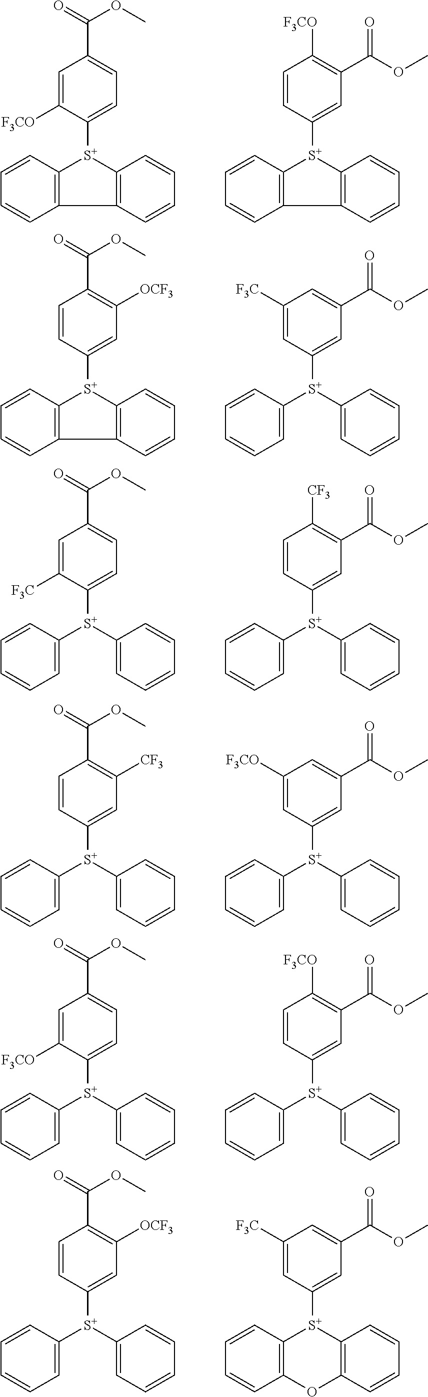

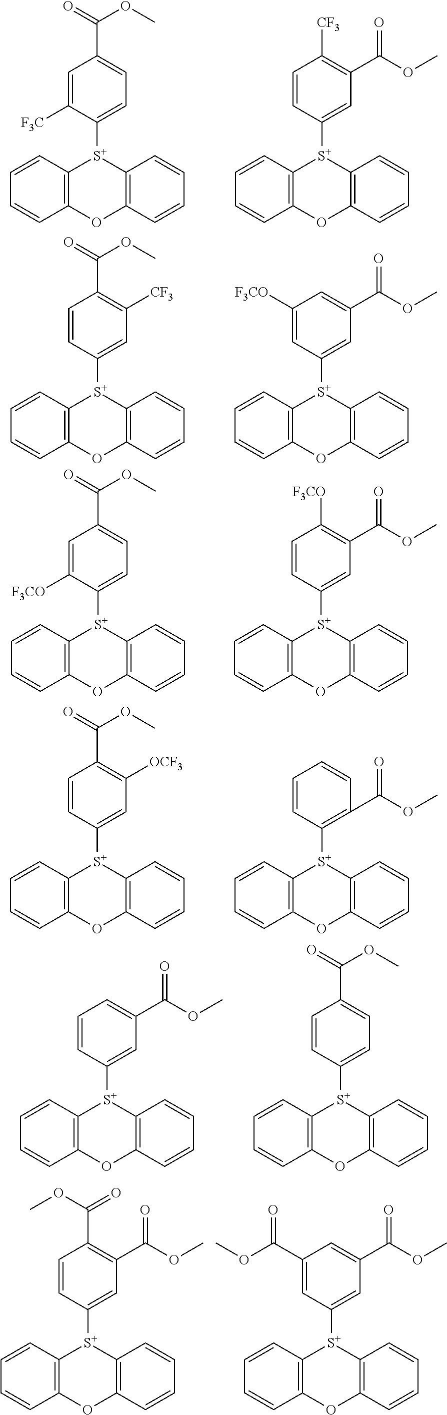

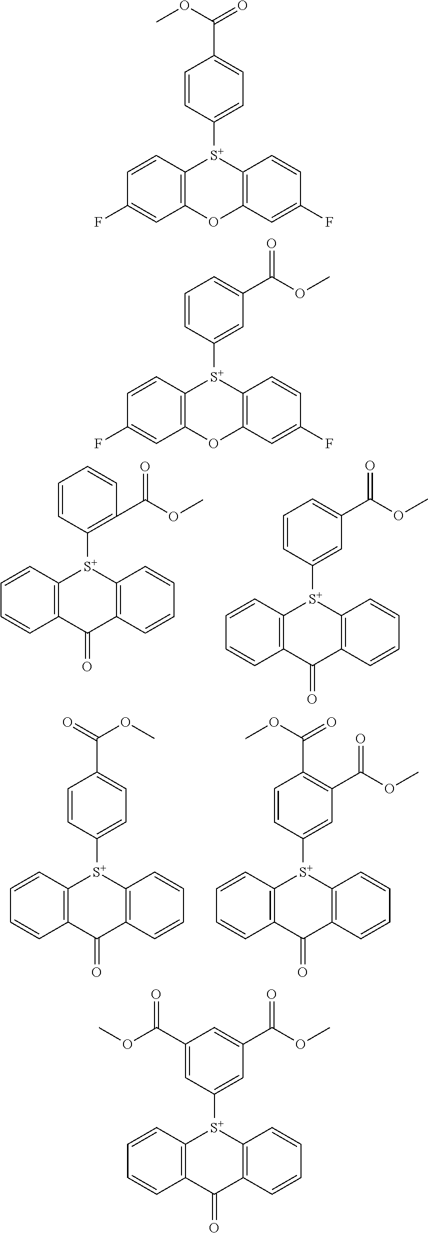

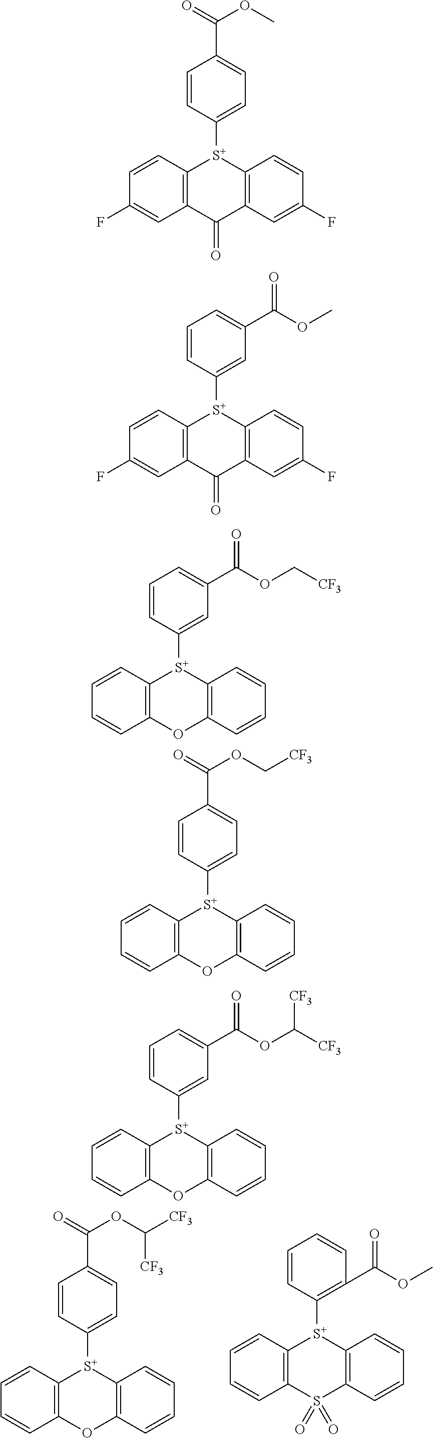

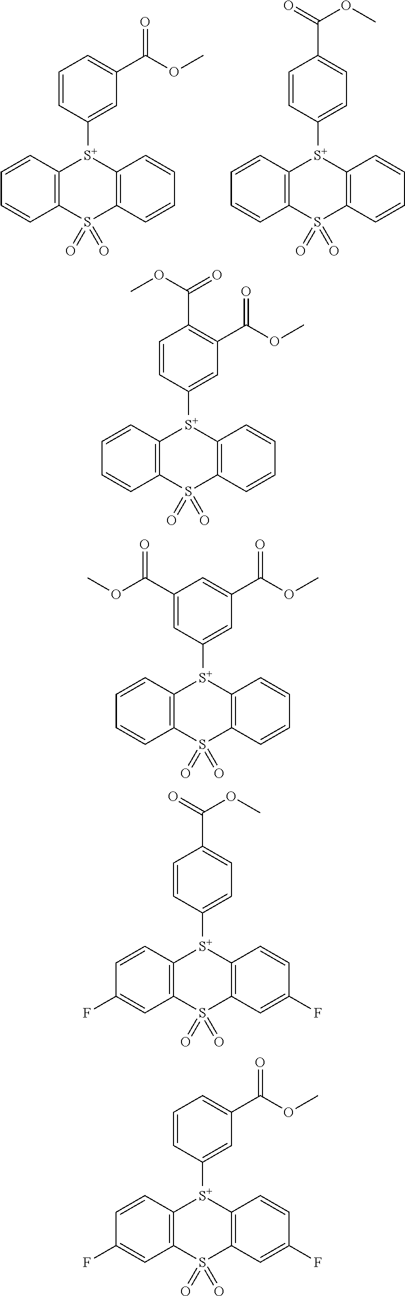

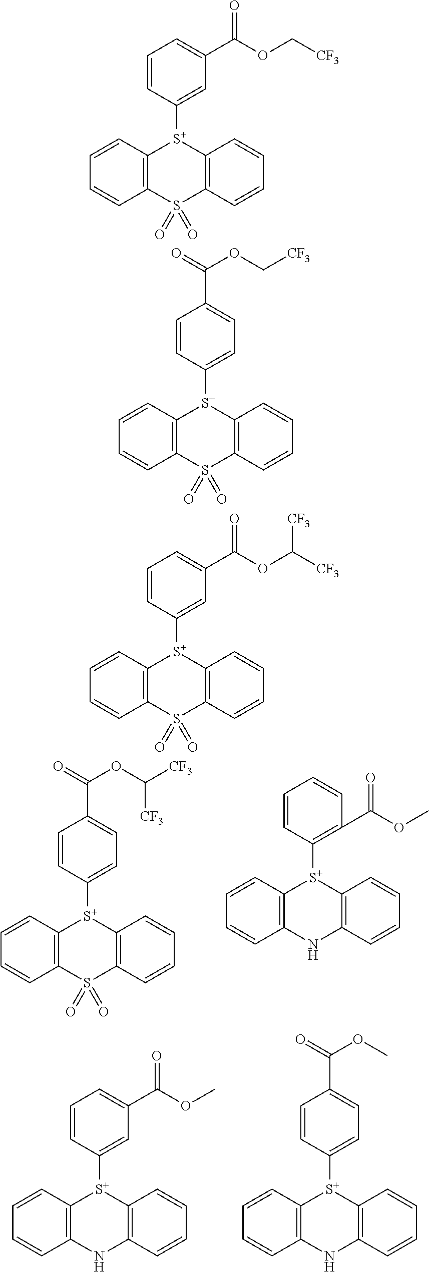

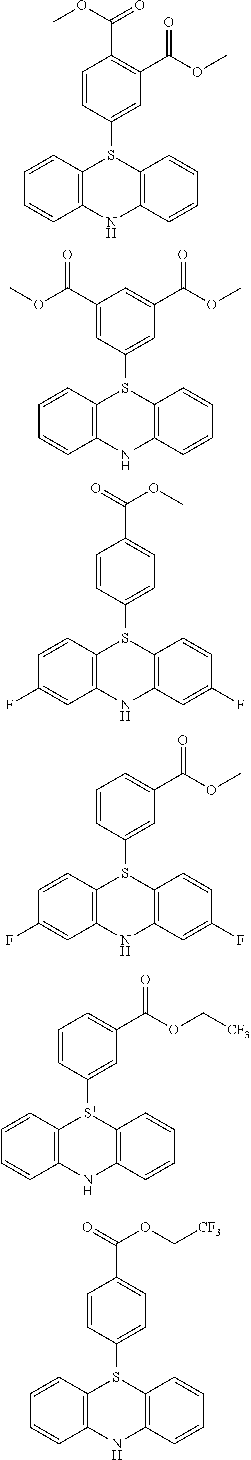

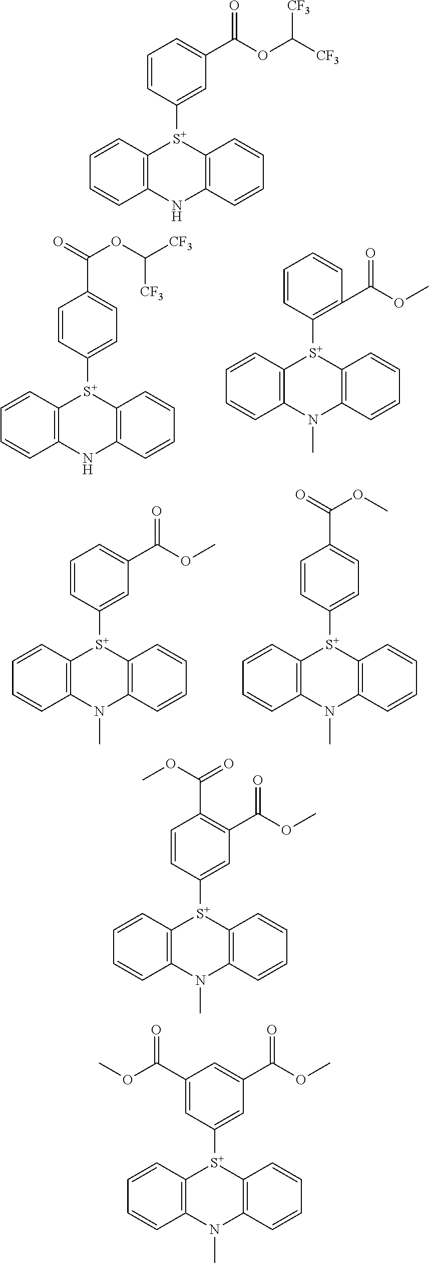

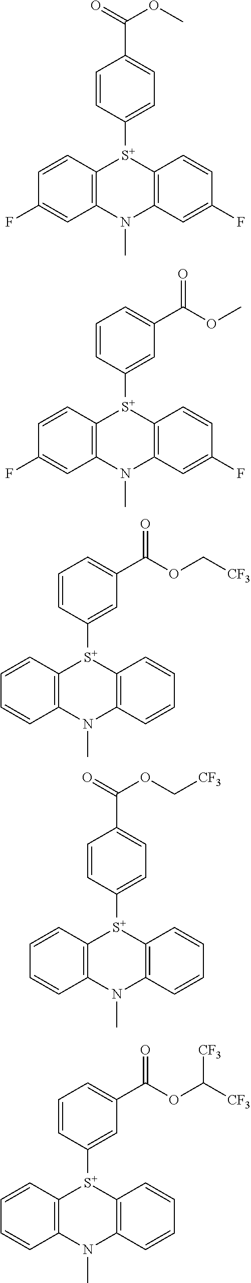 [SMILES: COC(=O)c1ccc([S+]2c3ccc(F)cc3N(C)c3cc(F)ccc32)cc1 ; COC(=O)c1cccc([S+]2c3ccc(F)cc3N(C)c3cc(F)ccc32)c1 ; CN1c2ccccc2[S+](c2cccc(C(=O)OCC(F)(F)F)c2)c2ccccc21 ; CN1c2ccccc2[S+](c2ccc(C(=O)OCC(F)(F)F)cc2)c2ccccc21 ; CN1c2ccccc2[S+](c2cccc(C(=O)OC(C(F)(F)F)C(F)(F)F)c2)c2ccccc21]

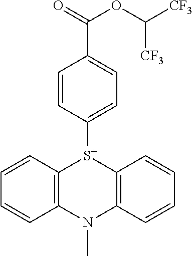 [SMILES: CN1c2ccccc2[S+](c2ccc(C(=O)OC(C(F)(F)F)C(F)(F)F)cc2)c2ccccc21]

For the sulfonium cation having formula (1), the cations described in paragraphs [0026] to [0040] of JP-A 2022-068394 can also be used.

The repeat units (a) preferably have formula (a1) (hereinafter, the repeat units are also referred to as repeat units (a1)) or formula (a2) (hereinafter, the repeat units are also referred to as repeat units (a2)).

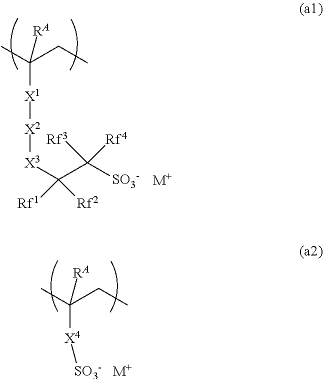

In formulae (a1) and (a2), R^{A} is each independently a hydrogen atom or a methyl group. X¹ is a single bond or an ester bond. X² is a single bond, —X²¹—C(═O)—O—, or —X²¹—O—. X²¹ is a C₁-C₂ hydrocarbylene group, a phenylene group, or a C₇-C₁₈ group obtained by combining the foregoing, which may contain a carbonyl group, a nitro group, a cyano group, an ester bond, an ether bond, a urethane bond, a fluorine atom, an iodine atom, or a bromine atom. X³ is a single bond, a methylene group, or an ethylene group. X⁴ is a single bond, a methylene group, an ethylene group, a phenylene group, a methylphenylene group, a dimethylphenylene group, a fluorinated phenylene group, a trifluoromethyl-substituted phenylene group, —O—X⁴¹—, —C(═O)—O—X⁴¹—, or —C(═O)—NH—X⁴¹—. X¹ is a C₁-C₆ aliphatic hydrocarbylene group, a phenylene group, a methylphenylene group, a dimethylphenylene group, a fluorinated phenylene group, or a trifluoromethyl-substituted phenylene group, which may contain a carbonyl group, an ester bond, an ether bond, a hydroxy group, or a halogen atom. Rf¹ to Rf⁴ are each independently a hydrogen atom, a fluorine atom, or a trifluoromethyl group, at least one of Rf¹ to Rf⁴ is a fluorine atom or a trifluoromethyl group, and Rf¹ and Rf² may together form a carbonyl group. M⁺ is the sulfonium cation having formula (1).

Examples of the anion in the monomer from which the repeat units (a1) are derived include those shown below, but are not limited thereto. In the formulae, R^{A} is as defined above.

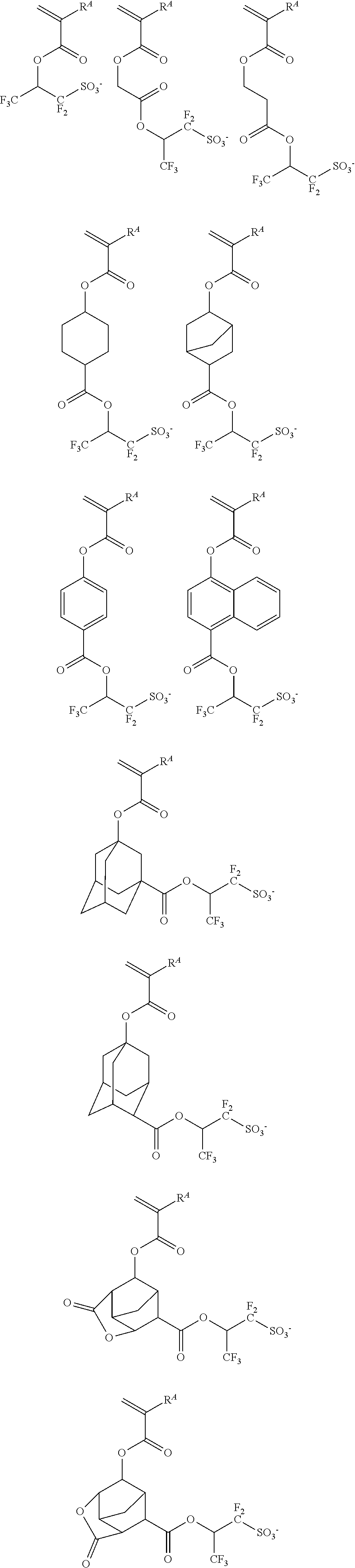

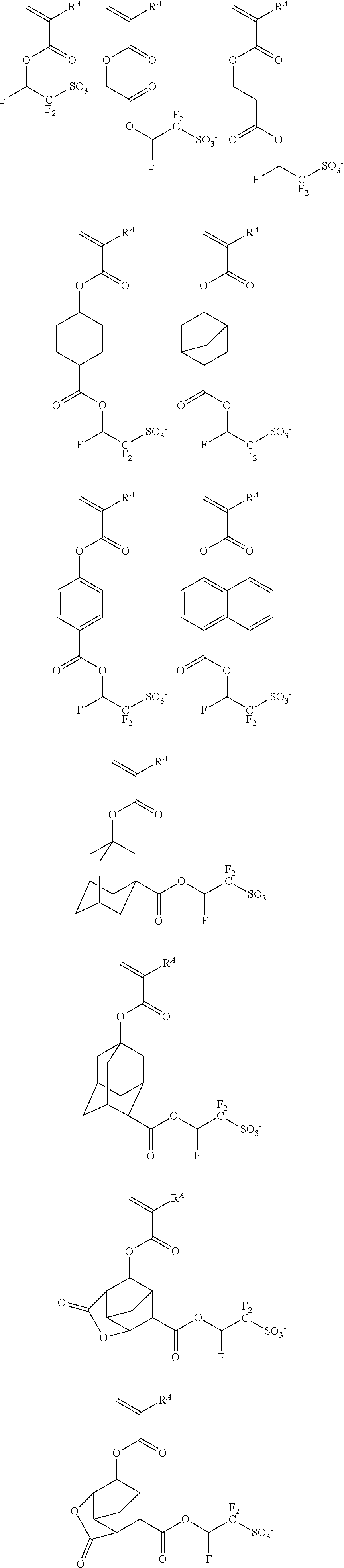

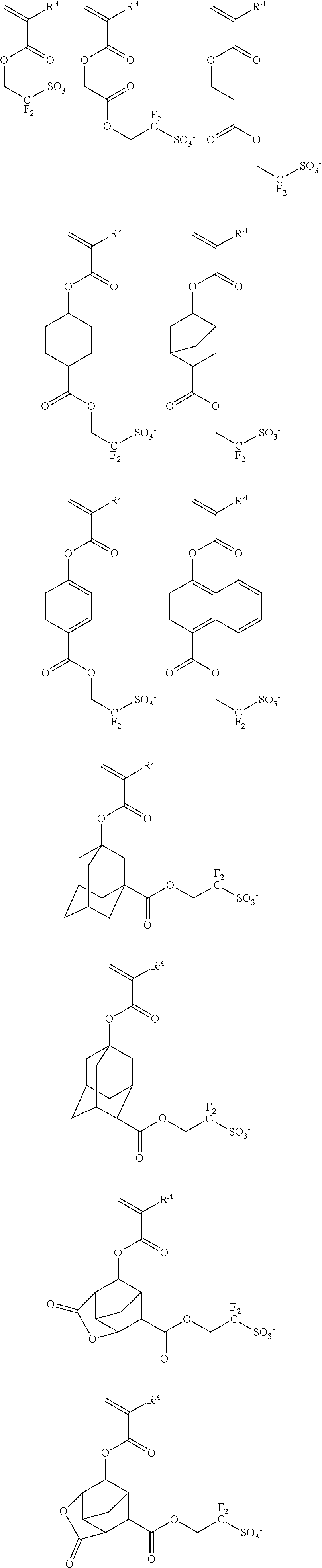

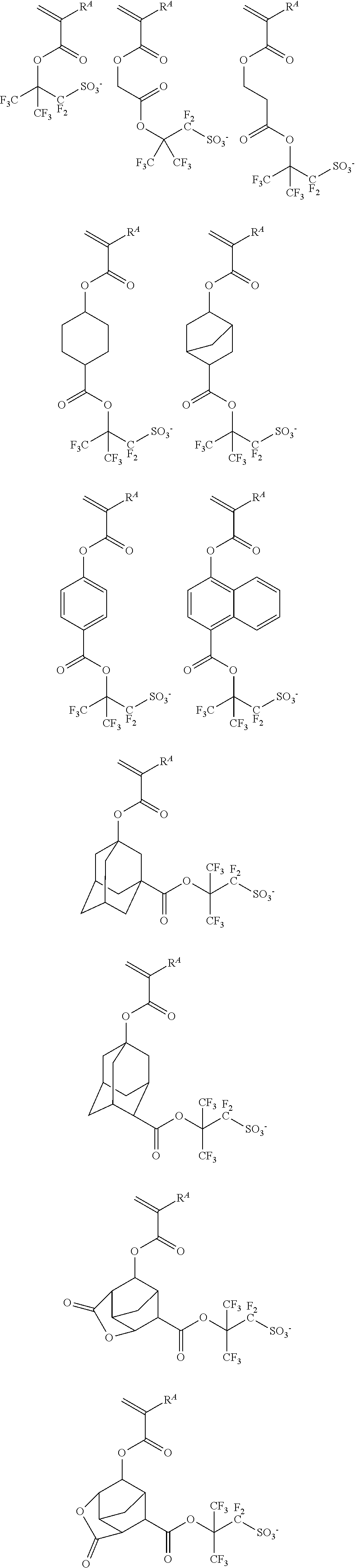

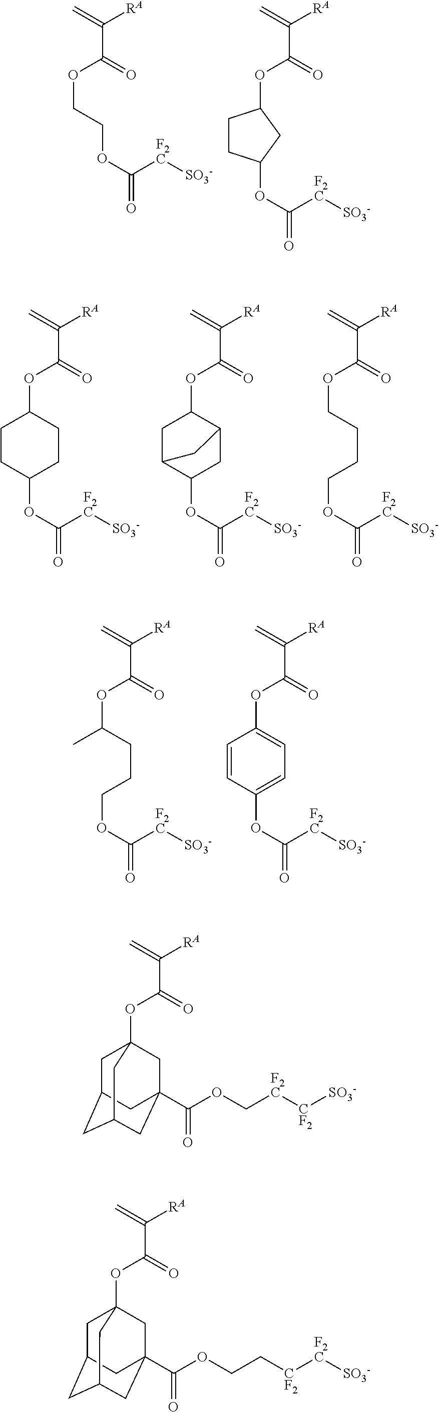

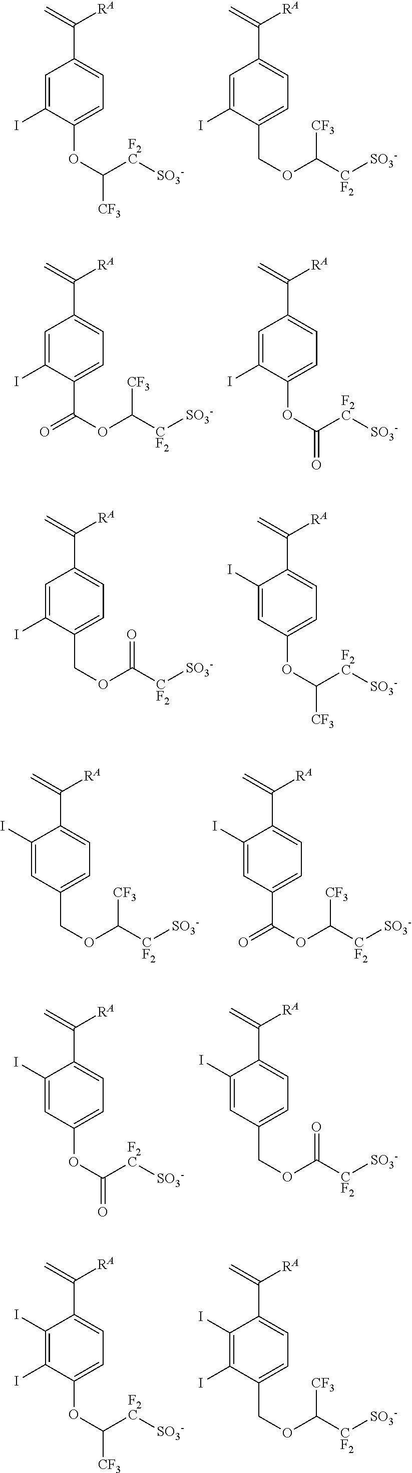

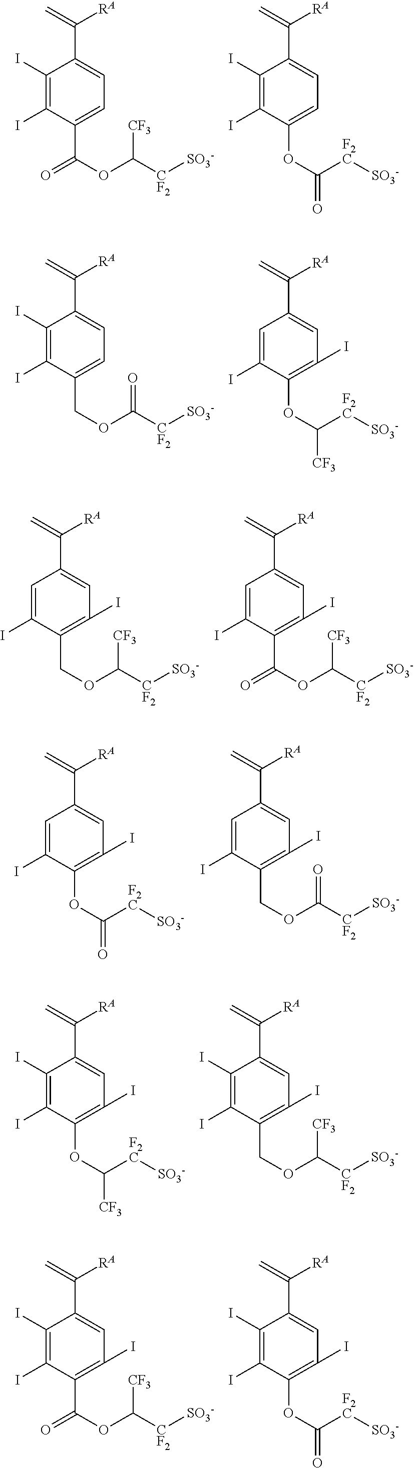

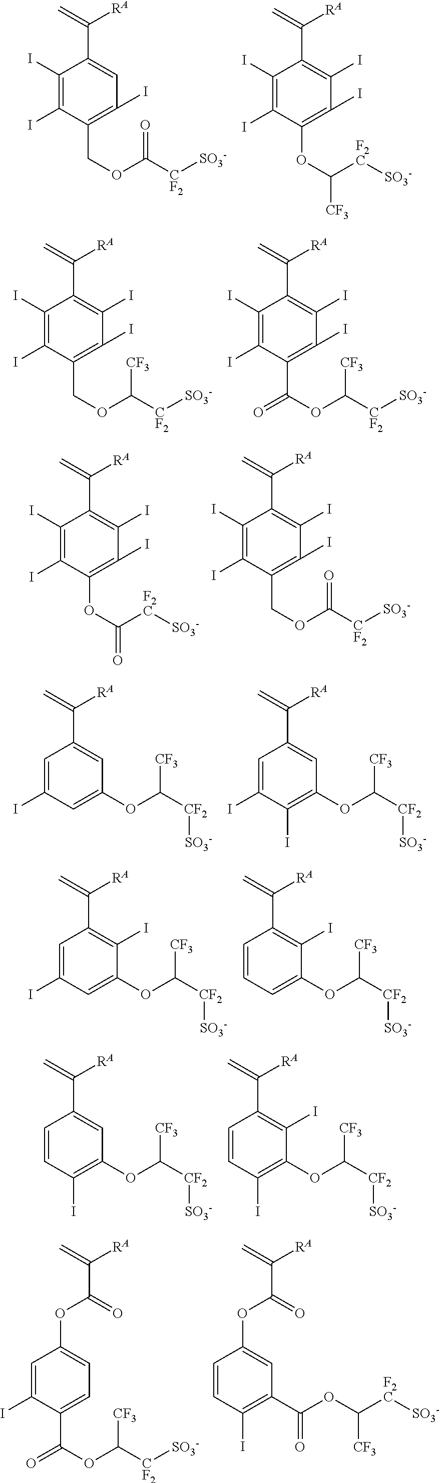

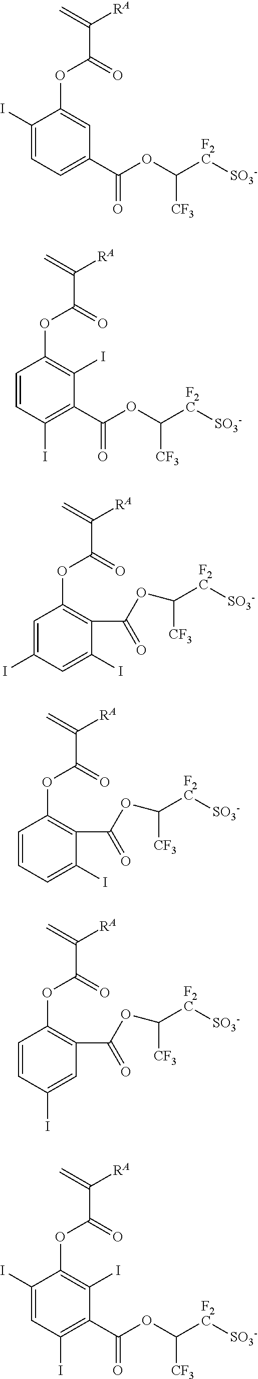

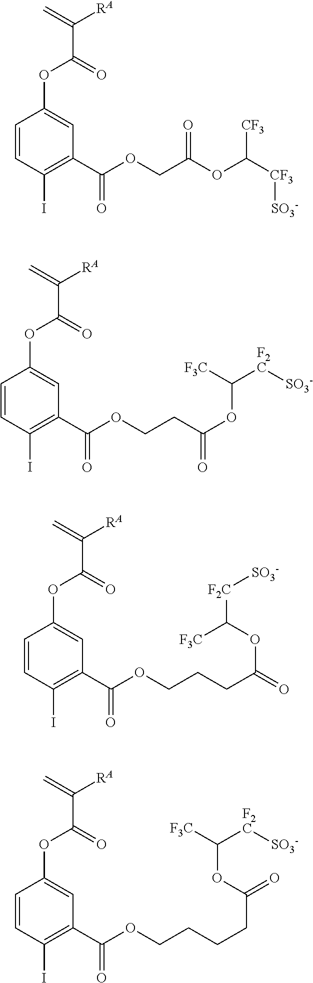

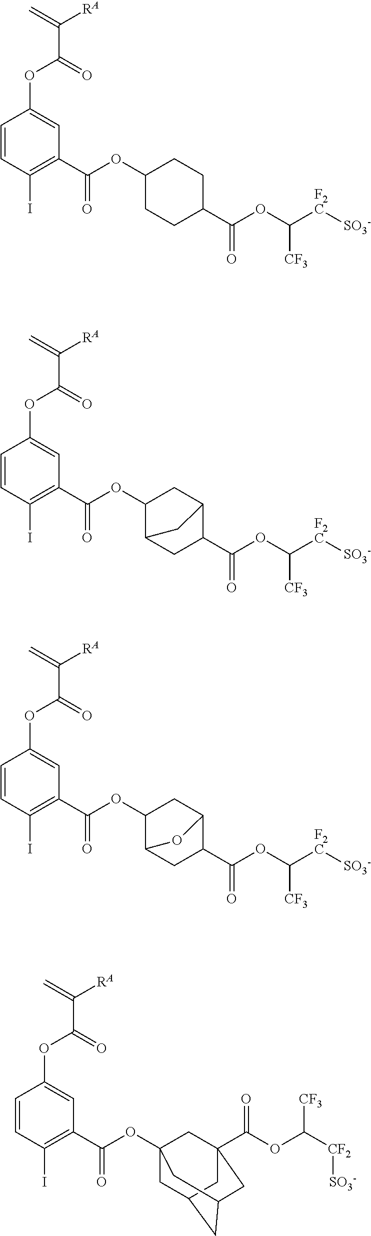

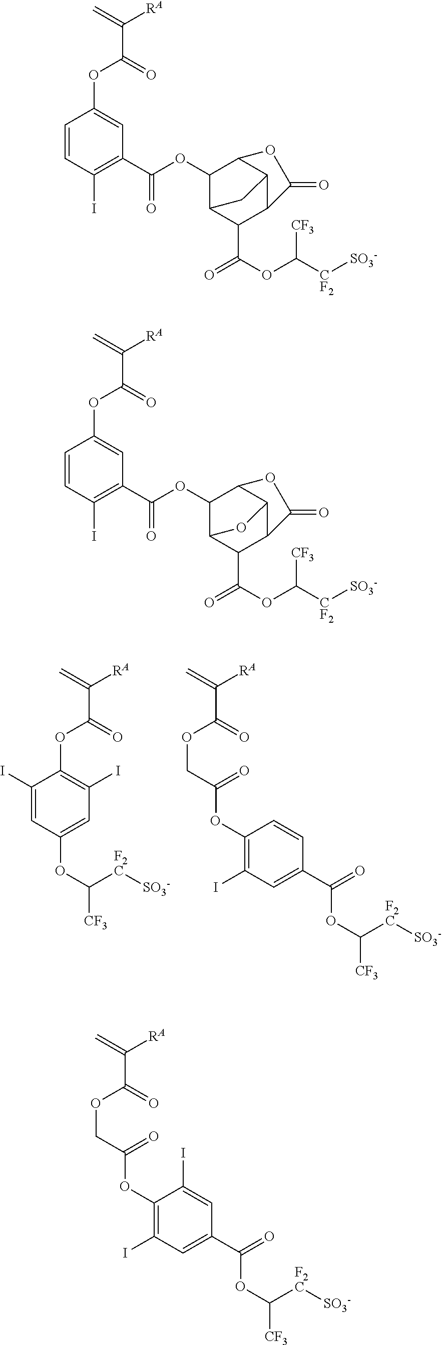

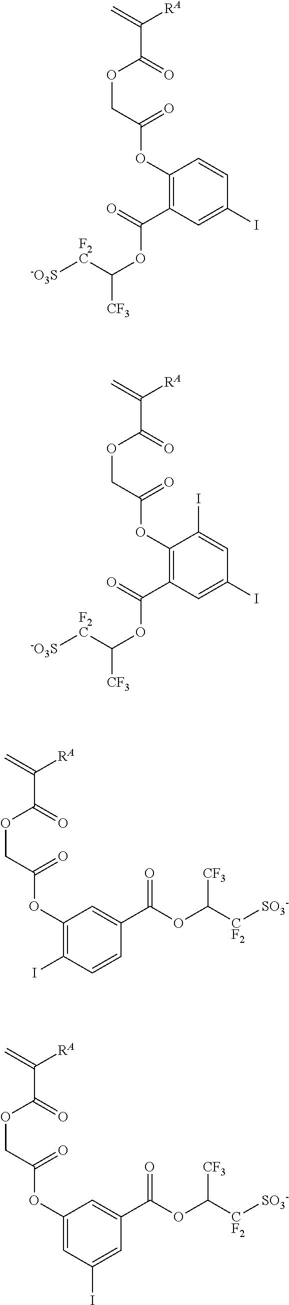

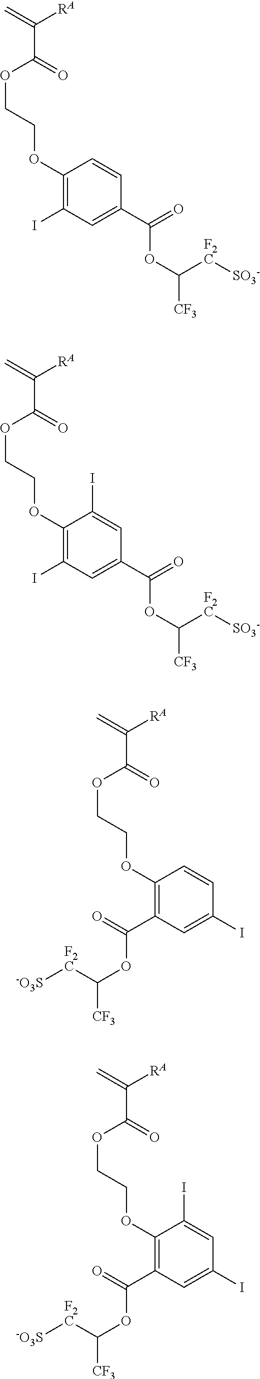

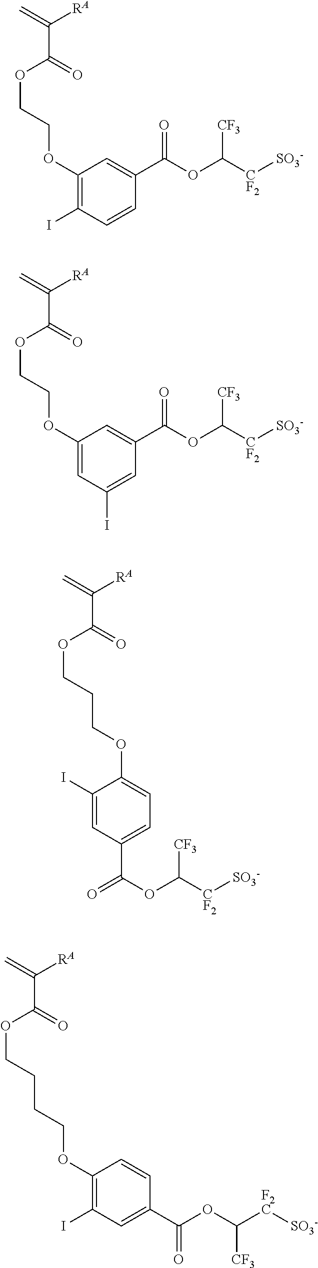

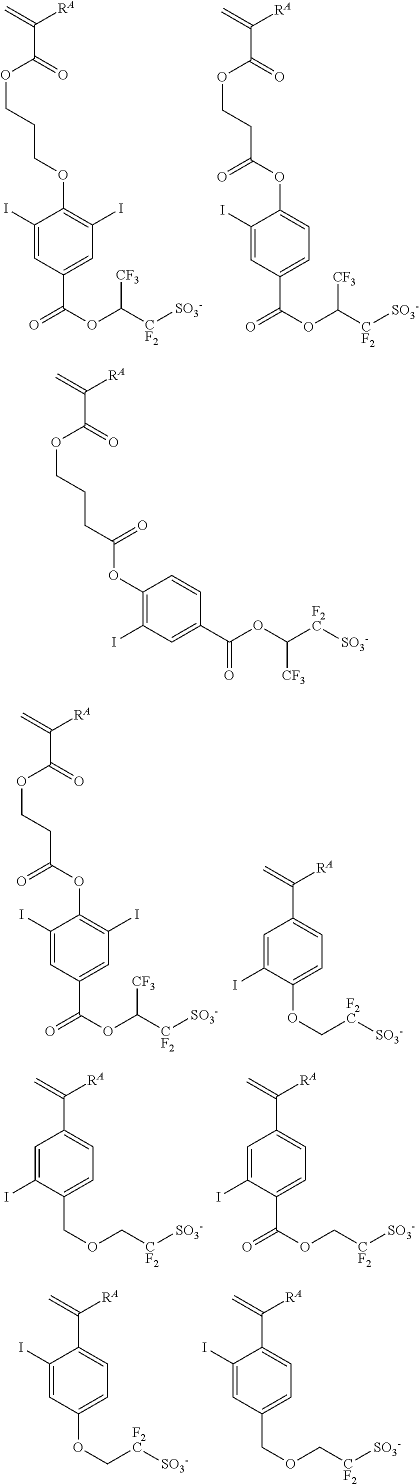

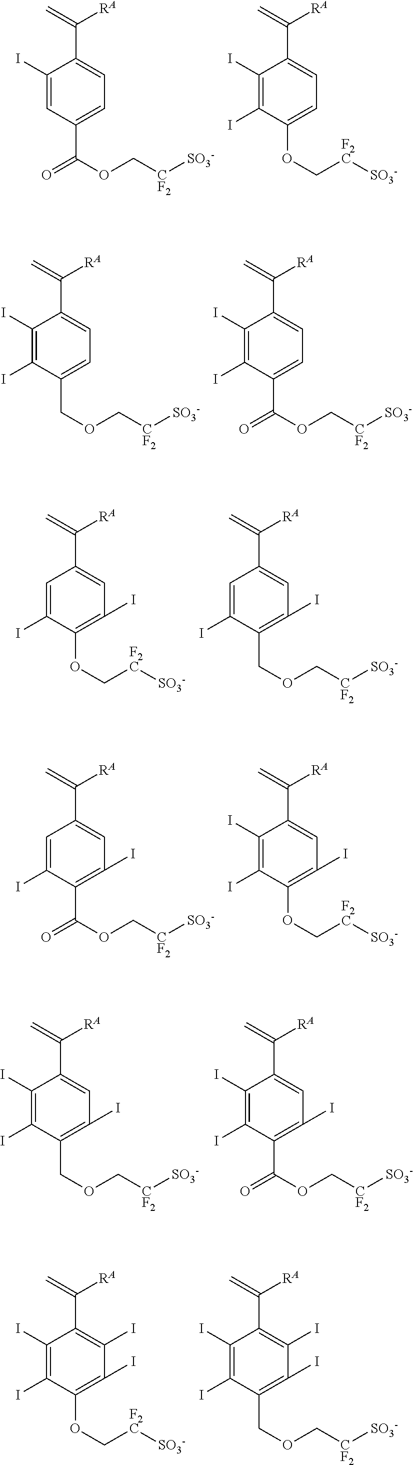

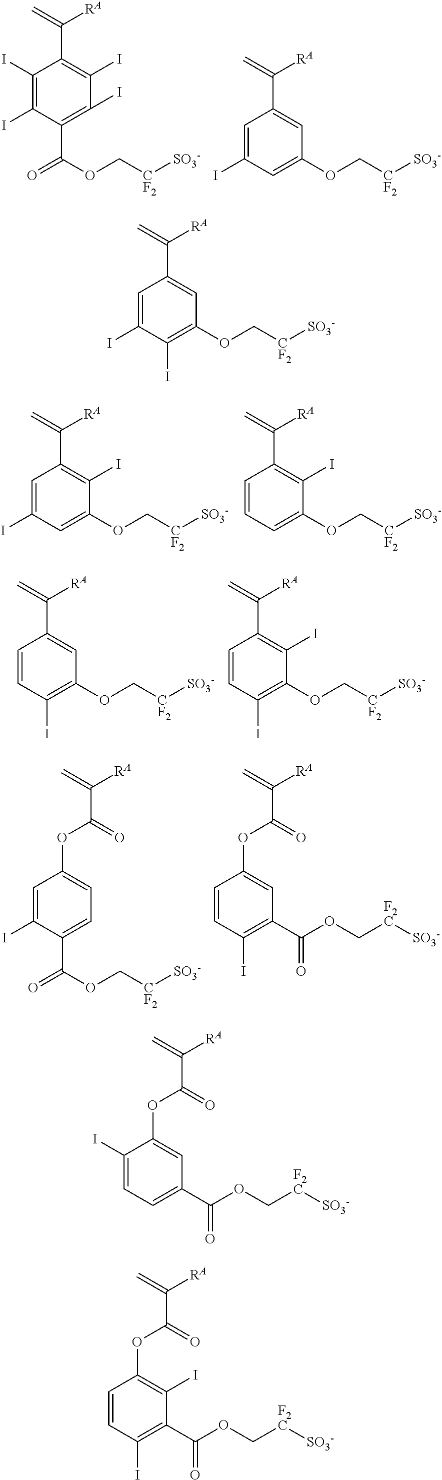

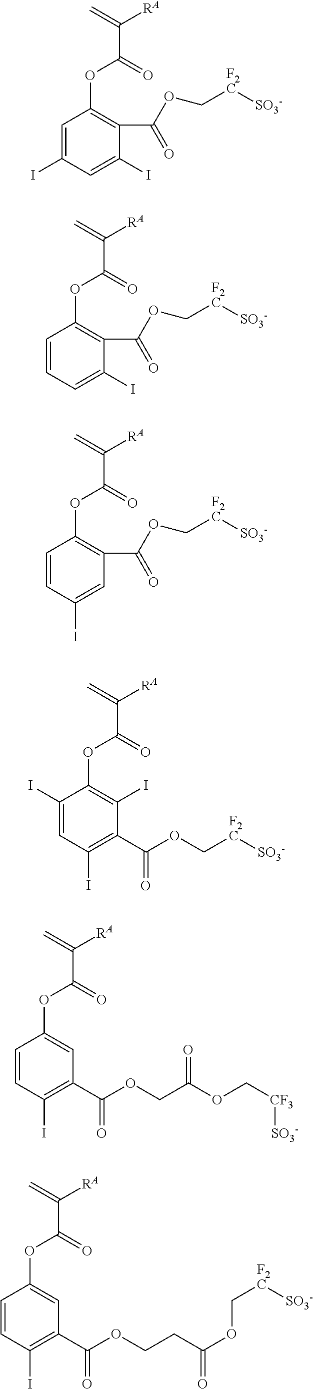

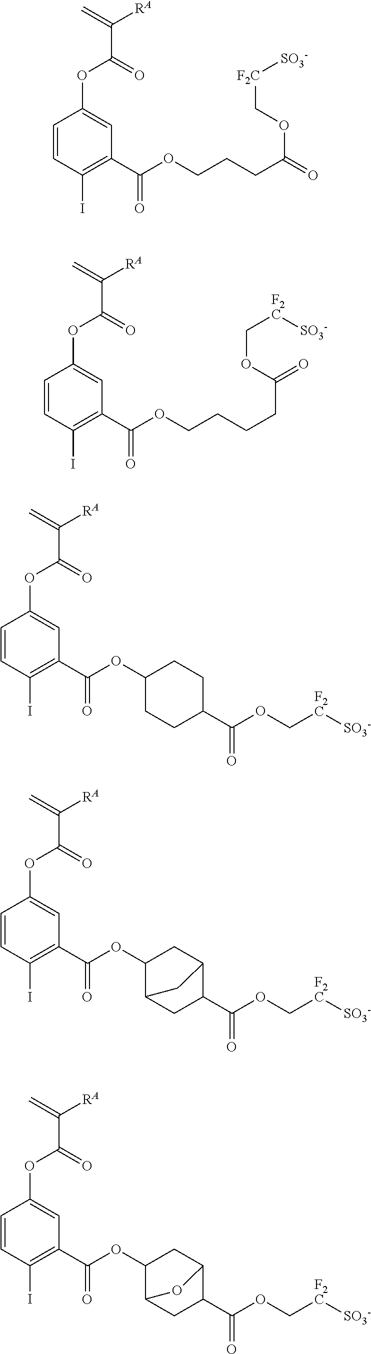

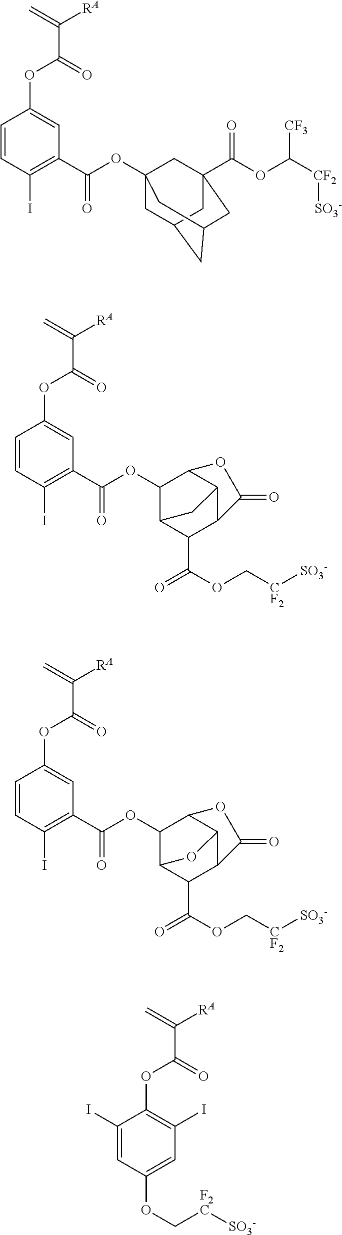

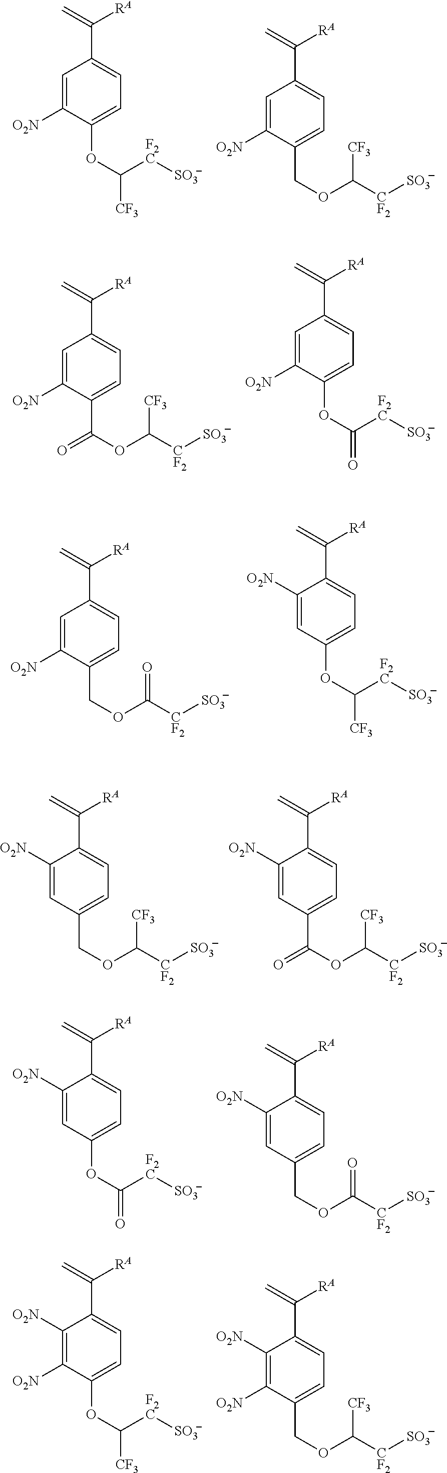

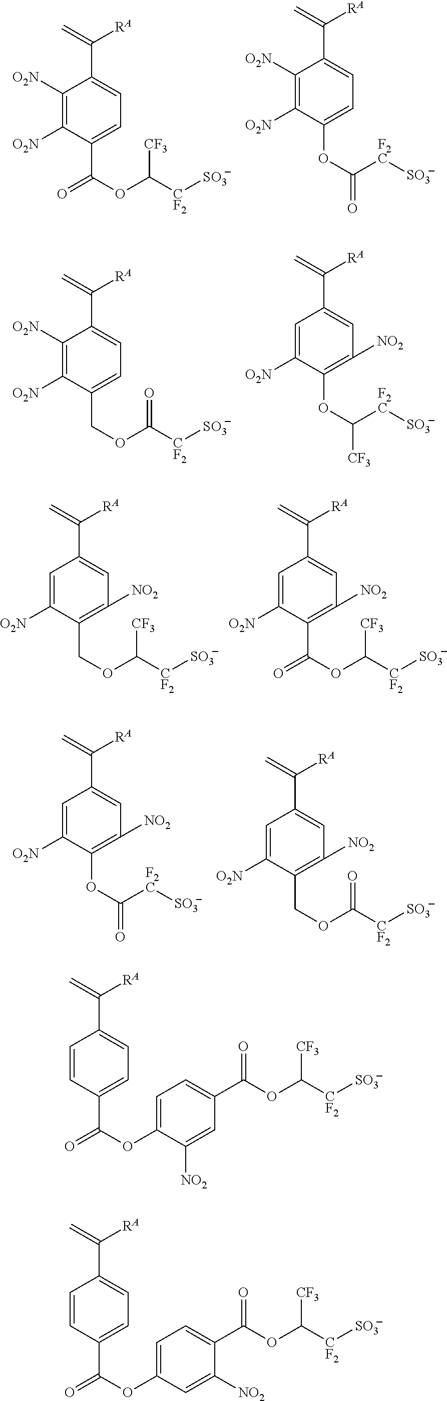

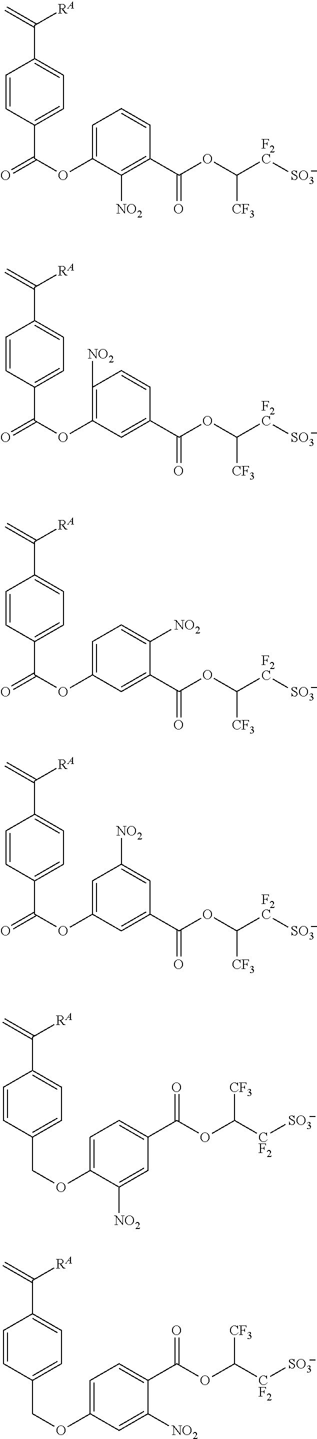

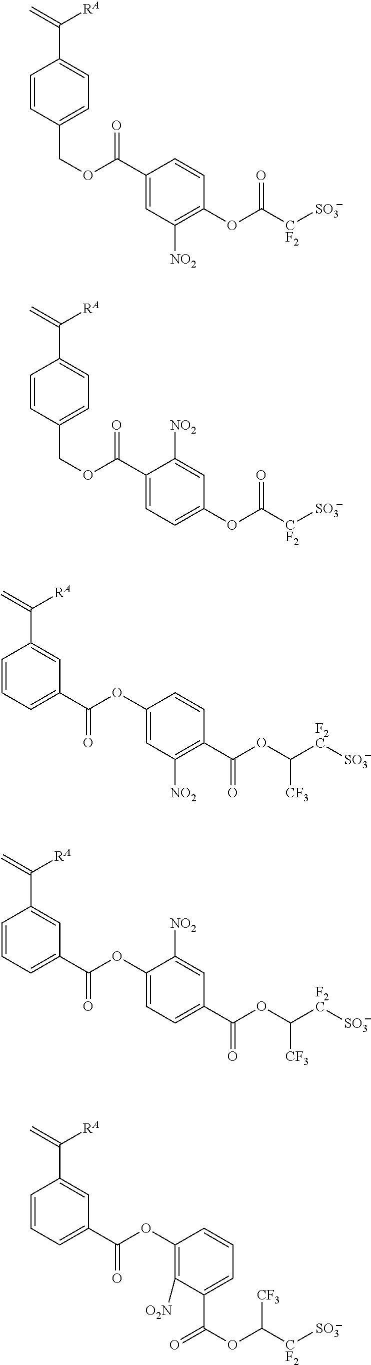

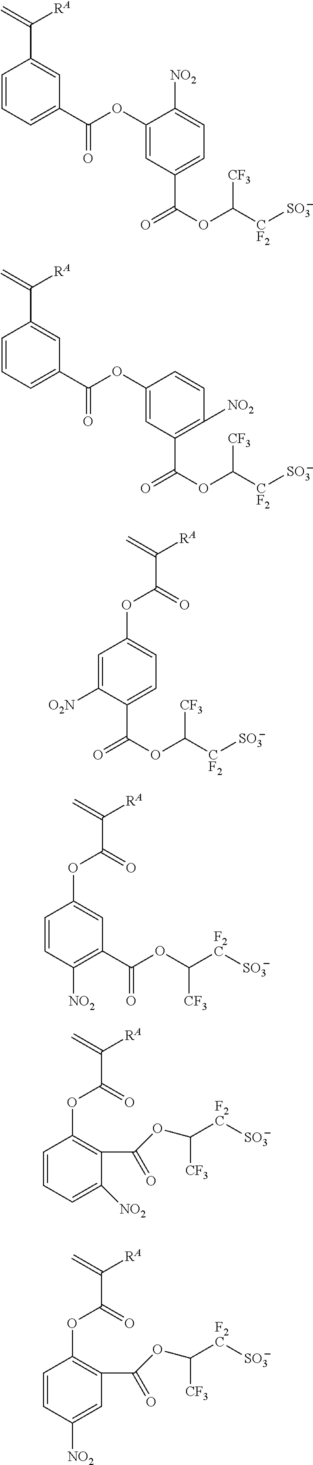

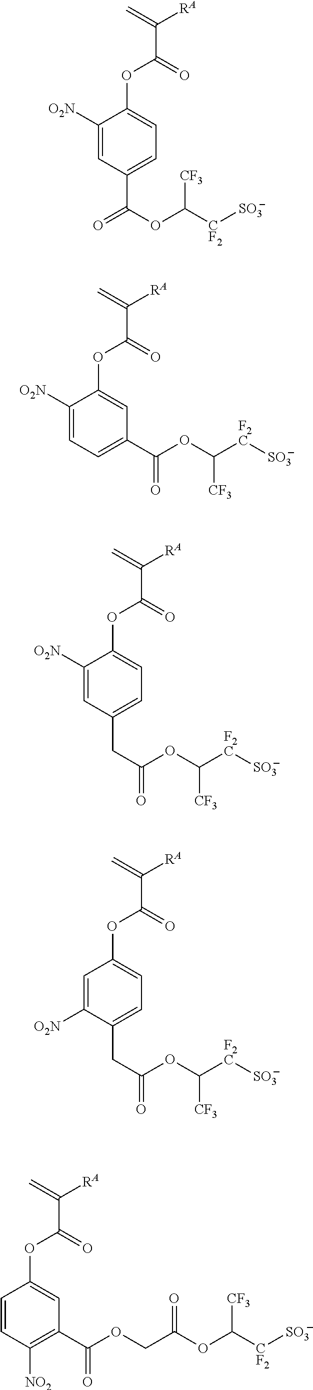

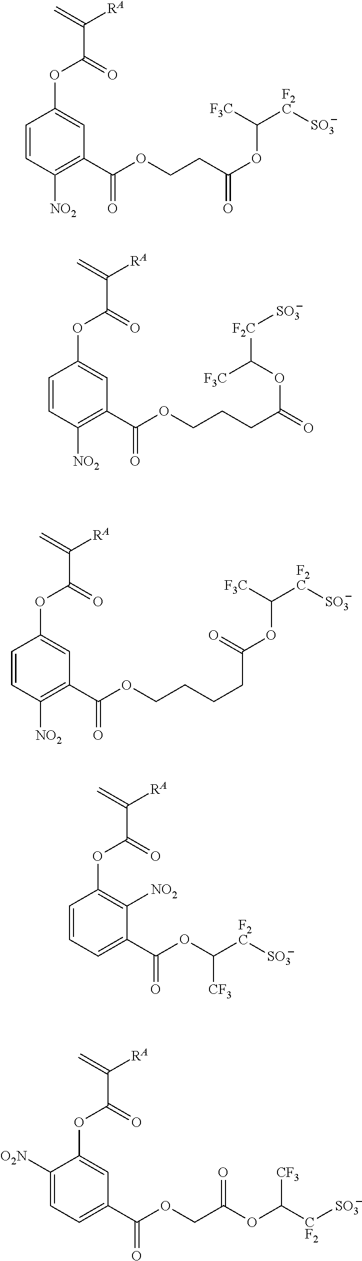

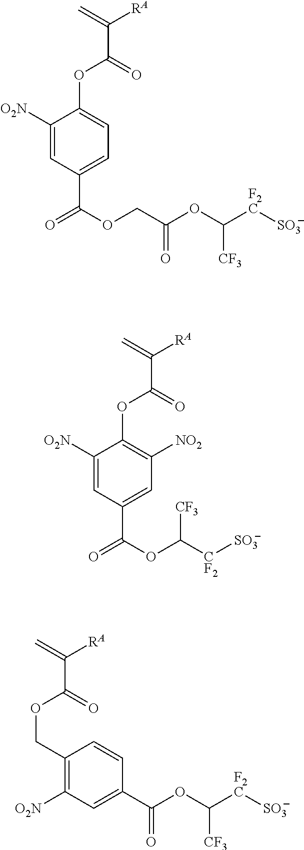

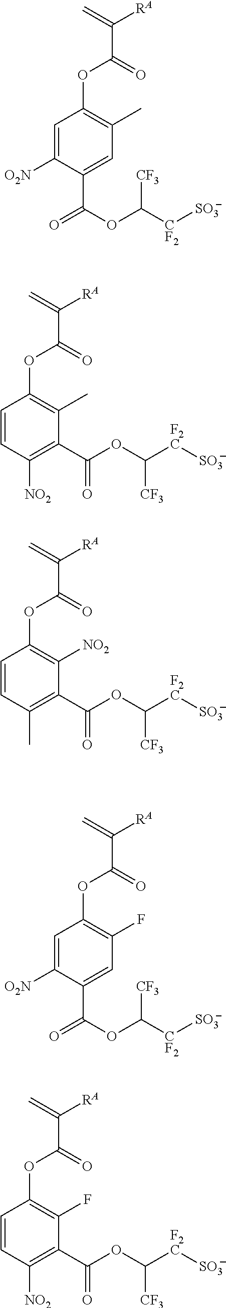

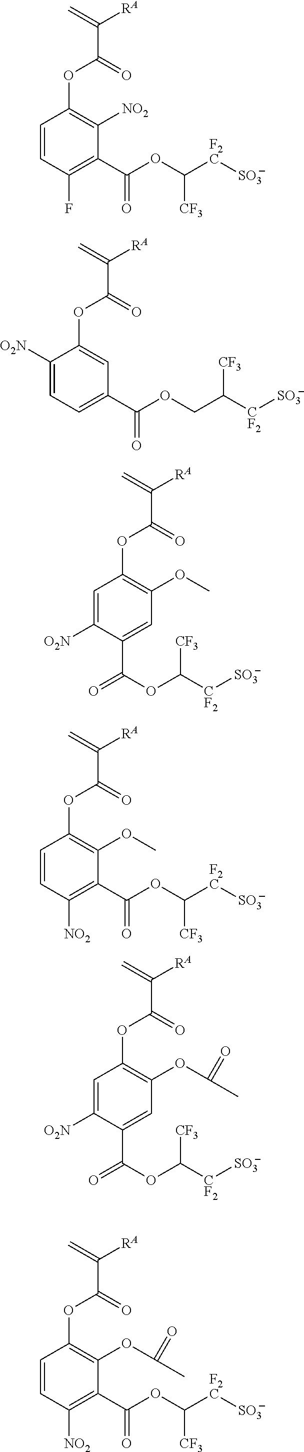

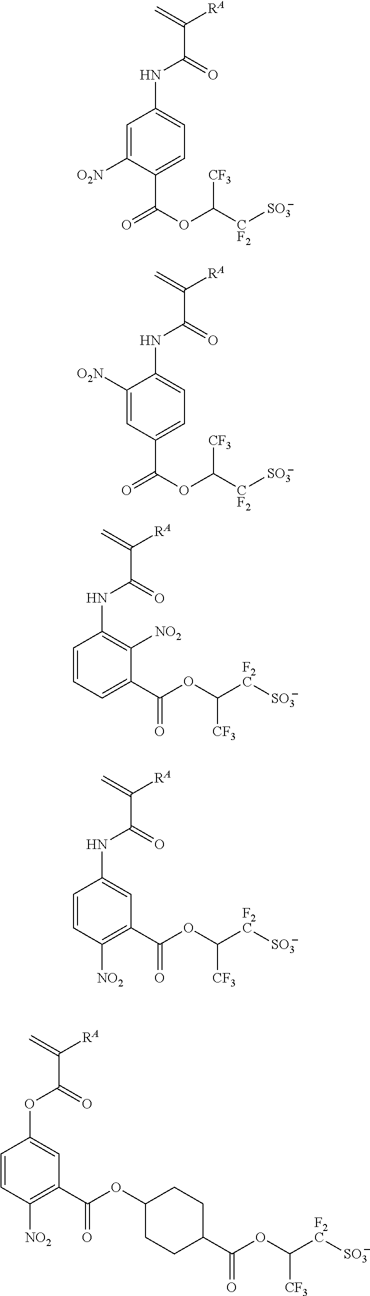

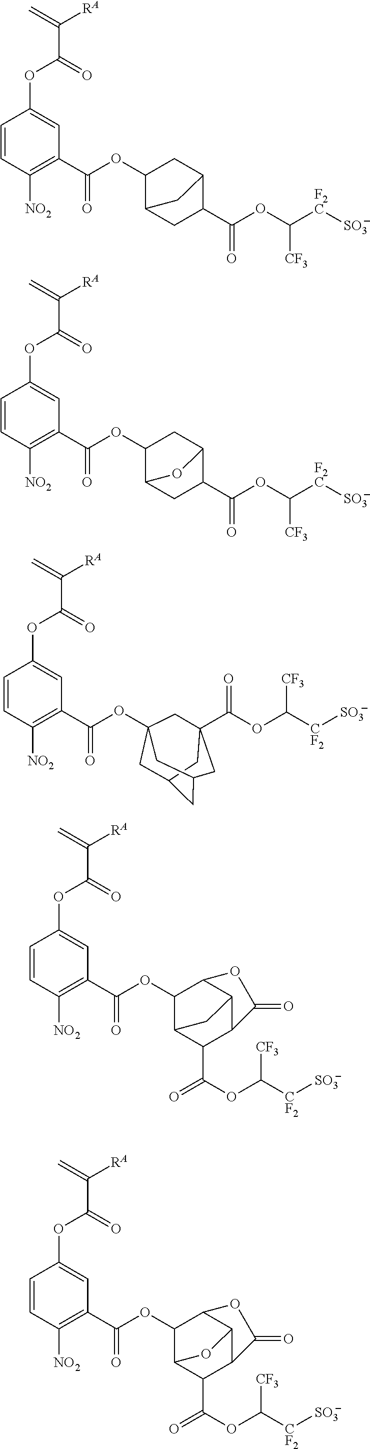

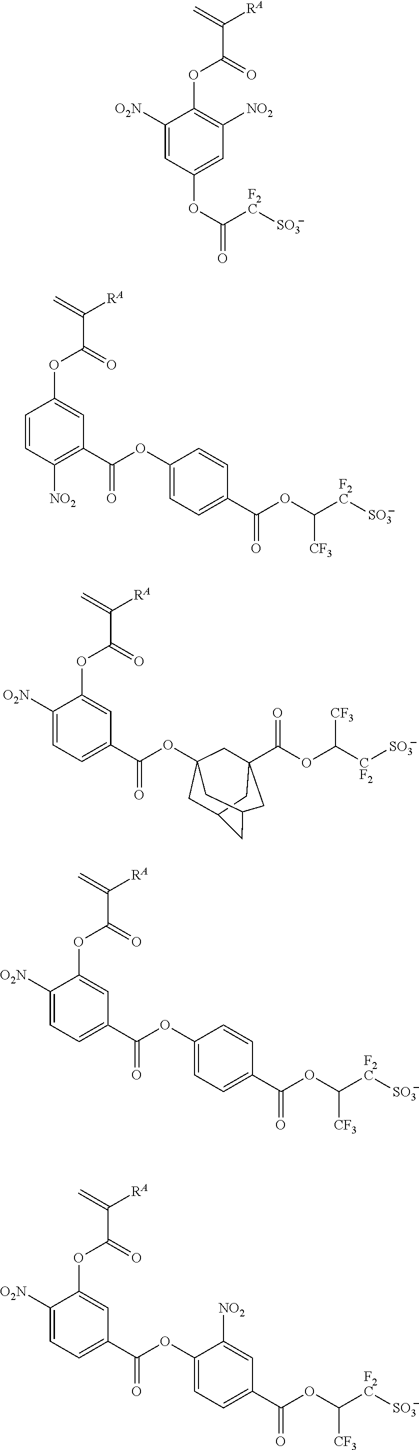

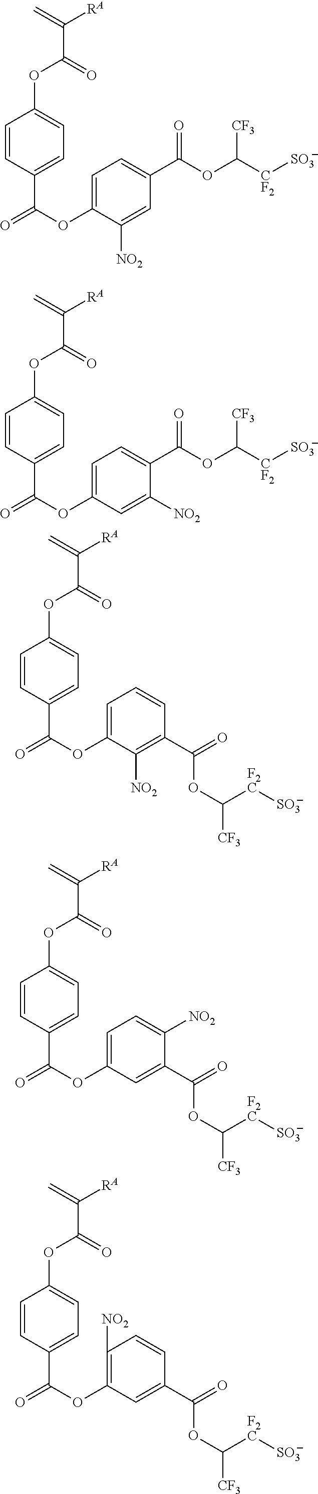

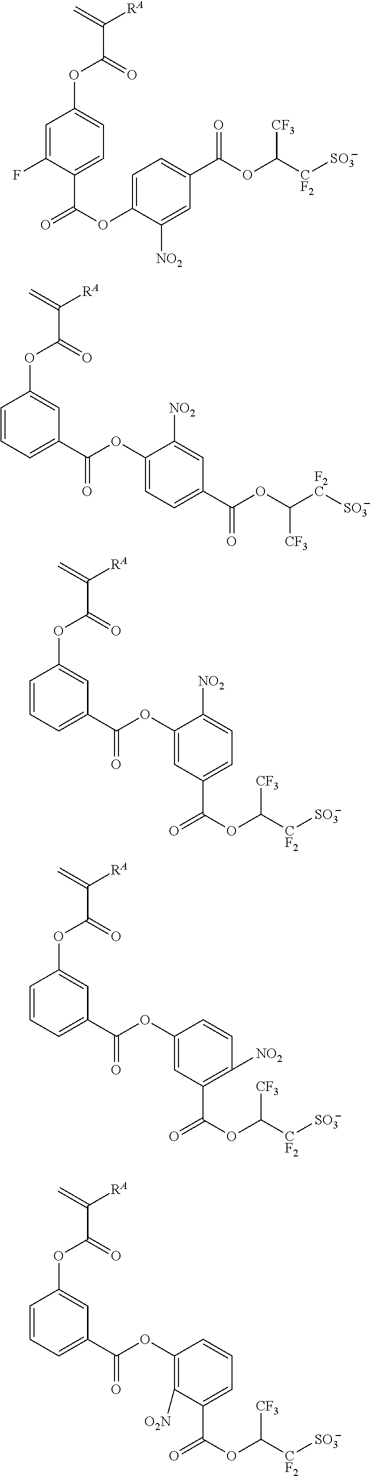

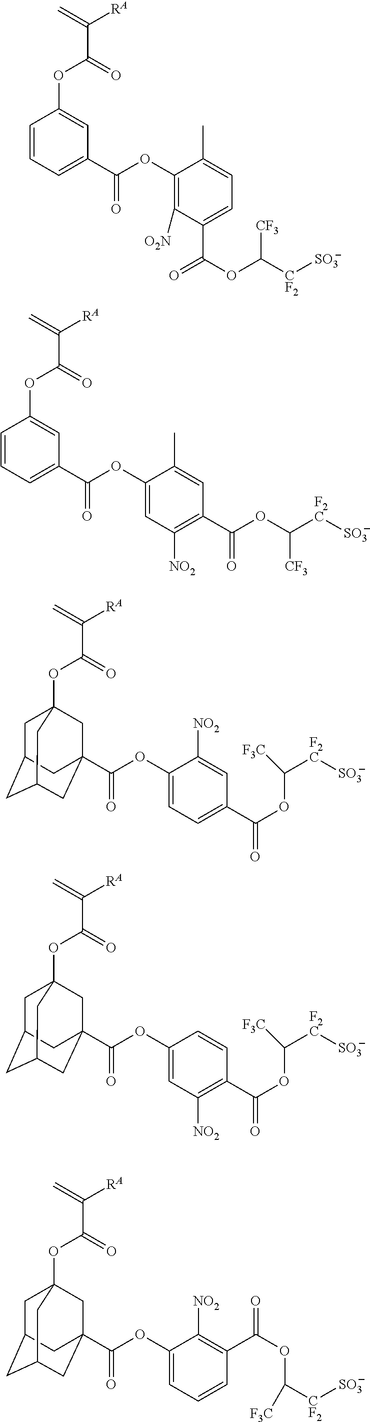

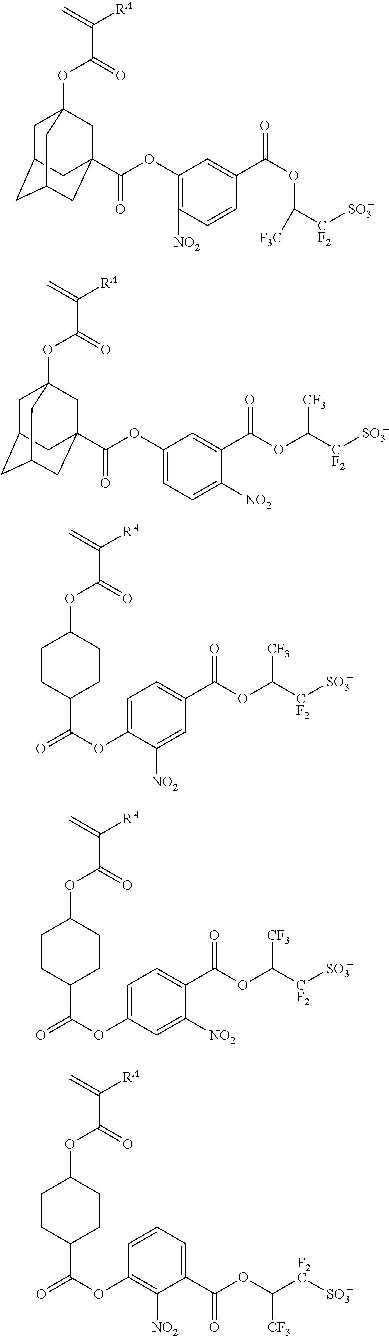

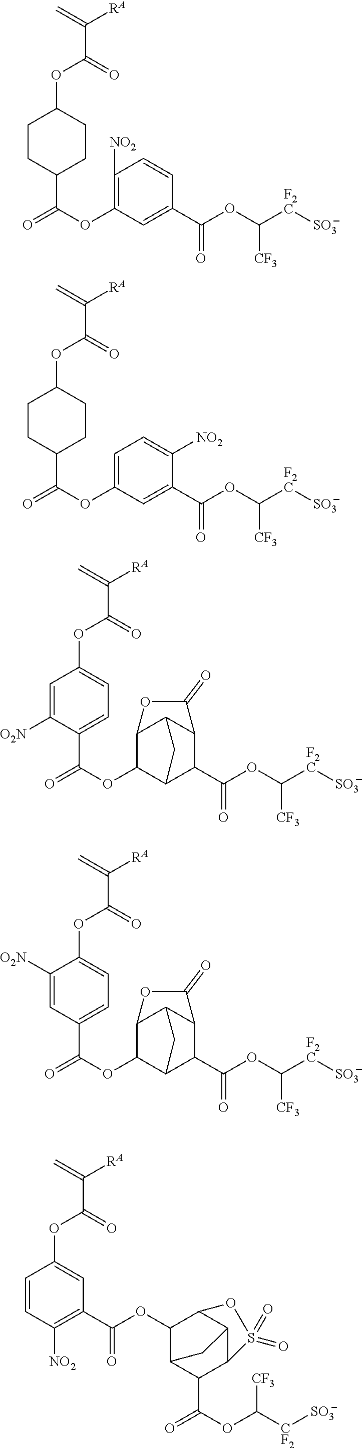

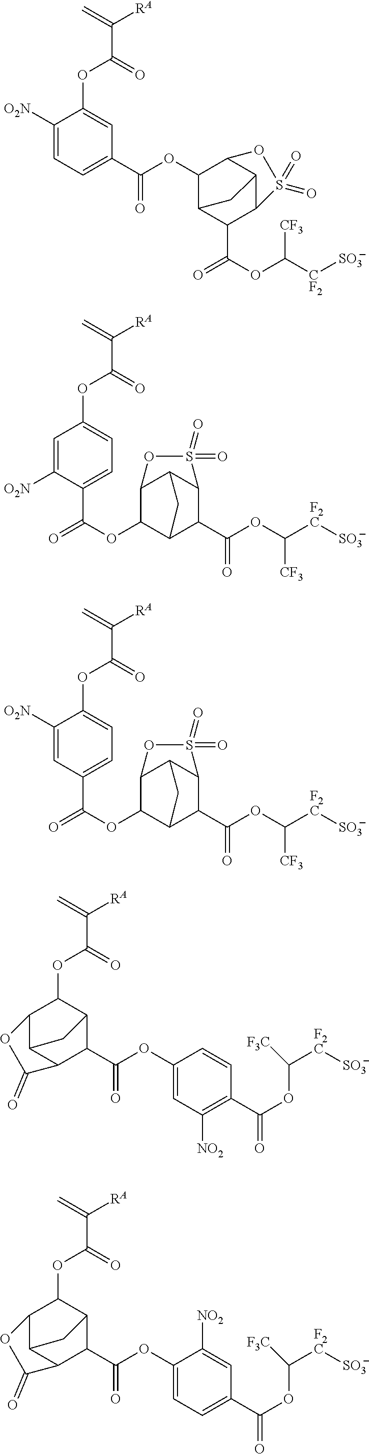

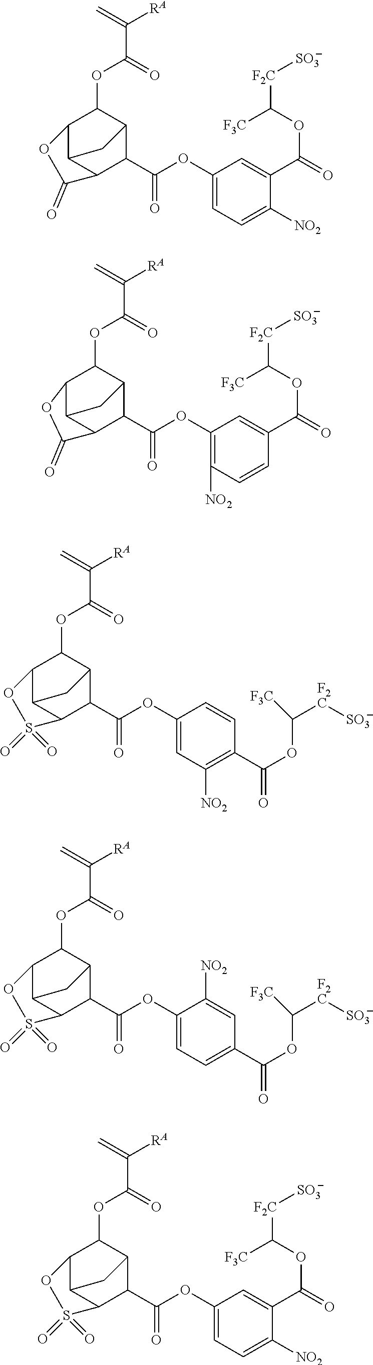

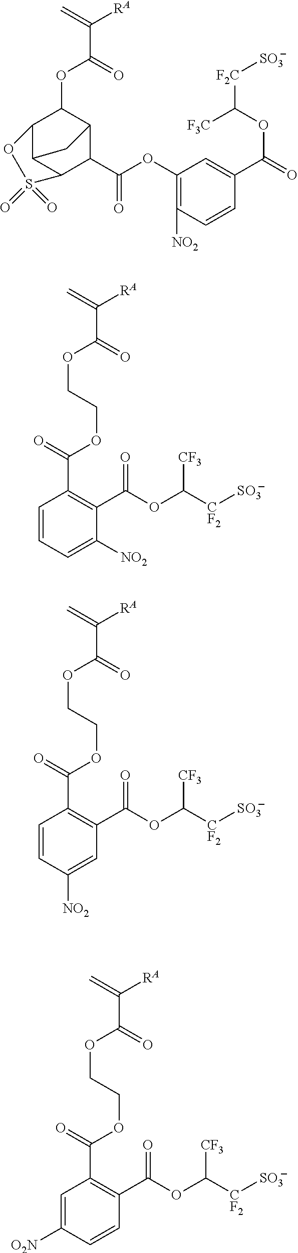

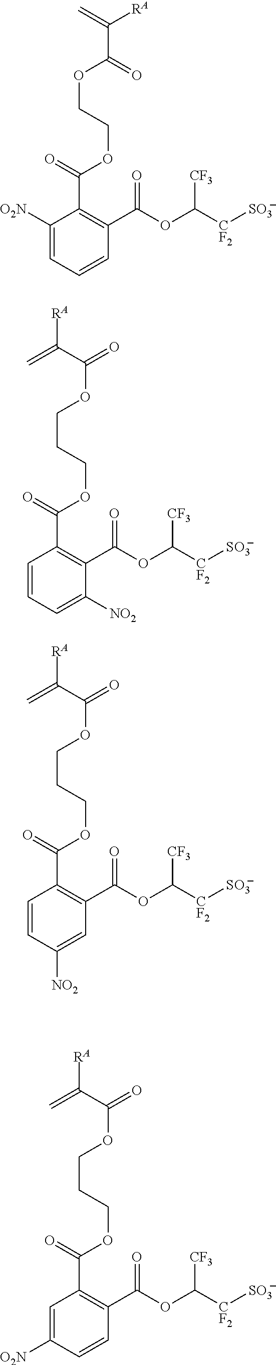

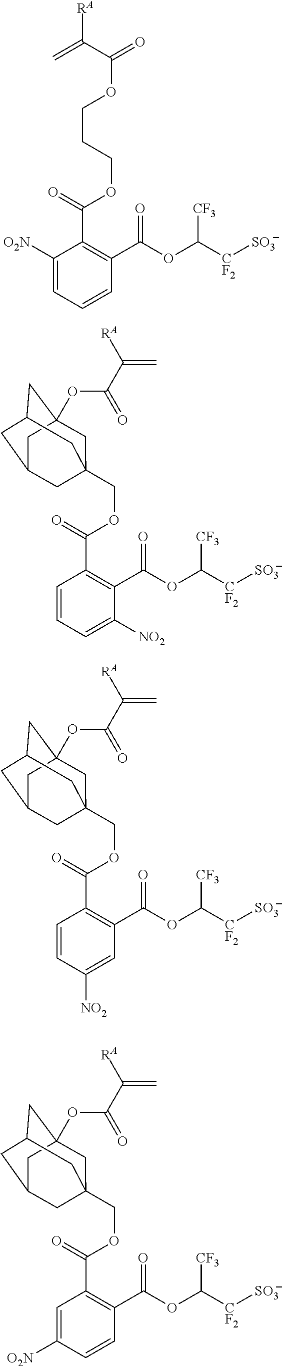

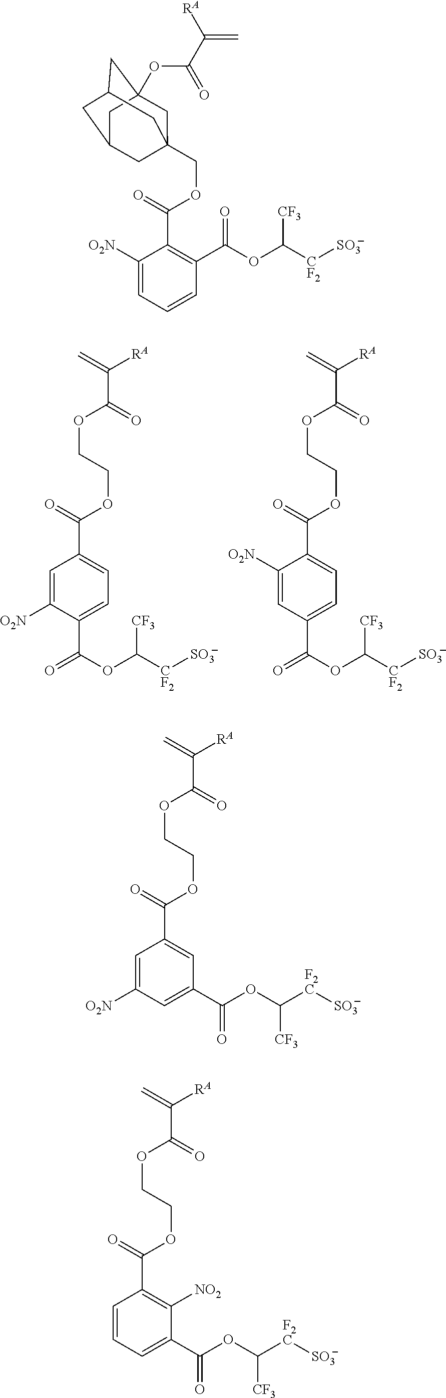

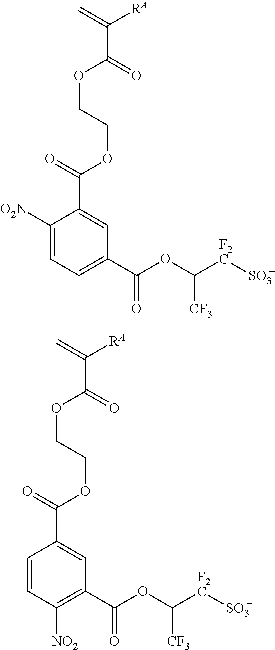

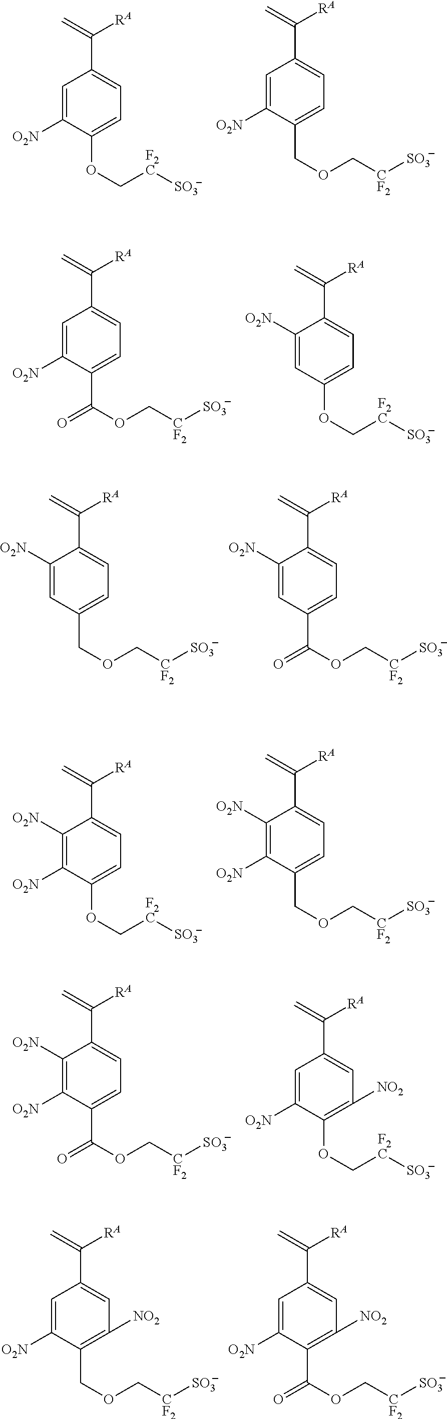

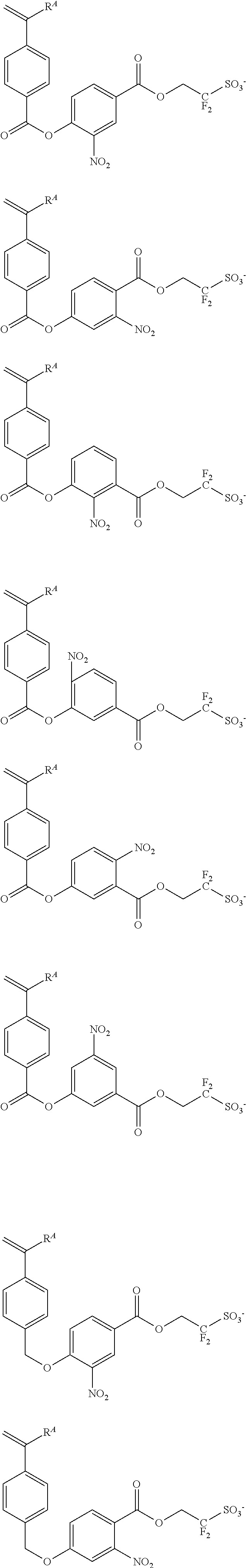

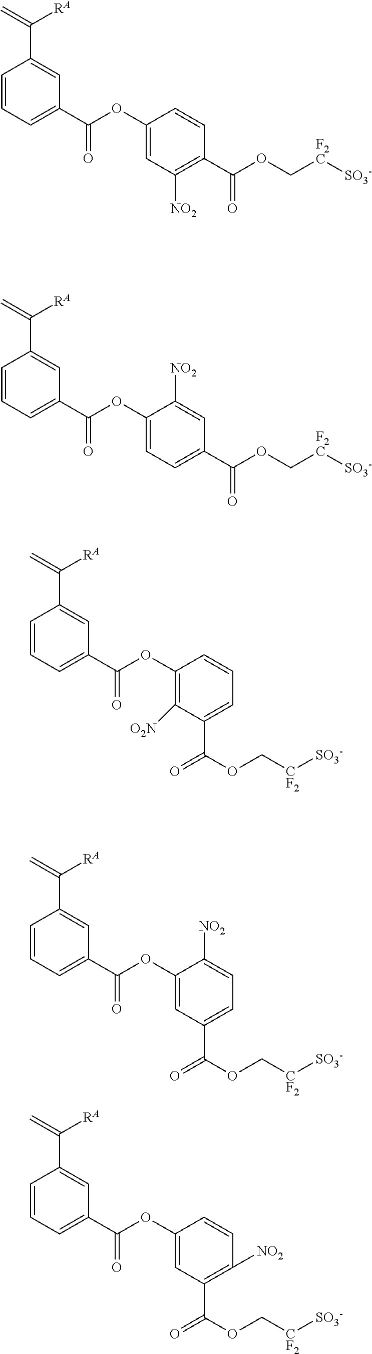

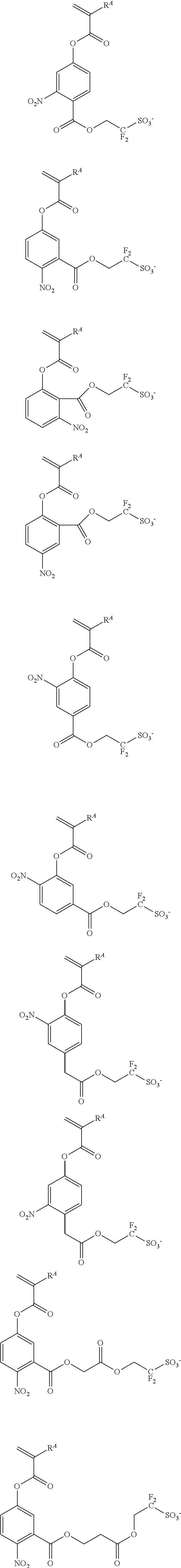

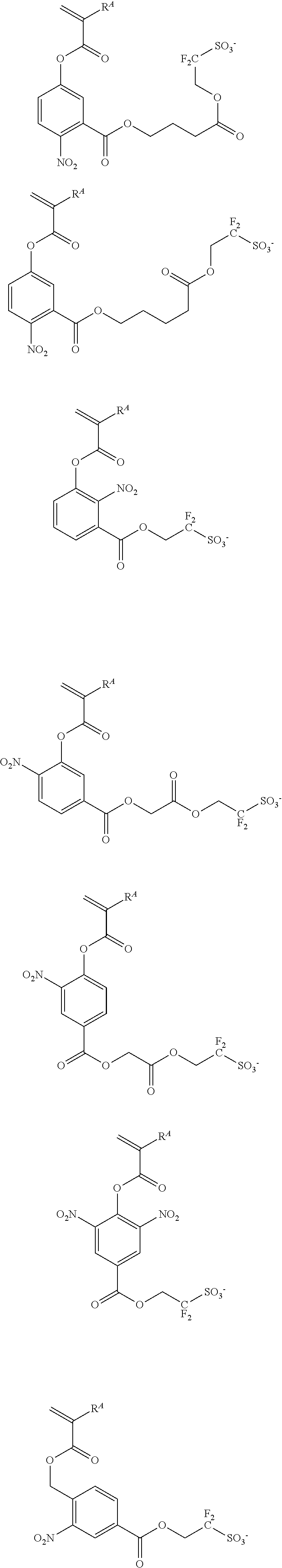

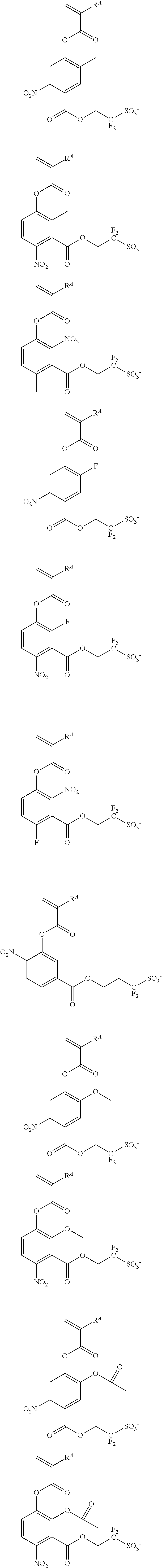

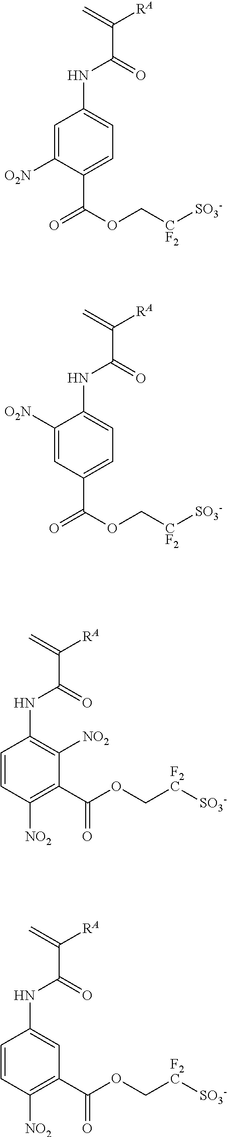

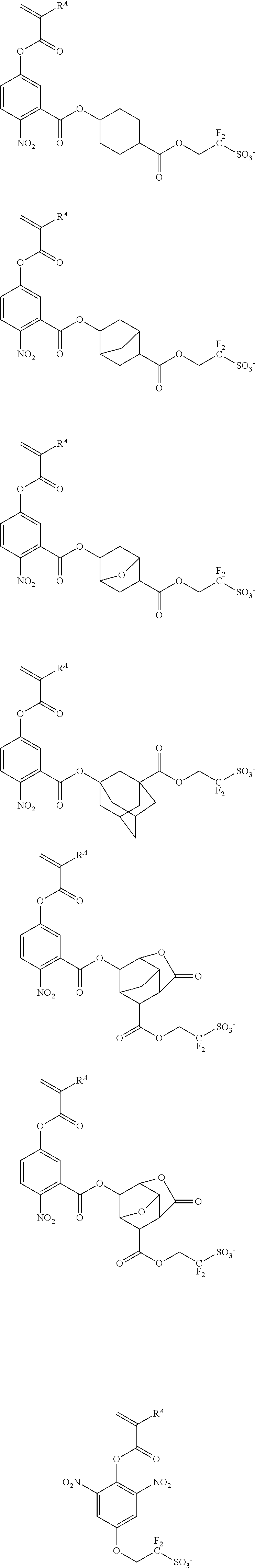

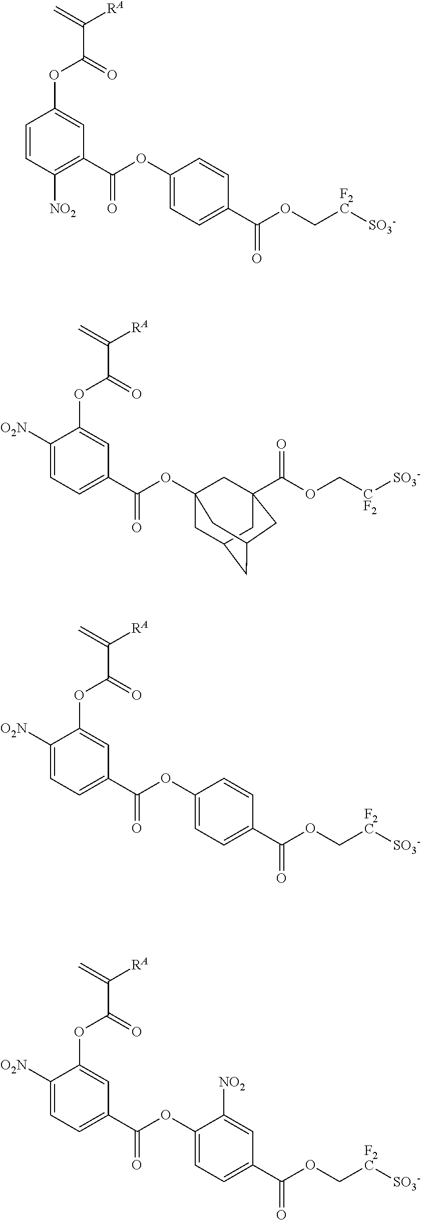

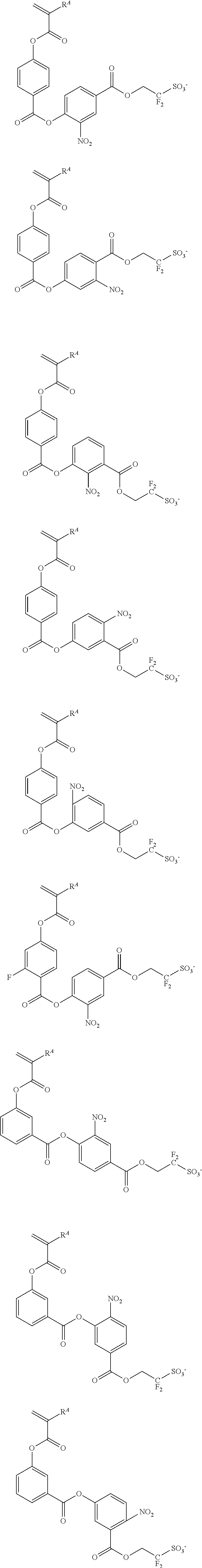

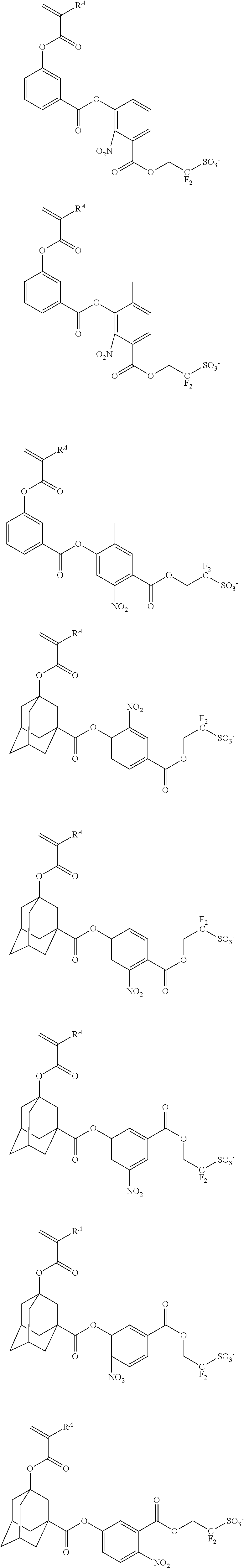

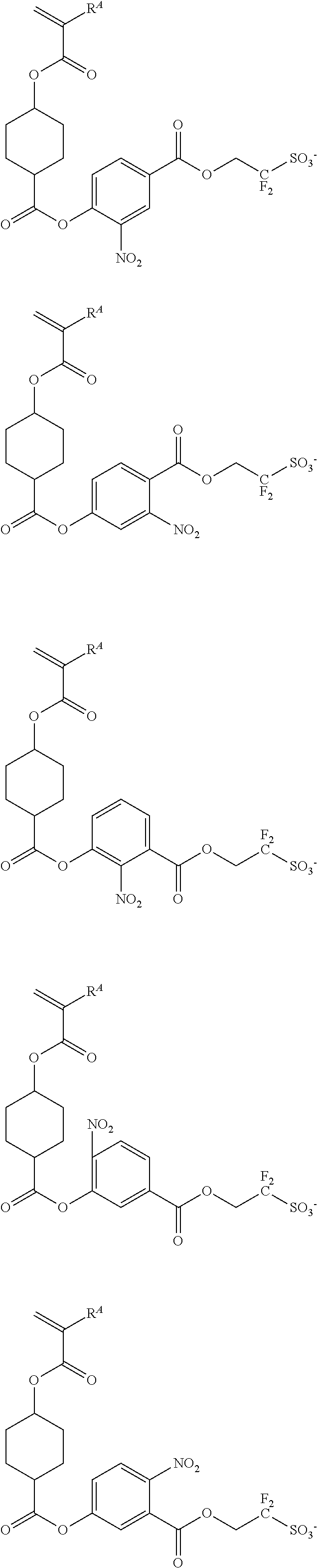

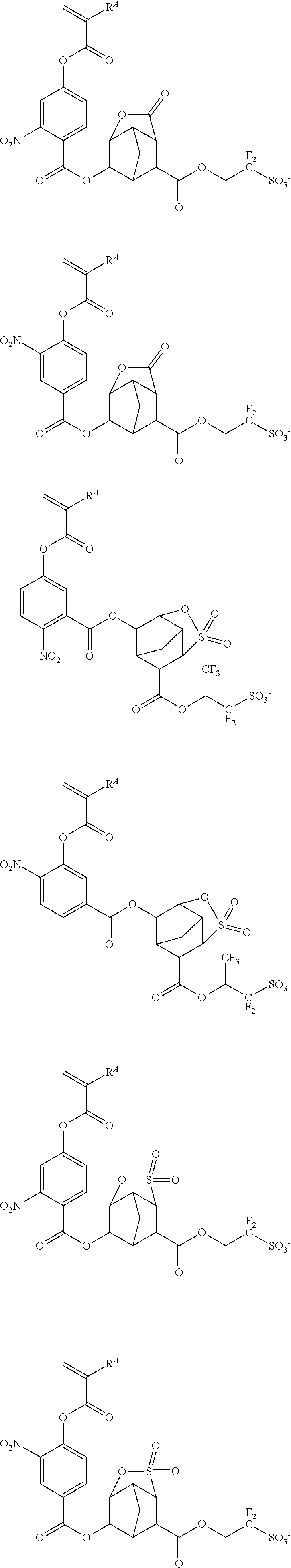

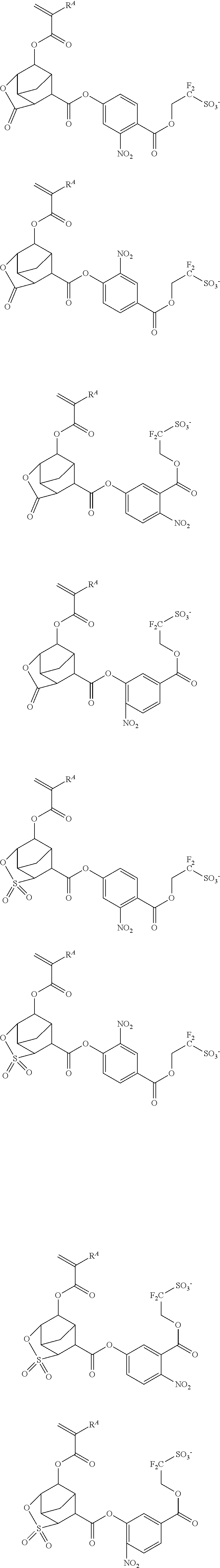

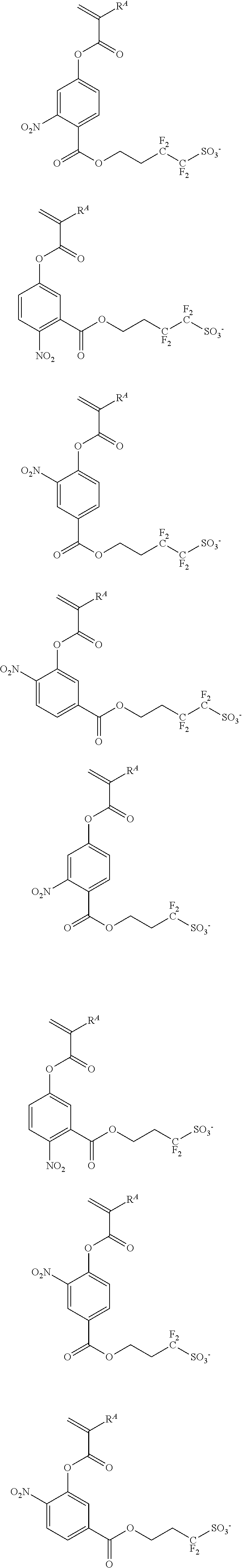

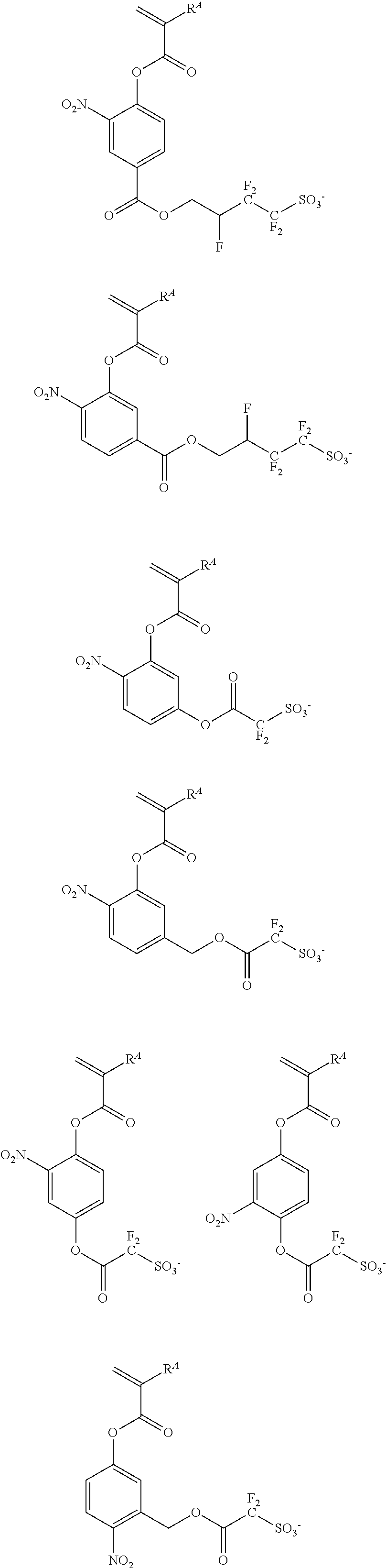

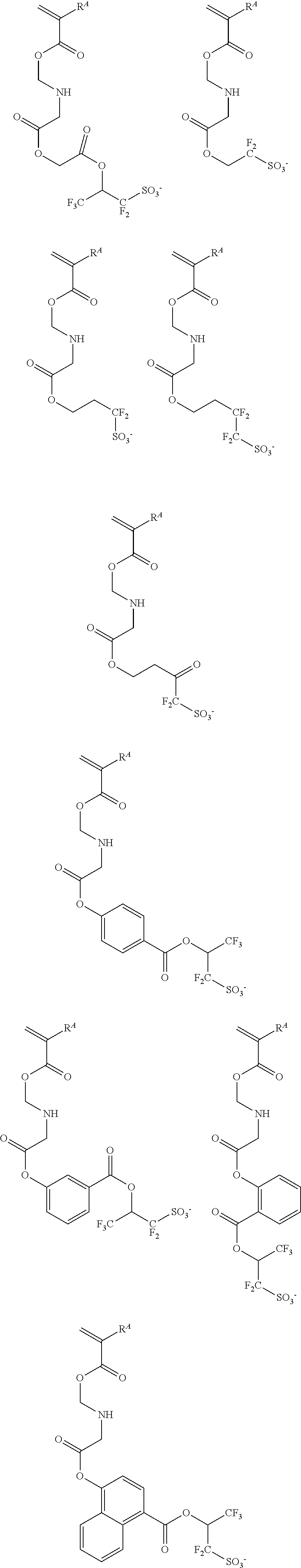

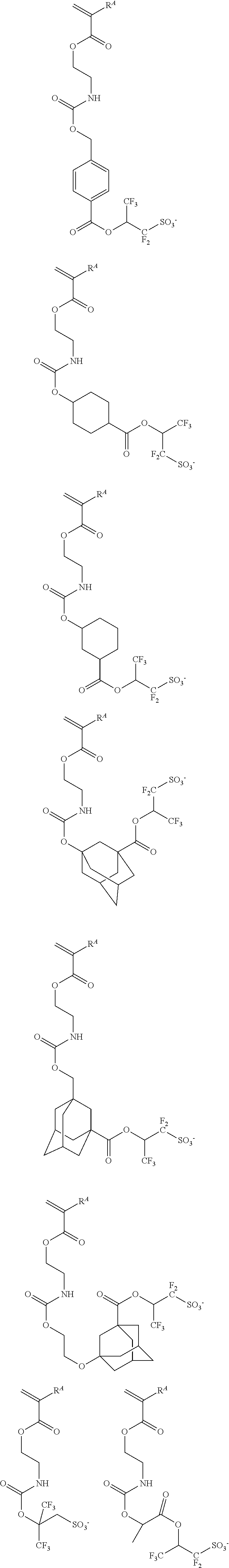

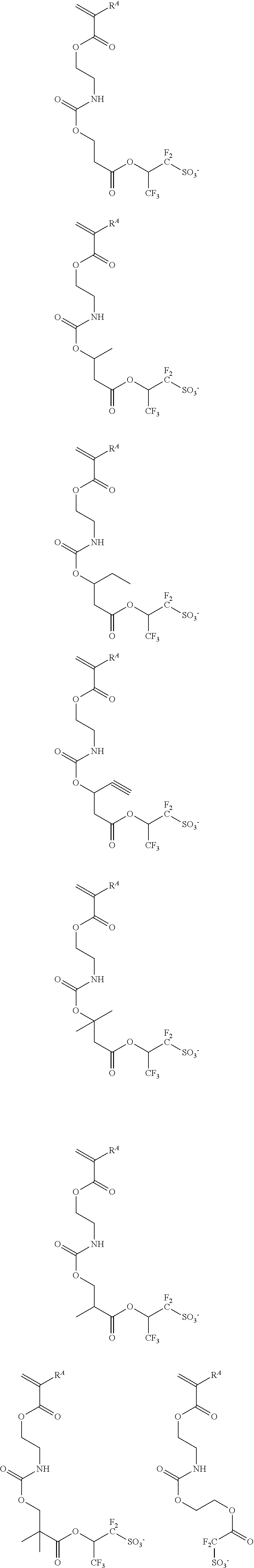

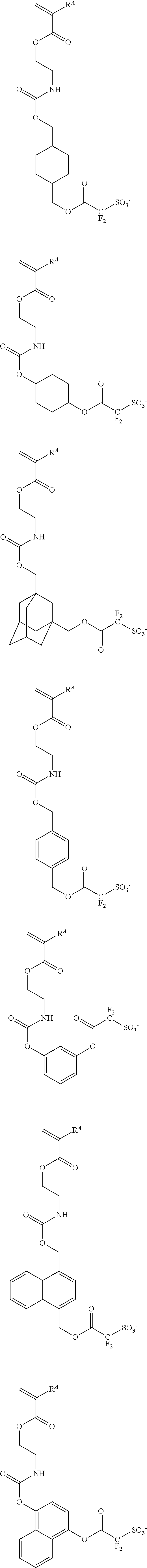

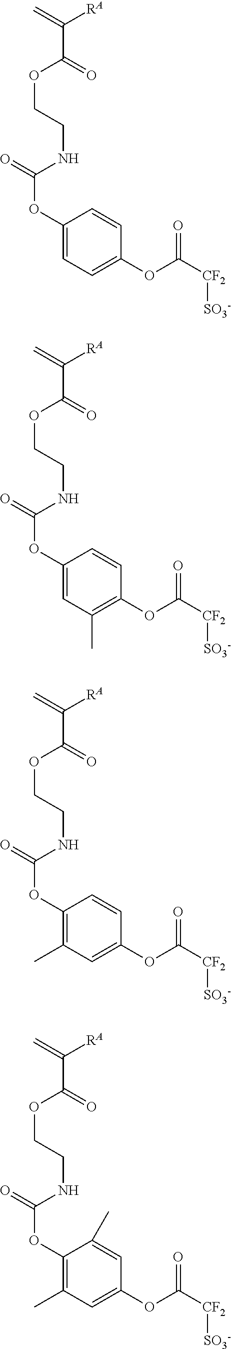

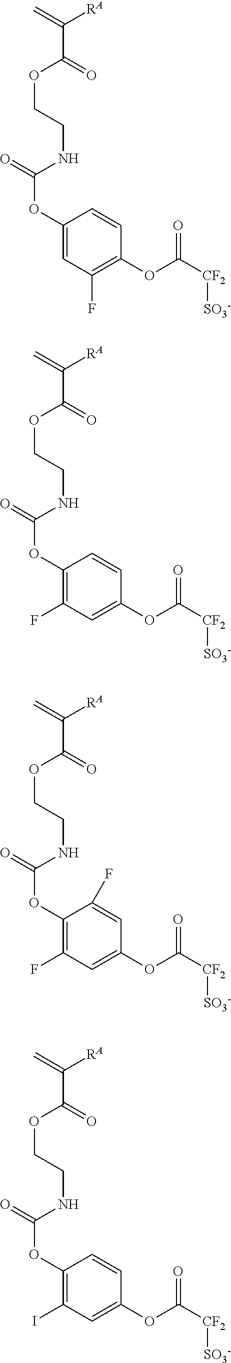

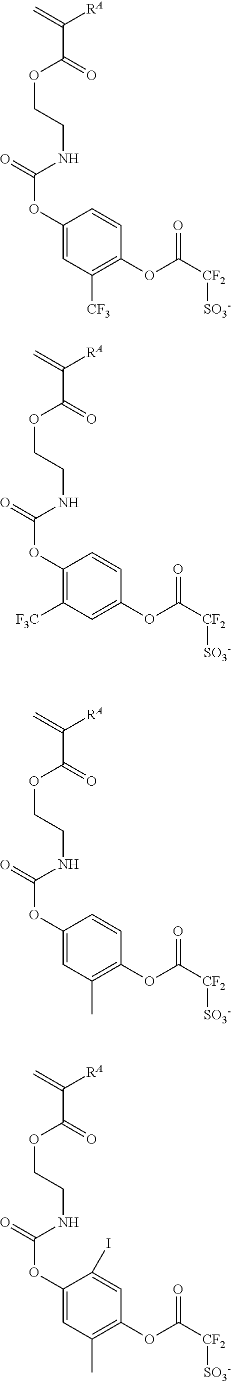

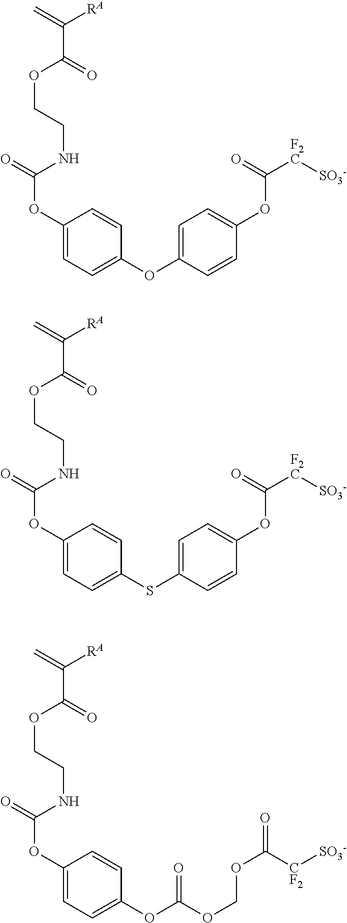

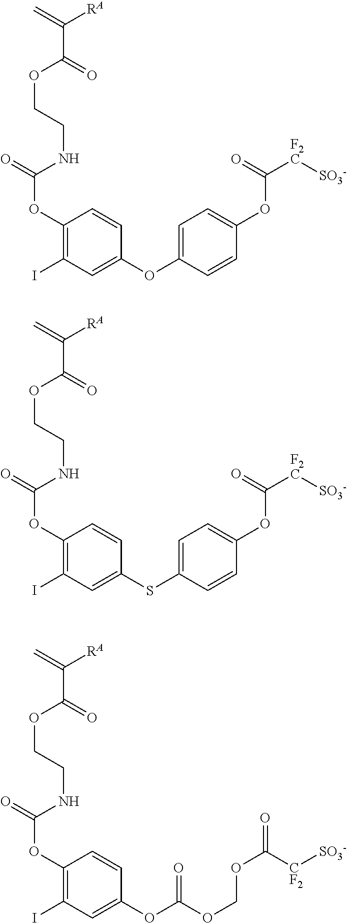

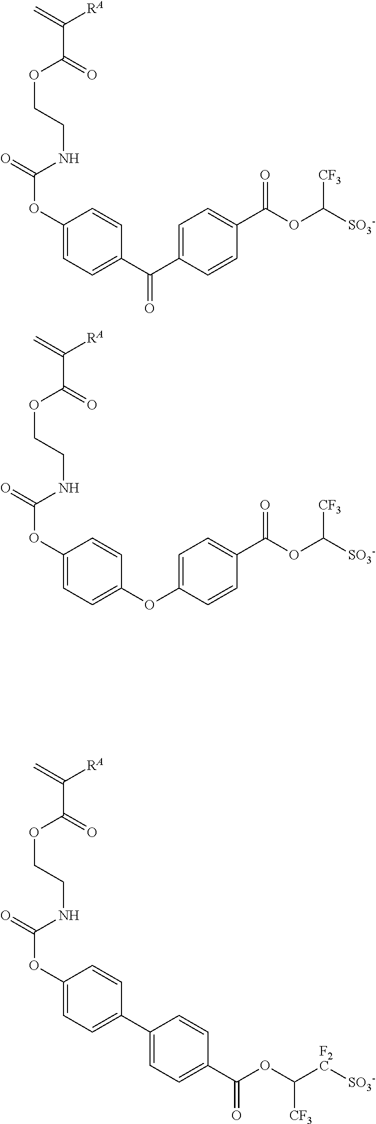

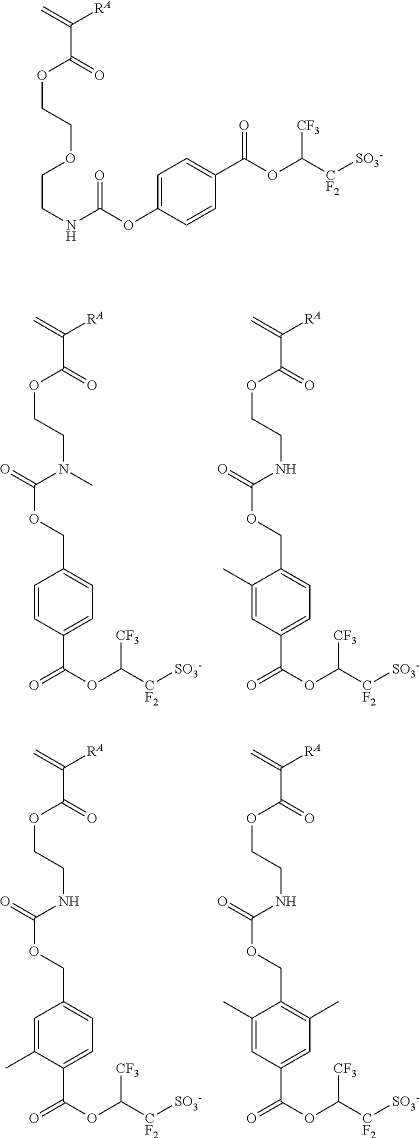

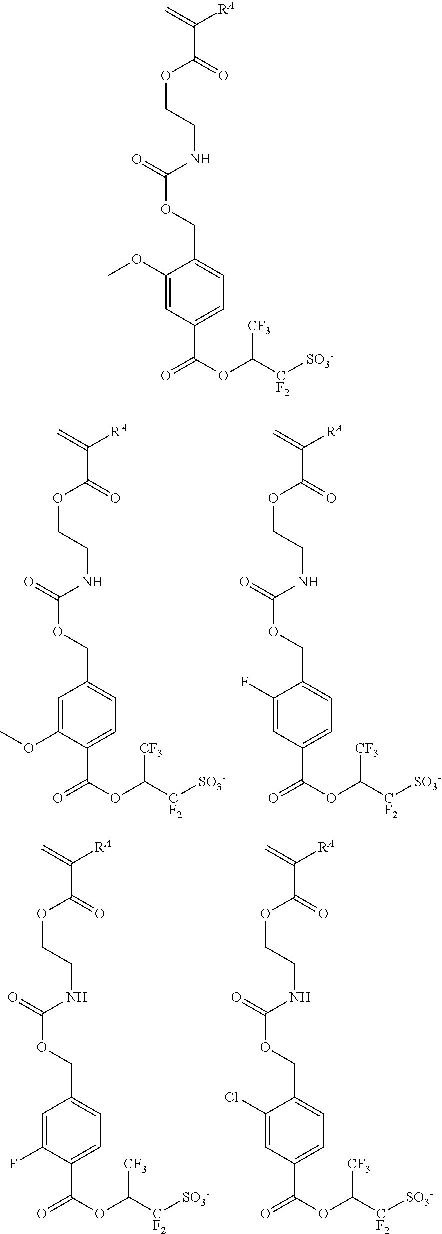

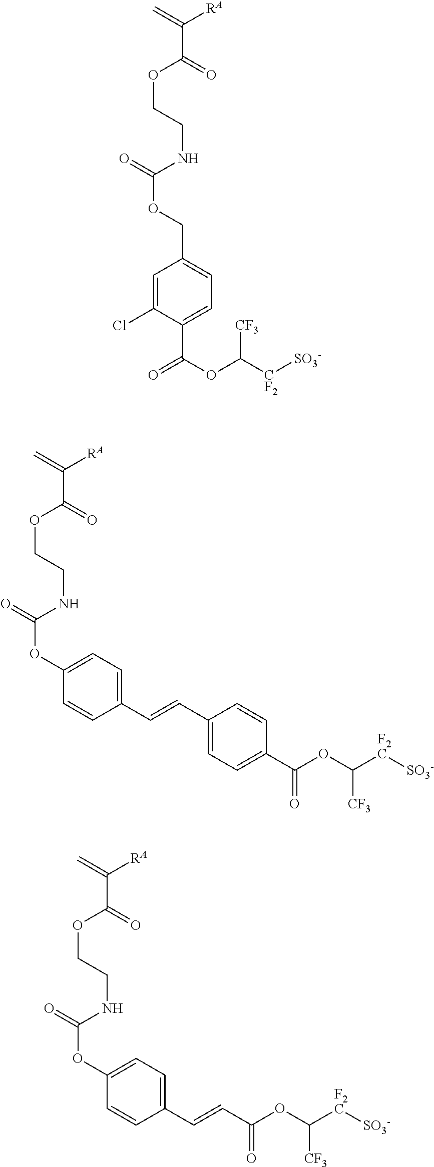

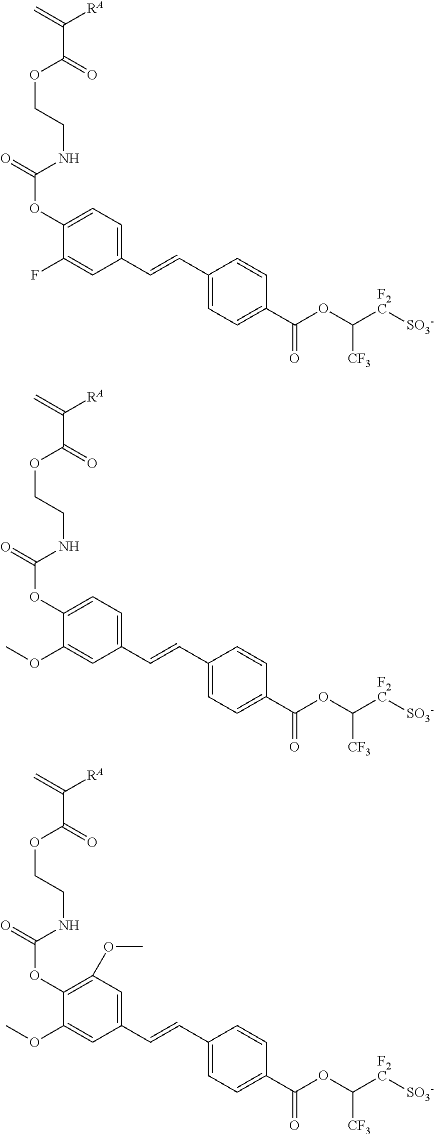

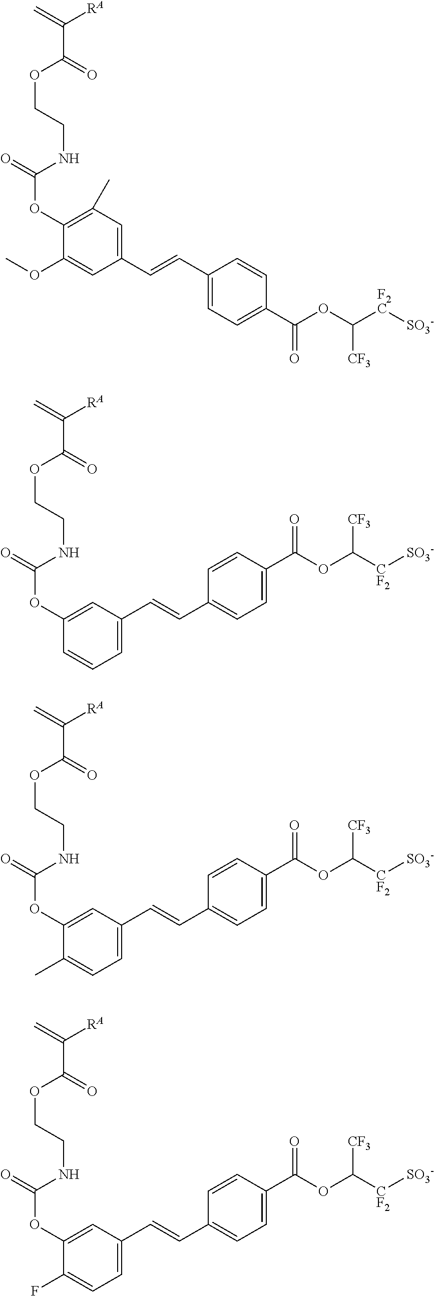

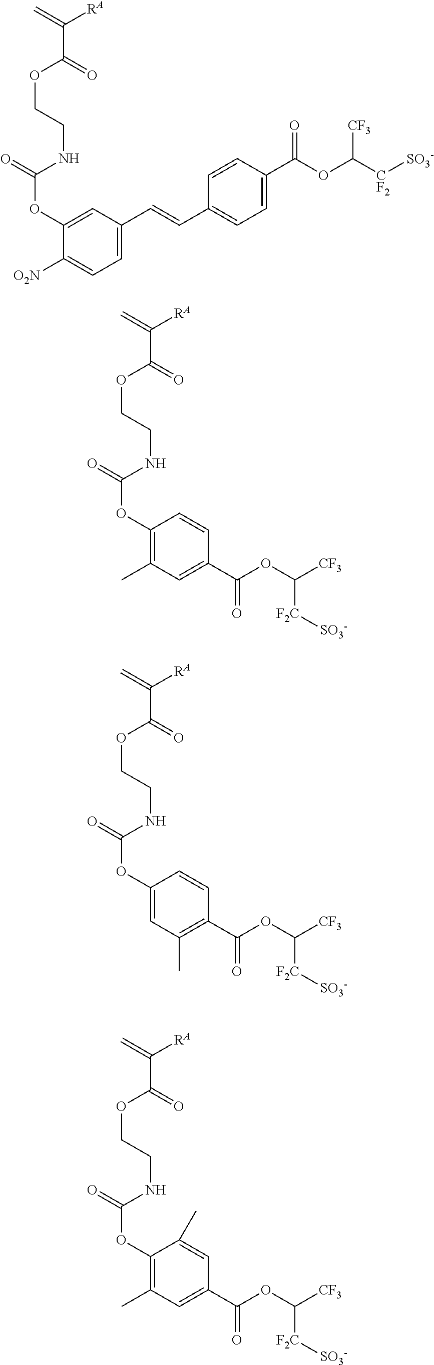

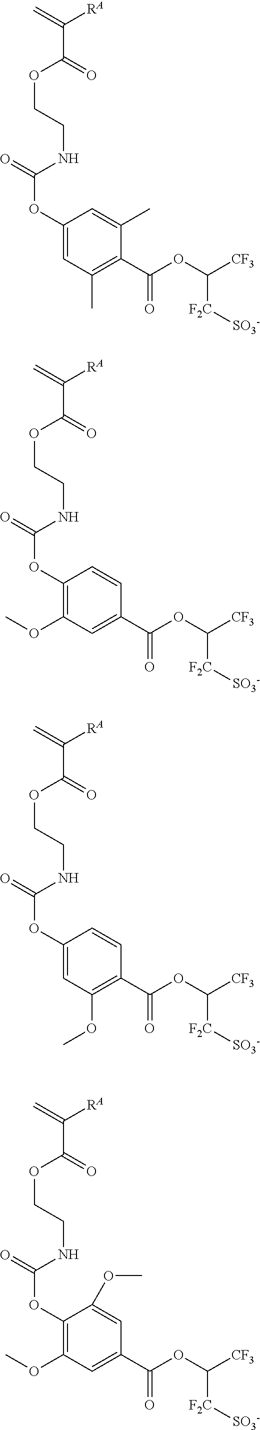

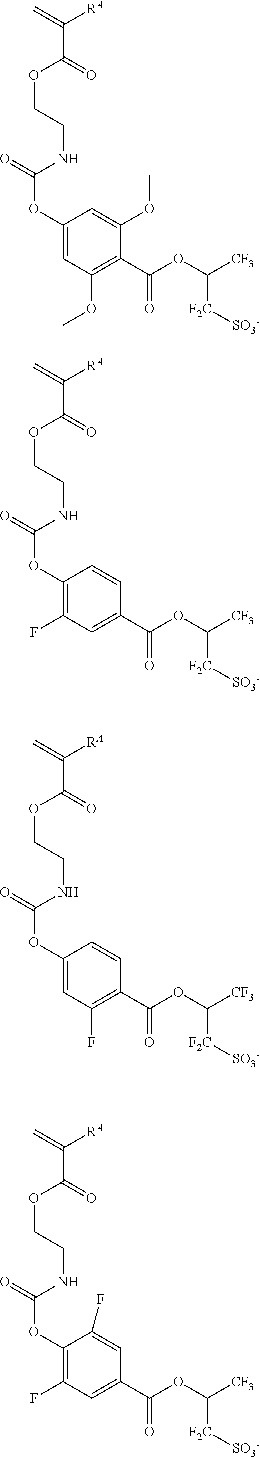

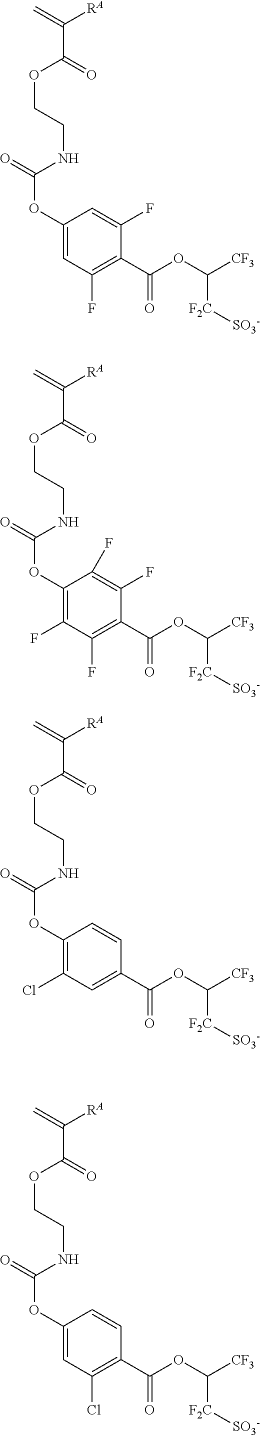

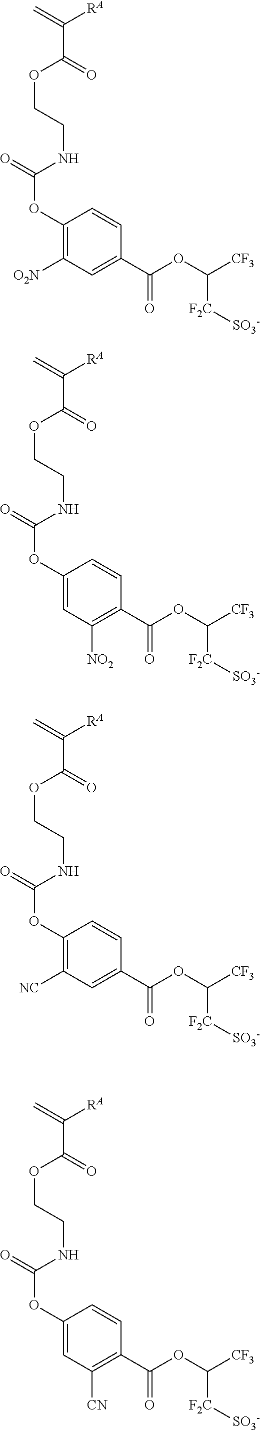

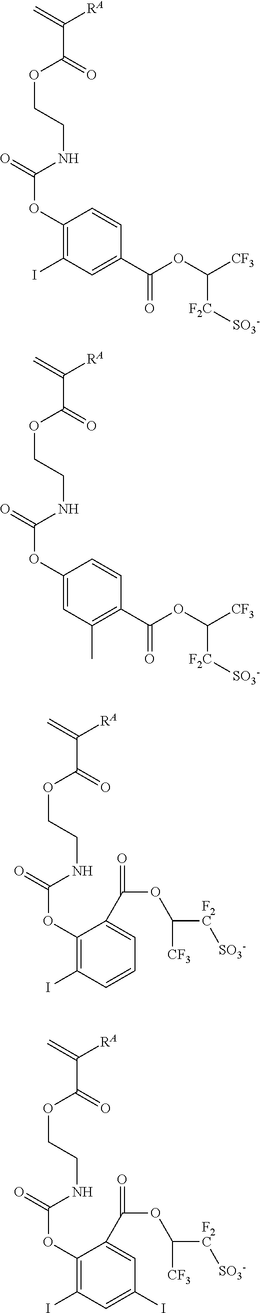

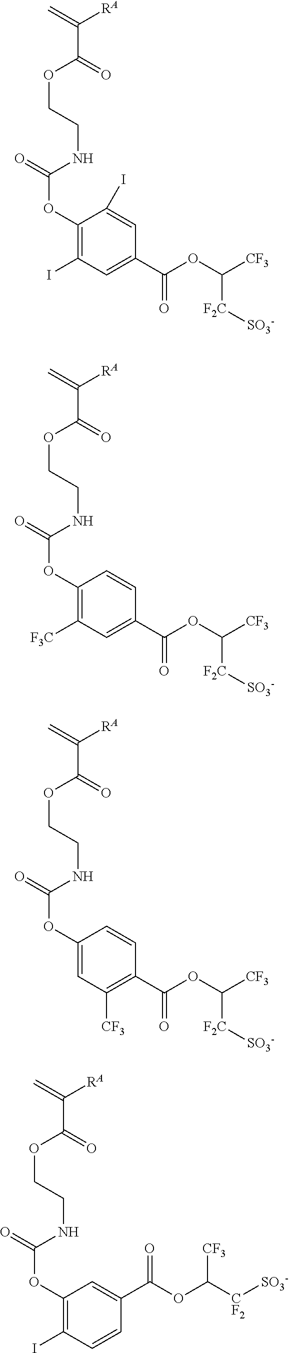

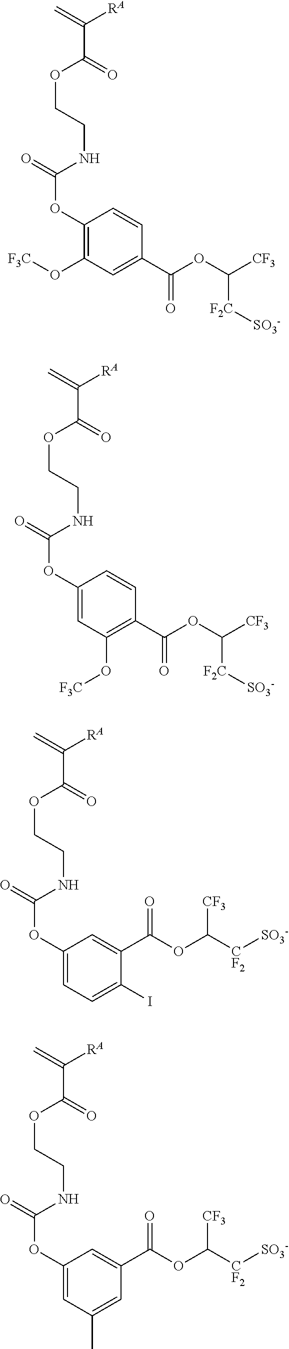

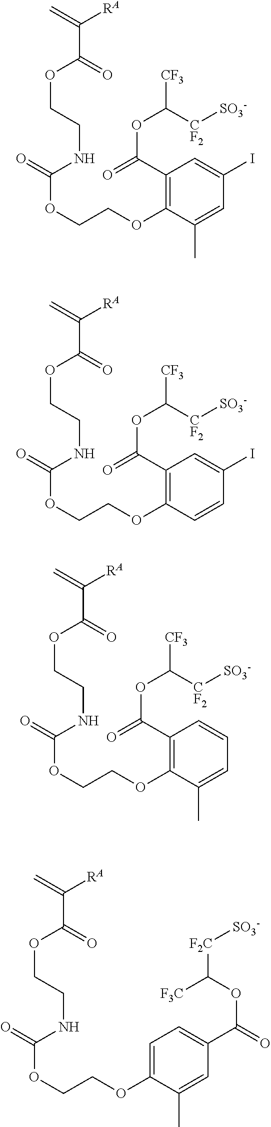

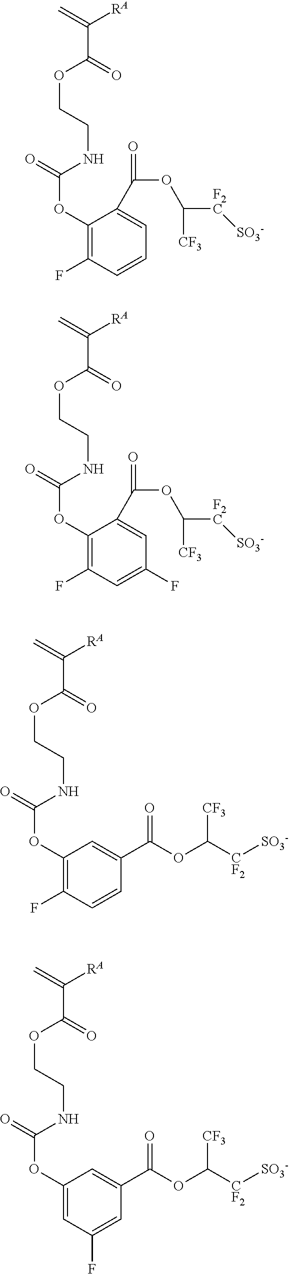

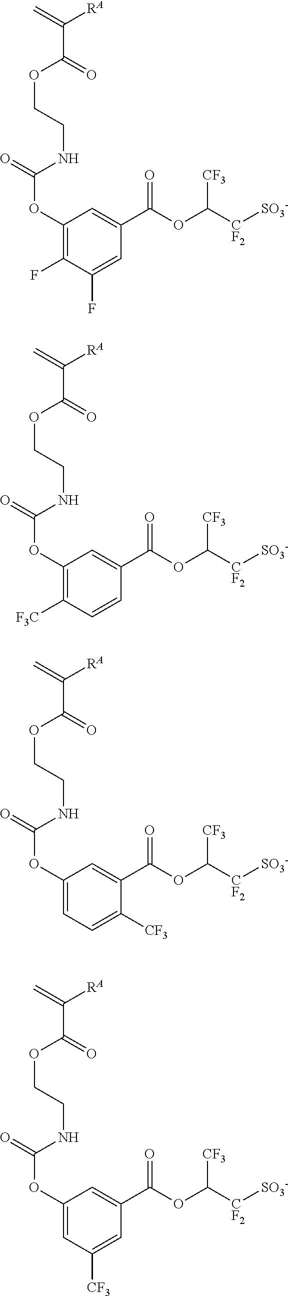

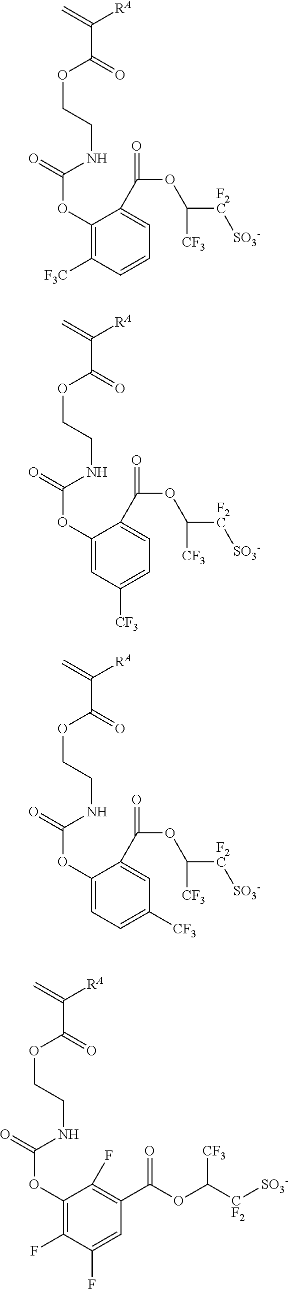

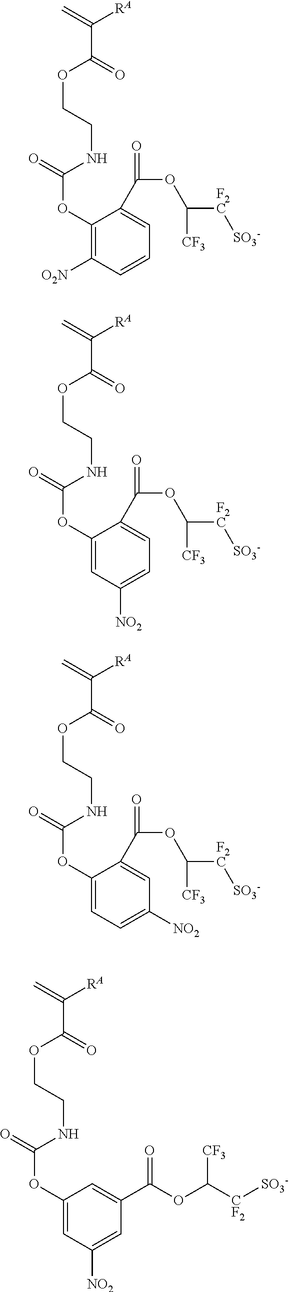

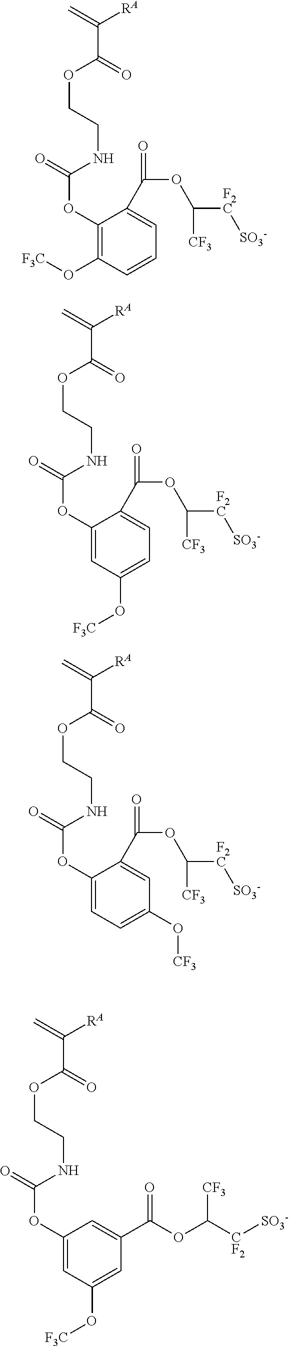

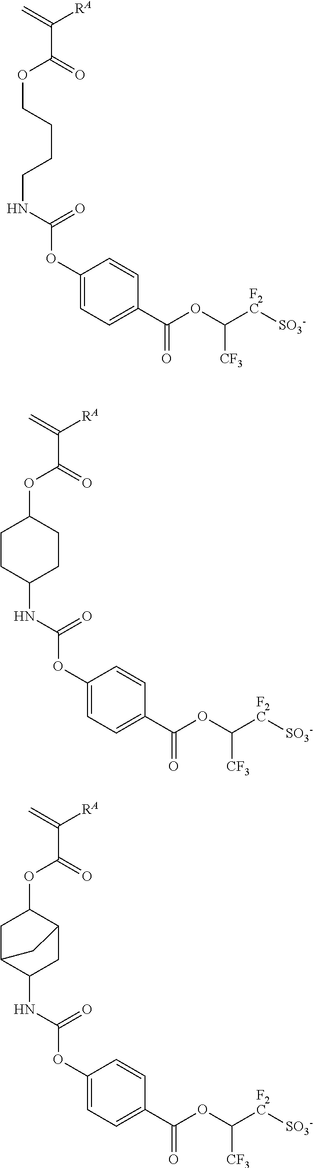

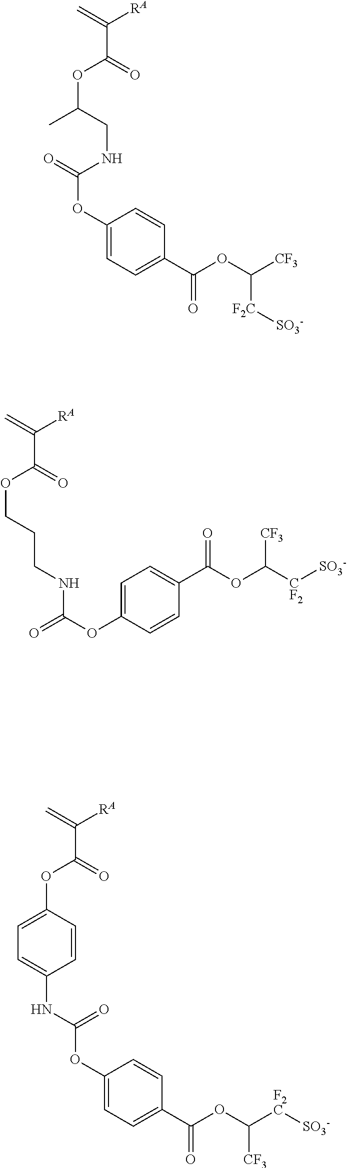

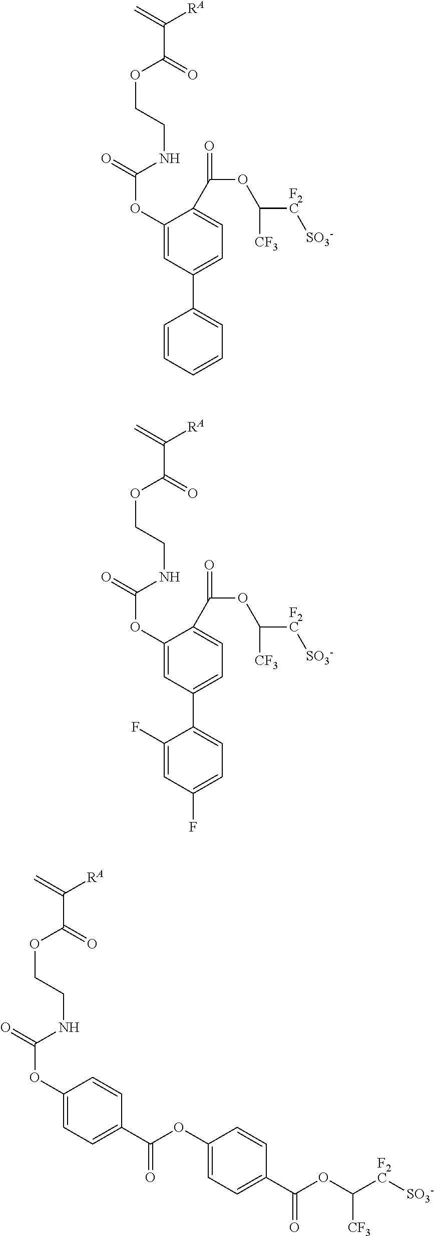

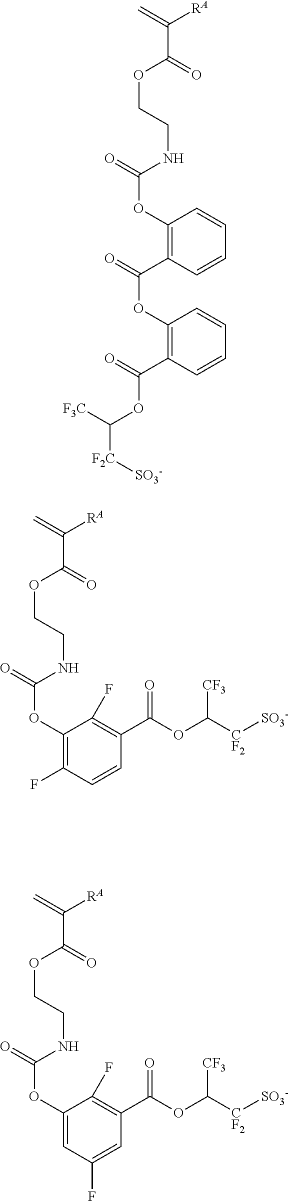

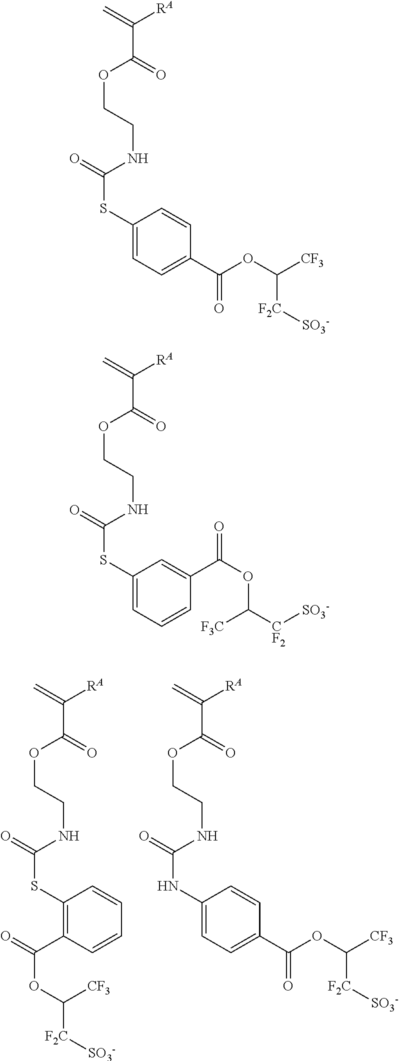

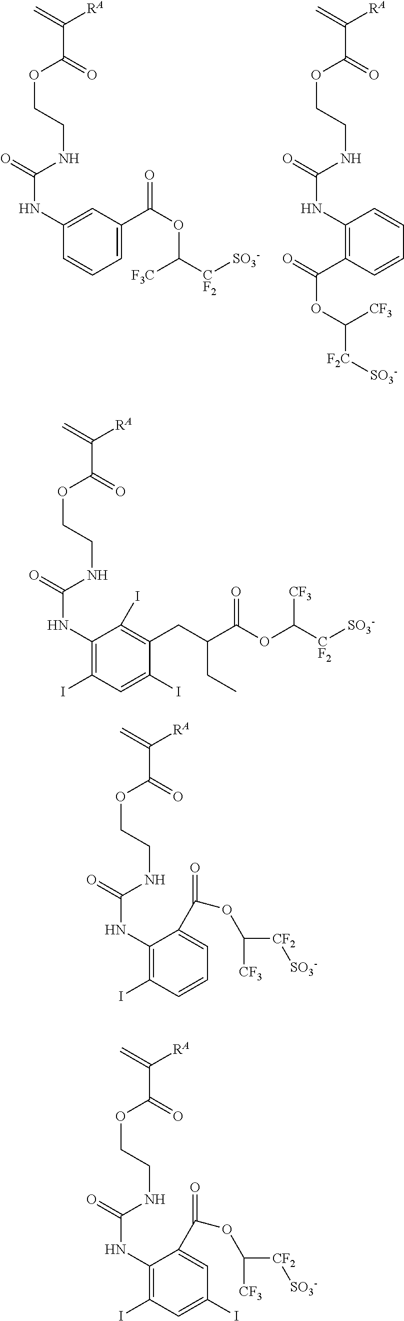

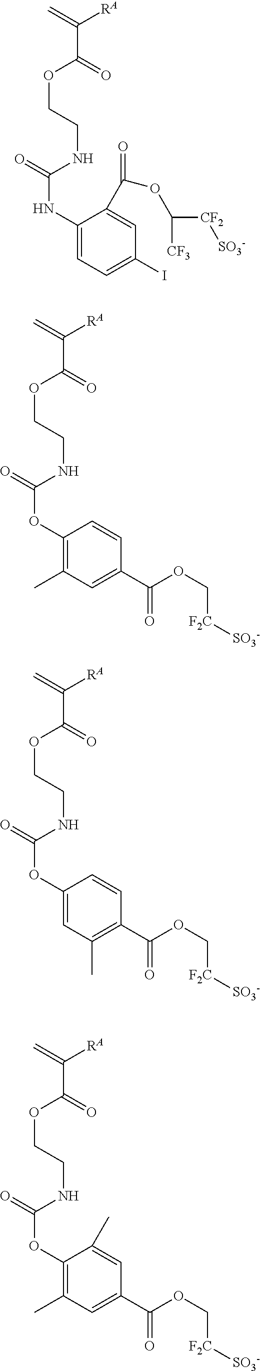

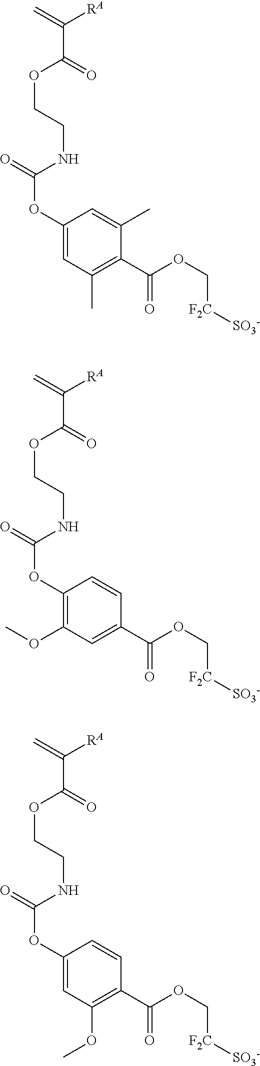

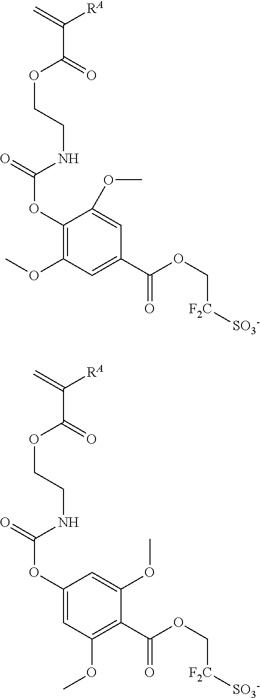

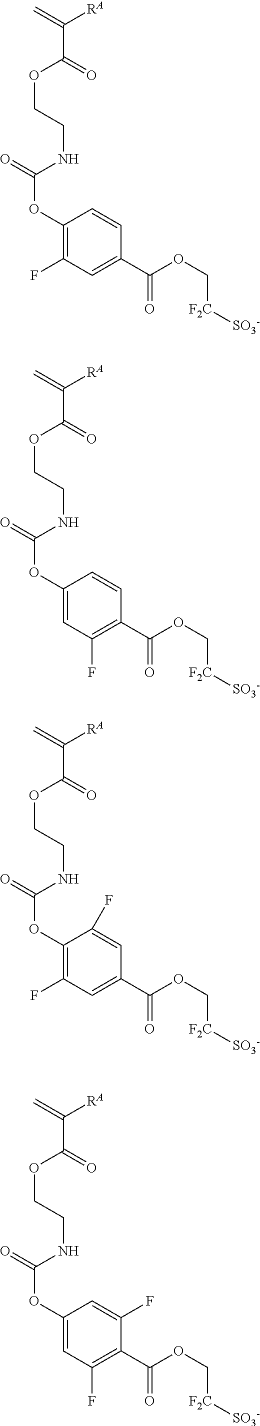

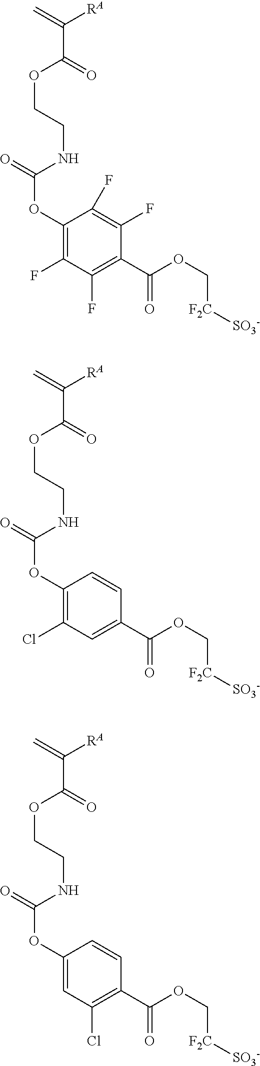

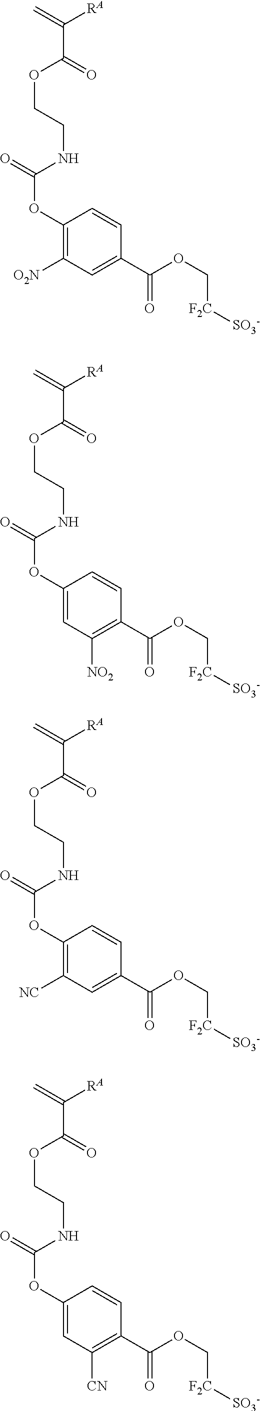

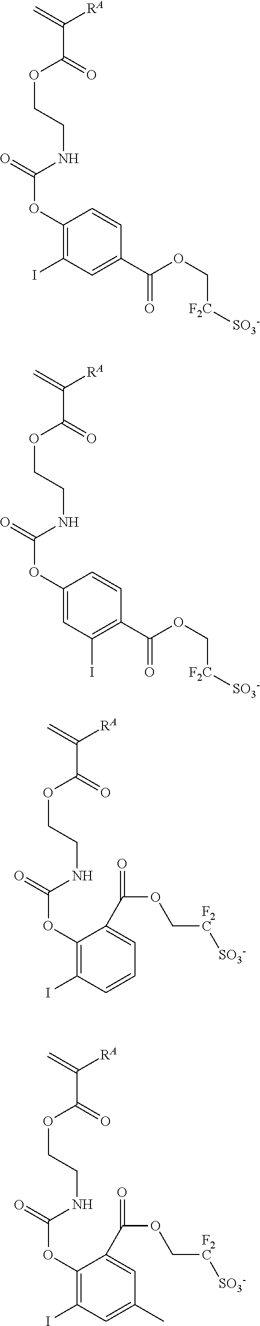

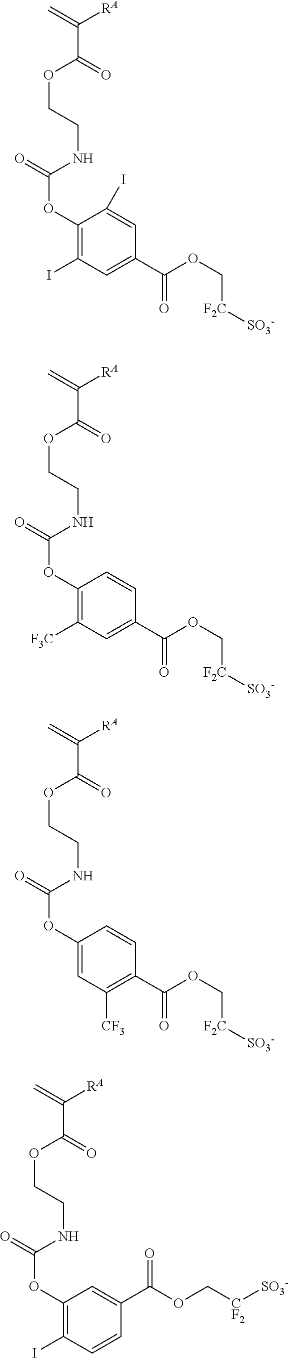

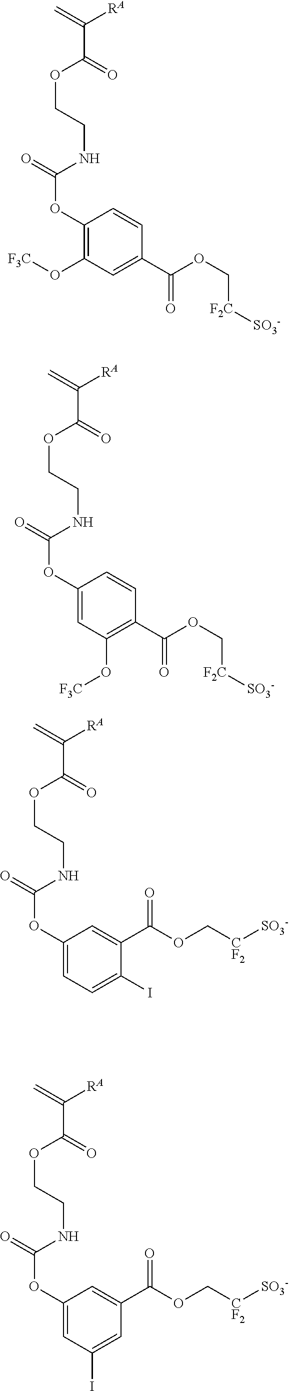

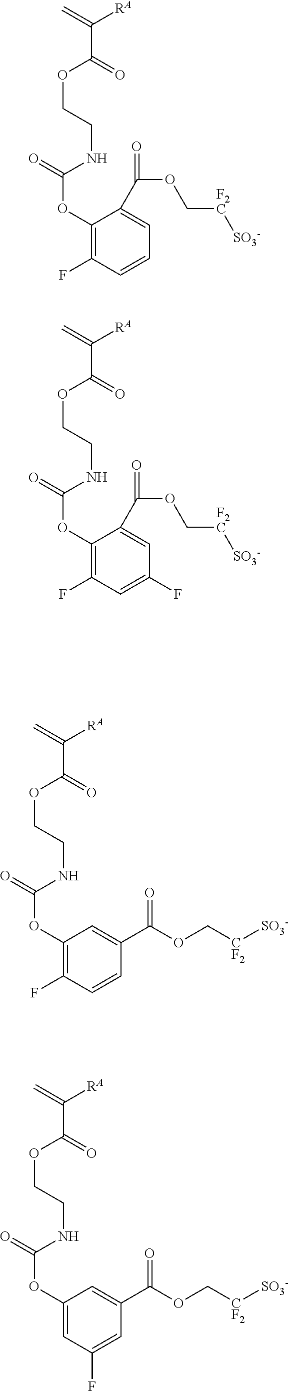

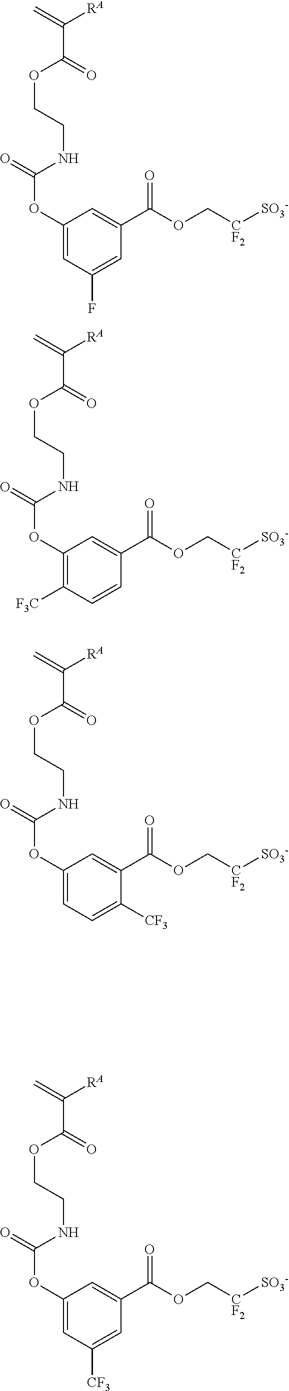

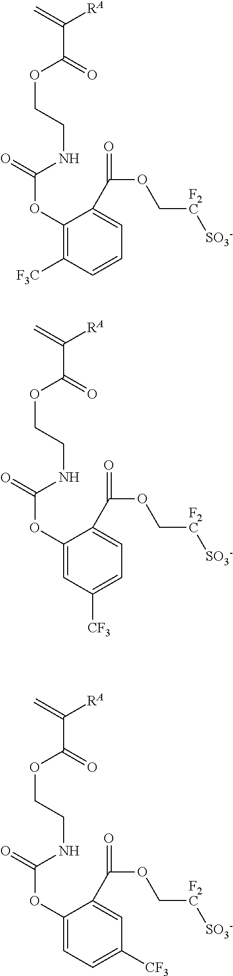

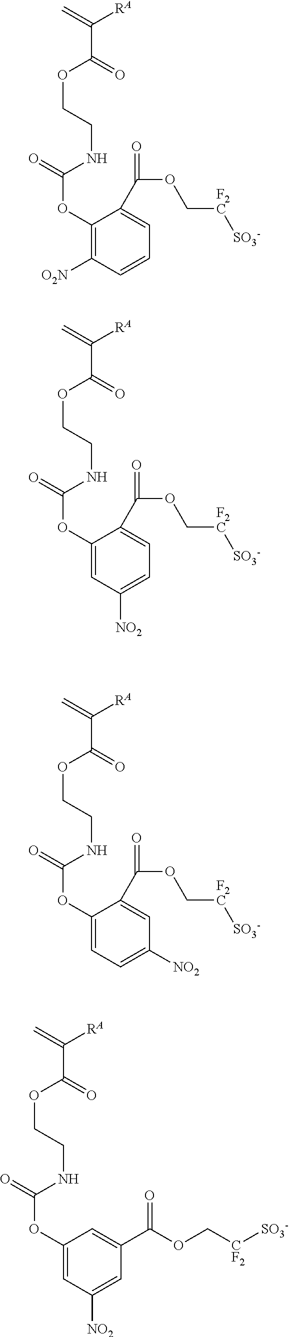

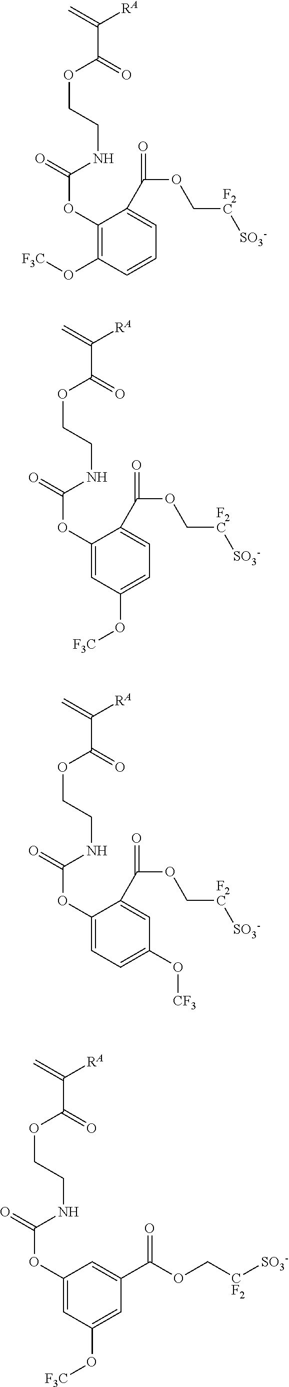

Examples of the anion in the monomer from which the repeat units (a2) are derived include those shown below, but are not limited thereto. In the formulae, R^{A} is as defined above.

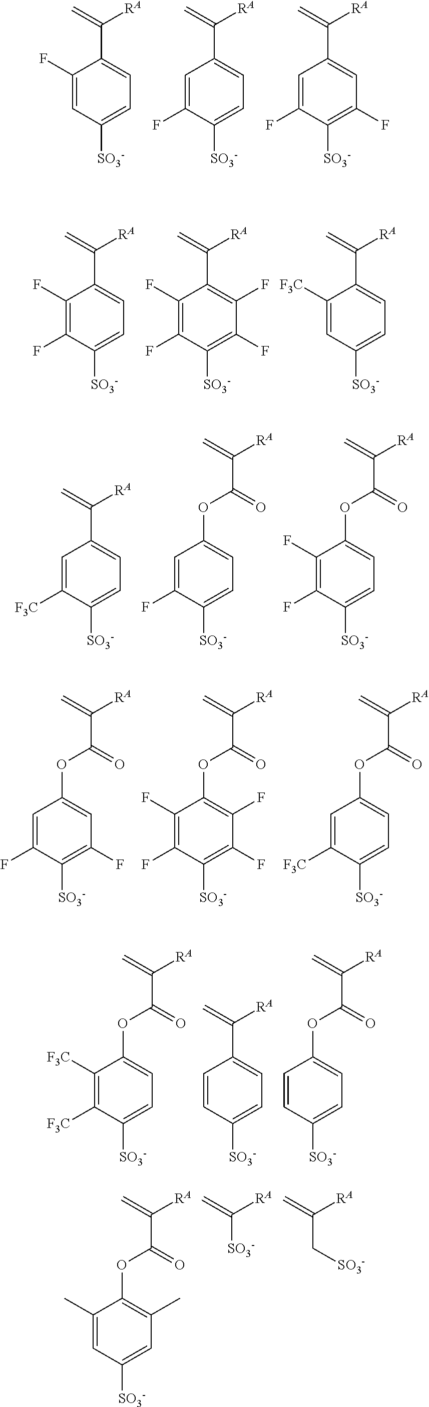

The sulfonium salt from which the repeat units (a1) or (a2) are derived may be synthesized, for example, by ion exchange between a salt containing the sulfonium cation and a weak acid anion and an ammonium salt having the above anion. The sulfonium cation can be obtained, for example, by the method described in paragraphs [0094] to [0097] of JP-A 2022-068394.

When the resist composition is of positive tone, the base polymer preferably further contains repeat units containing an acid labile group. The repeat units containing an acid labile group are preferably repeat units having formula (b1)(hereinafter, the repeat units are also referred to as repeat units (b1)) or repeat units having formula (b2) (hereinafter, the repeat units are also referred to as repeat units (b2)). In the exposed region, not only the repeat units (b1) and (b2) each containing an acid labile group, but also the repeat units (a1) and (a2) each containing an acid generator in the base polymer undergo catalytic reaction, whereby the dissolution rate in the developer is accelerated. Thus, a positive resist composition having very high sensitivity is obtained.

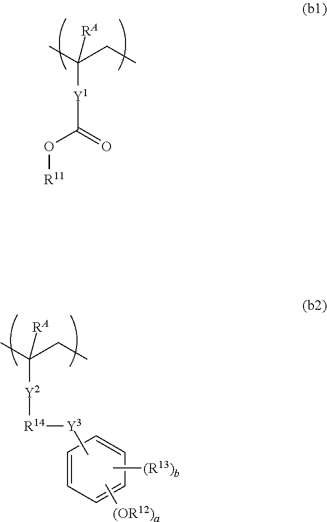

In formulae (b1) and (b2), R^{A} is each independently a hydrogen atom or a methyl group. Y¹ is a single bond, a phenylene group, a naphthylene group, or a C₁-C₁₂ linking group containing at least one moiety selected from an ester bond, an ether bond, and a lactone ring. Y² is a single bond or an ester bond. Y³ is a single bond, an ether bond, or an ester bond. R¹¹ and R¹² are each independently an acid labile group. R³ is a fluorine atom, a trifluoromethyl group, a cyano group, a C₁-C₆ saturated hydrocarbyl group, a C₁-C₆ saturated hydrocarbyloxy group, a C₂-C₇ saturated hydrocarbylcarbonyl group, a C₂-C₇ saturated hydrocarbylcarbonyloxy group, or a C₂-C₇ saturated hydrocarbyloxycarbonyl group. R¹⁴ is a single bond or a C₁-C₆ alkanediyl group in which some constituent —CH₂— may be substituted with an ether bond or an ester bond, a is 1 or 2, and b is an integer of 0 to 4, provided that 1≤a+b≤5.

Examples of the monomer from which the repeat units (b1) are derived include those shown below, but are not limited thereto. In the formulae, R^{A} and R¹¹ are as defined above.

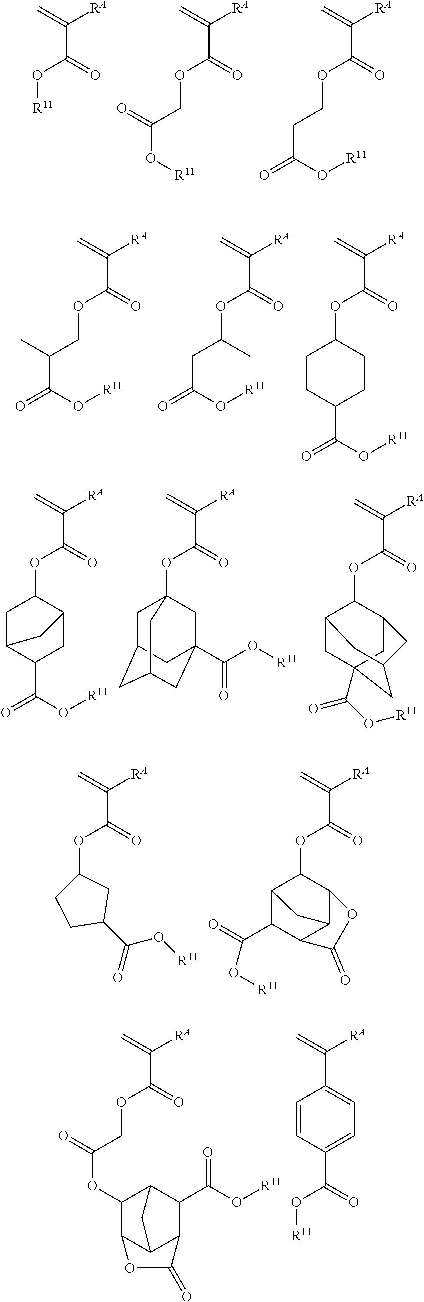

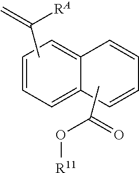

Examples of the monomer from which the repeat units (b2) are derived include those shown below, but are not limited thereto. In the formulae, R^{A} and R¹² are as defined above.

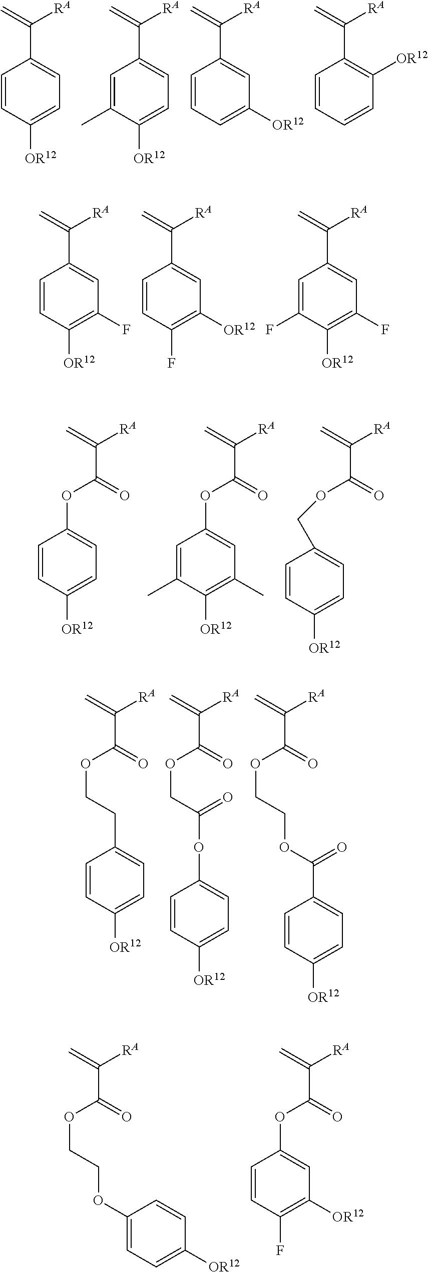

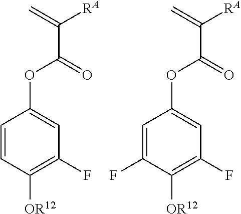

Examples of the acid labile groups represented by R¹¹ and R¹² in formulae (b1) and (b2) include those described in JP-A 2013-080022 and JP-A 2013-083821.

Typical examples of the acid labile groups include those represented by formulae (AL-1) to (AL-3).

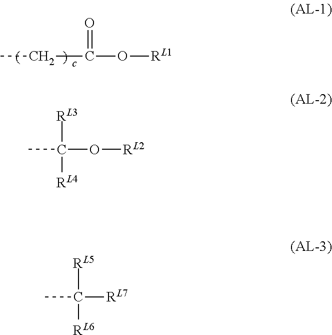

In the formulae, a broken line designates a bond.

In formulae (AL-1) and (AL-2), RV and RV are each independently a C₁-C₄₀ hydrocarbyl group which may contain a heteroatom such as an oxygen atom, a sulfur atom, a nitrogen atom, or a fluorine atom. The hydrocarbyl group may be saturated or unsaturated, and may be straight, branched, or cyclic. Preferred are C₁-C₄₀ saturated or C₂-C₄₀ unsaturated hydrocarbyl groups, especially C₁-C₂₀ saturated or C₂-C₂₀ unsaturated hydrocarbyl groups.

In formula (AL-1), c is an integer of 0 to 10, preferably an integer of 1 to 5.

In formula (AL-2), R_{L3} and R_{L4} are each independently a hydrogen atom or a C₁-C₂₀ hydrocarbyl group which may contain a heteroatom such as an oxygen atom, a sulfur atom, a nitrogen atom, or a fluorine atom. The hydrocarbyl group may be saturated or unsaturated, and may be straight, branched, or cyclic. Preferred are C₁-C₂₀ saturated hydrocarbyl groups. Any two of R^{L2}, R^{L3}, and R^{L4} may bond together to form a ring, typically an alicyclic ring, with the carbon atom or carbon and oxygen atoms to which they are bonded, the ring containing 3 to 20 carbon atoms, preferably 4 to 16 carbon atoms.

In formula (AL-3), R^{L5}, R^{L6}, and R^{L7} are each independently a C₁-C₂₀ hydrocarbyl group which may contain a heteroatom such as an oxygen atom, a sulfur atom, a nitrogen atom, or a fluorine atom. The hydrocarbyl group may be saturated or unsaturated, and may be straight, branched, or cyclic. Preferred are C₁-C₂₀ saturated hydrocarbyl groups. Any two of R^{L5}, R^{L6}, and R^{L7} may bond together to form a ring, typically an alicyclic ring, with the carbon atom to which they are bonded, the ring containing 3 to 20 carbon atoms, preferably 4 to 16 carbon atoms and optionally containing a double bond or a triple bond.

Also useful as the acid labile group having formula (AL-3) are aromatic group-containing acid labile groups as described in JP 5655754, JP 5655755, JP 5655756, JP 5407941, JP 5434983, JP 5565293, and JP-A 2007-279699; triple bond-containing acid labile groups as described in JP-A 2008-268741; and double or triple bond-containing acid labile groups as described in JP-A 2021-050307.

The base polymer may further contain repeat units (c) having a phenolic hydroxy group as an adhesive group. Examples of the monomer from which the repeat units (c) are derived include those shown below, but are not limited thereto. In the formulae, R^{A} is as defined above.

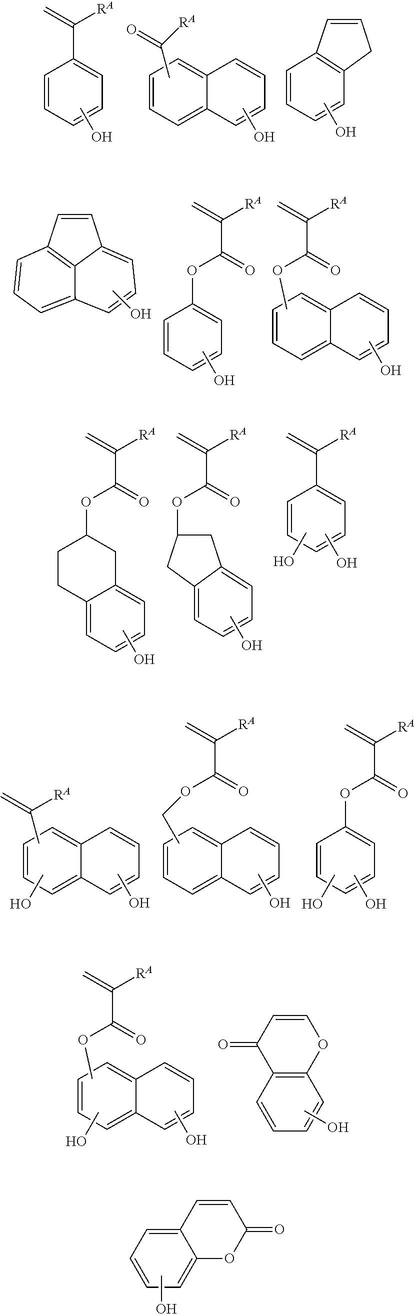

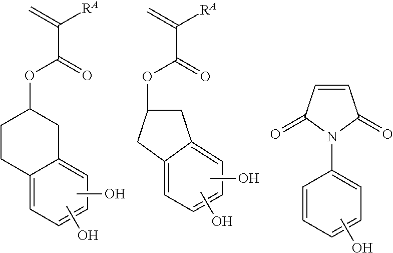

The base polymer may further contain repeat units (d) having another adhesive group selected from a hydroxy group other than the phenolic hydroxy group, a lactone ring, a sultone ring, an ether bond, an ester bond, a sulfonic ester bond, a carbonyl group, a sulfonyl group, a cyano group, and a carboxy group. Examples of the monomer from which the repeat units (d) are derived include those shown below, but are not limited thereto. In the formulae, R^{A} is as defined above.

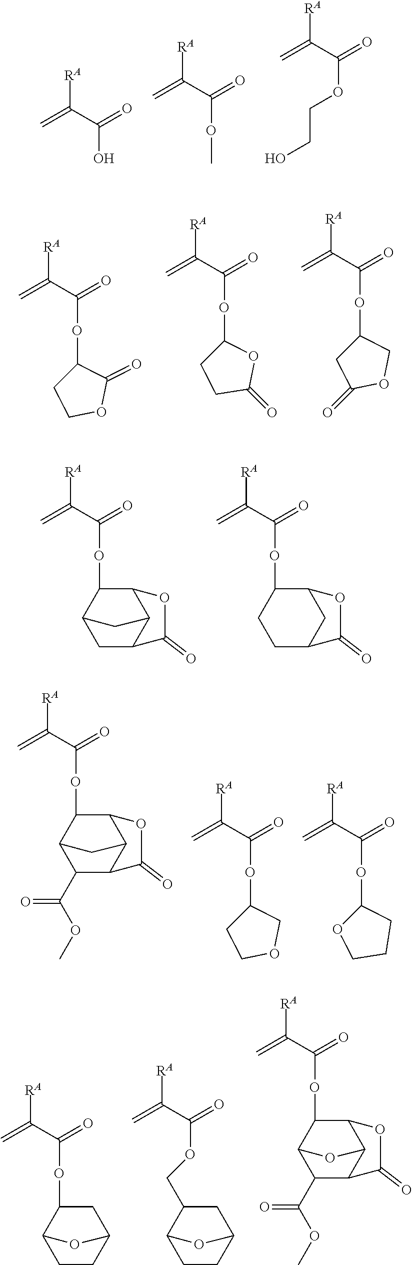

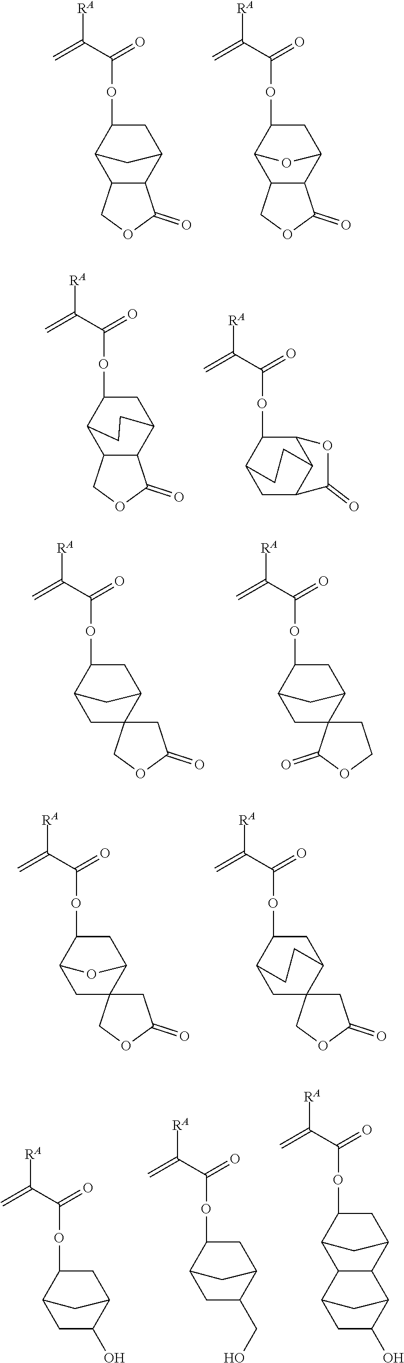

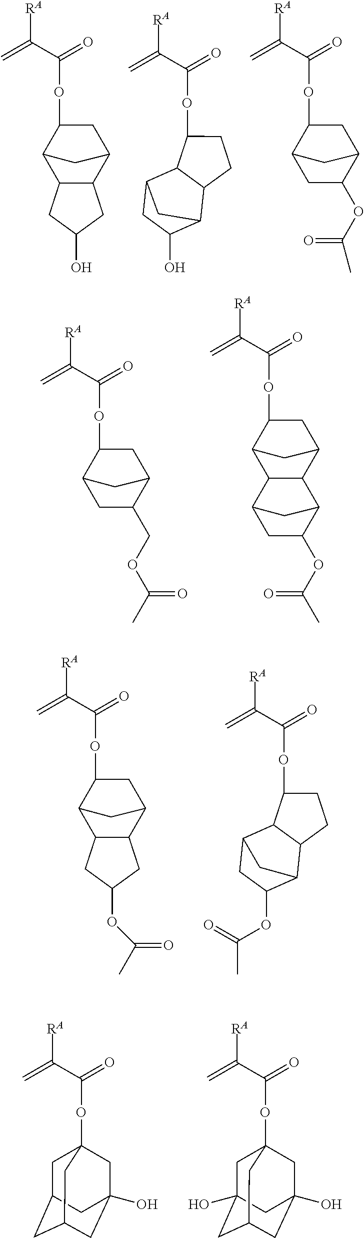

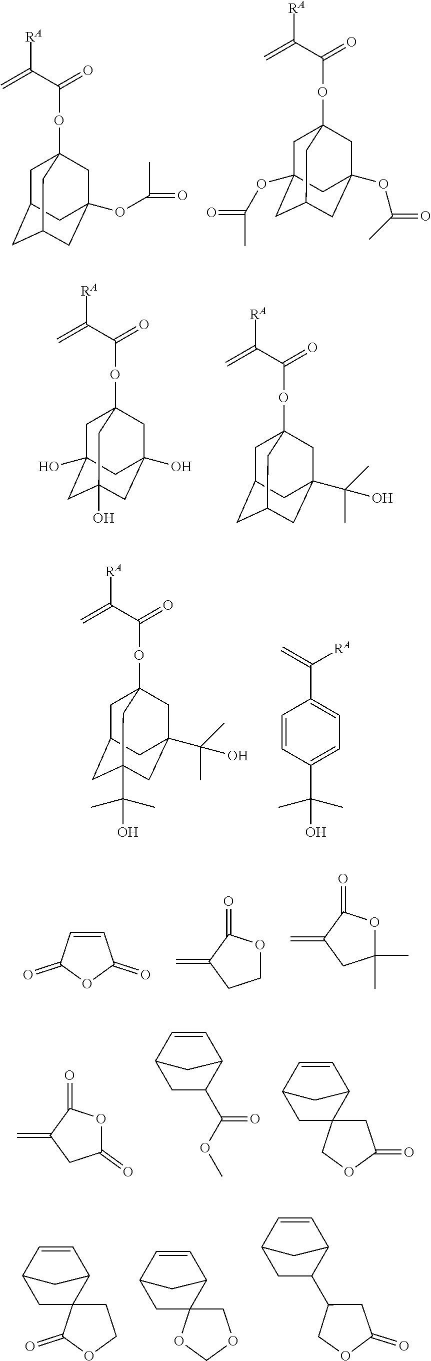

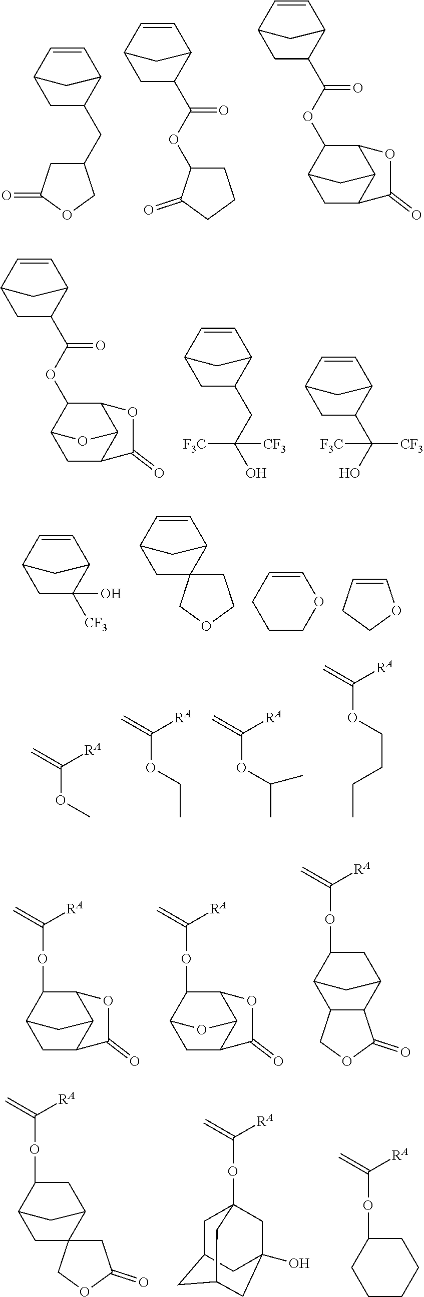

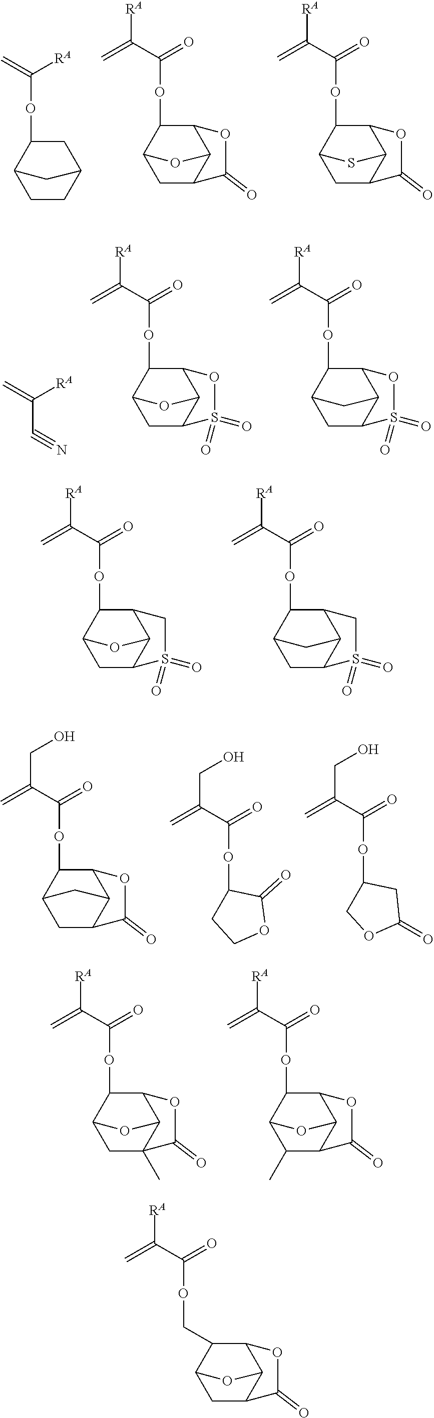

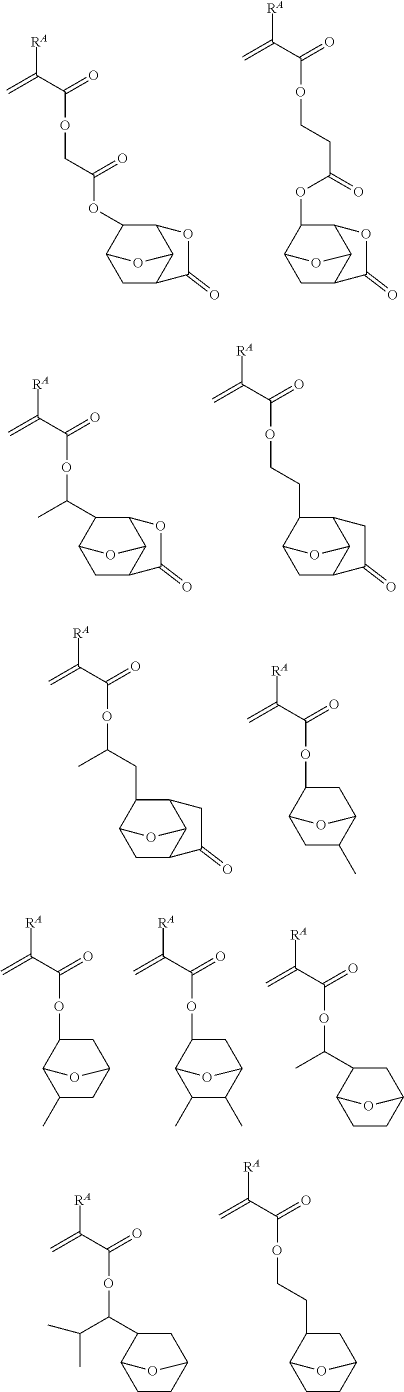

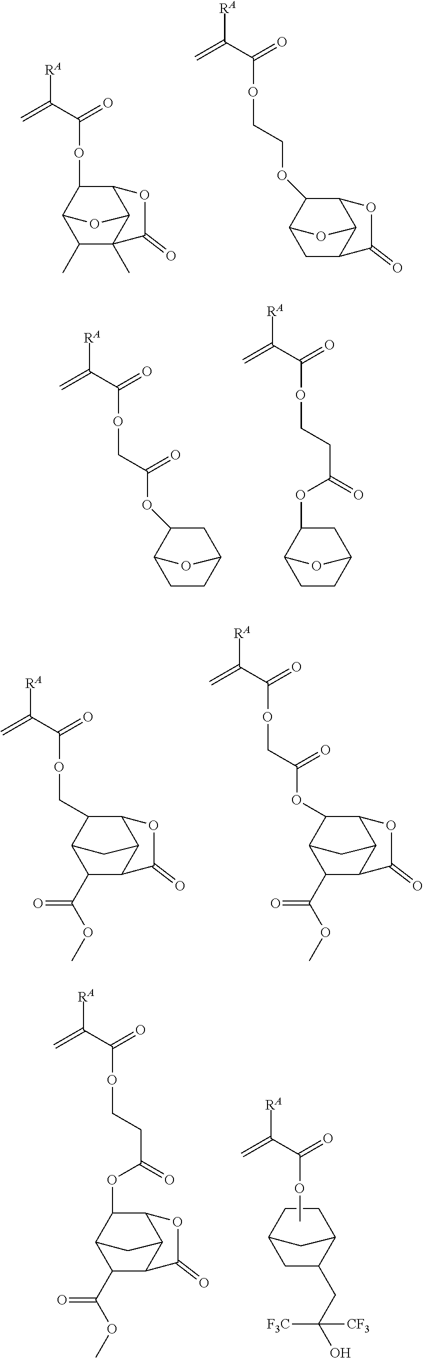

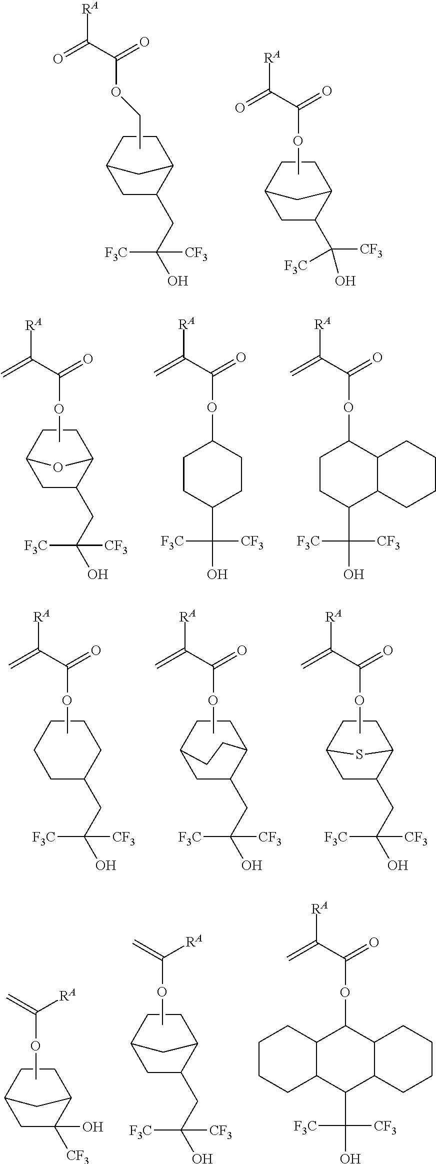

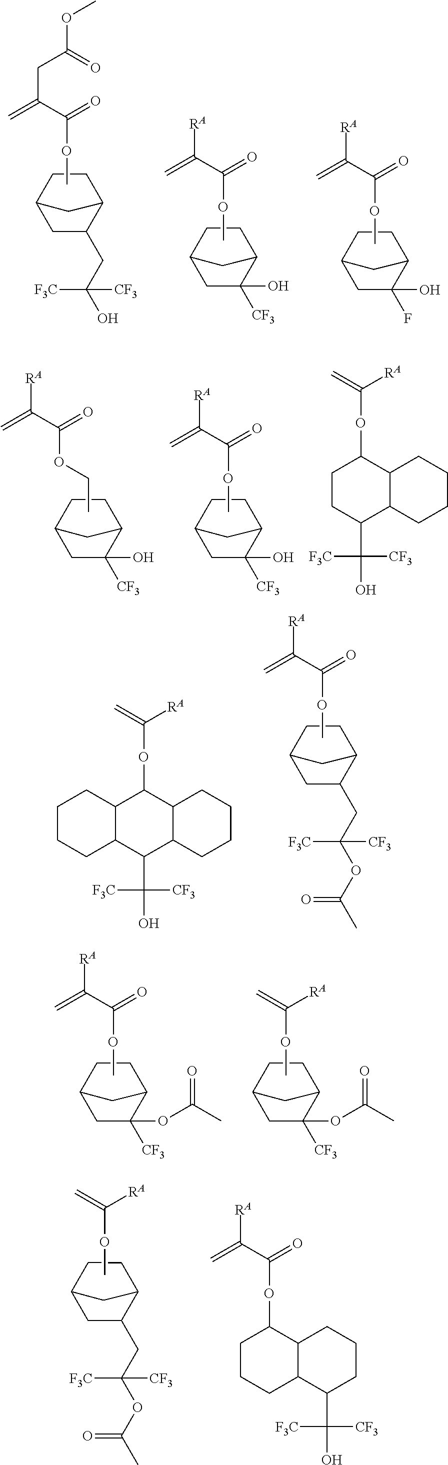

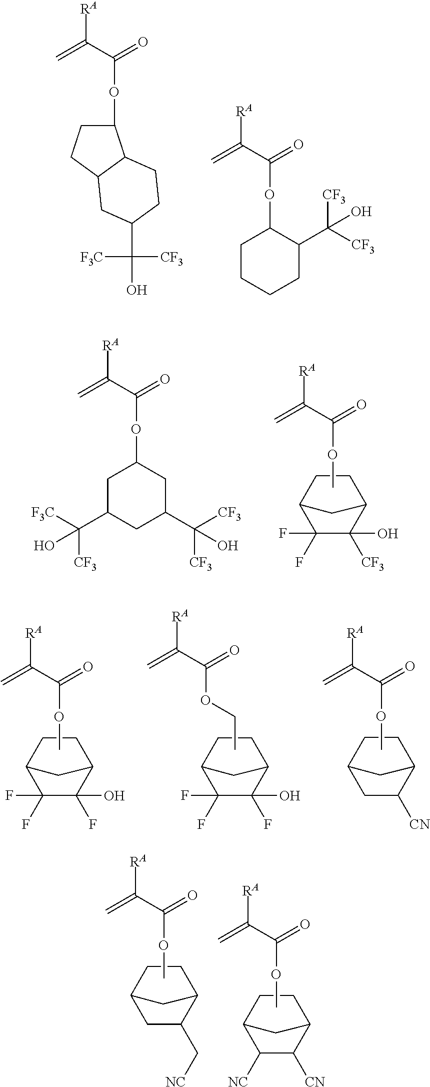

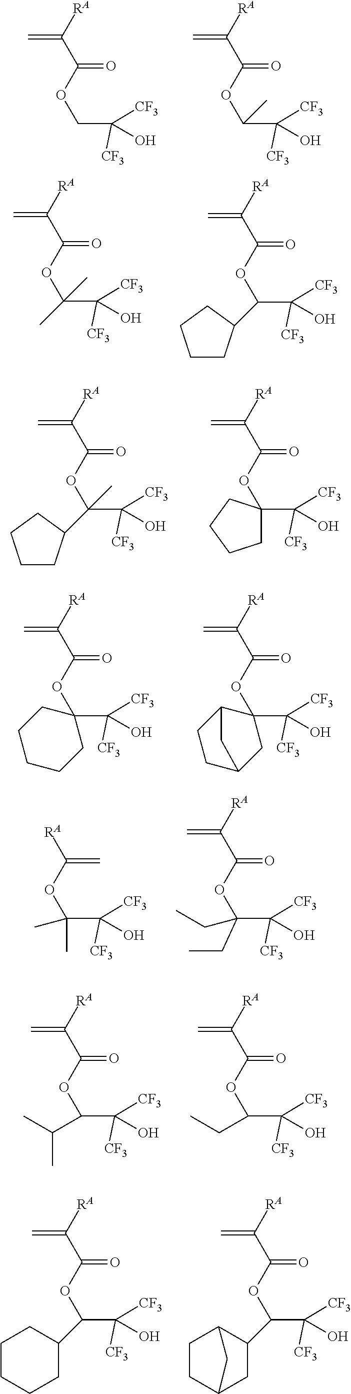

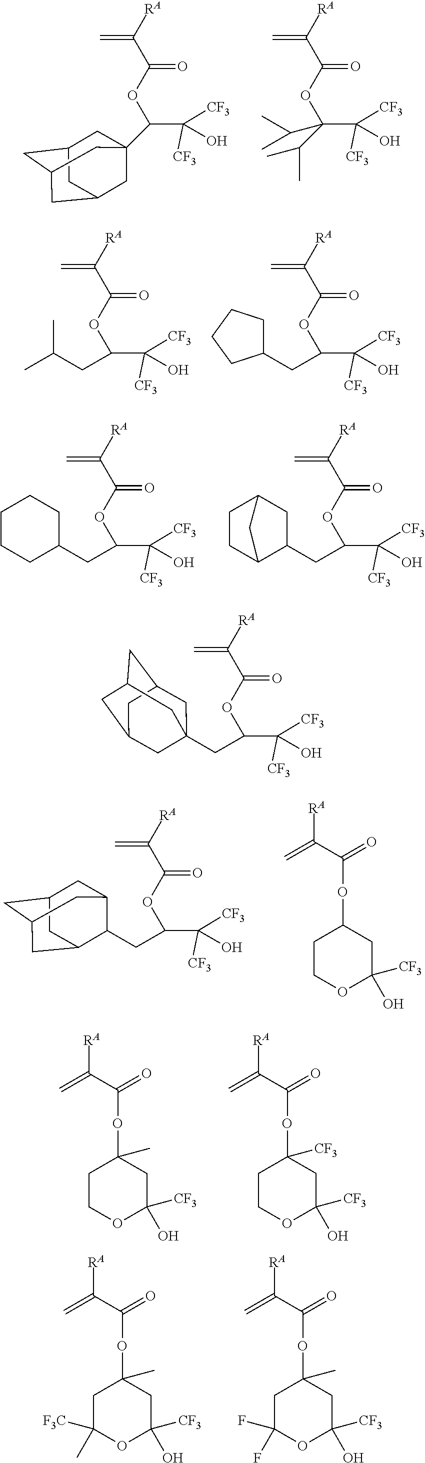

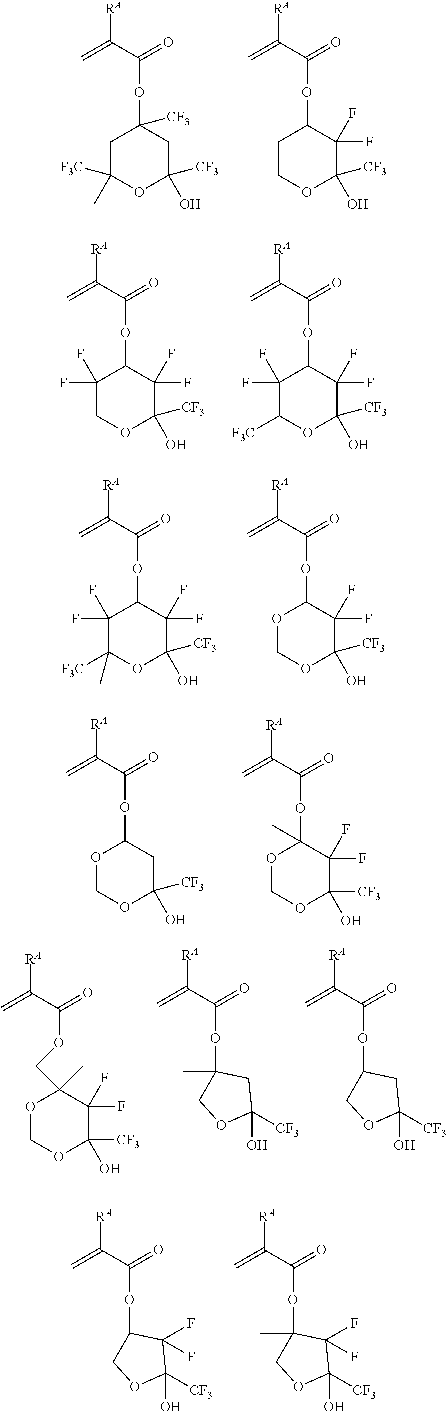

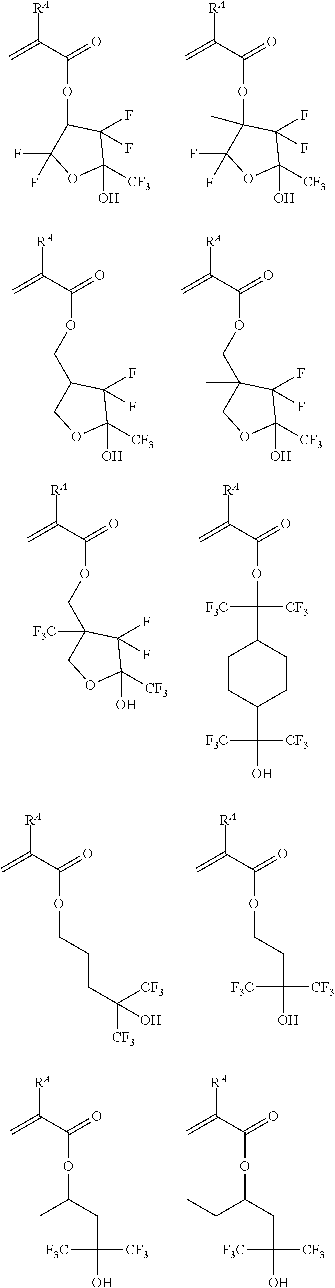

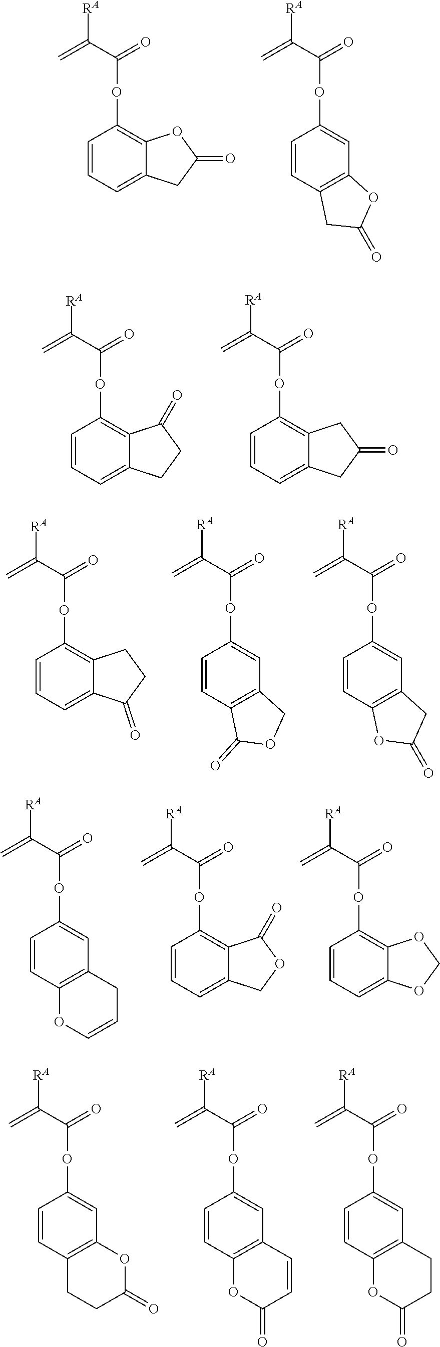

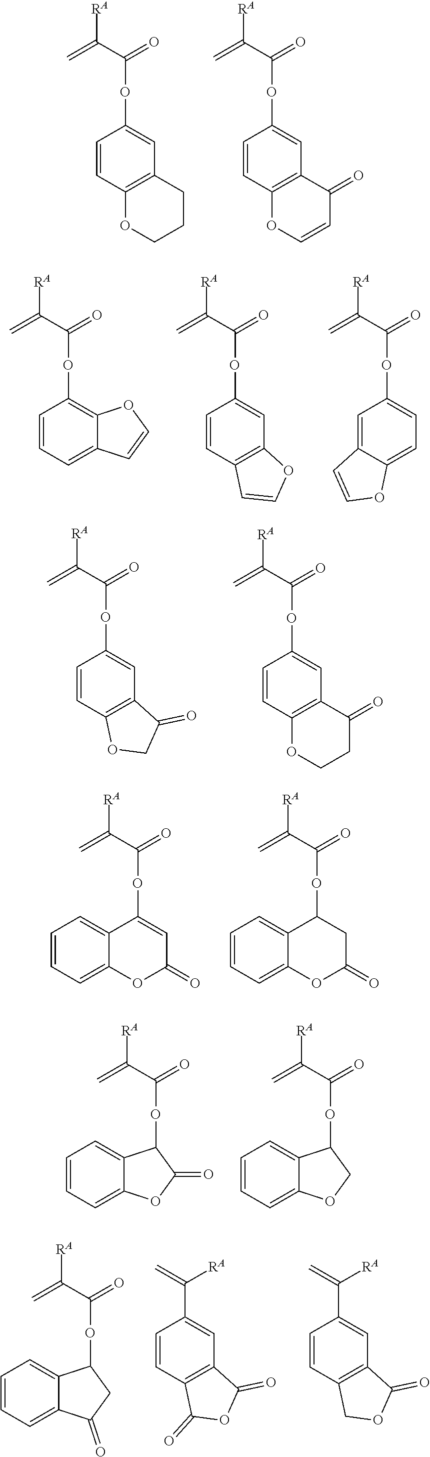

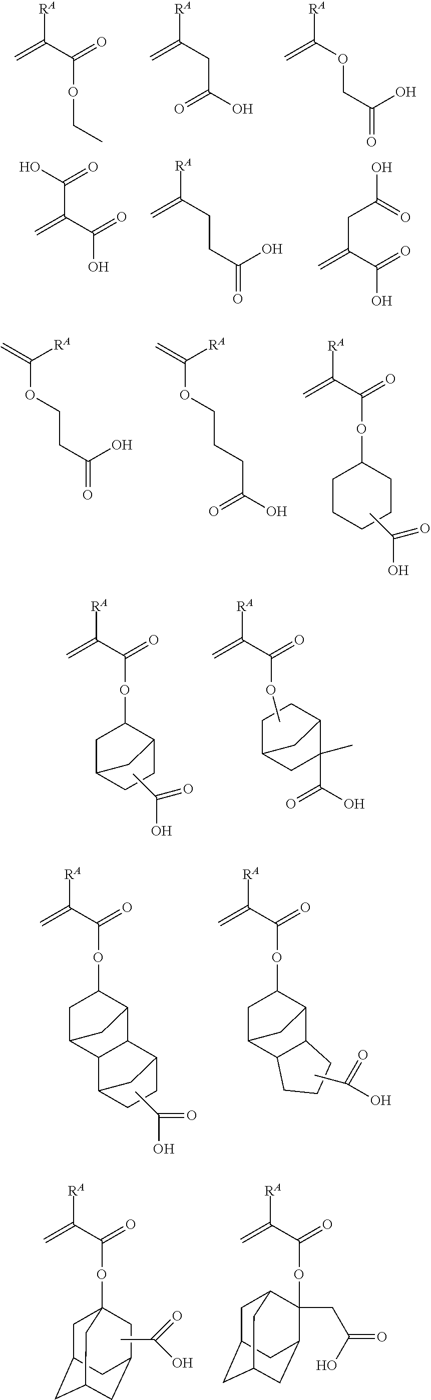

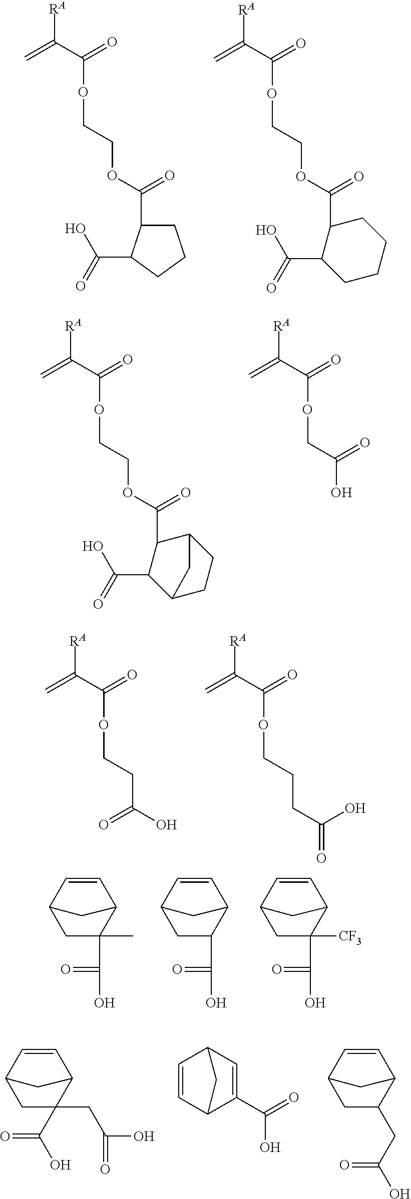

The base polymer may further contain repeat units (e) derived from indene, benzofuran, benzothiophene, acenaphthylene, chromone, coumarin, norbornadiene, or a derivative thereof. Examples of the monomer from which the repeat units (e) are derived include those shown below, but are not limited thereto.

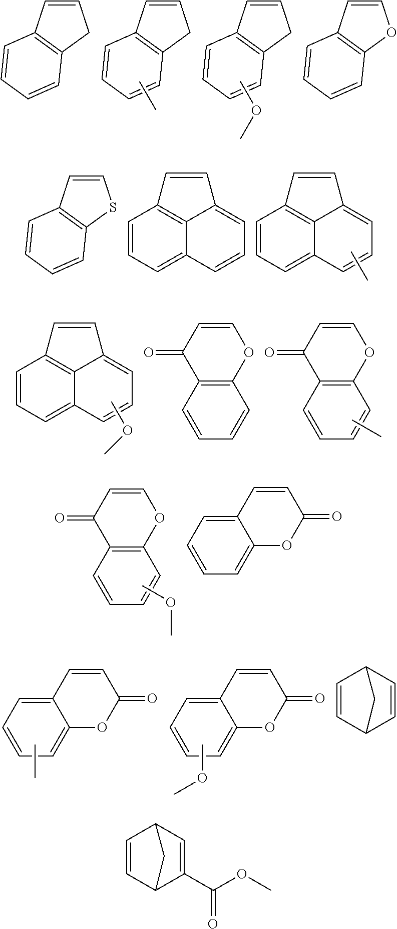

The base polymer may further contain repeat units (f) derived from styrene, vinylnaphthalene, vinylanthracene, vinylpyrene, methyleneindane, vinylpyridine, or vinylcarbazole.

The base polymer contains repeat units (a1) or (a2) as an essential component. In this case, the fractions of the repeat units (a1), (a2), (b), (c), (d), (e), and (f) are preferably 0≤(a1)≤0.5, 0≤(a2)≤0.5, 0<(a1)+(a2)≤0.5, 0≤(b1)≤0.8, 0≤(b2)≤0.8, 0.1≤(b1)÷(b2)≤0.8, 0≤(c) 0.9, 0≤(d)≤0.8, 0≤(e)≤0.8, and 0≤(f)≤0.5, more preferably 0≤(a1)≤0.4, 0≤(a2)≤0.4, 0.01≤(a1)+(a2)≤0.4, 0≤(b1)≤0.7, 0≤(b2)≤0.7, 0.15≤(b1)+(b2)≤0.7, 0≤(c)≤0.8, 0≤(d)≤0.7, 0≤(e)≤0.7, and 0≤(f)≤0.4, and even more preferably 0≤(a1)≤0.35, 0≤(a2)≤0.35, 0.02≤(a1)÷(a2)≤0.35, 0≤(b1)≤0.65, 0≤(b2)≤0.65, 0.2≤(b1)+(b2)≤0.65, 0≤(c)≤0.7, 0≤(d)≤0.6, 0≤(e)≤0.6, and 0≤(f)≤0.3. Note that (a1)+(a2)+(b1)÷(b2)+(c)+(d)+(e)+(f)=1.0.

The base polymer may be synthesized, for example, by heating a monomer from which the repeat units are derived in an organic solvent with the addition of a radical polymerization initiator to perform polymerization.

Examples of the organic solvent used in the polymerization include toluene, benzene, tetrahydrofuran (THF), diethyl ether, and dioxane. Examples of the polymerization initiator include 2,2′-azobisisobutyronitrile (AIBN), 2,2′-azobis(2,4-dimethylvaleronitrile), dimethyl-2,2-azobis(2-methylpropionate), benzoyl peroxide, and lauroyl peroxide. The temperature during polymerization is preferably 50 to 80° C. The reaction time is preferably 2 to 100 hours, and more preferably 5 to 20 hours.

When a monomer having a hydroxy group is copolymerized, the hydroxy group may be substituted with an acetal group susceptible to deprotection with an acid such as an ethoxyethoxy group prior to polymerization, and the polymerization be followed by deprotection with a weak acid and water. Alternatively, the hydroxy group may be substituted with an acetyl group, a formyl group, a pivaloyl group or the like prior to polymerization, and the polymerization be followed by alkaline hydrolysis.

When hydroxystyrene or hydroxyvinylnaphthalene is copolymerized, acetoxystyrene or acetoxyvinylnaphthalene may be used instead of hydroxystyrene or hydroxyvinylnaphthalene, and after polymerization, the acetoxy group may be deprotected by alkaline hydrolysis for converting the polymer product to hydroxystyrene or hydroxyvinylnaphthalene.

For alkaline hydrolysis, a base such as aqueous ammonia or triethylamine may be used. The reaction temperature is preferably −20 to 100° C., and more preferably 0 to 60° C. The reaction time is preferably 0.2 to 100 hours, and more preferably 0.5 to 20 hours.

The base polymer preferably has a weight average molecular weight (Mw) in the range of 1,000 to 500,000, and more preferably 2,000 to 30,000, as measured by gel permeation chromatography (GPC) versus polystyrene standards using a THF solvent. A Mw in the range ensures that the resist film has heat resistance and high solubility in an alkaline developer.

If the base polymer has a wide molecular weight distribution (Mw/Mn), which indicates the presence of lower and higher molecular weight polymer fractions, there is a possibility that foreign matters are left on the pattern or the pattern profile is degraded after exposure. The influences of Mw and Mw/Mn tend to be stronger as the pattern rule becomes finer. Therefore, the base polymer should preferably have a nan-ow dispersity (Mw/Mn) of 1.0 to 2.0, especially 1.0 to 1.5, in order to provide a resist composition suitable for micropatterning to a small feature size.

The base polymer may contain two or more polymers having different compositional ratios, Mw, and Mw/Mn.

### Organic Solvent

The resist composition of the present invention may contain an organic solvent. The organic solvent is not particularly limited as long as the components described above and below are soluble therein. Examples of the organic solvent are described in paragraphs [0144] to [0145] of JP-A 2008-111103, and include ketones such as cyclohexanone, cyclopentanone, methyl-2-n-pentyl ketone, and 2-heptanone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol mono-tert-butyl ether acetate, methyl 2-hydroxyisobutyrate, ethyl 2-hydroxyisobutyrate, propyl 2-hydroxyisobutyrate, and butyl 2-hydroxyisobutyrate; and lactones such as γ-butyrolactone.

The organic solvent is preferably added to the resist composition of the present invention in an amount of 100 to 10,000 parts by weight, and more preferably 200 to 8,000 parts by weight per 100 parts by weight of the base polymer. The organic solvent may be used singly or as a mixture of two or more kinds thereof.

### Quencher

The resist composition of the present invention may contain a quencher. The quencher refers to a compound capable of trapping the acid generated from the acid generator in the resist composition to prevent the acid from diffusing to the unexposed region.

Examples of the quencher include conventional basic compounds. Examples of the conventional basic compounds include primary, secondary, and tertiary aliphatic amines, mixed amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amide derivatives, imide derivatives, and carbamate derivatives. In particular, primary, secondary, and tertiary amine compounds described in paragraphs [0146] to [0164] of JP-A 2008-111103, particularly amine compounds having a hydroxy group, an ether bond, an ester bond, a lactone ring, a cyano group, or a sulfonic ester bond, and compounds having a carbamate group described in JP 3790649 are preferred. Addition of a basic compound may be effective for further reducing the diffusion rate of the acid in the resist film or con-ecting the pattern profile.

Examples of the quencher also include onium salts such as sulfonium salts, iodonium salts, and ammonium salts of sulfonic acids which are not fluorinated at the α-position, carboxylic acids, or fluorinated alkoxides, as described in JP-A 2008-158339. While a sulfonic acid which is fluorinated at the α-position, imide acid, or methide acid is necessary for deprotecting the acid labile group of a carboxylic acid ester, an α-non-fluorinated sulfonic acid, a carboxylic acid, or fluorinated alcohol is released by salt exchange with an α-non-fluorinated onium salt. The α-non-fluorinated sulfonic acid, carboxylic acid, and fluorinated alcohol function as a quencher because they do not induce deprotection reaction.

Examples of such a quencher include a compound having formula (2) (an onium salt of an α-non-fluorinated sulfonic acid), a compound having formula (3) (an onium salt of a carboxylic acid), and a compound having formula (4) (an onium salt of an alkoxide).

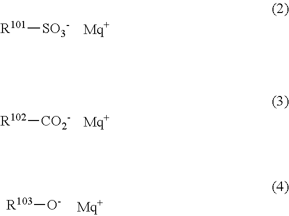

In formula (2), R¹⁰¹ is a hydrogen atom or a C₁-C₄₀ hydrocarbyl group which may contain a heteroatom, exclusive of a hydrocarbyl group in which a hydrogen atom bonded to the carbon atom at the α-position of the sulfo group is substituted with a fluorine atom or a fluoroalkyl group.

The C₁-C₄₀ hydrocarbyl group represented by R¹⁰¹ may be saturated or unsaturated, and may be straight, branched, or cyclic. Examples thereof include C₁-C₄₀ alkyl groups such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group, and a n-decyl group; C₃-C₄₀ cyclic saturated hydrocarbyl groups such as a cyclopentyl group, a cyclohexyl group, a cyclopentylmethyl group, a cyclopentylethyl group, a cyclopentylbutyl group, a cyclohexyhnethyl group, a cyclohexylethyl group, a cyclohexylbutyl group, a norbornyl group, a tricyclo[5.2.1.0^{2,6}]decyl group, an adamantyl group, and an adamantyhnethyl group; C₂-C₄₀ alkenyl groups such as a vinyl group, an allyl group, a propenyl group, a butenyl group, and a hexenyl group; C₃-C₄ cyclic unsaturated aliphatic hydrocarbyl groups such as a cyclohexenyl group; C₆-C₄₀ aryl groups such as a phenyl group, a naphthyl group, alkylphenyl groups (e.g., a 2-methylphenyl group, a 3-methylphenyl group, a 4-methylphenyl group, a 4-ethylphenyl group, a 4-tert-butylphenyl group, and a 4-n-butylphenyl group), dialkylphenyl groups (e.g., a 2,4-dimethylphenyl group and a 2,4,6-triisopropylphenyl group), alkyhlaphthyl groups (e.g., a methyhnaphthyl group and an ethylnaphthyl group), and dialkylnaphthyl groups (e.g., a dimethylnaphthyl group and a diethylnaphthyl group); and C₇-C₄₀ aralkyl groups such as a beuzyl group, a 1-phenylethyl group, and a 2-phenylethyl group.

Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a cyano group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. Examples of the heteroatom-containing hydrocarbyl group include heteroaryl groups such as a thienyl group; alkoxyphenyl groups such as a 4-hydroxyphenyl group, a 4-methoxyphenyl group, a 3-methoxyphenyl group, a 2-methoxyphenyl group, a 4-ethoxyphenyl group, a 4-tert-butoxyphenyl group, and a 3-tert-butoxyphenyl group; alkoxynaphthyl groups such as a methoxynaphthyl group, an ethoxynaphthyl group, a n-propoxynaphthyl group, and a n-butoxynaphthyl group; dialkoxynaphthyl groups such as a dimethoxynaphthyl group and a diethoxynaphthyl group; and aryloxoalkyl groups, typically 2-aryl-2-oxoethyl groups such as a 2-phenyl-2-oxoethyl group, a 2-(1-naphthyl)-2-oxoethyl group, and a 2-(2-naphthyl)-2-oxoethyl group.

In formula (3). R¹⁰² is a C₁-C₄₀ hydrocarbyl group which may contain a heteroatom. Examples of the hydrocarbyl group represented by R¹⁰² include those groups mentioned as the hydrocarbyl group represented by R¹⁰¹. Also included are fluorinated alkyl groups such as a trifluoromethyl group, a trifluoroethyl group, a 2,2,2-trifluoro-1-methyl-1-hydroxyethyl group, and a 2,2,2-trifluoro-1-(trifluoromethyl)-1-hydroxyethyl group; and fluorinated aryl groups such as a pentafluorophenyl group and a 4-trifluoromethylphenyl group.

In formula (4), R¹⁰³ is a C₁-C₈ saturated hydrocarbyl group containing at least 3 fluorine atoms or a C₆-C₁₀ aryl group containing at least 3 fluorine atoms, and may contain a nitro group.

In formulae (2), (3), and (4), Mq⁺ is an onium cation. The onium cation is preferably a sulfonium cation, an iodonium cation, or an ammonium cation, and more preferably a sulfonium cation. Examples of the sulfonium cation include sulfonium cations described in JP-A 2017-219836.

A sulfonium salt of iodized benzene ring-containing carboxylic acid having formula (5) is also suitable for the quencher.

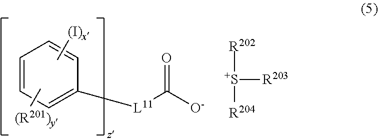

In formula (5). R²⁰¹ is a hydroxy group, a fluorine atom, a chlorine atom, a bromine atom, an amino group, a nitro group, a cyano group, or a C₁-C₆ saturated hydrocarbyl group, a C₁-C₆ saturated hydrocarbyloxy group, a C₂-C₆ saturated hydrocarbylcarbonyloxy group, or a C₁-C₄ saturated hydrocarbylsulfonyloxy group, in which some or all hydrogen atoms may be substituted with a halogen atom, —N(R^{201A})—C(═O)—R^{201B}, or —N(R^{201A})—C(═O)—O—R^{201B}, wherein R^{201A} is a hydrogen atom or a C₁-C₆ saturated hydrocarbyl group, and R^{201B} is a C₁-C₆ saturated hydrocarbyl group or a C₂-C₈ unsaturated aliphatic hydrocarbyl group.

In formula (5), x′ is an integer of 1 to 5, y′ is an integer of 0 to 3. z′ is an integer of 1 to 3. L¹¹ is a single bond, or a C₁-C₂₀ (z′+1)-valent linking group which may contain at least one moiety selected from an ether bond, a carbonyl group, an ester bond, an amide bond, a sultone ring, a lactam ring, a carbonate bond, a halogen atom, a hydroxy group, and a carboxy group. The saturated hydrocarbyl group, the saturated hydrocarbyloxy group, the saturated hydrocarbylcarbonyloxy group, and the saturated hydrocarbylsulfonyloxy group may be straight, branched, or cyclic. Groups R²⁰¹ may be identical or different when y′ and/or z′ is 2 or more.

In formula (5), R²⁰², R²⁰³, and R²⁰⁴ are each independently a halogen atom, or a C₁-C₂₀ hydrocarbyl group which may contain a heteroatom. The hydrocarbyl group may be saturated or unsaturated, and may be straight, branched, or cyclic. Examples thereof include C₁-C₂ alkyl groups such as a methyl group, an ethyl group, a n-propyl group, an isopropyl group, a n-butyl group, an isobutyl group, a sec-butyl group, a tert-butyl group, a n-pentyl group, a n-hexyl group, a n-octyl group, a n-nonyl group, a n-decyl group, an undecyl group, a dodecyl group, a tridecyl group, a tetradecyl group, a pentadecyl group, a heptadecyl group, an octadecyl group, a nonadecyl group, and an icosyl group; C₃-C₂₀ cyclic saturated hydrocarbyl groups such as a cyclopropyl group, a cyclopentyl group, a cyclohexyl group, a cyclopropyhnethyl group, a 4-methylcyclohexyl group, a cyclohexylmethyl group, a norbornyl group, and an adamantyl group; C₂-C₂₀ alkenyl groups such as a vinyl group, a propenyl group, a butenyl group, and a hexenyl group; C₂-C₂₀ cyclic unsaturated aliphatic hydrocarbyl groups such as a cyclohexenyl group and a norbornenyl group; C₂-C₂₀ alkynyl groups such as an ethynyl group, a propynyl group, and a butynyl group; C₆-C₂₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butyinaphthyl group, an isobutylnaphthyl group, a sec-butylnaphthyl group, and a tert-butylnaphthyl group; C₇-C₂₀ aralkyl groups such as a benzyl group and a phenethyl group; and groups obtained by combining the foregoing. In these hydrocarbyl groups, some or all of hydrogen atoms may be substituted with a hydroxy group, a carboxy group, a halogen atom, an oxo group, a cyano group, a nitro group, a sultone ring, a sulfo group, or a sulfonium salt-containing group, and some constituent —CH₂— may be substituted with an ether bond, an ester bond, a carbonyl group, an amide bond, a carbonate bond, or a sulfonic ester bond. R²⁰² and R²⁰³ may bond together to form a ring together with the sulfur atom to which they are bonded.

Examples of the compound having formula (5) include compounds described in JP-A 2017-219836 and JP-A 2021-091666.

Another example of the quencher is a polymeric quencher described in JP-A 2008-239918. The polymeric quencher segregates at the resist film surface and thus enhances the rectangularity of the resist pattern. When a protective film is applied as is often the case in immersion lithography, the polymeric quencher is also effective for preventing a film thickness loss of the resist pattern or rounding of the pattern top.

Other useful quenchers include sulfonium salts of betaine structure as described in JP 6848776 and JP-A 2020-037544, fluorine-free methide acids as described in JP-A 2020-055797, sulfonium salts of sulfonamide as described in JP 5807552, and sulfonium salts of iodized sulfonamide as described in JP-A 2019-211751.

The quencher is preferably added to the resist composition of the present invention in an amount of 0 to 5 parts by weight, and more preferably 0 to 4 parts by weight per 100 parts by weight of the base polymer. The quencher may be used singly or in combination of two or more kinds thereof.

### Other Components

In addition to the foregoing components, the resist composition of the present invention may contain other components such as an acid generator of sulfonium or iodonium salt type (hereinafter referred to as another acid generator), a surfactant, a dissolution inhibitor, a water repellency improver, and an acetylene alcohol.

Examples of the other acid generator include a compound that generates an acid in response to actinic rays or radiation (the compound is referred to as photoacid generator, PAG). Although the PAG may be any compound capable of generating an acid upon exposure to high-energy radiation, those compounds capable of generating a sulfonic acid, imide acid (imidic acid), or methide acid are preferred. Suitable PAGs include sulfonium salts, iodonium salts, sulfonyldiazomethane, N-sulfonyloxyimide, and oxime-O-sulfonate acid generators. Examples of the PAG include those described in paragraphs [0122] to [0142] of JP-A 2008-111103, JP-A 2018-005224, and JP-A 2018-025789. Especially suited for EUV resist compositions are sulfonium or iodonium salts of iodized sulfonic acid anions as described in JP 6720926 and JP 6743781. The other acid generator is preferably added to the resist composition of the present invention in an amount of 0 to 200 parts by weight, and more preferably 0.1 to 100 parts by weight per 100 parts by weight of the base polymer.

Examples of the surfactant include those described in paragraphs [0165] to [0166] of JP-A 2008-111103. Addition of a surfactant may improve or control the coating characteristics of the resist composition. The surfactant is preferably added to the resist composition of the present invention in an amount of 0.0001 to 10 parts by weight per 100 parts by weight of the base polymer. The surfactant may be used singly or in combination of two or more kinds thereof.

In the embodiment wherein the resist composition of the present invention is of positive tone, the addition of a dissolution inhibitor may lead to an increased difference in dissolution rate between the exposed region and the unexposed region and a further improvement in resolution. Examples of the dissolution inhibitor include a compound having at least two phenolic hydroxy groups in the molecule, in which 0 to 100 mol % of all the hydrogen atoms in the phenolic hydroxy groups are substituted with acid labile groups or a compound having at least one carboxy group in the molecule, in which an average of 50 to 100 mol % of all the hydrogen atoms in the carboxy group are substituted with acid labile groups, both the compounds preferably having a molecular weight of 100 to 1,000, and more preferably 150 to 800. Examples thereof include bisphenol A, trisphenol, phenolphthalein, cresol novolac, naphthalenecarboxylic acid, adamantanecarboxylic acid, and cholic acid derivatives, in which the hydrogen atom in the hydroxy or carboxy group is substituted with an acid labile group, as described in paragraphs [0155] to [0178] of JP-A 2008-122932.

The dissolution inhibitor is preferably added to the resist composition of positive tone of the present invention in an amount of 0 to 50 parts by weight, and more preferably 5 to 40 parts by weight per 100 parts by weight of the base polymer. The dissolution inhibitor may be used singly or in combination of two or more kinds thereof.

The water repellency improver improves the water repellency of the surface of the resist film, and can be used in the topcoatless immersion lithography. Examples of preferred water repellency improvers include polymers having a fluoroalkyl group and polymers having a specific structure with a 1,1,1,3,3,3-hexafluoro-2-propanol residue, and those described in JP-A 2007-297590 and JP-A 2008-111103, for example, are more preferred. The water repellency improver should be soluble in alkaline developers and organic solvent developers. The water repellency improver having a specific structure with a 1,1,1,3,3,3-hexafluoro-2-propanol residue is well soluble in the developer. A polymer having an amino group or amine salt copolymerized as repeat units may serve as the water repellency improver and is effective for preventing evaporation of the acid during PEB, thus preventing any hole pattern opening failure after development. The water repellency improver is preferably added to the resist composition of the present invention in an amount of 0 to 20 parts by weight, and more preferably 0.5 to 10 parts by weight per 100 parts by weight of the base polymer. The water repellency improver may be used singly or in combination of two or more kinds thereof.

Examples of the acetylene alcohol include those described in paragraphs [0179] to [0182] of JP-A 2008-122932. The acetylene alcohol is preferably added to the resist composition of the present invention in an amount of 0 to 5 parts by weight per 100 parts by weight of the base polymer. The acetylene alcohol may be used singly or in combination of two or more kinds thereof.

The resist composition of the present invention may be prepared by sufficiently mixing the components to form a solution, adjusting the solution so as to meet a predetermined range of sensitivity and film thickness, and filtering the solution. The filtering step is important for reducing the number of defects in a resist pattern after development. The membrane for filtration or filter preferably has a pore size of up to 1 μm, more preferably up to 10 nm, and even more preferably up to 5 nm. As the filter pore size is smaller, the number of defects in a small size pattern is reduced. Examples of the materials of the membrane include tetrafluoroethylene, polyethylene, polypropylene, nylon, polyurethane, polycarbonate, polyimide, polyamide-imide, and polysulfone. Membranes of tetrafluoroethylene, polyethylene, and polypropylene which have been surface-modified so as to increase an adsorption ability are also useful. Unlike the membranes of nylon, polyurethane, polycarbonate, and polyimide having an ability to adsorb gel and metal ions due to their polarity, membranes of tetrafluoroethylene, polyethylene, and polypropylene which are non-polar do not have the gel/metal ion adsorption ability in themselves, but can be endowed with the adsorption ability by surface modification with a functional group having polarity. In particular, filters obtained by surface modification of membranes of polyethylene and polypropylene, in which pores of a smaller size can be formed, are effective for removing not only submicron particles, but also polar particles and metal ions. A laminate of membranes of different materials or a laminate of membranes having different pore sizes may also be used.

A membrane having an ion exchange ability are also useful. For example, an ion-exchange membrane capable of adsorbing cations acts to adsorb metal ions to thereby reduce metal impurities.

In the practice of filtration, a plurality of filters may be connected. The type and pore size of membranes in the plurality of filters may be the same or different. The filter may be disposed in a conduit between vessels. Alternatively, the filter may be disposed in a conduit between inlet and outlet ports of a single vessel so that the solution is filtered while it is circulated. The filters may be connected through serial or parallel pipes.

### Pattern Forming Process

The resist composition of the present invention is used in the fabrication of various integrated circuits by a well-known lithography technique. Examples of the pattern forming process include a process comprising the steps of: applying the resist composition onto a substrate to form a resist film thereon, exposing the resist film to high-energy radiation, and developing the exposed resist film in a developer.

The resist composition of the present invention is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, CrN, MoSi₂, SiO₂, a MoSi₂ multilayer film, Ta, TaN, TaCN, Ru, Nb, Mo. Mn, Co, Ni, or an alloy thereof) by a suitable coating technique such as spin coating, roll coating, flow coating, dipping, spraying, or doctor coating so that the coating may have a thickness of 0.01 to 2 μm. The coating is prebaked on a hotplate preferably at a temperature of 60 to 150° C. for 10 seconds to 30 minutes, and more preferably at 80 to 120° C. for 30 seconds to 20 minutes to form a resist film.

The resist film is then exposed to high-energy radiation such as LW, deep-LW, EB, EUV having a wavelength of 3 to 15 nm, X-rays, soft X-rays, excimer laser, γ-rays, or synchrotron radiation. When UV, deep-UV, EUV, X-rays, soft X-rays, excimer laser, γ-rays, or synchrotron radiation is used as the high-energy radiation, the resist film is exposed thereto directly or through a mask having a desired pattern preferably at a dose of about 1 to 200 mJ/cm², and more preferably about 10 to 100 mJ/cm². When EB is used as the high-energy radiation, the resist film is exposed thereto directly or through a mask having a desired pattern preferably at a dose of about 0.1 to 300 pC/cm², and more preferably about 0.5 to 200 pC/cm². It is appreciated that the resist composition of the present invention is suitable for micropatterning using high-energy radiation such as KrF excimer laser, ArF excimer laser, EB, EUV, X-rays, soft X-rays, 7-rays, or synchrotron radiation, especially for micropatterning using EB or EUV.

After the exposure, the resist film may be baked (PEB) on a hotplate or in an oven preferably at 30 to 150° C. for 10 seconds to 30 minutes, and more preferably at 50 to 120° C. for 30 seconds to 20 minutes.

After the exposure or PEB, the resist film is developed in a developer in the form of an alkaline aqueous solution for 3 seconds to 3 minutes, preferably 5 seconds to 2 minutes by conventional techniques such as dip, puddle, and spray techniques to form a desired pattern. A preferred developer is a 0.1 to 10 wt %, preferably 2 to 5 wt % aqueous solution of tetramethylammonium hydroxide (TMIAH), tetraethylammonium hydroxide (TEAH), tetrapropylammonium hydroxide (TPAH), or tetrabutylammoniu hydroxide (TBAH). In the case of a positive resist composition, the resist film in the exposed region is dissolved in the developer whereas the resist film in the unexposed region is not dissolved. In this way, the desired positive pattern is formed on the substrate. In the case of a negative resist composition, inversely the resist film in the exposed region is insolubilized in the developer whereas the resist film in the unexposed region is dissolved.

A negative pattern can be obtained from the positive resist composition comprising a base polymer containing an acid labile group by effecting organic solvent development. Examples of the developer used herein include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. The organic solvent may be used singly or as a mixture of two or more kinds thereof.

At the end of development, the resist film is rinsed. The rinsing liquid is preferably a solvent which is miscible with the developer and does not dissolve the resist film. Examples of preferred solvents include alcohols having 3 to 10 carbon atoms, ether compounds having 8 to 12 carbon atoms, alkanes, alkenes, and alkynes each having 6 to 12 carbon atoms, and aromatic solvents.

Examples of the alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Examples of the alkanes having 6 to 12 carbon atoms include hexane, heptane, octane, nonane, decane, undecane, dodecane, methylcyclopentane, dimethylcyclopentane, cyclohexane, methylcyclohexane, dinethylcyclohexane, cycloheptane, cyclooctane, and cyclononane. Examples of the alkenes having 6 to 12 carbon atoms include hexene, heptene, octene, cyclohexene, niethylcyclohexene, dimethylcyclohexene, cycloheptene, and cyclooctene. Examples of the alkynes having 6 to 12 carbon atoms include hexyne, heptyne, and octyne.

Examples of the aromatic solvents include toluene, xylene, ethylbenzene, isopropylbenzene, tert-butylbenzene, and mesitylene.

Rinsing is effective for reducing the resist pattern collapse and defect fomiation. However, rinsing is not essential. If rinsing is omitted, the amount of solvent used may be reduced.

A hole or trench pattern after development may be shrunk by the thermal flow, RELACS®, or DSA process. A hole pattern is shrunk by applying a shrink agent thereto, and baking the resist composition such that the shrink agent may undergo crosslinking at the resist film surface due to diffusion of the acid catalyst from the resist film during baking, and the shrink agent may attach to the sidewall of the hole pattern. The baking temperature is preferably 70 to 180° C., more preferably 80 to 170° C., and the baking time is preferably 10 to 300 seconds to remove the excess shrink agent and slhink the hole pattern.

### EXAMPLES

Hereinafter, the present invention is specifically described with reference to Synthesis Examples, Examples, and Comparative Examples, but the present invention is not limited to the following Examples.

Monomers PM-1 to PM-23, cPM-1 to cPM-3, AM-1 to AM-4, and FM-1 used in the synthesis of base polymers are shown below. Monomers PM-1 to PM-23 were synthesized by ion exchange between an ammonium salt of a fluorinated sulfonic acid that provides the anion shown below and sulfonium chloride that provides the cation shown below. The Mw of a polymer is determined by GPC versus polystyrene standards using a THF solvent.

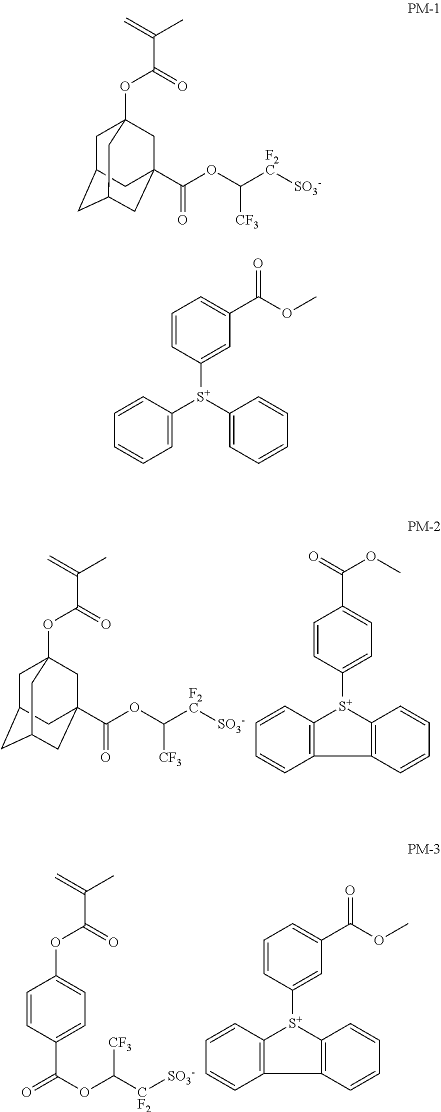

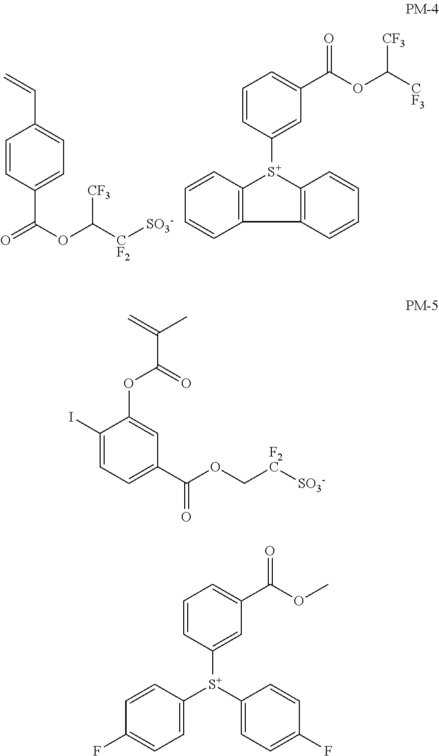

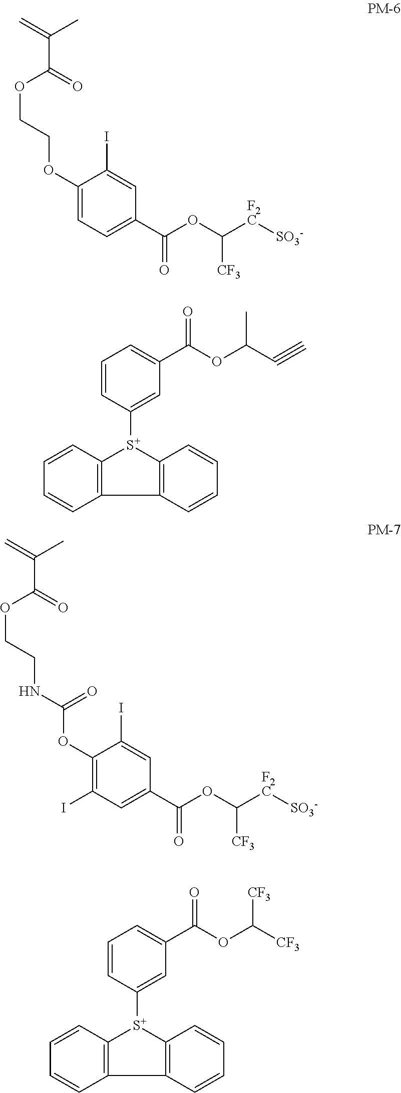

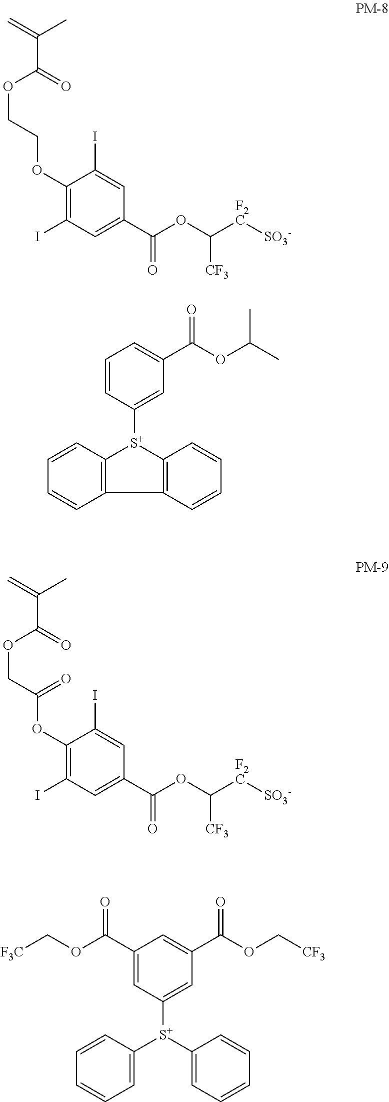

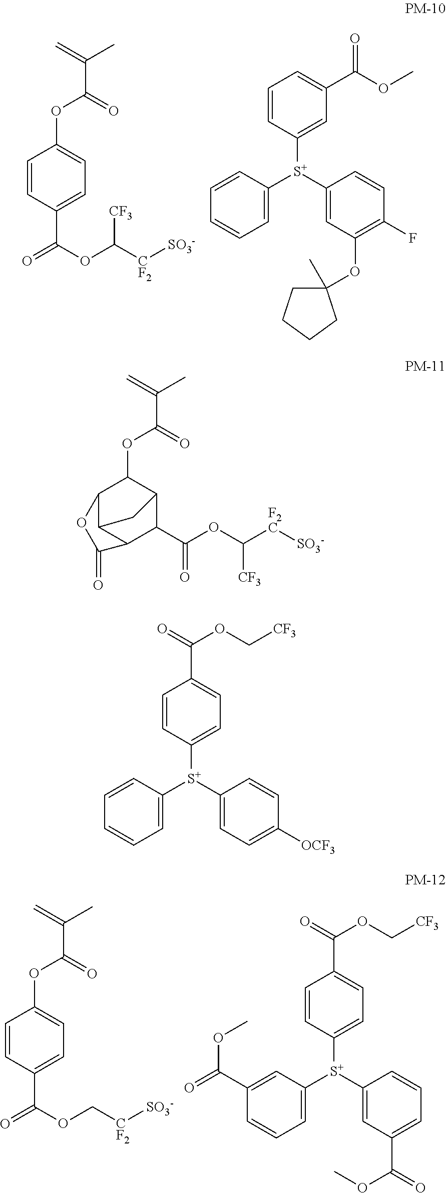

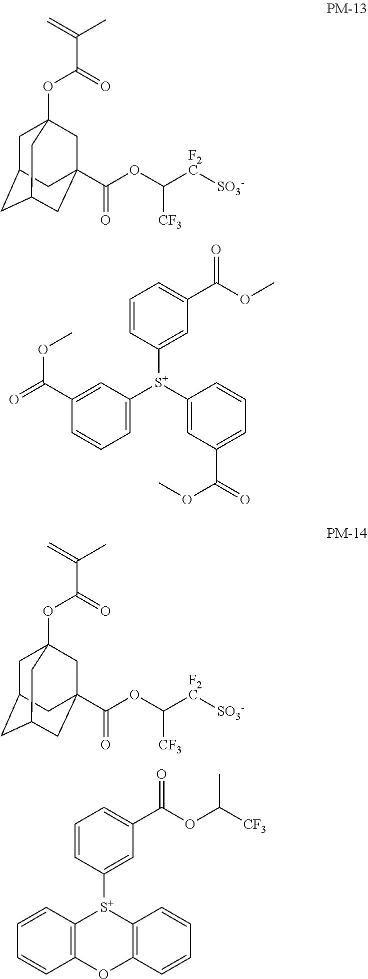

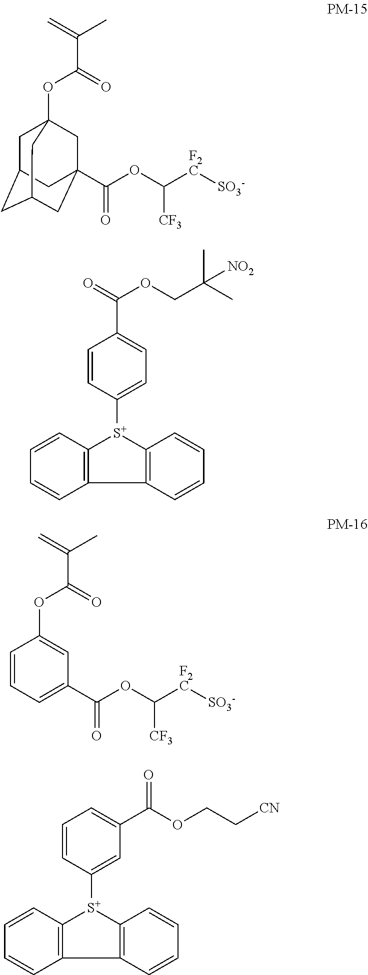

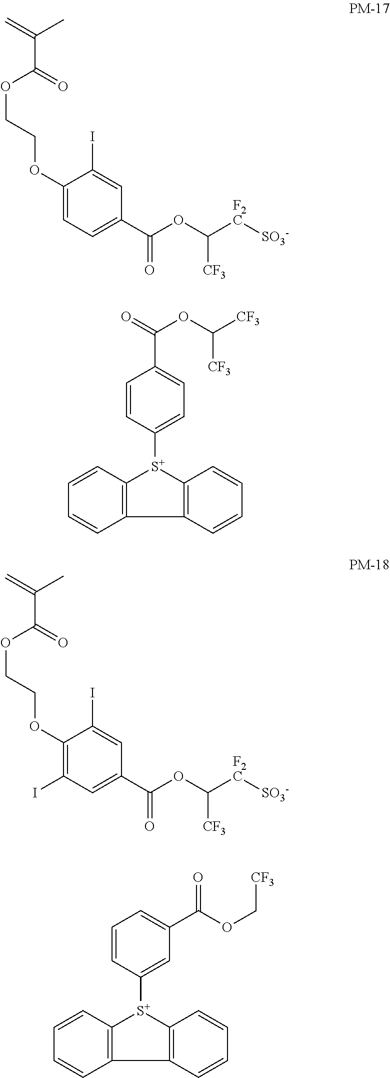

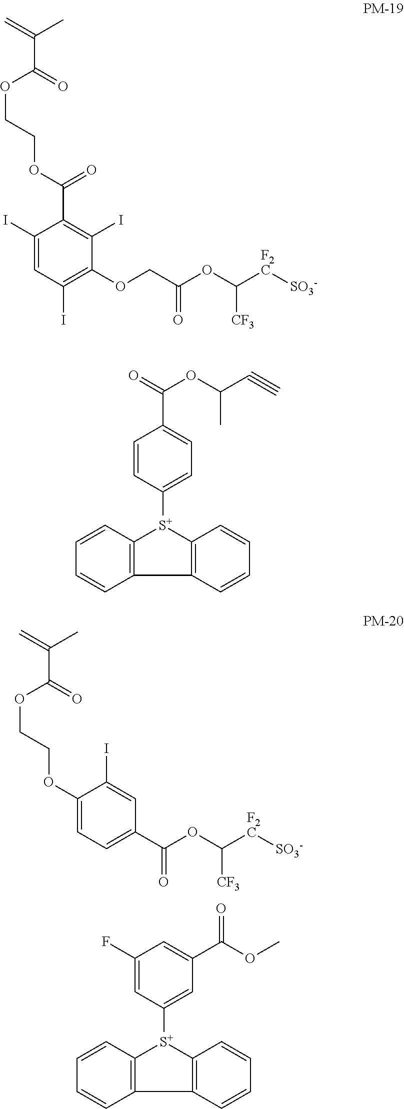

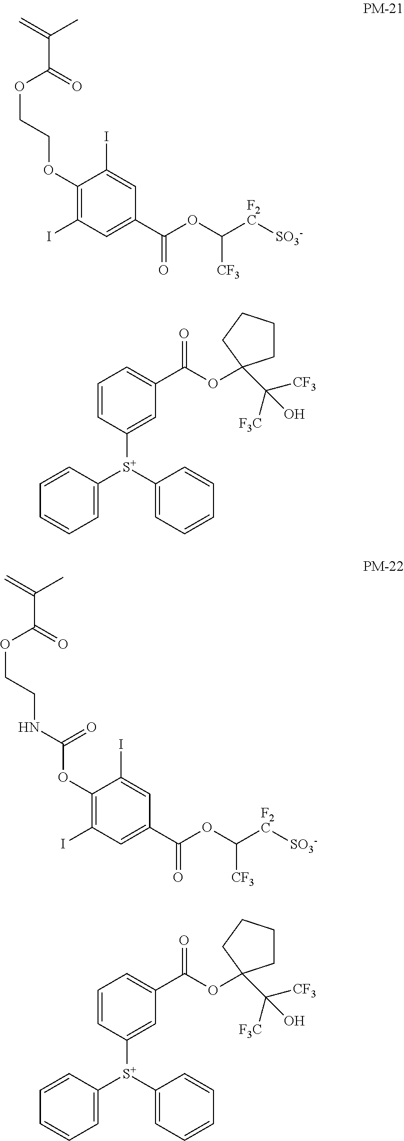

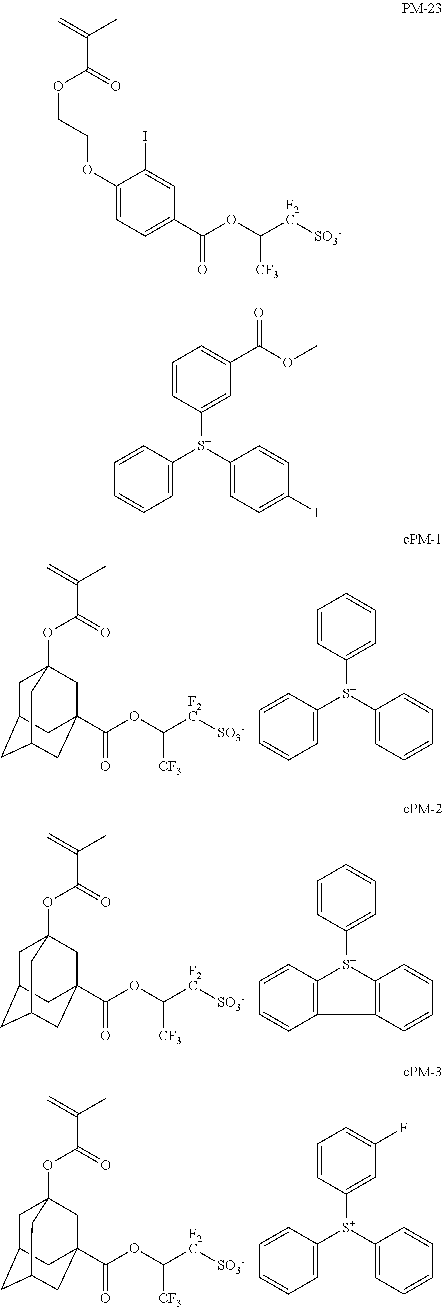

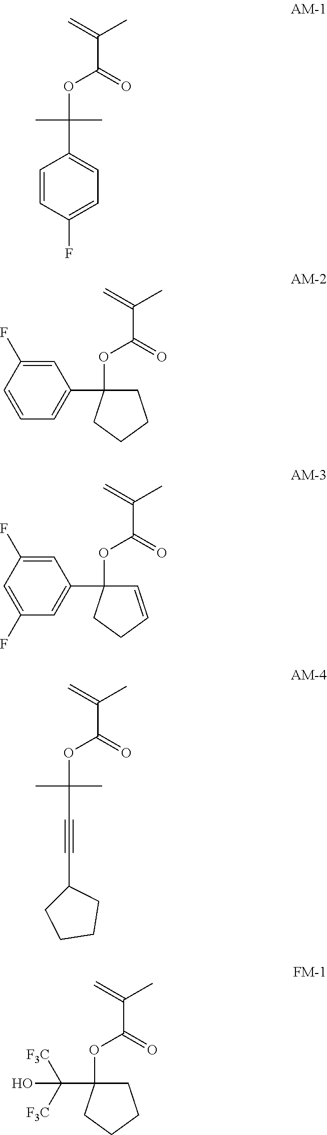

### Synthesis Example 1 Synthesis of Polymer P-1

A 2-L flask was charged with 8.4 g of 1-methyl-1-cyclopentyl methacrylate, 4.8 g of 4-hydroxystyrene, 8.0 g of PM-1, and 40 g of a THF solvent. The reactor was cooled to −70° C. in a nitrogen atmosphere, after which vacuum pumping and nitrogen blowing were repeated three times. The reactor was warmed up to room temperature, and 1.2 g of azobisisobutyronitrile (AIBN) as a polymerization initiator was added. The reactor was heated to 60° C. and the reaction was run for 15 hours. The reaction solution was poured into 1 L of isopropyl alcohol (IPA), and the precipitated white solid was collected by filtration. The resulting white solid was vacuum dried at 60° C., yielding Polymer P-1. Polymer P-1 was analyzed for composition by ¹³C-NMR and ¹H-NMR and for Mw and Mw/Mn by GPC.

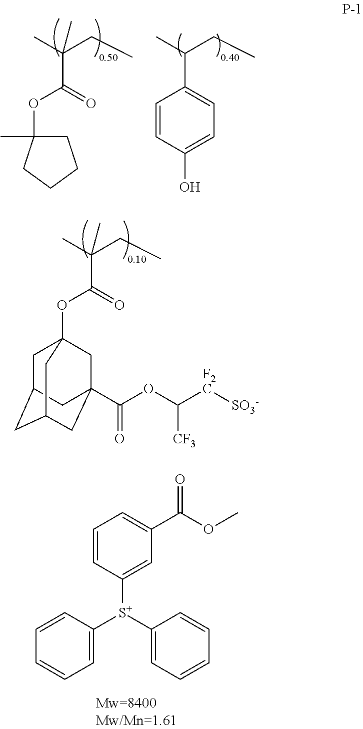

### Synthesis Example 2 Synthesis of Polymer P-2

A 2-L flask was charged with 8.0 g of AM-1, 4.8 g of 3-hydroxystyrene, 7.9 g of PM-2, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was un for 15 hours. The reaction solution was poured into 1 L of IPA, and the precipitated white solid was collected by filtration. The resulting white solid was vacuum dried at 60° C., yielding Polymer P-2. Polymer P-2 was analyzed for composition by ¹³C-NMR and ¹H-NMR and for Mw and Mw/Mn by GPC.

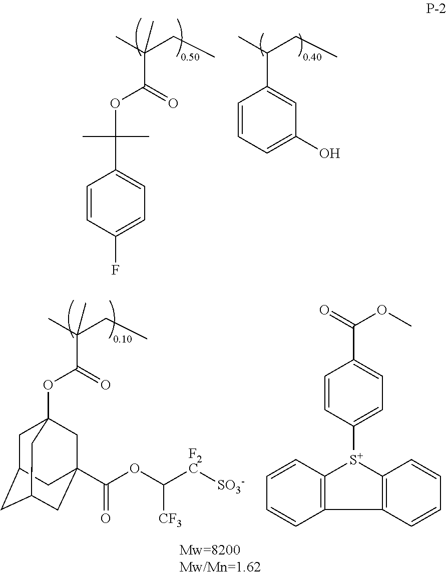

### Synthesis Example 3 Synthesis of Polymer P-3

A 2-L flask was charged with 11.1 g of AM-1, 4.8 g of 3-hydroxystyrene, 7.5 g of PM-3, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-3. Polymer P-3 was analyzed for composition by ¹³C-NMR and ¹H-NMR and for Mw and Mw/Mn by GPC.

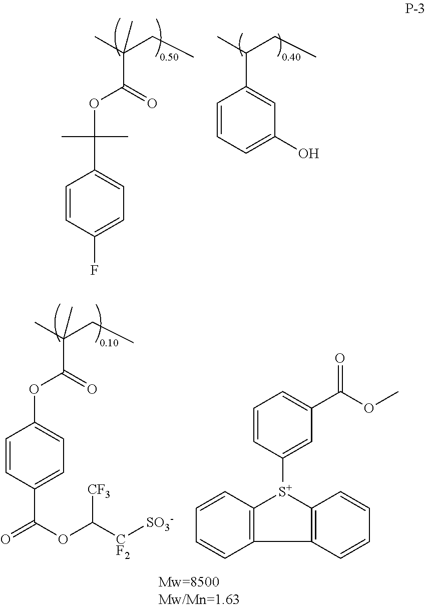

### Synthesis Example 4 Synthesis of Polymer P-4

A 2-L flask was charged with 8.7 g of AM-2, 4.0 g of AM-4, 4.8 g of 3-hydroxystyrene, 8.1 g of PM-4, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P4. Polymer P4 was analyzed for composition by ¹³C-NMR and ¹H-NMR and for Mw and Mw/Mn by GPC.

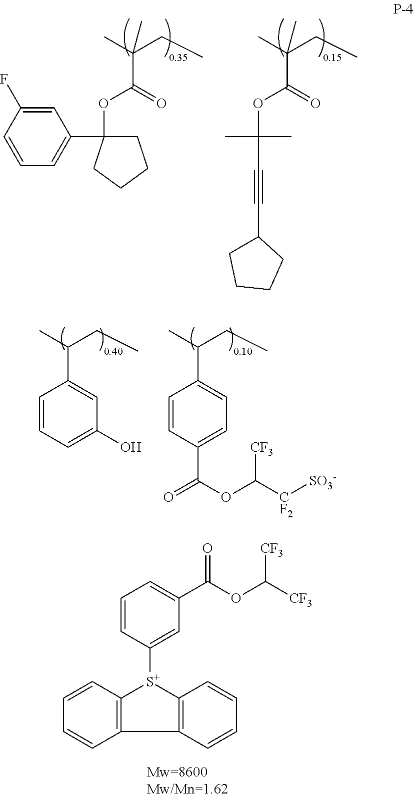

### Synthesis Example 5 Synthesis of Polymer P-5

A 2-L flask was charged with 12.7 g of AM-3, 5.2 g of 3-hydroxystyrene, 8.3 g of PM-5, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-5. Polymer P-5 was analyzed for composition by ¹³C-NMR and ¹H-NMR and for Mw and Mw/Mn by GPC.

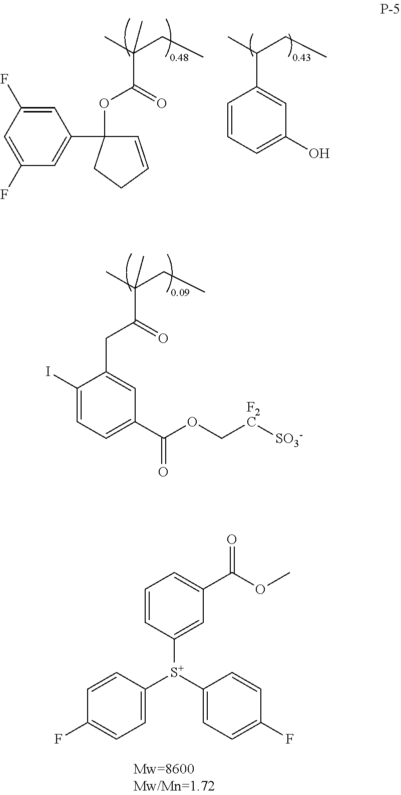

### Synthesis Example 6 Synthesis of Polymer P-6

A 2-L flask was charged with 11.1 g of AM-1, 4.8 g of 3-hydroxystyrene, 9.4 g of PM-6, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-6. Polymer P-6 was analyzed for composition by ¹³C-NMR and ¹H-NMR and for Mw and Mw/Mn by GPC.

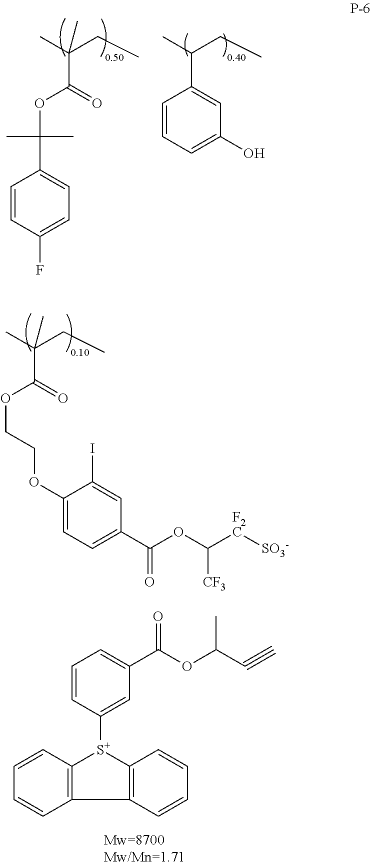

### Synthesis Example 7 Synthesis of Polymer P-7

A 2-L flask was charged with 11.1 g of AM-1, 3.4 g of 3-hydroxystyrene, 3.2 g of the monomer FM-1, 14.5 g of PM-7, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-7. Polymer P-7 was analyzed for composition by ¹³C-NMR and ¹H-NMR and for Mw and Mw/Mn by GPC.

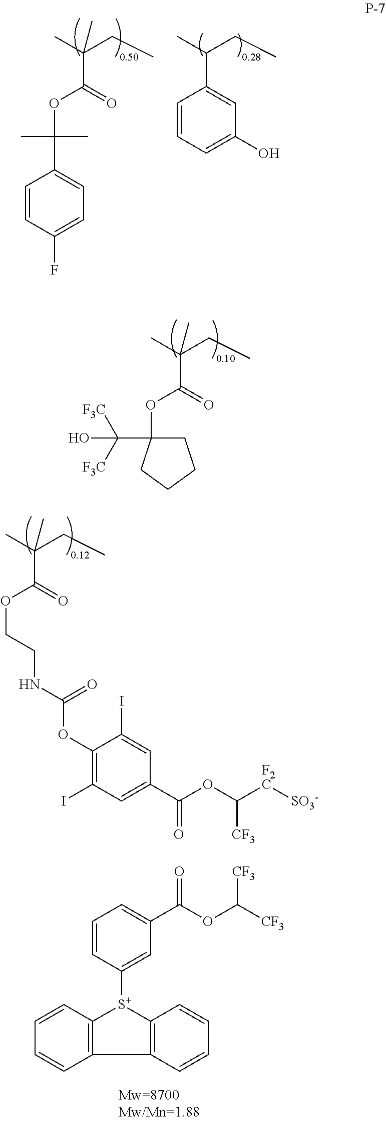

### Synthesis Example 8 Synthesis of Polymer P-8

A 2-L flask was charged with 11.1 g of AM-1, 4.8 g of 3-hydroxystyrene, 10.6 g of PM-8, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-8. Polymer P-8 was analyzed for composition by ¹³C-NMR and ¹H-NMR and for Mw and Mw/Mn by GPC.

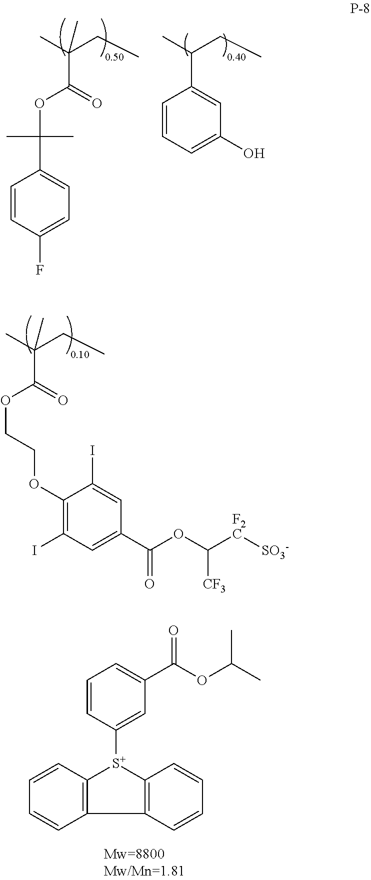

### Synthesis Example 9 Synthesis of Polymer P-9

A 2-L flask was charged with 11.1 g of AM-1, 4.8 g of 3-hydroxystyrene, 12.4 g of PM-9, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-9. Polymer P-9 was analyzed for composition by ¹³C-NMR and ¹H-NMR and for Mw and Mw/Mn by GPC.

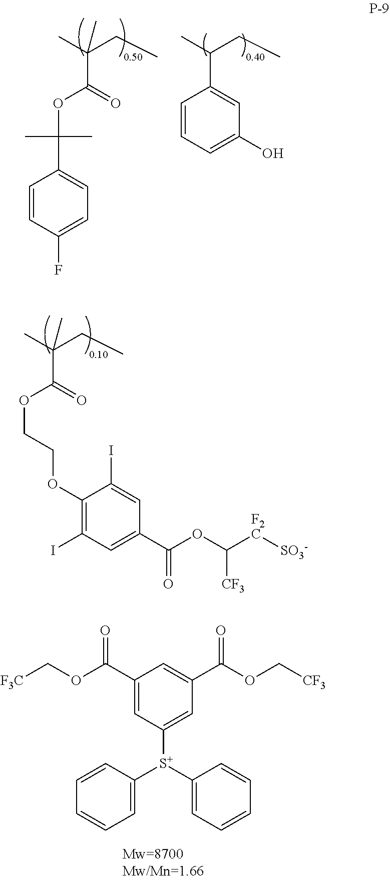

### Synthesis Example 10 Synthesis of Polymer P-10

A 2-L flask was charged with 11.1 g of AM-1, 4.8 g of 3-hydroxystyrene, 8.5 g of PM-10, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-10. Polymer P-10 was analyzed for composition by ¹³C-NMR and ¹H-NMR and for Mw and Mw/Mn by GPC.

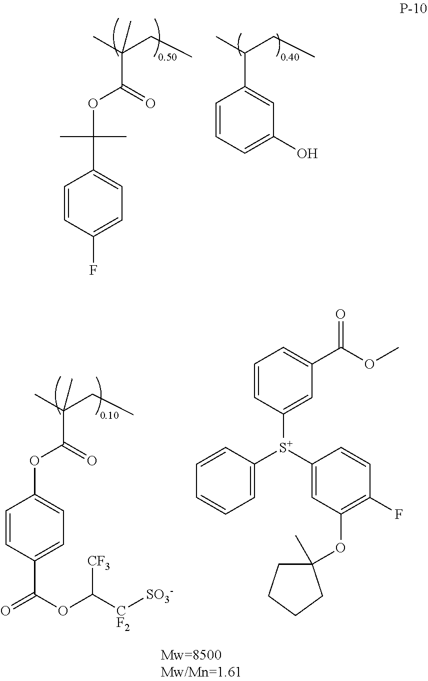

### Synthesis Example 11 Synthesis of Polymer P-11

A 2-L flask was charged with 11.1 g of AM-1, 4.8 g of 3-hydroxystyrene, 9.5 g of PM-11, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-11. Polymer P-11 was analyzed for composition by ¹³C-NMR and ¹H-NMR and for Mw and Mw/Mn by GPC.

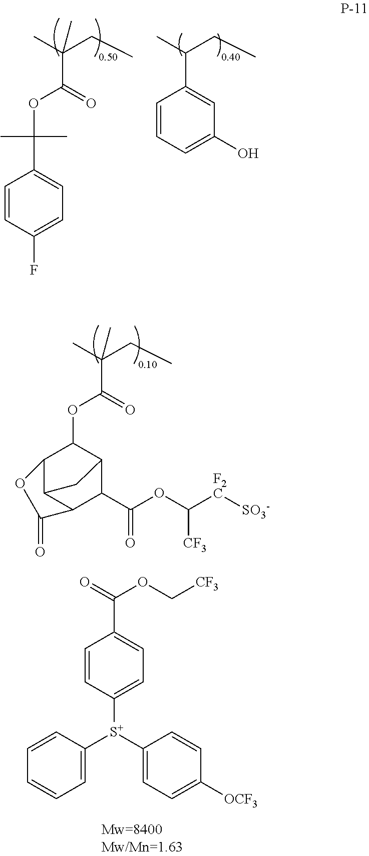

### Synthesis Example 12 Synthesis of Polymer P-12

A 2-L flask was charged with 11.1 g of AM-1, 4.8 g of 3-hydroxystyrene, 8.5 g of PM-12, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-12. Polymer P-12 was analyzed for composition by ¹³C-NMR and ¹H-NMR and for Mw and Mw/Mn by GPC.

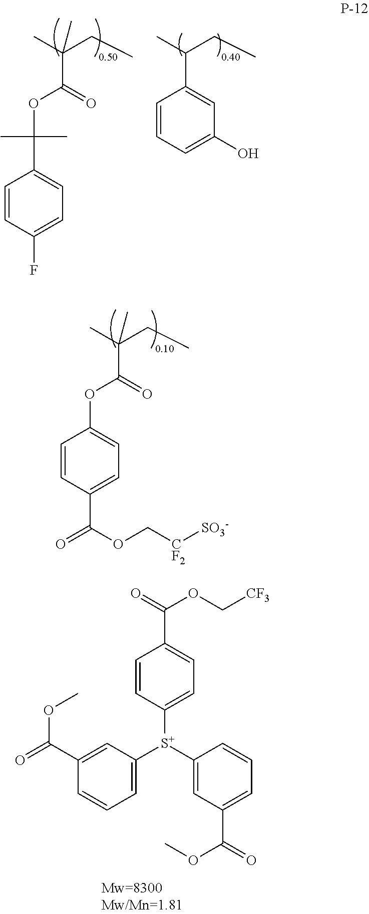

### Synthesis Example 13 Synthesis of Polymer P-13

A 2-L flask was charged with 11.1 g of AM-1, 4.8 g of 3-hydroxystyrene, 9.1 g of PM-13, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-13. Polymer P-13 was analyzed for composition by ¹³C-NMR and ¹H-NMR and for Mw and Mw/Mn by GPC.

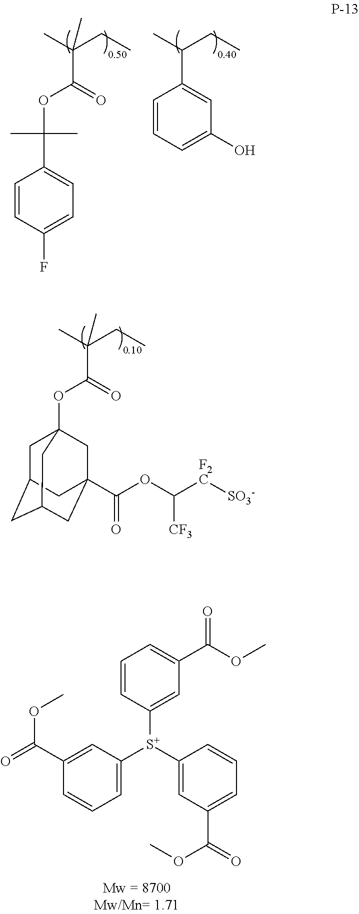

### Synthesis Example 14 Synthesis of Polymer P-14

A 2-L flask was charged with 11.1 g of AM-1, 4.8 g of 3-hydroxystyrene, 8.9 g of PM-14, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-14. Polymer P-14 was analyzed for composition by ¹³C-NMVR and ¹H-NMR and for Mw and Mw/Mn by GPC.

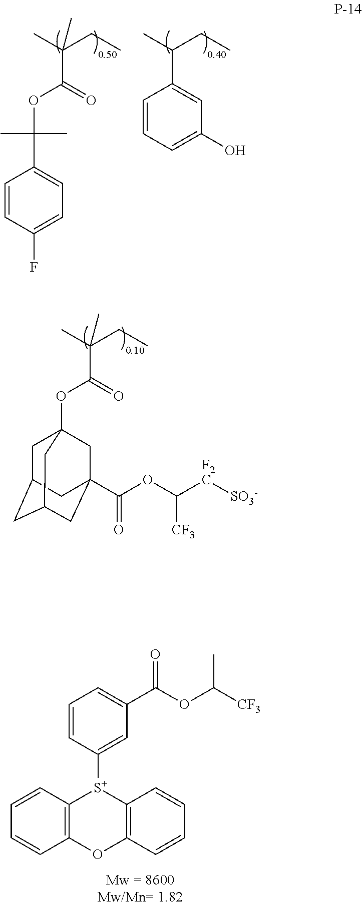

### Synthesis Example 15 Synthesis of Polymer P-15

A 2-L flask was charged with 11.1 g of AM-1, 4.8 g of 3-hydroxystyrene, 7.8 g of PM-15, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-15. Polymer P-15 was analyzed for composition by ¹³C-NMR and ¹H-NMR and for Mw and Mw/Mn by GPC.

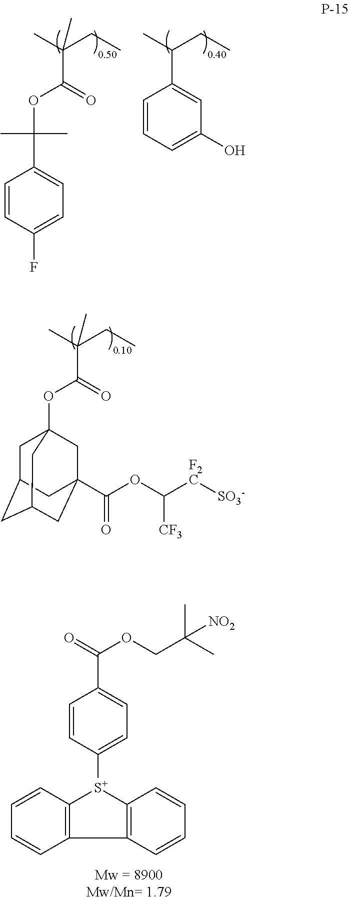

### Synthesis Example 16 Synthesis of Polymer P-16

A 2-L flask was charged with 11.1 g of AM-1, 4.8 g of 3-hydroxystyrene, 7.8 g of PM-16, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-16. Polymer P-16 was analyzed for composition by ¹³C-NMR and ¹H-NMR and for Mw and Mw/Mn by GPC.

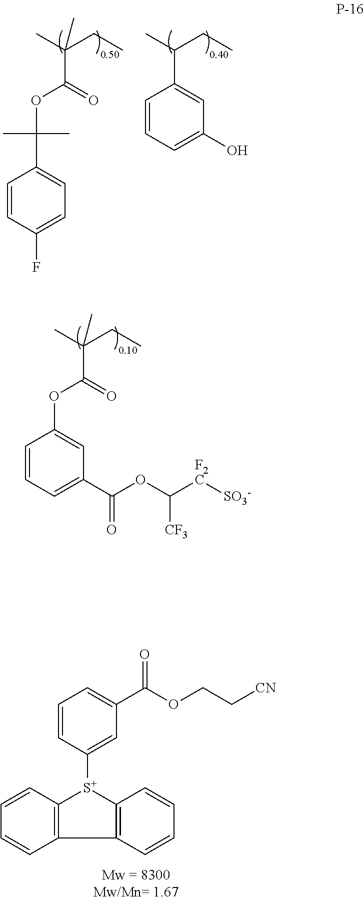

### Synthesis Example 17 Synthesis of Polymer P-17

A 2-L flask was charged with 11.1 g of AM-1, 4.8 g of 4-hydroxystyrene, 10.4 g of PM-17, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-17. Polymer P-17 was analyzed for composition by ¹³C-NMR and ¹H-NMR and for Mw and Mw/Mn by GPC.

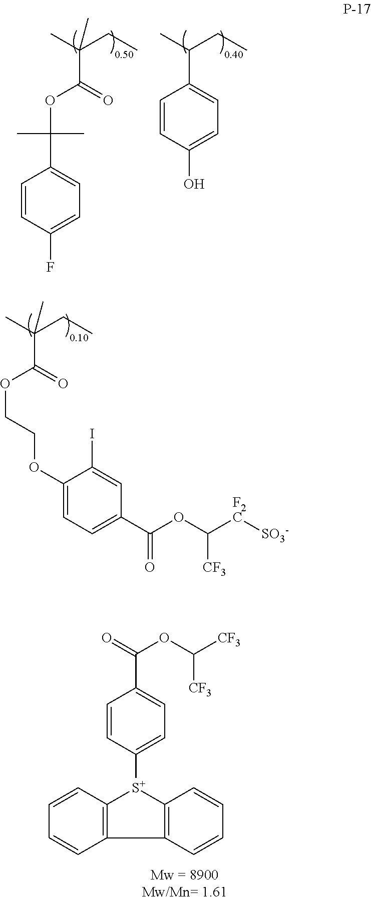

### Synthesis Example 18 Synthesis of Polymer P-18

A 2-L flask was charged with 11.1 g of AM-1, 4.8 g of 4-hydroxystyrene, 11.0 g of PM-18, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-18. Polymer P-18 was analyzed for composition by ¹³C-NMR and ¹H-NMR and for Mw and Mw/Mn by GPC.

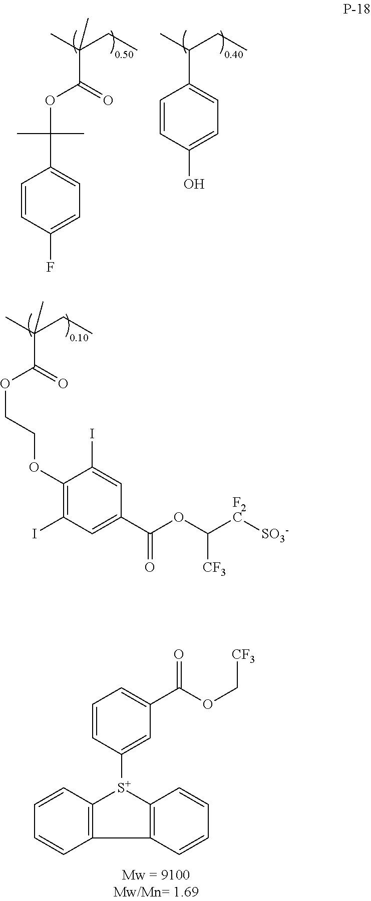

### Synthesis Example 19 Synthesis of Polymer P-19

A 2-L flask was charged with 11.1 g of AM-1, 4.8 g of 4-hydroxystyrene, 12.5 g of PM-19, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-19. Polymer P-19 was analyzed for composition by ¹³C-NMR and ¹H-NMR and for Mw and Mw/Mn by GPC.

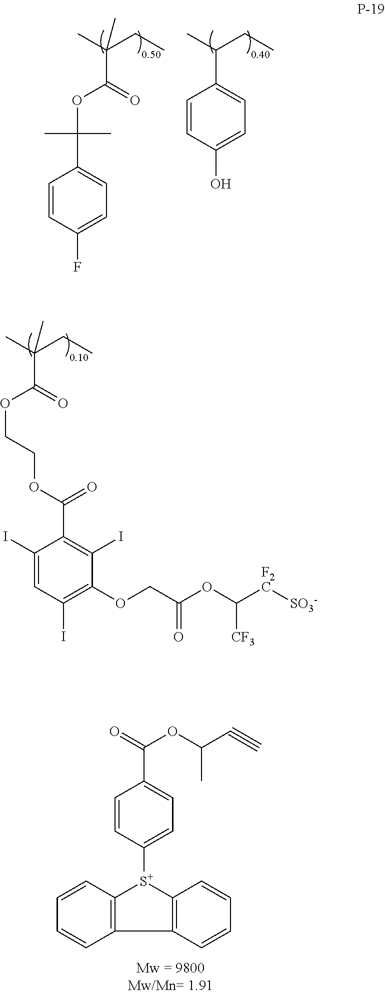

### Synthesis Example 20 Synthesis of Polymer P-20

A 2-L flask was charged with 11.1 g of AM-1, 4.8 g of 4-hydroxystyrene, 9.2 g of PM-20, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-20. Polymer P-20 was analyzed for composition by ¹³C-NMR and ¹H-NMR and for Mw and Mw/Mn by GPC.

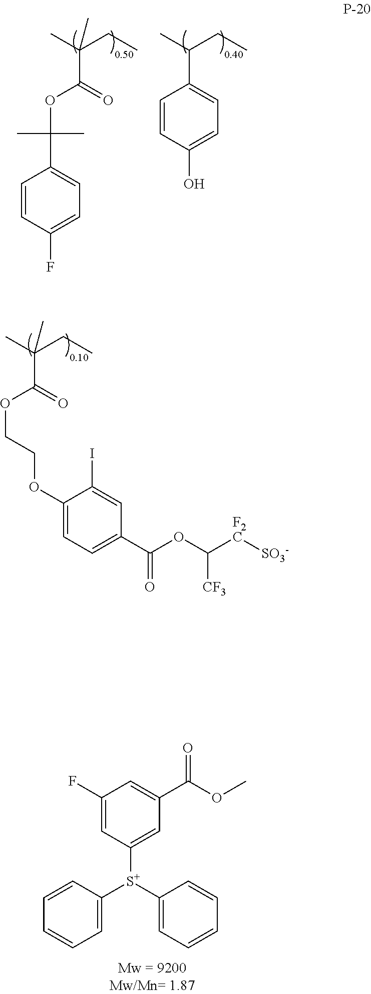

### Synthesis Example 21 Synthesis of Polymer P-21

A 2-L flask was charged with 11.1 g of AM-1, 4.8 g of 4-hydroxystyrene, 12.5 g of PM-21, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-21. Polymer P-21 was analyzed for composition by ¹³C-NMR and ¹H-NMR and for Mw and Mw/Mn by GPC.

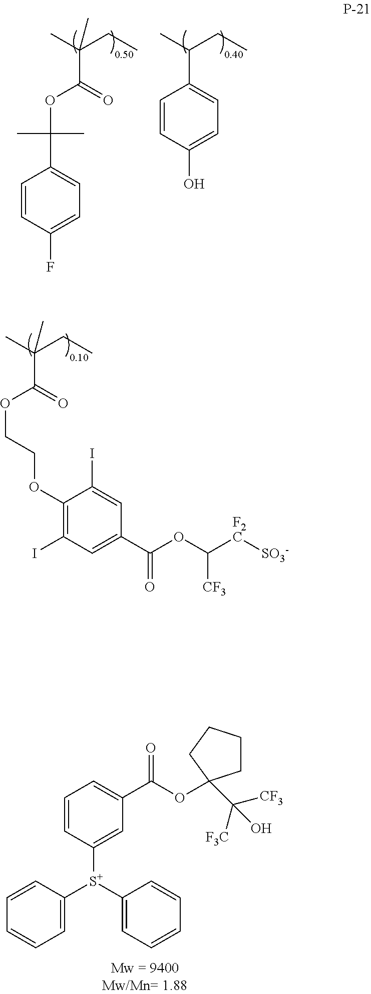

### Synthesis Example 22 Synthesis of Polymer P-22

A 2-L flask was charged with 11.1 g of AM-1, 4.8 g of 4-hydroxystyrene, 13.0 g of PM-22, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-22. Polymer P-22 was analyzed for composition by ¹³C-NMR and ¹H-NMR and for Mw and Mw/Mn by GPC.

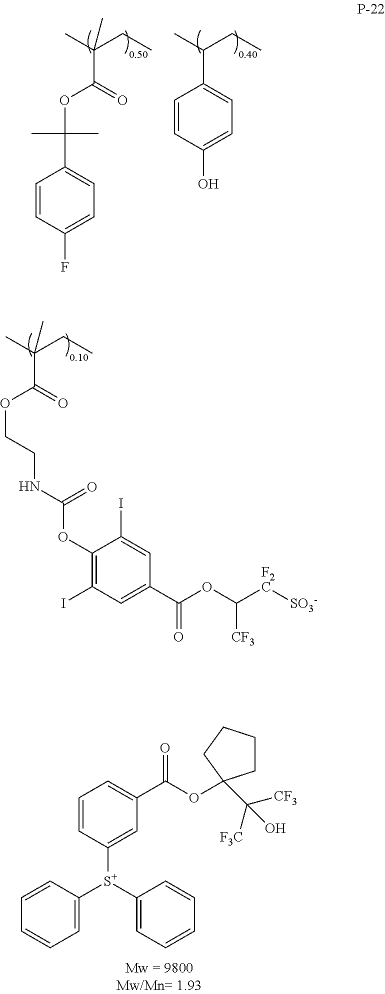

### Synthesis Example 23 Synthesis of Polymer P-23

A 2-L flask was charged with 11.1 g of AM-1, 4.8 g of 4-hydroxystyrene, 10.3 g of PM-23, and 40 g of a THF solvent. The reactor was cooled to −70° C. in a nitrogen atmosphere, after which vacuum pumping and nitrogen blowing were repeated three times. The reactor was warmed up to room temperature, and 1.2 g of AIBN as a polymerization initiator was added. The reactor was heated to 60° C. and the reaction was run for 15 hours. The reaction solution was poured into 1 L of IPA, and the precipitated white solid was collected by filtration. The resulting white solid was vacuum dried at 60° C., yielding Polymer P-23. Polymer P-23 was analyzed for composition by ¹³C-NMR and ¹H-NMR and for Mw and Mw/Mn by GPC.

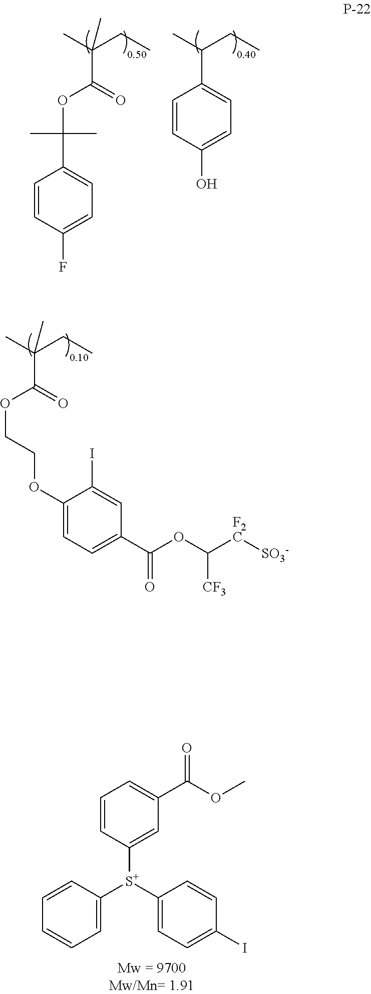

### Comparative Synthesis Example 1 Synthesis of Comparative Polymer cP-1

Comparative Polymer cP-1 was synthesized in the same manner as in Synthesis Example 1 except that PM-1 was changed to cPM-1.

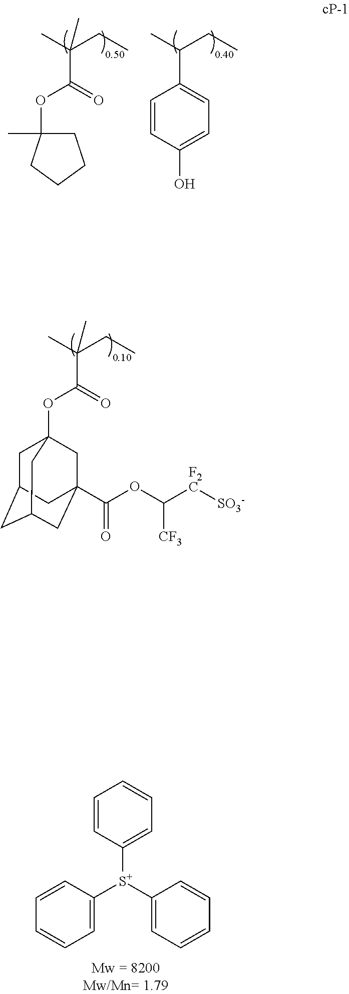

### Comparative Synthesis Example 2 Synthesis of Comparative Polymer cP-2

Comparative Polymer cP-2 was synthesized in the same manner as in Synthesis Example 1 except that PMI-1 was changed to cPM-2.

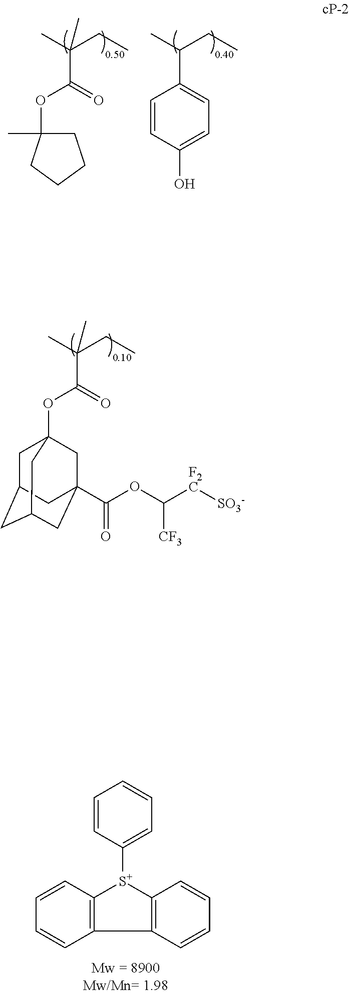

### Comparative Synthesis Example 3 Synthesis of Comparative Polymer cP-3

Comparative Polymer cP-3 was synthesized in the same manner as in Synthesis Example 1 except that PM-1 was changed to cPM-3.

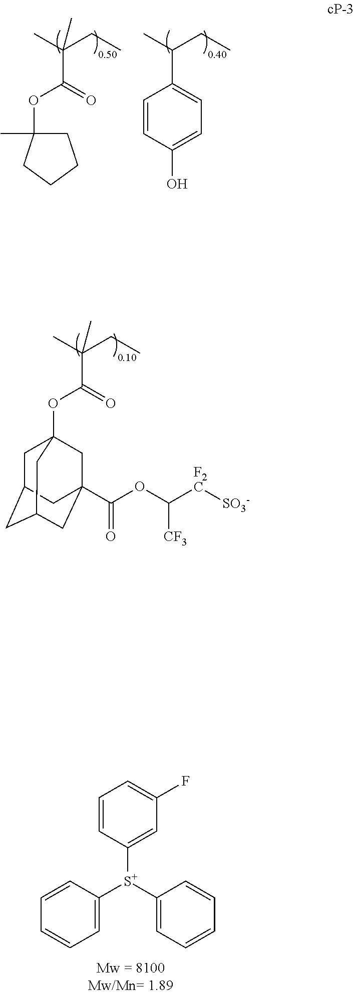

### Examples 1 to 25 and Comparative Examples 1 to 3 Preparation and Evaluation of Resist Compositions

### (1) Preparation of Resist Compositions

In a solvent in which 100 ppm of Polyfox PF-636 manufactured by Onmova Solutions, Inc. was dissolved as a surfactant, the components having the composition shown in Table 1 were dissolved. The resulting solution was filtered through a filter having a pore size of 0.2 μm to prepare a resist composition.

The components in Table 1 are as follows.

### Organic Solvents:

PGMEA (propylene glycol monomethyl ether acetate)
EL (ethyl lactate)
DAA (diacetone alcohol)
   Acid generator: PAG-1

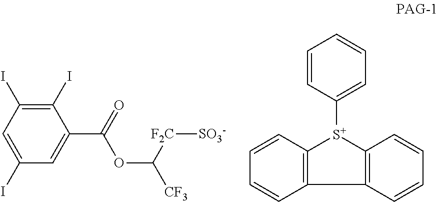

### Quenchers: Q-1 to Q-5

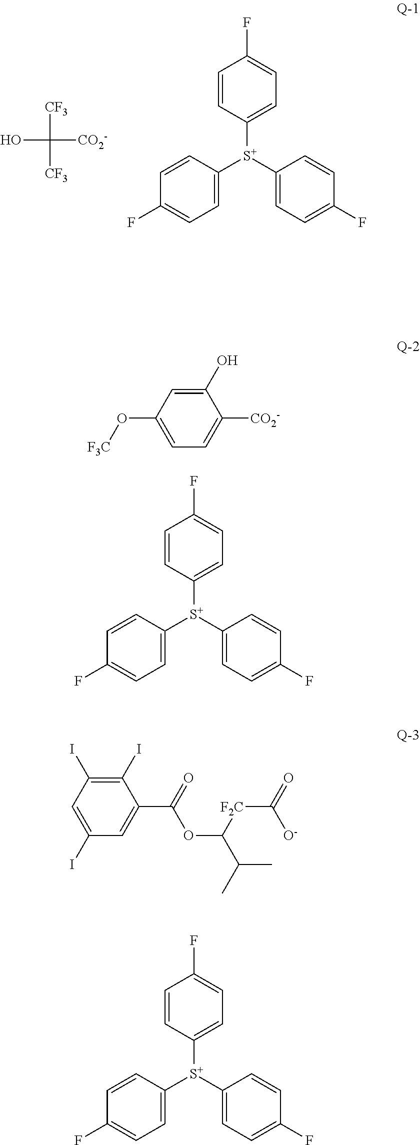

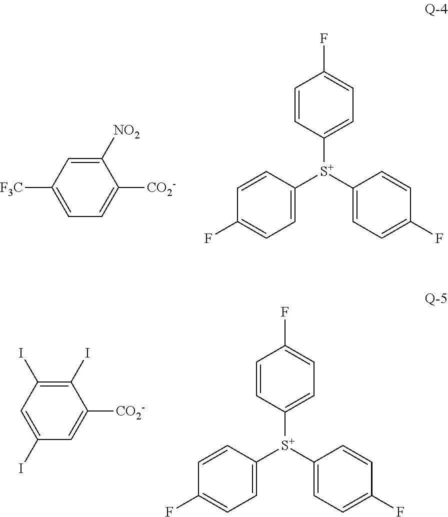

### (2) EUV Lithography Evaluation

Each of the resist compositions shown in Table 1 was applied by spin coating to a silicon substrate having a 20-nm coating of silicon-containing spin-on hard mask SHB-A940 (Shin-Etsu Chemical Co., Ltd., Si content 43 wt %) and prebaked on a hotplate at 105° C. for 60 seconds to form a 60 nm-thick resist film. Using an EUV scanner NXE3400 (ASML, NA 0.33, a 0.9/0.6, quadrupole illumination), the resist film was exposed to EUV through a mask bearing a hole pattern at a pitch of 40 nm (on-wafer size) and +20% bias. The resist film was baked (PEB) on a hotplate at the temperature shown in Table 1 for 60 seconds and developed in a 2.38 wt % TMAH aqueous solution for 30 seconds to form a hole pattern having a size of 20 nm.

The resist pattern was observed under CD-SEM (CG6300, Hitachi High-Technologies Corp.). The exposure dose that provides a hole pattern having a size of 20 nm was reported as sensitivity. The size of 50 holes printed at that dose was measured, from which a 3-fold value (3a) of the standard deviation (a) was computed and reported as CDU. The results are shown in Table 1.

TABLE 1

| | | | Acid | | Organic | | | |
|---|---|---|---|---|---|---|---|---|
| | | Polymer | generator | Quencher | solvent | PEB | Sensitivity | CDU |
| | | (pbw) | (pbw) | (pbw) | (pbw) | (° C.) | (mJ/cm²) | (nm) |
| Example | 1 | P-1 | — | Q-1 | PGMEA (500) | 90 | 28 | 2.8 |
| | | (100) | | (5.28) | EL (2000) | | | |
| | 2 | P-2 | — | Q-1 | PGMEA (500) | 90 | 28 | 2.7 |
| | | (100) | | (5.28) | EL (2000) | | | |
| | 3 | P-3 | — | Q-1 | PGMEA (500) | 90 | 27 | 2.6 |
| | | (100) | | (5.28) | EL (2000) | | | |
| | 4 | P-4 | — | Q-1 | PGMEA (2000) | 90 | 26 | 2.6 |
| | | (100) | | (5.28) | DAA (500) | | | |
| | 5 | P-5 | — | Q-1 | PGMEA (2000) | 80 | 27 | 2.5 |
| | | (100) | | (5.28) | DAA (500) | | | |
| | 6 | P-6 | — | Q-1 | PGMEA (2000) | 90 | 28 | 2.6 |
| | | (100) | | (5.28) | DAA (500) | | | |
| | 7 | P-7 | — | Q-1 | PGMEA (2000) | 90 | 26 | 2.6 |
| | | (100) | | (5.28) | DAA (500) | | | |
| | 8 | P-8 | — | Q-2 | PGMEA (2000) | 90 | 25 | 2.6 |
| | | (100) | | (5.38) | DAA (500) | | | |
| | 9 | P-9 | — | Q-2 | PGMEA (2000) | 90 | 24 | 2.8 |
| | | (100) | | (5.38) | DAA (500) | | | |
| | 10 | P-10 | — | Q-3 | PGMEA (2000) | 90 | 28 | 2.6 |
| | | (100) | | (9.66) | DAA (500) | | | |
| | 11 | P-11 | — | Q-3 | PGMEA (2000) | 90 | 25 | 2.8 |
| | | (100) | | (9.66) | DAA (500) | | | |
| | 12 | P-12 | — | Q-4 | PGMEA (2000) | 85 | 25 | 2.7 |
| | | (100) | | (5.51) | DAA (500) | | | |
| | 13 | P-13 | — | Q-5 | PGMEA (2000) | 90 | 26 | 2.7 |
| | | (100) | | (8.16) | DAA (500) | | | |
| | 14 | P-1 | PAG-1 | Q-1 | PGMEA (2000) | 85 | 25 | 2.8 |
| | | (100) | (5.0) | (5.28) | DAA (500) | | | |
| | 15 | P-14 | — | Q-3 | PGMEA (2000) | 90 | 26 | 2.5 |
| | | (100) | | (9.66) | DAA (500) | | | |
| | 16 | P-15 | — | Q-3 | PGMEA (2000) | 90 | 28 | 2.6 |
| | | (100) | | (9.66) | DAA (500) | | | |
| | 17 | P-16 | — | Q-3 | PGMEA (2000) | 90 | 27 | 2.5 |
| | | (100) | | (9.66) | DAA (500) | | | |
| | 18 | P-17 | — | Q-3 | PGMEA (2000) | 90 | 28 | 2.7 |
| | | (100) | | (9.66) | DAA (500) | | | |
| | 19 | P-18 | — | Q-3 | PGMEA (2000) | 90 | 27 | 2.8 |
| | | (100) | | (9.66) | DAA (500) | | | |
| | 20 | P-19 | — | Q-3 | PGMEA (2000) | 90 | 26 | 2.7 |
| | | (100) | | (9.66) | DAA (500) | | | |
| | 21 | P-20 | — | Q-3 | PGMEA (2000) | 90 | 27 | 2.7 |
| | | (100) | | (9.66) | DAA (500) | | | |
| | 22 | P-21 | — | Q-3 | PGMEA (2000) | 90 | 26 | 2.7 |
| | | (100) | | (9.66) | DAA (500) | | | |
| | 23 | P-22 | — | Q-3 | PGMEA (2000) | 90 | 28 | 2.6 |
| | | (100) | | (9.66) | DAA (500) | | | |
| | 24 | P-23 | — | Q-3 | PGMEA (2000) | 90 | 29 | 2.7 |
| | | (100) | | (9.66) | DAA (500) | | | |
| | 25 | P-23 | PAG-1 | Q-3 | PGMEA (2000) | 90 | 23 | 2.7 |
| | | (100) | (9.7) | (9.66) | DAA (500) | | | |
| Comparative | 1 | cP-1 | — | Q-1 | PGMEA (2000) | 90 | 32 | 3.2 |
| Example | | (100) | | (5.28) | DAA (500) | | | |
| | 2 | cP-2 | — | Q-1 | PGMEA (2000) | 90 | 30 | 3.0 |
| | | (100) | | (5.28) | DAA (500) | | | |
| | | cP-3 | — | Q-1 | PGMEA (2000) | 90 | 30 | 3.1 |
| | | (100) | | (5.28) | DAA (500) | | | |

From the results shown in Table 1, it was found that the resist composition of the present invention, which comprises a base polymer containing, as an acid generator, repeat units having a salt structure containing a sulfonic acid anion bonded to a polymer backbone and a sulfonium cation having formula (1), has good CDU.

Japanese Patent Application No. 2022-169769 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a base polymer containing repeat units (a) having a salt structure containing a sulfonic acid anion bonded to a polymer backbone and a sulfonium cation having formula (1): 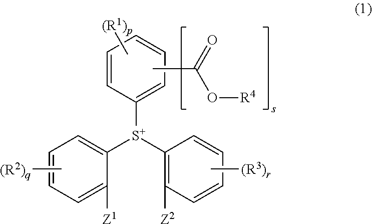
wherein p, q, and r are each independently an integer of 0 to 3, and s is 1 or 2, provided that 1≤r+s≤3,
R¹ is a halogen atom, a trifluoromethyl group, a trifluoromethoxy group, a trifluoromethylthio group, a nitro group, a cyano group, —C(═O)—R⁵, —O—C(═O)—R⁵, or —O—R⁵,
R² and R³ are each independently a halogen atom, a trifluoromethyl group, a trifluoromethoxy group, a trifluoromethylthio group, a nitro group, a cyano group, —C(═O)—O—R⁴, —C(═O)—R⁵—, —O—C(═O)—R⁵, —O—C(═O)—O—R⁵, or —O—R⁵,
R⁴ is a C₁-C₁₀ aliphatic hydrocarbyl group, a C₆-C₁₂ aryl group, or a C₄-C₁₂ heteroaryl group, some or all of hydrogen atoms of these groups may be substituted with a halogen atom other than an iodine atom, a hydroxy group, a cyano group, a nitro group, a halogenated alkyl group, a halogenated alkoxy group, or a halogenated alkylthio group, and some of —CH₂— of these groups may be substituted with an ether bond, an ester bond, a carbonyl group, or a sulfonic ester bond, provided that R⁴ is not an acid labile group,
R⁵ is a C₁-C₁₀ hydrocarbyl group, and
Z¹ and Z² are each independently a hydrogen atom, a halogen atom, a trifluoromethyl group, a trifluoromethoxy group, a trifluoromethylthio group, a nitro group, a cyano group, —C(═O)—O—R⁴, —C(═O)—R⁵, —O—C(═O)—R⁵, —O—C(═O)—O—R⁵, or —O—R⁵, and Z¹ and Z² may together form a single bond, an ether bond, a carbonyl group, —N(O)—, a sulfide bond, or a sulfonyl group, wherein R^{N} is a hydrogen atom or a C₁-C₆ saturated hydrocarbyl group.

2. The resist composition of claim 1, wherein the repeat units (a) have formula (a1) or (a2): 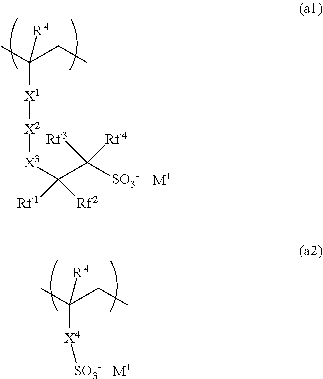
wherein R^{A} is each independently a hydrogen atom or a methyl group,
X¹ is a single bond or an ester bond,
X² is a single bond, —X²¹—C(═O)—O—, or —X²¹—O—, wherein X²¹ is a C₁-C₁₂ hydrocarbylene group, a phenylene group, or a C₇-C₁₈ group obtained by combining the foregoing, which may contain a carbonyl group, a nitro group, a cyano group, an ester bond, an ether bond, a urethane bond, a fluorine atom, an iodine atom, or a bromine atom,
X³ is a single bond, a methylene group, or an ethylene group,
X⁴ is a single bond, a methylene group, an ethylene group, a phenylene group, a methylphenylene group, a dimethylphenylene group, a fluorinated phenylene group, a trifluoromethyl-substituted phenylene group, —O—X⁴¹—, —C(═O)—O—X¹—, or —C(═O)—NH—X⁴¹—, wherein X⁴¹ is a C₁-C₆ aliphatic hydrocarbylene group, a phenylene group, a methylphenylene group, a dimethyiphenylene group, a fluorinated phenylene group, or a trifluoromethyl-substituted phenylene group, which may contain a carbonyl group, an ester bond, an ether bond, a hydroxy group, or a halogen atom,
R^{f1} to R^{f4} are each independently a hydrogen atom, a fluorine atom, or a trifluoromethyl group, at least one of R^{f} to Rf⁴ is a fluorine atom or a trifluoromethyl group, and R^{f1} and R^{f2} may together form a carbonyl group, and
M⁺ is the sulfonium cation having formula (1).

3. The resist composition of claim 1, wherein the base polymer further contains repeat units having formula (b1) or repeat units having formula (b2): 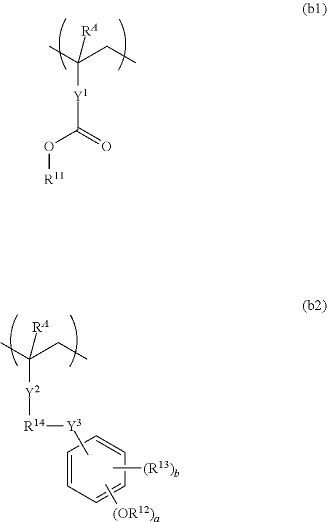
wherein R^{A} is each independently a hydrogen atom or a methyl group,
Y¹ is a single bond, a phenylene group, a naphthylene group, or a C₁-C₁₂ linking group containing at least one moiety selected from an ester bond, an ether bond, and a lactone ring,
Y² is a single bond or an ester bond,
Y³ is a single bond, an ether bond, or an ester bond,
R¹¹ and R¹² are each independently an acid labile group,
R¹³ is a fluorine atom, a trifluoromethyl group, a cyano group, a C₁-C₆ saturated hydrocarbyl group, a C₁-C₆ saturated hydrocarbyloxy group, a C₂-C₇ saturated hydrocarbylcarbonyl group, a C₂-C₇ saturated hydrocarbylcarbonyloxy group, or a C₂-C₇ saturated hydrocarbyloxycarbonyl group,
R¹⁴ is a single bond or a C₁-C₆ alkanediyl group in which some constituent —CH₂— may be substituted with an ether bond or an ester bond, and
a is 1 or 2, and b is an integer of 0 to 4, provided that 1 s a+b s 5.

4. The resist composition of claim 3, which is a chemically amplified positive resist composition.

5. The resist composition of claim 1, further comprising an organic solvent.

6. The resist composition of claim 1, further comprising a surfactant.

7. A pattern forming process comprising the steps of:
applying the resist composition of claim 1 onto a substrate to form a resist film thereon,
exposing the resist film to high-energy radiation, and
developing the exposed resist film in a developer.

8. The pattern forming process of claim 7, wherein the high-energy radiation is KrF excimer laser, ArF excimer laser, electron beam, or extreme ultraviolet having a wavelength of 3 to 15 nm.
